(19) United States
(12) Patent Application Publication
(10) Pub. No.: US 2026/0370063 A1
(43) Pub. Date: Nov. 19, 2026

(54) SPACE-BASED ENERGY SYSTEM AND METHODOLOGIES

(71) Applicant: Aetherflux, Inc., Capitola, CA (US)

(72) Inventors: Baiju Bhatt, Half Moon Bay, CA (US); Andrew Yarmola, West Hartford, CT (US); Kevin Pounds, Hillsboro, OR (US); William B. Simpson, Danville, CA (US); Peter K. Kiernan, Palo Alto, CA (US)

(21) Appl. No.: 19/228,626

(22) Filed: Jun. 4, 2025

Related U.S. Application Data
(60) Provisional application No. 63/656,514, filed on Jun. 5, 2024.
(60) Provisional application No. 63/726,080, filed on Nov. 27, 2024.
(60) Provisional application No. 63/779,676, filed on Mar. 28, 2025.
(60) Provisional application No. 63/779,641, filed on Mar. 28, 2025.
(60) Provisional application No. 63/779,938, filed on Mar. 28, 2025.

(51) Int. Cl. H02J 50/90; B60L 8/00; B60L 53/37; B64G 1/42; H02J 50/80; H02S 50/00

(52) U.S. Cl. CPC H02J 50/90; B60L 8/003; B60L 53/37; B64G 1/4282; H02J 50/80; H02S 50/00

(57) ABSTRACT

A method, computer program product, and computing system for: enabling an electromagnetic radiation energy receiver on a terrestrial vehicle; providing a celestial energy beam from an electromagnetic radiation energy source toward the electromagnetic radiation energy receiver; providing alignment feedback to the electromagnetic radiation energy source via one or more feedback devices included within the electromagnetic radiation energy receiver; and performing an initial alignment procedure based upon the alignment feedback received from the electromagnetic radiation energy receiver to initially align the celestial energy beam with the electromagnetic radiation energy receiver on the terrestrial vehicle.

### PRIORITY APPLICATION

This application claims the benefit of U.S. Provisional Application No. 63/656,514, filed on 5 Jun. 2024; U.S. Provisional Application No. 63/726,080, filed on 27 Nov. 2024; and U.S. Provisional Application Nos. 63/779,676, 63/779,641, and 63/779,938, all filed on 28 Mar. 2025, their entire contents of which are herein incorporated by reference.

### TECHNICAL FIELD

This disclosure relates to space-based energy systems and, more particularly, to systems and methods that gather energy in space and provide this gathered energy to other locations.

### BACKGROUND

The history of space-based solar power traces its roots to the mid-20th century, a time when the potential of space exploration was first being realized and the growing energy needs of Earth were becoming more apparent. While solar power had already been harnessed on Earth in the form of photovoltaic panels, the idea of collecting solar energy in space stemmed from the unique advantages that the vacuum of space provided: a constant, uninterrupted supply of sunlight and no atmospheric interference. In theory, this would allow for a much more efficient method of energy collection compared to terrestrial solar power systems, which are hindered by weather, the day-night cycle, and geographic location.

The key breakthrough came in 1968 when Peter Glaser, a NASA scientist and engineer, published a paper that proposed the idea of space-based solar power. Glaser's vision included large solar arrays placed in geostationary orbit, about 35,786 kilometers (22,236 miles) above Earth, where they would be exposed to constant sunlight. These arrays would convert solar energy into microwaves or lasers and beam the power back to Earth using a giant, ground-based receiver. Glaser's paper was groundbreaking and sparked interest in the concept, with various government agencies and research institutions beginning to explore the feasibility of such a system.

In the 1970s, research on space-based solar power gained momentum, with NASA conducting feasibility studies. However, while the idea appeared promising, the technology and infrastructure needed to realize it were far beyond the capabilities of the time. For instance, the launch costs associated with placing large solar arrays into orbit were astronomical. At that time, the cost of launching a single kilogram into low Earth orbit was around $50,000; numbers that made the practicality of space-based solar power seem distant. Additionally, the energy conversion and transmission systems needed to convert solar energy into microwaves and then beam it safely to Earth were not fully developed. The concept of sending large amounts of energy via microwaves raised potential safety and environmental concerns, particularly about the impact of such high-powered transmissions on living organisms and the atmosphere.

Despite these challenges, the potential of space-based solar power remained a subject of scientific curiosity, and in the decades that followed, smaller-scale studies and proposals continued. In the 1980s and 1990s, Japan, which had been a leader in space research and technology, made significant contributions to space-based solar power. In 1998, the Japan Aerospace Exploration Agency (JAXA) began researching the feasibility of using microwave transmission as part of their space-based solar power systems, and in 2009, Japan announced a project to build a prototype for a space-based solar power system by 2030. Japan's initiative sparked renewed interest in the concept, as it began to consider how space-based solar power could be a sustainable energy solution in the face of growing energy demands and the need for clean, renewable sources of power.

The 21st century has seen further advancements in space-based solar power research, particularly as the technological landscape has evolved. Advancements in solar cell efficiency, materials science, wireless energy transmission, and miniaturization of electronics have made the concept seem more feasible. The increasing cost-effectiveness of launching payloads into space, due to the rise of private companies like SpaceX, has also provided a glimmer of hope that space-based solar power may become economically viable in the near future. SpaceX, with its reusable Falcon rockets, has significantly lowered the cost of launching payloads into space, which could help reduce one of the most significant barriers to space-based solar power development: launch costs.

Several technological breakthroughs have also been explored in recent years. In particular, improvements in photovoltaic cells (solar panels) designed for space, such as more efficient and lightweight cells, could enable greater energy capture in orbit. Additionally, new methods of wireless power transmission, such as using highly directed microwave beams or lasers, have seen progress. For instance, researchers are exploring the use of beam-forming techniques that would allow energy to be transmitted more precisely, minimizing potential risks to Earth-based ecosystems. In 2015, researchers from the Japan-based project “Space Solar Power Transmission” successfully demonstrated the first small-scale transmission of energy via microwave, albeit at a very low power level, proving the basic concept's viability.

While the technological advancements are promising, the major hurdles to widespread adoption of space-based solar power remain. The most significant of these hurdles are the costs associated with building and maintaining the infrastructure, including launching massive arrays into space and constructing ground-based receivers that can safely collect the transmitted energy. The current cost of placing materials into space is still a barrier, although this cost is expected to continue to decrease as space technologies mature. Moreover, international cooperation and regulatory frameworks will likely play a critical role in the deployment of space-based solar power systems, given the global nature of energy distribution and the potential for geopolitical implications.

### Summary of Disclosure

### (16) Methodologies of Providing Power to Terrestrial Vehicle.

In one implementation, a computer-implemented method is executed on a computing device and includes: enabling an electromagnetic radiation energy receiver on a terrestrial vehicle; providing a celestial energy beam from an electromagnetic radiation energy source toward the electromagnetic radiation energy receiver; providing alignment feedback to the electromagnetic radiation energy source via one or more feedback devices included within the electromagnetic radiation energy receiver; and performing an initial alignment procedure based upon the alignment feedback received from the electromagnetic radiation energy receiver to initially align the celestial energy beam with the electromagnetic radiation energy receiver on the terrestrial vehicle.

One or more of the following features may be included. The one or more feedback devices included within the electromagnetic radiation energy receiver may include one or more of: a centrally-positioned feedback device within the electromagnetic radiation energy receiver; and a plurality of peripherally-positioned feedback devices within the electromagnetic radiation energy receiver. At least one of the feedback devices may be a retroreflector. Performing an initial alignment procedure based upon the alignment feedback received from the electromagnetic radiation energy receiver to initially align the celestial energy beam with the electromagnetic radiation energy receiver on the terrestrial vehicle may include: reducing the energy density of the celestial energy beam; aligning the celestial energy beam with the electromagnetic radiation energy receiver on the terrestrial vehicle; and increasing the energy density of the celestial energy beam. Reducing the energy density of the celestial energy beam may include one or more of: increasing the divergence of the celestial energy beam; and reducing the power of the celestial energy beam. Aligning the celestial energy beam with the electromagnetic radiation energy receiver on the terrestrial vehicle may include: initiating a location sweeping operation; receiving feedback from the electromagnetic radiation energy receiver at a defined point within the location sweeping operation; reinitiating the location sweeping operation at the defined point; and receiving updated feedback from the electromagnetic radiation energy receiver at an updated point within the location sweeping operation. Aligning the celestial energy beam with the electromagnetic radiation energy receiver on the terrestrial vehicle further may include: repeatedly reinitiating the location sweeping operation until feedback is received from the electromagnetic radiation energy receiver that identifies a point within the location sweeping operation that defines a peak return power, thus defining a location for the electromagnetic radiation energy receiver. Increasing the energy density of the celestial energy beam may include one or more of: decreasing the divergence of the celestial energy beam; and increasing the power of the celestial energy beam. The electromagnetic radiation energy source may include: a energy beam source; and a beam forming package. A realignment procedure may be periodically performed based upon alignment feedback received from the electromagnetic radiation energy receiver to realign the celestial energy beam with the electromagnetic radiation energy receiver to offset movement of the terrestrial vehicle.

In another implementation, a computer program product resides on a computer readable medium and has a plurality of instructions stored on it. When executed by a processor, the instructions cause the processor to perform operations including: enabling an electromagnetic radiation energy receiver on a terrestrial vehicle; providing a celestial energy beam from an electromagnetic radiation energy source toward the electromagnetic radiation energy receiver; providing alignment feedback to the electromagnetic radiation energy source via one or more feedback devices included within the electromagnetic radiation energy receiver; and performing an initial alignment procedure based upon the alignment feedback received from the electromagnetic radiation energy receiver to initially align the celestial energy beam with the electromagnetic radiation energy receiver on the terrestrial vehicle.

One or more of the following features may be included. The one or more feedback devices included within the electromagnetic radiation energy receiver may include one or more of: a centrally-positioned feedback device within the electromagnetic radiation energy receiver; and a plurality of peripherally-positioned feedback devices within the electromagnetic radiation energy receiver. At least one of the feedback devices may be a retroreflector. Performing an initial alignment procedure based upon the alignment feedback received from the electromagnetic radiation energy receiver to initially align the celestial energy beam with the electromagnetic radiation energy receiver on the terrestrial vehicle may include: reducing the energy density of the celestial energy beam; aligning the celestial energy beam with the electromagnetic radiation energy receiver on the terrestrial vehicle; and increasing the energy density of the celestial energy beam. Reducing the energy density of the celestial energy beam may include one or more of: increasing the divergence of the celestial energy beam; and reducing the power of the celestial energy beam. Aligning the celestial energy beam with the electromagnetic radiation energy receiver on the terrestrial vehicle may include: initiating a location sweeping operation; receiving feedback from the electromagnetic radiation energy receiver at a defined point within the location sweeping operation; reinitiating the location sweeping operation at the defined point; and receiving updated feedback from the electromagnetic radiation energy receiver at an updated point within the location sweeping operation. Aligning the celestial energy beam with the electromagnetic radiation energy receiver on the terrestrial vehicle further may include: repeatedly reinitiating the location sweeping operation until feedback is received from the electromagnetic radiation energy receiver that identifies a point within the location sweeping operation that defines a peak return power, thus defining a location for the electromagnetic radiation energy receiver. Increasing the energy density of the celestial energy beam may include one or more of: decreasing the divergence of the celestial energy beam; and increasing the power of the celestial energy beam. The electromagnetic radiation energy source may include: a energy beam source; and a beam forming package. A realignment procedure may be periodically performed based upon alignment feedback received from the electromagnetic radiation energy receiver to realign the celestial energy beam with the electromagnetic radiation energy receiver to offset movement of the terrestrial vehicle.

In another implementation, a computing system including a processor and memory is configured to perform operations including: enabling an electromagnetic radiation energy receiver on a terrestrial vehicle; providing a celestial energy beam from an electromagnetic radiation energy source toward the electromagnetic radiation energy receiver; providing alignment feedback to the electromagnetic radiation energy source via one or more feedback devices included within the electromagnetic radiation energy receiver; and performing an initial alignment procedure based upon the alignment feedback received from the electromagnetic radiation energy receiver to initially align the celestial energy beam with the electromagnetic radiation energy receiver on the terrestrial vehicle.

One or more of the following features may be included. The one or more feedback devices included within the electromagnetic radiation energy receiver may include one or more of: a centrally-positioned feedback device within the electromagnetic radiation energy receiver; and a plurality of peripherally-positioned feedback devices within the electromagnetic radiation energy receiver. At least one of the feedback devices may be a retroreflector. Performing an initial alignment procedure based upon the alignment feedback received from the electromagnetic radiation energy receiver to initially align the celestial energy beam with the electromagnetic radiation energy receiver on the terrestrial vehicle may include: reducing the energy density of the celestial energy beam; aligning the celestial energy beam with the electromagnetic radiation energy receiver on the terrestrial vehicle; and increasing the energy density of the celestial energy beam. Reducing the energy density of the celestial energy beam may include one or more of: increasing the divergence of the celestial energy beam; and reducing the power of the celestial energy beam. Aligning the celestial energy beam with the electromagnetic radiation energy receiver on the terrestrial vehicle may include: initiating a location sweeping operation; receiving feedback from the electromagnetic radiation energy receiver at a defined point within the location sweeping operation; reinitiating the location sweeping operation at the defined point; and receiving updated feedback from the electromagnetic radiation energy receiver at an updated point within the location sweeping operation. Aligning the celestial energy beam with the electromagnetic radiation energy receiver on the terrestrial vehicle further may include: repeatedly reinitiating the location sweeping operation until feedback is received from the electromagnetic radiation energy receiver that identifies a point within the location sweeping operation that defines a peak return power, thus defining a location for the electromagnetic radiation energy receiver. Increasing the energy density of the celestial energy beam may include one or more of: decreasing the divergence of the celestial energy beam; and increasing the power of the celestial energy beam. The electromagnetic radiation energy source may include: a energy beam source; and a beam forming package. A realignment procedure may be periodically performed based upon alignment feedback received from the electromagnetic radiation energy receiver to realign the celestial energy beam with the electromagnetic radiation energy receiver to offset movement of the terrestrial vehicle.

The details of one or more implementations are set forth in the accompanying drawings and the description below. Other features and advantages will become apparent from the description, the drawings, and the claims.

### BRIEF DESCRIPTION OF THE DRAWINGS

FIG. 1 is a diagrammatic view of a space-based energy system according to an implementation of the present disclosure;

FIG. 2 is a diagrammatic view of a solar energy gathering system of the space-based energy system of FIG. 1 according to an implementation of the present disclosure;

FIG. 3 is another diagrammatic view of the space-based energy system of FIG. 1 according to an implementation of the present disclosure;

FIG. 4 is a diagrammatic view of a waste heat dissipation system of the space-based energy system of FIG. 1 according to an implementation of the present disclosure;

FIG. 5 is a diagrammatic view of another waste heat dissipation system of the space-based energy system of FIG. 1 according to an implementation of the present disclosure;

FIG. 6 is a diagrammatic view of an electromagnetic radiation energy receiver of the space-based energy system of FIG. 1 according to an implementation of the present disclosure;

FIG. 7 is another diagrammatic view of the space-based energy system of FIG. 1 according to an implementation of the present disclosure;

FIG. 8 is another diagrammatic view of the space-based energy system of FIG. 1 according to an implementation of the present disclosure;

FIG. 9 is a diagrammatic view of a distributed computing network including a computing device that executes an energy acquisition and delivery process on the space-based energy system of FIG. 1 according to an implementation of the present disclosure;

FIG. 10 is a flowchart of another implementation of the energy acquisition and delivery process of FIG. 9 according to an implementation of the present disclosure;

FIG. 11 is a flowchart of another implementation of the energy acquisition and delivery process of FIG. 9 according to an implementation of the present disclosure;

FIG. 12 is a flowchart of another implementation of the energy acquisition and delivery process of FIG. 9 according to an implementation of the present disclosure;

FIG. 13 is a flowchart of another implementation of the energy acquisition and delivery process of FIG. 9 according to an implementation of the present disclosure;

FIG. 14 is a flowchart of another implementation of the energy acquisition and delivery process of FIG. 9 according to an implementation of the present disclosure;

FIG. 15 is a diagrammatic view of a sweeping operation executed by the energy acquisition and delivery process of FIG. 9 according to an implementation of the present disclosure;

FIG. 16 is a flowchart of another implementation of the energy acquisition and delivery process of FIG. 9 according to an implementation of the present disclosure;

FIG. 17 is a flowchart of another implementation of the energy acquisition and delivery process of FIG. 9 according to an implementation of the present disclosure;

FIGS. 18A-18B is a flowchart of another implementation of the energy acquisition and delivery process of FIG. 9 according to an implementation of the present disclosure;

FIGS. 19A-19B is a flowchart of another implementation of the energy acquisition and delivery process of FIG. 9 according to an implementation of the present disclosure;

FIGS. 20A-20B is a flowchart of another implementation of the energy acquisition and delivery process of FIG. 9 according to an implementation of the present disclosure;

FIGS. 21A-21B is a flowchart of another implementation of the energy acquisition and delivery process of FIG. 9 according to an implementation of the present disclosure;

FIG. 22 is a flowchart of another implementation of the energy acquisition and delivery process of FIG. 9 according to an implementation of the present disclosure;

FIG. 23 is a flowchart of another implementation of the energy acquisition and delivery process of FIG. 9 according to an implementation of the present disclosure;

FIG. 24 is a flowchart of another implementation of the energy acquisition and delivery process of FIG. 9 according to an implementation of the present disclosure;

FIGS. 25A-25B is a flowchart of another implementation of the energy acquisition and delivery process of FIG. 9 according to an implementation of the present disclosure;

FIGS. 26A-26B is a flowchart of another implementation of the energy acquisition and delivery process of FIG. 9 according to an implementation of the present disclosure;

FIG. 27 is a flowchart of another implementation of the energy acquisition and delivery process of FIG. 9 according to an implementation of the present disclosure;

FIG. 28 is a flowchart of another implementation of the energy acquisition and delivery process of FIG. 9 according to an implementation of the present disclosure;

FIG. 29 is a flowchart of another implementation of the energy acquisition and delivery process of FIG. 9 according to an implementation of the present disclosure;

FIG. 30 is a flowchart of another implementation of the energy acquisition and delivery process of FIG. 9 according to an implementation of the present disclosure;

FIGS. 31A-31B is a flowchart of another implementation of the energy acquisition and delivery process of FIG. 9 according to an implementation of the present disclosure;

FIGS. 32A-32C is a flowchart of another implementation of the energy acquisition and delivery process of FIG. 9 according to an implementation of the present disclosure;

FIGS. 33A-33C is a flowchart of another implementation of the energy acquisition and delivery process of FIG. 9 according to an implementation of the present disclosure;

FIG. 34 is a flowchart of another implementation of the energy acquisition and delivery process of FIG. 9 according to an implementation of the present disclosure;

FIG. 35 is a flowchart of another implementation of the energy acquisition and delivery process of FIG. 9 according to an implementation of the present disclosure;

FIG. 36 is a diagrammatic view of a sweeping operation executed by the energy acquisition and delivery process of FIG. 9 according to an implementation of the present disclosure;

FIG. 37 is a flowchart of another implementation of the energy acquisition and delivery process of FIG. 9 according to an implementation of the present disclosure; and

FIG. 38 is a diagrammatic view of an alignment operation executed by the energy acquisition and delivery process of FIG. 9 according to an implementation of the present disclosure.

Like reference symbols in the various drawings indicate like elements.

### DETAILED DESCRIPTION OF THE PREFERRED EMBODIMENTS

### Space-Based Energy System:

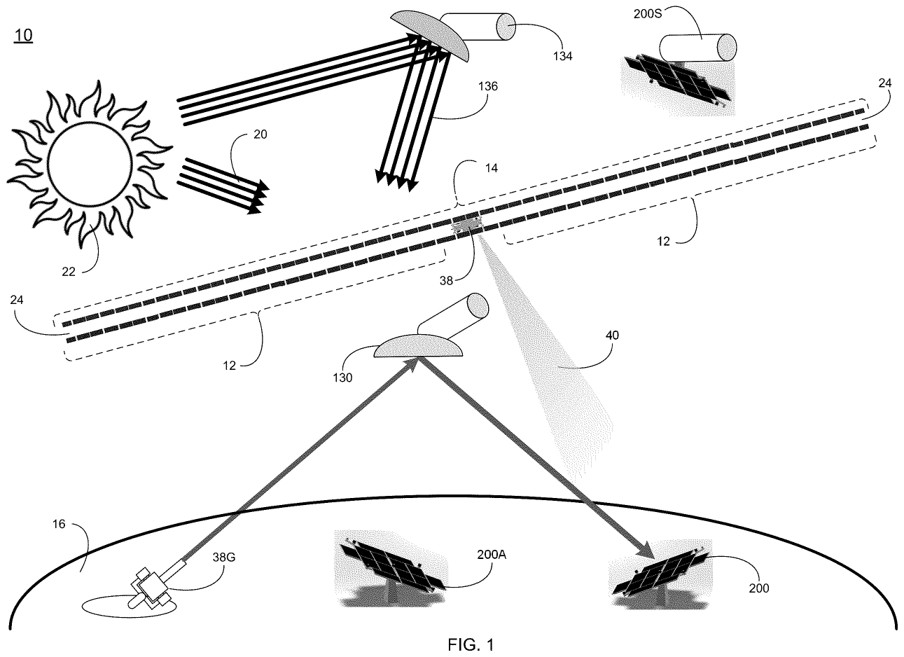

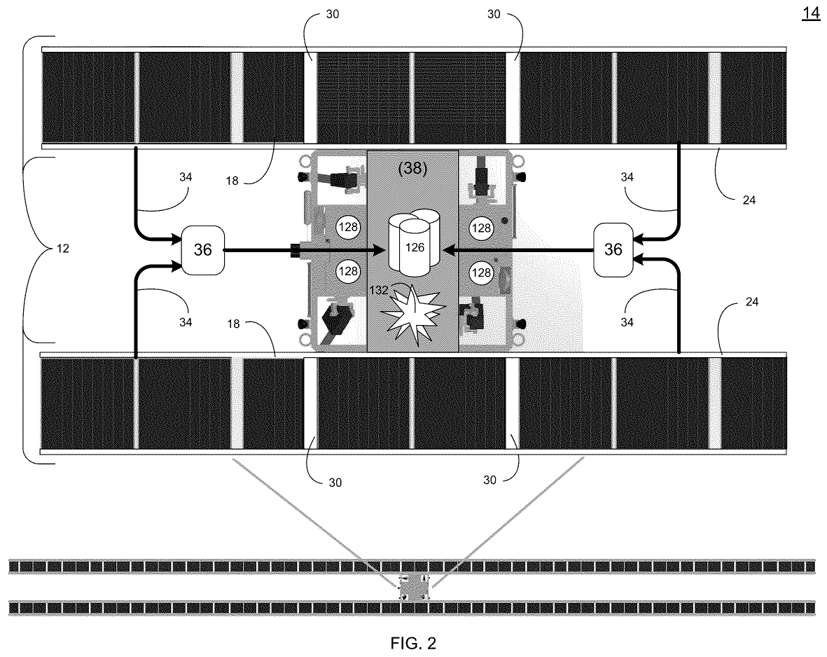

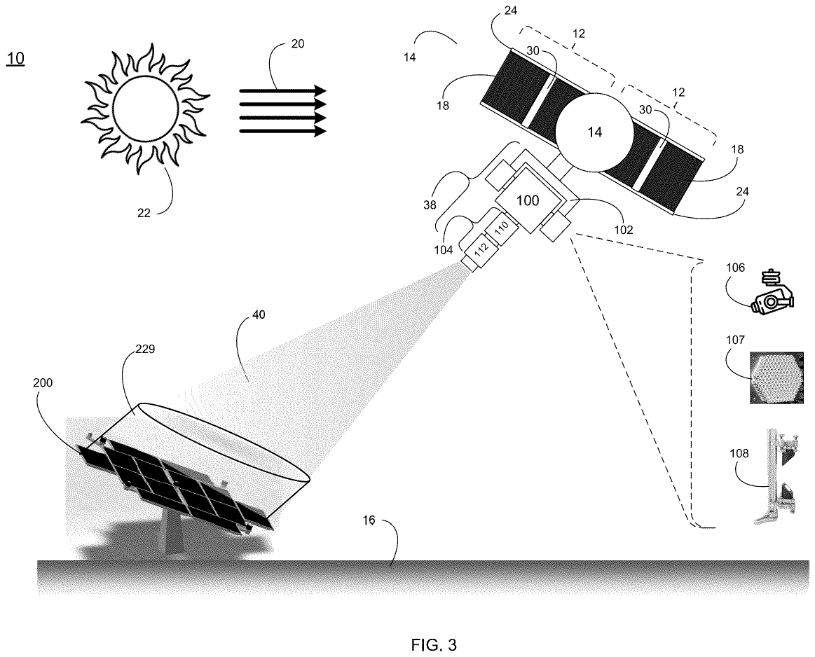

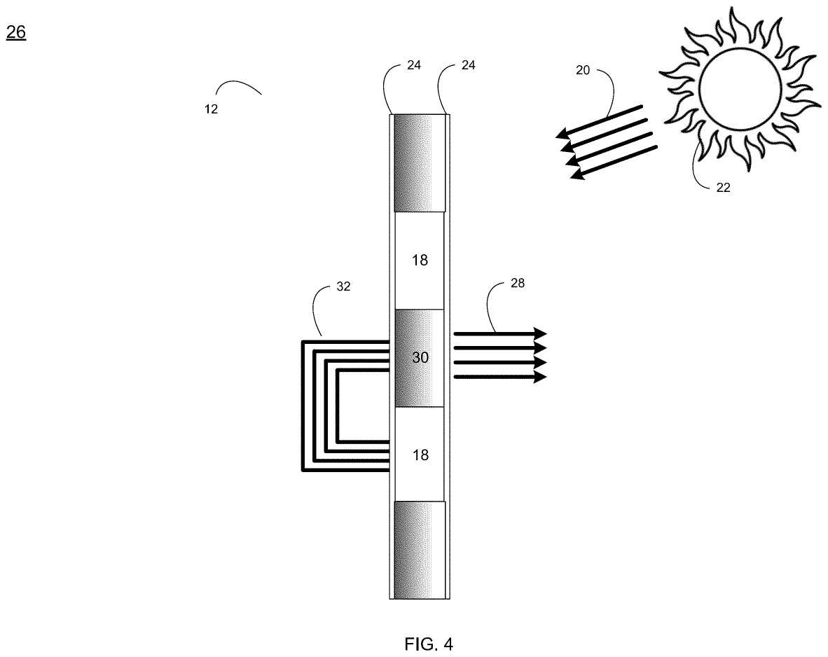

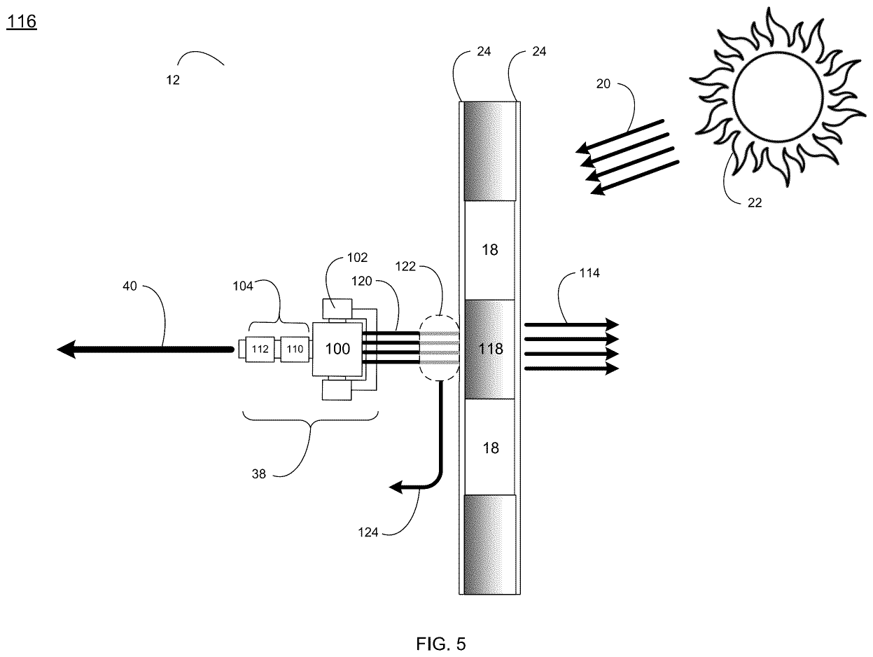

Referring to FIGS. 1-5, there is shown a space-based energy system (e.g., space-based energy system 10). As will be discussed below in greater detail, the space-based energy system (e.g., space-based energy system 10) may be configured to gather solar energy in outer space through the use of various orbiting satellites. This gathered solar energy may then be used to form a celestial energy beam that is directed toward a distal target (e.g., earth-based receivers, planetary receivers, terrestrial vehicles, space-based vehicles, etc.), thus enabling the efficient collection and distribution of solar energy in a manner that reduces the complications associated with atmospheric interference, day/night light cycles, geographic location, inclement weather, etc.

### Space-Based Energy Gathering Subsystem:

The space-based energy system (e.g., space-based energy system 10) may include a solar energy gathering system (e.g., solar energy gathering system 12). As will be discussed below in greater detail, the solar energy gathering system (e.g., solar energy gathering system 12) is the portion of the space-based energy system (e.g., space-based energy system 10) that will gather solar energy and convert the same to useable electrical power.

The solar energy gathering system (e.g., solar energy gathering system 12) may be a portion of a satellite (e.g., satellite 14) that is orbiting (in this example) the earth (e.g., earth 16). The solar energy gathering system (e.g., solar energy gathering system 12) may include one or more energy gathering devices (e.g., energy gathering devices 18). These energy gathering devices (e.g., energy gathering devices 18) may be configured to gather light-based energy, an example of which may include but is not limited to solar energy (e.g., solar energy 20) that is provided by the sun (e.g., sun 22).

As is known in the art, solar energy (e.g., solar energy 20) is the energy that is harnessed from the radiation of the sun (e.g., sun 22). Solar energy is a renewable and clean source of energy that can be captured and converted into usable forms, such as electricity or heat. The most common methods of capturing solar energy are through the use of photovoltaic solar panels (which convert sunlight directly into electricity) and solar thermal systems (which use mirrors or lenses to focus sunlight and produce heat that can be used for heating water or generating electricity).

The energy gathering devices (e.g., energy gathering devices 18) included within solar energy gathering system (e.g., solar energy gathering system 12) may include one or more of: one or more photovoltaic cells; one or more photodiodes; one or more heat engines; and one or more rectenna arrays.

Photovoltaic cells, also known as solar cells, are devices that convert light directly into electricity through the photovoltaic effect. When photons enter the cell, which are typically made from semiconductor materials like silicon, they transfer their energy to electrons, knocking them loose from atoms. This creates an electric current as the freed electrons are directed through an external circuit. Photovoltaic cells are commonly used in solar panels to generate power from sunlight, but they can also be designed to respond to specific wavelengths, such as those emitted by lasers, making them useful for applications like wireless power transfer or space-based energy systems. Their efficiency depends on the material, light intensity, and spectral match between the light source and the cell.

Photodiodes are semiconductor devices that convert light into an electrical current, but unlike photovoltaic cells, they are primarily used as light sensors rather than power generators. When photons hit the photodiode's active region, they generate electron-hole pairs that produce a current proportional to the light intensity. Photodiodes operate quickly and with high sensitivity, making them ideal for detecting modulated light signals in applications such as optical communication, laser detection, and imaging systems. Some specialized photodiodes are optimized for specific wavelengths, including Infrared or ultraviolet light, depending on the application.

Heat engines are devices that convert heat energy into useful work. For example, such heat engines may be mechanical or solid-state in nature. Solid-state heat engines such as thermoelectric generators (TEGs) convert heat into electricity using the Seebeck effect, wherein a voltage is generated across two different conductors or semiconductors when there is a temperature difference between them. As heat flows from the hot side to the cold side, charge carriers in the material move, producing a current. TEGs have no moving parts and can operate in harsh environments, making them useful in remote or space-based applications where maintenance is difficult. They are often used in spacecraft, wearable devices, or industrial waste-heat recovery systems. However, their conversion efficiency is generally lower than that of photovoltaic or rectenna systems.

Rectennas, short for rectifying antennas, are devices that convert electromagnetic energy—such as microwaves or radio waves—into direct current (DC) electricity. They consist of an antenna that captures incoming electromagnetic waves and a rectifying circuit, usually containing high-speed diodes, that converts the alternating current (AC) signal into DC power. Rectennas are particularly useful in wireless power transmission systems, such as microwave-based space solar power, where energy is beamed from a satellite to a ground station. When arranged in large arrays, rectennas can collect significant amounts of power over wide areas. Their design can be tuned for different frequencies, and they offer high efficiency when matched well to the transmission system.

The solar energy gathering system (e.g., solar energy gathering system 12) may include: a deployable structure assembly (e.g., deployable structure assembly 24) for deploying the one or more energy gathering devices (e.g., energy gathering devices 18) in a modular configuration. This deployable structure assembly (e.g., deployable structure assembly 24) may be an essential technology used on satellites to deploy the energy-gathering devices (e.g., energy gathering devices 18) in space. Due to the limited space available during launch, these deployable structure assemblies (e.g., deployable structure assembly 24) are designed to be compact and stowed in a folded or rolled form. Once the satellite reaches its designated orbit, the deployable structure assembly (e.g., deployable structure assembly 24) unfolds or expands using mechanisms like spring-loaded systems, motors, or pneumatic actuators. This deployment allows the energy-gathering devices (e.g., energy gathering devices 18) to extend and maximize the surface area needed for efficient energy collection.

During use, the one or more energy gathering devices (e.g., energy gathering devices 18) of the solar energy gathering system (e.g., solar energy gathering system 12) may generate heat.

Generally speaking, energy-gathering devices (e.g., energy gathering devices 18) become hot during operation because a significant portion of the sunlight they absorb is not converted into electricity but instead turns into heat. Most energy-gathering devices (e.g., energy gathering devices 18) are only 15-35% efficient, meaning that the majority of the incoming solar energy is reflected or lost as heat due to the inherent inefficiency of the conversion process. Additionally, sunlight contains Infrared radiation, which carries thermal energy that is absorbed by the solar panel materials and contributes to the rise in temperature. Another source of heat is electrical resistance within the wiring and circuits of the energy-gathering devices (e.g., energy gathering devices 18), wherein some energy is inevitably lost as heat as current flows through conductive materials. Furthermore, a process known as thermalization occurs when high-energy photons strike the panel; if the energy of the photon exceeds what is needed to move an electron across the material's bandgap, the excess energy is dissipated as heat. In space where there is no atmosphere to conduct or convect heat away, managing this heat buildup becomes especially challenging. Accordingly and without proper thermal control, overheating can reduce the efficiency of energy conversion and accelerate the degradation of materials.

Accordingly, the solar energy gathering system (e.g., solar energy gathering system 12) may include a waste heat dissipation system (e.g., waste heat dissipation system 26) for removing waste heat (e.g., waste heat 28) from the solar energy gathering system (e.g., solar energy gathering system 12).

The waste heat dissipation system (e.g., waste heat dissipation system 26) for removing waste heat (e.g., waste heat 28) from the solar energy gathering system (e.g., solar energy gathering system 12) may include: a thermal radiator (e.g., thermal radiator 30) for dissipating the waste heat (e.g., waste heat 28) and a heat transfer system (e.g., heat transfer system 32) for transferring the waste heat (e.g., waste heat 28) from a heat source (e.g., energy gathering devices 18) to the thermal radiator (e.g., thermal radiator 30).

This waste heat dissipation system (e.g., waste heat dissipation system 26) for removing waste heat (e.g., waste heat 28) from the solar energy gathering system (e.g., solar energy gathering system 12) may be essential for managing the excess heat generated by the energy-gathering devices (e.g., energy gathering devices 18) on the satellite (e.g., satellite 14). As these devices (e.g., energy gathering devices 18) absorb sunlight (e.g., solar energy 20) and convert it into electricity, a significant amount of energy is lost as waste heat (e.g., waste heat 28), which must be efficiently removed to maintain performance and prevent overheating.

The heat transfer system (e.g., heat transfer system 32) may be configured to collect and transfer the waste heat (e.g., waste heat 28) from a heat source (e.g., energy gathering devices 18) to the thermal radiator (e.g., thermal radiator 30), which is configured for dissipating the waste heat (e.g., waste heat 28). This transfer is often achieved using thermal conductors like heat pipe systems or coolant circulation systems, which efficiently carry the waste heat (e.g., waste heat 28) away from the energy-gathering devices (e.g., energy gathering devices 18).

Heat pipe systems, for example, are sealed tubes containing a fluid that evaporates at the hot end, carrying waste heat (e.g., waste heat 28) to a cooler section where the fluid condenses and releases the waste heat (e.g., waste heat 28). Coolant circulation systems circulate a coolant that absorbs the waste heat (e.g., waste heat 28) from the energy-gathering devices (e.g., energy gathering devices 18) and transfers the same to the thermal radiator (e.g., thermal radiator 30).

Once the waste heat (e.g., waste heat 28) is transferred to the thermal radiator (e.g., thermal radiator 30), thermal radiator 30 (e.g., a large surface area panel mounted on satellite 14), radiates the waste heat (e.g., waste heat 28) into space, where there is no atmosphere to absorb it. The radiator is usually made of materials with high thermal conductivity and emissivity, ensuring that it can efficiently release the waste heat (e.g., waste heat 28) into the cold vacuum of space. Accordingly, the waste heat dissipation system (e.g., waste heat dissipation system 26) helps keep the internal components of the satellite (e.g., satellite 14) within the required temperature range, thus preventing performance degradation, ensuring the longevity of the satellite (e.g., satellite 14), and allowing it to operate effectively in the harsh environment of space.

The thermal radiator (e.g., thermal radiator 30) may include one or more of: a fixed surface radiator; a deployable radiator; a heat pipe radiator; a loop heat pipe/capillary pumped loop system; a variable emittance radiator; and a phase change material (PCM) radiator. Thermal radiators (e.g., thermal radiator 30) are crucial components of a thermal management system of a satellite (e.g., satellite 14), as they help dissipate excess heat (e.g., waste heat 28) generated by onboard systems, including the energy-gathering devices (e.g., energy gathering devices 18). Different types of thermal radiators (e.g., thermal radiator 30) are used in space depending on the mission requirements, available space, and heat dissipation needs. Below is an explanation of each type of thermal radiator:
A fixed surface radiator is a simple and reliable thermal management solution commonly used in satellite design. It consists of a flat or slightly curved surface mounted on the satellite (e.g., satellite 14) and designed to radiate heat into space. This type of radiator is permanently attached and does not change position during the satellite's operation. The surface is typically made of materials with high thermal conductivity and emissivity, such as aluminum or graphite, to efficiently release the absorbed heat (e.g., waste heat 28). Although effective in many situations, fixed surface radiators can be limited by the available surface area and may not be ideal for missions requiring large heat dissipation capacities or those with varying thermal loads.
A deployable radiator is designed to be compact during launch and then extended once the satellite (e.g., satellite 14) is in orbit. The radiator is folded or stowed in a compact form to minimize space during launch, and after deployment, it unfolds or expands to provide a larger surface area for heat dissipation. This type of radiator is often used on satellites with tight launch constraints but requiring substantial heat dissipation. Deployable radiators can be folded like an accordion, rolled, or deployed in various ways, depending on the design. They are particularly useful for missions where the satellite (e.g., satellite 14) needs to conserve space during launch but still requires the ability to dissipate large amounts of heat once in orbit.
A heat pipe radiator integrates heat pipes into the radiator structure to enhance heat transfer. Heat pipes are sealed tubes containing a working fluid that evaporates at the hot end (near the heat source, such as energy gathering devices 18) and condenses at the cold end (near thermal radiator 30). This allows for efficient heat transport without relying on convection, which is not possible in space. The heat pipe transfers heat to the radiator surface, where it can then be radiated into space. Heat pipe radiators are often used when there is a need to move heat over a distance within the satellite before dissipating it, or when the heat source is located away from the radiator itself.
The Loop Heat Pipe (LHP) and Capillary Pumped Loop (CPL) are advanced thermal management systems that are designed to transport heat with high efficiency over long distances or from multiple heat sources to a single radiator. These systems rely on capillary action (the movement of a fluid through a porous medium without external forces) to circulate a working fluid. In an LHP or CPL system, heat (e.g., waste heat 28) from the satellite's components (e.g., energy gathering devices 18) is absorbed by an evaporator, where the working fluid evaporates. The vapor then travels through a loop or capillary network to a condenser, where it releases the heat to the radiator. This type of system is often used in satellites with high thermal demands, as it provides a highly efficient and flexible means of heat transport and dissipation. LHPs and CPLs are particularly effective in maintaining uniform temperatures across large or complex systems.
A variable emittance radiator adjusts its heat dissipation capabilities based on temperature or other environmental factors. This type of radiator can change the emissivity (the ability to emit heat) of its surface, allowing it to regulate heat flow in response to varying thermal loads. For example, in response to increased temperature, a variable emittance radiator may increase its surface emissivity to radiate more heat, or it may reduce emissivity in cooler conditions to conserve heat. This adaptive feature is typically achieved through the use of special coatings or materials that can alter their emissivity based on external conditions such as temperature or voltage. Variable emittance radiators are particularly useful in missions where thermal conditions fluctuate significantly, as they provide more precise thermal control and can help improve efficiency and extend the life of the satellite.
A Phase Change Material (PCM) radiator uses materials that absorb and release heat (e.g., waste heat 28) by changing phase, typically from solid to liquid or liquid to gas. These materials, such as certain waxes or salts, have a high heat capacity, meaning they can absorb a large amount of heat as they transition from one phase to another. In a PCM radiator system, the phase change material is integrated into the radiator structure. As the satellite absorbs heat, the PCM melts or vaporizes, absorbing the excess heat and preventing the temperature of the satellite (e.g., satellite 14) from rising too quickly. Once the satellite is in the shadow of the Earth or experiences cooler conditions, the material solidifies or condenses, releasing the stored heat. PCM radiators are beneficial for missions where the satellite needs to handle fluctuating or intermittent heat loads, as they can smooth out temperature variations and provide temporary thermal storage.

Each of these thermal radiators (e.g., thermal radiator 30) plays a specific role in managing the temperature of satellites (e.g., satellite 14) in space. Fixed surface radiators are simple and efficient but lack flexibility, while deployable radiators allow for space-efficient heat dissipation after launch. Heat pipe radiators and advanced systems like Loop Heat Pipes or Capillary Pumped Loops offer efficient long-distance heat transport. Variable emittance radiators provide adaptive temperature control, and PCM radiators use phase change materials to store and release heat, offering unique solutions for fluctuating thermal conditions. The selection of a thermal radiator depends on the satellite's mission requirements, including heat dissipation capacity, space constraints, and the expected thermal environment in orbit.

The thermal radiator (e.g., thermal radiator 30) may be mounted to the deployable structure assembly (e.g., deployable structure assembly 24) and/or deployed from the deployable structure assembly (e.g., deployable structure assembly 24). Accordingly and if the thermal radiator (e.g., thermal radiator 30) is a fixed size (i.e., non-deployable) thermal radiator, thermal radiator 30 may be attached to the deployable structure assembly (e.g., deployable structure assembly 24) and interspersed with the energy-gathering devices (e.g., energy gathering devices 18). Additionally/alternatively and if the thermal radiator (e.g., thermal radiator 30) is a deployable thermal radiator, the thermal radiator may be attached to the deployable structure assembly (e.g., deployable structure assembly 24), wherein the deployable thermal radiator may be deployed once the deployable structure assembly 24 is fully deployed.

Accordingly and once fully deployed, the solar energy gathering system (e.g., solar energy gathering system 12) may be configured to gather solar energy (e.g., solar energy 20) on the one or more energy gathering devices (e.g., energy gathering devices 18) and generate gathered electrical energy (e.g., gathered electrical energy 34).

The solar energy gathering system (e.g., solar energy gathering system 12) may include an electrical coupling system (e.g., electrical coupling system 36) configured to electrically couple the solar energy gathering system (e.g., solar energy gathering system 12) to an electromagnetic radiation energy source (e.g., electromagnetic radiation energy source 38) and enable the transfer of the gathered electrical energy (e.g., gathered electrical energy 34) to the electromagnetic radiation energy source (e.g., electromagnetic radiation energy source 38), which will be discussed below in greater detail.

An electrical coupling system (e.g., electrical coupling system 36) plays an important role in linking the solar energy gathering system (e.g., solar energy gathering system 12) to the electromagnetic radiation energy source (e.g., electromagnetic radiation energy source 38) that generates a celestial energy beam (e.g., celestial energy beam 40), such as a microwave beam or laser beam. These coupling systems (e.g., electrical coupling system 36) ensure that the electrical power (e.g., gathered electrical energy 34) harvested by the energy gathering devices (e.g., energy gathering devices 18) is properly managed, conditioned, and delivered to the electromagnetic radiation energy source (e.g., electromagnetic radiation energy source 38) for efficient transmission of energy (e.g., celestial energy beam 40).

One common example of such an electrical coupling system (e.g., electrical coupling system 36) is a Power Conditioning and Distribution Unit (PCDU), which stabilizes the variable output from the energy gathering devices (e.g., energy gathering devices 18) and regulates the flow of power to the electromagnetic radiation energy source (e.g., electromagnetic radiation energy source 38), ensuring consistent operation and system protection. In cases where the voltage or current levels from the energy gathering devices (e.g., energy gathering devices 18) do not match the requirements of the electromagnetic radiation energy source (e.g., electromagnetic radiation energy source 38), electrical coupling system (e.g., electrical coupling system 36) may include a high-efficiency DC-DC converters to step the voltage up or down, often incorporating isolation features and protective circuitry. For microwave-based energy transmission, electrical coupling system (e.g., electrical coupling system 36) may include Solid-State Power Amplifier (SSPA) interfaces to convert the DC electrical power (e.g., gathered electrical energy 34) into high-frequency radio signals, using voltage regulation and advanced switching systems to efficiently power devices like magnetrons or klystrons. In laser-based systems, electrical coupling system (e.g., electrical coupling system 36) may include laser driver modules to serve as the coupling mechanism, providing precision control over the current and voltage supplied to laser diode arrays, often using pulse-width modulation and thermal management to maintain performance. In some designs, electrical coupling system (e.g., electrical coupling system 36) may include energy storage elements (e.g., batteries and/or supercapacitors) to buffer and regulate energy delivery, particularly for pulsed laser beams that require short bursts of high power. Electrical coupling system (e.g., electrical coupling system 36) may include photonic power conversion, where electrical energy from the energy gathering devices (e.g., energy gathering devices 18) may be converted into laser light via fiber-coupled laser modules, allowing for high-efficiency energy transmission across long distances.

One or all of these electrical coupling systems (e.g., electrical coupling system 36) may ensure that energy (e.g., gathered electrical energy 34) collected in space is efficiently and reliably routed to the appropriate beaming technology, enabling effective wireless power transfer.

### Space-Based Energy Transmission Subsystem:

The space-based energy system (e.g., space-based energy system 10) may include an electromagnetic radiation energy source (e.g., electromagnetic radiation energy source 38) configured to receive the gathered electrical energy (e.g., gathered electrical energy 34) and generate a celestial energy beam (e.g., celestial energy beam 40) from at least a portion of the gathered electrical energy (e.g., gathered electrical energy 34). The electromagnetic radiation energy source (e.g., electromagnetic radiation energy source 38) may be a portion of a satellite (e.g., satellite 14) that is orbiting (in this example) the earth (e.g., earth 16). The gathered electrical energy (e.g., gathered electrical energy 34) may be provided from the solar energy gathering system (e.g., solar energy gathering system 12) to the electromagnetic radiation energy source (e.g., electromagnetic radiation energy source 38) via the above-described electrical coupling system (e.g., electrical coupling system 36).

The electromagnetic radiation energy source (e.g., electromagnetic radiation energy source 38) may include: an energy beam source (e.g., energy beam source 100) for generating the celestial energy beam (e.g., celestial energy beam 40); a beam aiming assembly (e.g., beam aiming assembly 102) for steering the celestial energy beam (e.g., celestial energy beam 40) toward a target; and a beam forming package (e.g., beam forming package 104) for forming the celestial energy beam (e.g., celestial energy beam 40).

The energy beam source (e.g., energy beam source 100) for generating the celestial energy beam (e.g., celestial energy beam 40) may include one or more of: a visible-light laser beam source; an Infrared laser beam source; a short wavelength Infrared laser beam source, a mid-Infrared laser beam source; a near-Infrared laser beam source; and a microwave beam source, each of which is describe below in greater detail:
A Visible-Light laser beam source is a device that emits a focused, coherent beam within the 400-700 nm range, which the human eye can see. Common types include diode lasers (used in pointers, scanners, and electronics), DPSS lasers (which convert infrared to visible light, often green), and gas lasers like helium-neon (He—Ne), which produce stable red beams for labs and education. Dye lasers are tunable across the visible spectrum but mainly used in research, while frequency-converted fiber lasers offer high power and precision. These sources are widely used in medicine, industry, communications, and scientific applications due to their intensity, accuracy, and wavelength control
An Infrared laser beam source is a device that emits coherent light in the Infrared (IR) portion of the electromagnetic spectrum, typically with wavelengths ranging from 700 nanometers (nm) to 1 millimeter (mm). These wavelengths are longer than visible light and are not detectable by the human eye. Infrared lasers are used for a wide range of applications, including communication, sensing, and energy transmission. In the context of space-based solar power, Infrared lasers can be used to transmit energy collected from solar arrays in space down to Earth-based receivers, where it is converted back into electrical power. Their relatively low atmospheric absorption and ability to focus energy make them suitable for long-distance, line-of-sight energy beaming.
A near-Infrared (NIR) laser beam source specifically emits laser light in the near-Infrared portion of the spectrum, typically between 700 nm and 1400 nm. This is the closest band to the visible spectrum, and it retains many of the advantageous properties of laser light, including coherence, monochromaticity, and directionality. NIR lasers are especially favored for space-to-Earth power beaming due to their balance between atmospheric transmission efficiency and the availability of photovoltaic materials (such as gallium arsenide or indium gallium arsenide) that can effectively convert NIR light into electricity. NIR beams can penetrate the Earth's atmosphere relatively well, allowing for efficient and relatively safe energy transmission when appropriately directed and controlled.
A microwave beam source generates and emits electromagnetic radiation in the microwave frequency range, typically from 300 megahertz (MHz) to 300 gigahertz (GHz), corresponding to wavelengths between 1 millimeter and 1 meter. In wireless power transmission, a microwave source (often a magnetron, klystron, or solid-state amplifier) converts electrical energy into microwave radiation, which is then directed as a focused beam to a receiving station, typically equipped with a rectifying antenna (rectenna). Microwaves are particularly useful for energy beaming over long distances because they can travel through the Earth's atmosphere with relatively low attenuation, even through clouds and rain. Due to their longer wavelength, microwave beams are less precise than laser beams but are considered safer and easier to manage over wide areas.

These three different types of energy beam sources (e.g., energy beam source 100) offer different trade-offs in terms of efficiency, beam control, atmospheric penetration, and safety; wherein the choice of source depends on mission requirements, technological constraints, and environmental considerations.

An energy beam source (e.g., energy beam source 100) designed to generate Infrared laser beams, near-Infrared laser beams, or microwave beams may contain several key hardware components that work together to produce, shape, and direct electromagnetic energy.

For Infrared and near-Infrared laser beams, the energy beam source (e.g., energy beam source 100) may include a gain medium, such as a CO₂ gas for far-Infrared beams or a solid-state crystal like Nd:YAG or Yb:YAG for near-Infrared output. The gain medium is energized by a pump source, such as a diode laser, flashlamp, or electrical excitation system. The light is amplified within an optical resonator, typically consisting of two mirrors that allow light to bounce back and forth until a coherent laser beam is emitted through a partially reflective output mirror. The system is powered and regulated by control electronics, which manage output power, pulse timing, and thermal safety.

In contrast, microwave beam sources use different technologies but share the need for efficient energy generation and thermal control. Devices such as magnetrons, klystrons, traveling wave tubes (TWTs), or solid-state power amplifiers (SSPAs) generate or amplify microwave-frequency signals. These signals are channeled through waveguides, which are specialized structures that direct the high-frequency energy to an antenna, such as a horn antenna or a phased array, which can steer the beam electronically. Like laser systems, microwave sources require power conditioning units to convert and stabilize incoming power. Additional control systems monitor the beam output, ensure safe operation, and adjust parameters such as frequency or direction in real-time. Together, these components enable precise, high-power energy transmission, whether for communication, sensing, or wireless power applications.

The beam aiming assembly (e.g., beam aiming assembly 102) for steering the celestial energy beam (e.g., celestial energy beam 40) may include: a gimble mount assembly (e.g., Gimbal mount assembly 106) configured to direct the celestial energy beam (e.g., celestial energy beam 40) toward a target; a phased array assembly (e.g., phased array assembly 107) configured to direct the celestial energy beam (e.g., celestial energy beam 40) toward a target; and/or a periscope assembly (e.g., periscope assembly 108) configured to direct the celestial energy beam (e.g., celestial energy beam 40) toward a target.

A Gimbal mount assembly (e.g., Gimbal mount assembly 106), a phased array assembly (e.g., phased array assembly 107) and a periscope assembly (e.g., periscope assembly 108) can be effectively used in space-based energy systems to accurately direct a celestial energy beam (e.g., celestial energy beam 40), such as a laser or microwave beam, from a satellite (e.g., satellite 14) to a electromagnetic radiation energy receiver (to be discussed below in greater detail). These mechanical systems (e.g., Gimbal mount assembly 106, phased array assembly 107 and/or periscope assembly 108) that are configured to direct the celestial energy beam (e.g., celestial energy beam 40) may be essential for maintaining precise alignment with the electromagnetic radiation energy receiver despite the relative motion of the satellite, the rotation of the earth, and other environmental factors in space.

A Gimbal mount assembly (e.g., Gimbal mount assembly 106) typically consists of two or more rotational axes that allow a mounted device (e.g., energy beam source 100) to pivot freely in multiple directions. In a space-based energy system (e.g., space-based energy system 10), Gimbal mount assembly 106 can orient energy beam source 100 toward the electromagnetic radiation energy receiver by adjusting pitch, yaw, and sometimes roll. This enables real-time tracking and compensation for changes in the position of the satellite (e.g., satellite 14) and the movement of the electromagnetic radiation energy receiver. The Gimbal mount assembly (e.g., Gimbal mount assembly 106) ensures the celestial energy beam (e.g., celestial energy beam 40) remains focused and accurately aligned with the electromagnetic radiation energy receiver, maximizing energy transfer efficiency and minimizing beam dispersion or misalignment.

A phased array assembly (e.g., phased array assembly 107) may be configured to steer a microwave-based celestial energy beam (e.g., celestial energy beam 40). Phased array assembly 107 may include multiple antenna elements that may electronically control the phase of each signal to direct the celestial energy beam (e.g., celestial energy beam 40) without moving parts. Specifically, by adjusting phase differences, phased array assembly 107 generates constructive interference in a specific direction, allowing precise, real-time beam steering.

A periscope assembly (e.g., periscope assembly 108), on the other hand, uses a combination of mirrors or prisms to redirect the celestial energy beam (e.g., celestial energy beam 40) from a fixed source to a desired output direction. In such a system, the celestial energy beam (e.g., celestial energy beam 40) is emitted along a fixed internal path and then reflected or refracted through adjustable optical elements, such as tilting mirrors. By changing the angles of these reflective elements, periscope assembly 108 can steer celestial energy beam 40 without requiring the main source (e.g., energy beam source 100) to move. This is especially useful in confined or compact systems, or where minimizing mechanical complexity and inertia is critical. A periscope assembly (e.g., periscope assembly 108) can also be combined with a Gimbal mount assembly (e.g., Gimbal mount assembly 106) for greater range of motion and precision.

Together or independently, the Gimbal mount assembly (e.g., Gimbal mount assembly 106) phased array assembly 107 and the periscope assembly (e.g., periscope assembly 108) may provide essential pointing and tracking capabilities for a space-based energy system (e.g., space-based energy system 10), as they ensure that the celestial energy beam (e.g., celestial energy beam 40) remains precisely directed at the electromagnetic radiation energy receiver throughout the satellite's orbit, optimizing power delivery and system reliability.

The beam forming package (e.g., beam forming package 104) for forming the celestial energy beam (e.g., celestial energy beam 40) may include: collimating optics (e.g., collimating optics 110); and focusing optics (e.g., focusing optics 112). While the following discussion concerns the use of adaptive optics (e.g., moveable optical elements), it is understood that this is for illustrative purposes only and is not intended to be a limitation of this disclosure, as other configurations are possible and are considered to be within the scope of this disclosure. For example, beam forming package 104 may utilize deformable mirrors for wavefront correction to adjust the optical field so as the celestial energy beam (e.g., celestial energy beam 40) travels to the electromagnetic radiation energy receiver (e.g., electromagnetic radiation energy receiver 200) its profile, phase, divergence, size and other properties of the optical field may be adjusted to meet needs. These deformable mirrors may, as before, defocus or help collimate a beam, but they may also locally modify the beam shape to help deliver a focused or more uniform profile at the electromagnetic radiation energy receiver (e.g., electromagnetic radiation energy receiver 200). Additionally/alternatively, beam forming package 104 may utilize Spatial Light Modulators (SLM) to adjust the phase and amplitude of the wavefront, both locally and globally. These can help improve beam propagation and also include data encoding. An example of SLM wavefront adjustments may include liquid crystal techniques such as liquid crystal on silicon and sapphire based variants. Generally speaking, the optical field of the celestial energy beam (e.g., celestial energy beam 40) may include/define all characteristics of light propagation, examples of which may include but are not limited to the beam profile, the phase, the size, and the divergence of the celestial energy beam (e.g., celestial energy beam 40).

Collimating optics (e.g., collimating optics 110) are used to shape a celestial energy beam (e.g., celestial energy beam 40) so that its rays are parallel, resulting in a collimated beam i.e., one that doesn't spread out (diverge) significantly over distance. When a celestial energy beam (e.g., celestial energy beam 40) exits a source (e.g., energy beam source 100) like a diode, it typically diverges, meaning the beam spreads out as it travels. Collimating optics (e.g., collimating optics 110), such as a lens or a lens system, are placed in the beam path to correct this divergence.

By focusing the light emerging from a point-like or narrow source, collimating optics (e.g., collimating optics 110) create a beam with minimal angular spread. This is especially important for applications that require the beam to travel long distances (e.g., power transmission) or interact with precise optical components. In short, collimating optics (e.g., collimating optics 110) make a celestial energy beam (e.g., celestial energy beam 40) straighter and more focused over distance, improving its usability and efficiency in various optical systems.

Focusing optics (e.g., focusing optics 112) do the opposite of collimating optics (e.g., collimating optics 110), as they take a celestial energy beam (e.g., celestial energy beam 40) and converge it to a point or a small spot. This is usually achieved with lenses or curved mirrors that bend the incoming rays inward, concentrating the beam's energy into a smaller area. When a collimated or diverging celestial energy beam (e.g., celestial energy beam 40) passes through focusing optics (e.g., focusing optics 112), the optics manipulate the beam's path so that all rays come together at a focal point.

During use, the energy beam source (e.g., energy beam source 100) of the electromagnetic radiation energy source (e.g., electromagnetic radiation energy source 38) may generate heat.

Generally speaking, the energy beam source (e.g., energy beam source 100), such as a laser beam source or microwave beam source, generates heat during operation because not all of the electrical or light-based energy provided to energy beam source 100 is converted into usable beam energy. Specifically, these systems operate with less than 100% efficiency, meaning that a significant portion of the input energy is lost as waste heat (e.g., waste heat 114) due to several internal mechanisms.

In lasers, for example, energy losses occur through non-radiative transitions in the lasing medium, electrical resistance in power electronics, and imperfect optical components that absorb or scatter energy. Similarly, microwave sources like magnetrons, klystrons, or solid-state amplifiers lose energy through ohmic heating, dielectric losses, and cooling inefficiencies in high-frequency components. As a result, the device itself heats up, and if that heat is not removed efficiently, it can degrade performance, reduce lifespan, and even lead to thermal failure.

Accordingly, the energy beam source (e.g., energy beam source 100) may include various high energy electromagnetic components, examples of which may include but are not limited to one or more pump diodes, wherein at least a portion of the waste heat (e.g., waste heat 114) may be generated by these high energy electromagnetic components.

As is known in the art, a pump diode is a type of semiconductor laser used as the energy source to “pump” or excite the gain medium in certain types of lasers, particularly solid-state and fiber lasers. It plays a crucial role in the laser generation process by supplying the energy needed to produce population inversion, which is the condition required for stimulated emission—the key mechanism behind laser operation. In solid-state lasers like Nd:YAG or Yb:YAG, the gain medium is a crystal or glass doped with rare-earth ions. The pump diode emits light—typically in the near-Infrared range—that matches the absorption band of the doped ions. When the ions absorb this light, they are excited to a higher energy state. As they return to a lower energy state, they release photons, and under the right conditions (within an optical resonator), this leads to a coherent, amplified laser beam. Pump diodes are widely used because they are compact, efficient, reliable, and electrically powered, making them ideal for both industrial and space-based laser systems. But unfortunately, pump diodes generate a considerable amount of heat (e.g., waste heat 114).

To manage this waste heat (e.g., waste heat 114), a waste heat dissipation system (e.g., waste heat dissipation system 116) may be utilized. On Earth, such a system often includes heat sinks, liquid cooling systems, or active ventilation to transfer heat away from the device and release it into the surrounding air. In space, however, where conduction and convection are not possible due to the vacuum, waste heat must be removed through thermal radiation. This is typically accomplished via the use of thermal radiators, heat pipes, or loop heat pipes that transport the heat from the source (e.g., energy beam source 100) to surfaces that can radiate it away in the form of Infrared energy. Effective thermal control ensures that the energy source (e.g., energy beam source 100) remains at safe operating temperatures and continues to function reliably during extended use.

Therefore, the electromagnetic radiation energy source (e.g., electromagnetic radiation energy source 38) may include a waste heat dissipation system (e.g., waste heat dissipation system 116) for removing waste heat (e.g., waste heat 114) from the electromagnetic radiation energy source (e.g., electromagnetic radiation energy source 38).

The waste heat dissipation system (e.g., waste heat dissipation system 116) for removing waste heat (e.g., waste heat 114) from the electromagnetic radiation energy source (e.g., electromagnetic radiation energy source 38) may include: a thermal radiator (e.g., thermal radiator 118) for dissipating the waste heat (e.g., waste heat 114) and a heat transfer system (e.g., heat transfer system 120) for transferring the waste heat (e.g., waste heat 114) from a heat source to the thermal radiator (e.g., thermal radiator 118). One example of such a heat source may include but is not limited to the energy beam source (e.g., energy beam source 100) included within the electromagnetic radiation energy source (e.g., electromagnetic radiation energy source 38).

The thermal radiators (e.g., thermal radiator 118) utilized by the waste heat dissipation system (e.g., waste heat dissipation system 116) of the electromagnetic radiation energy source (e.g., electromagnetic radiation energy source 38) may be the same as (or different from) the thermal radiators (e.g., thermal radiator 30) utilized by the waste heat dissipation system (e.g., waste heat dissipation system 26) of the solar energy gathering system (e.g., solar energy gathering system 12).

The heat transfer system (e.g., heat transfer system 120) may be configured to collect and transfer the waste heat (e.g., waste heat 114) from a heat source (e.g., energy beam source 100) to the thermal radiator (e.g., thermal radiator 118), which is configured for dissipating the waste heat (e.g., waste heat 114). This transfer is often achieved using thermal conductors like heat pipe systems or coolant circulation systems, which efficiently carry the waste heat (e.g., waste heat 114) away from the energy beam source (e.g., energy beam source 100).

As discussed above, heat pipe systems are sealed tubes containing a fluid that evaporates at the hot end, carrying waste heat (e.g., waste heat 114) to a cooler section where the fluid condenses and releases the waste heat (e.g., waste heat 114). Coolant circulation systems circulate a coolant that absorbs the waste heat (e.g., waste heat 114) from the energy beam source (e.g., energy beam source 100) and transfers the same to the thermal radiator (e.g., thermal radiator 118).

Once the waste heat (e.g., waste heat 114) is transferred to the thermal radiator (e.g., thermal radiator 118), thermal radiator 118 (e.g., a large surface area panel mounted on satellite 14) radiates the waste heat (e.g., waste heat 114) into space, where there is no atmosphere to absorb it. The radiator is usually made of materials with high thermal conductivity and emissivity, ensuring that it can efficiently release the waste heat (e.g., waste heat 114) into the cold vacuum of space. Accordingly, the waste heat dissipation system (e.g., waste heat dissipation system 116) helps keep the internal components of the satellite (e.g., satellite 14) within the required temperature range, thus preventing performance degradation, ensuring the longevity of the satellite (e.g., satellite 14), and allowing it to operate effectively in the harsh environment of space.

As discussed above, the thermal radiator (e.g., thermal radiator 118) may include one or more of: a fixed surface radiator; a deployable radiator; a heat pipe radiator; a loop heat pipe/capillary pumped loop system; a variable emittance radiator; and a phase change material (PCM) radiator. Thermal radiators (e.g., thermal radiator 118) are crucial components of a thermal management system of a satellite (e.g., satellite 14), as they help dissipate excess heat (e.g., waste heat 114) generated by onboard systems, including the energy beam source (e.g., energy beam source 100). As discussed above, different types of thermal radiators (e.g., thermal radiator 118) are used in space depending on the mission requirements, available space, and heat dissipation needs.

As discussed above, the thermal radiator (e.g., thermal radiator 118) may be mounted to the deployable structure assembly (e.g., deployable structure assembly 24) and/or deployed from the deployable structure assembly (e.g., deployable structure assembly 24). Accordingly and if the thermal radiator (e.g., thermal radiator 118) is a fixed size (i.e., non-deployable) thermal radiator, thermal radiator 118 may be attached to the deployable structure assembly (e.g., deployable structure assembly 24) and interspersed with the energy-gathering devices (e.g., energy gathering devices 18). Additionally/alternatively and if the thermal radiator (e.g., thermal radiator 118) is a deployable thermal radiator, thermal radiator 118 may be attached to the deployable structure assembly (e.g., deployable structure assembly 24), wherein the deployable thermal radiator may be deployed once the deployable structure assembly 24 is fully deployed.

Instead of dissipating all of the waste heat (e.g., waste heat 114) into space, some or all of waste heat 114 may be utilized to generate electrical energy. Therefore, the electromagnetic radiation energy source (e.g., electromagnetic radiation energy source 38) may include a thermoelectric generation system (e.g., thermoelectric generation system 122) for receiving at least a portion of the waste heat (e.g., waste heat 114) to generate recovered electrical energy (e.g., recovered electrical energy 124) that may be used to supplement the gathered electrical energy (e.g., gathered electrical energy 34). Examples of such a thermoelectric generation system (e.g., thermoelectric generation system 122) may include but are not limited to one or more of: a Sebeck-effect device; a Peltier-effect device; and a Thompson-effect device.

Specifically, a thermoelectric generation system (e.g., thermoelectric generation system 122) on a satellite can convert waste heat (e.g., waste heat 114) into electrical energy (e.g., recovered electrical energy 124) using the principles of thermoelectric effects-specifically the Seebeck effect for thermoelectric generators (TEGs), Peltier effect, and Thomson effect. These effects are all related to the interaction between heat flow and electric current in conductive or semiconductive materials, and each plays a role in how thermoelectric systems operate in the space environment.

The Seebeck effect is the primary mechanism used in heat engines to produce electricity. When two dissimilar conductive materials are joined to form a closed loop and their junctions are held at different temperatures, a voltage is generated due to the diffusion of charge carriers from the hot side to the cold side. In a satellite, this is exploited by attaching one side of a thermoelectric module to a hot surface—such as electronics, power systems, or propulsion components- and the other side to a cold sink, like a radiator panel exposed to the cold of space. The temperature difference across the junctions drives a current, producing electrical power without any moving parts.

The Peltier effect, which is essentially the inverse of the Seebeck effect, occurs when an electric current flows through the junction of two different conductors and either absorbs or releases heat, depending on the direction of current. While primarily used in thermoelectric cooling systems, the Peltier effect can also influence the performance of heat engines. In satellite applications, Peltier elements might be used in tandem with Seebeck devices to help manage localized thermal gradients, optimizing conditions for electricity generation.

The Thomson effect involves the absorption or emission of heat when an electric current flows through a single homogeneous conductor with a temperature gradient. This effect is typically smaller than the Seebeck or Peltier effects but still contributes to the overall efficiency of thermoelectric conversion. In space applications, the Thomson effect is considered when designing materials and temperature profiles to maximize the overall performance of heat engines.

In summary, a thermoelectric generation system (e.g., thermoelectric generation system 122) on a satellite (e.g., satellite 14) primarily uses Seebeck-effect devices to convert waste heat (e.g., waste heat 114) into electricity, with Peltier and Thomson effects contributing to thermal and electrical behavior. These systems enhance energy efficiency, reduce reliance on batteries during low-sunlight periods, and help manage thermal conditions in the satellite's confined environment.

The electromagnetic radiation energy source (e.g., electromagnetic radiation energy source 38) may include: a gathered energy storage system (e.g., gathered energy storage system 126) configured to store at least a portion of the gathered electrical energy (e.g., gathered electrical energy 34) to enable generation of the celestial energy beam (e.g., celestial energy beam 40) even when the solar energy (e.g., solar energy 20) is not sufficiently available. Specifically, the gathered electrical energy (e.g., gathered electrical energy 34) is only generated if the solar energy (e.g., solar energy 20) striking the energy gathering devices (e.g., energy gathering devices 18) is sufficient to generate such gathered electrical energy (e.g., gathered electrical energy 34). And being this gathered electrical energy (e.g., gathered electrical energy 34) is utilized to generate the celestial energy beam (e.g., celestial energy beam 40), if the solar energy (e.g., solar energy 20) striking the energy gathering devices (e.g., energy gathering devices 18) is insufficient to generate such gathered electrical energy (e.g., gathered electrical energy 34), the celestial energy beam (e.g., celestial energy beam 40) will not be generated. Accordingly, the gathered energy storage system (e.g., gathered energy storage system 126) may store at least a portion of the gathered electrical energy (e.g., gathered electrical energy 34) to enable generation of the celestial energy beam (e.g., celestial energy beam 40) even when the solar energy (e.g., solar energy 20) is not sufficiently available.

When solar energy (e.g., solar energy 20) is not available (such as when a satellite (e.g., satellite 14) is in the Earth's shadow or during eclipses), satellites (e.g., satellite 14) rely on onboard energy storage systems (e.g., gathered energy storage system 126) to continue functioning. These systems must be lightweight, durable, and capable of storing and delivering power efficiently in the harsh environment of space. Examples of such a gathered energy storage system (e.g., gathered energy storage system 126) may include but are not limited to:
Rechargeable Batteries: The most widely used energy storage systems in satellites are battery storage systems. Modern satellites commonly use lithium-ion batteries because of their high energy density, long cycle life, and relatively low weight. Older systems often used nickel-cadmium (NiCd) or nickel-hydrogen (NiH₂) batteries, which offer excellent durability and tolerance to deep discharge but are heavier and less efficient than lithium-ion options.
Supercapacitors: Supercapacitors store energy electrostatically and are capable of rapid charge and discharge cycles. While they have lower energy density than batteries, they are highly effective for short-term power support, such as handling peak power loads or providing backup during power transitions. They are sometimes used in conjunction with rechargeable batteries for hybrid storage systems.
Flywheel Energy Storage Systems: Flywheels store energy mechanically by spinning a rotor at high speeds in a vacuum. This kinetic energy can be converted into electricity when needed. Flywheels offer high cycle life and fast response times, but they are more complex and less common in most modern satellites. However, they have been studied for both power storage and attitude control.

In summary, satellites typically use lithium-ion batteries as their primary energy storage system, often supplemented by supercapacitors or flywheels for specific power management needs.

### Ground-Based Energy Receiving/Distribution Subsystem:

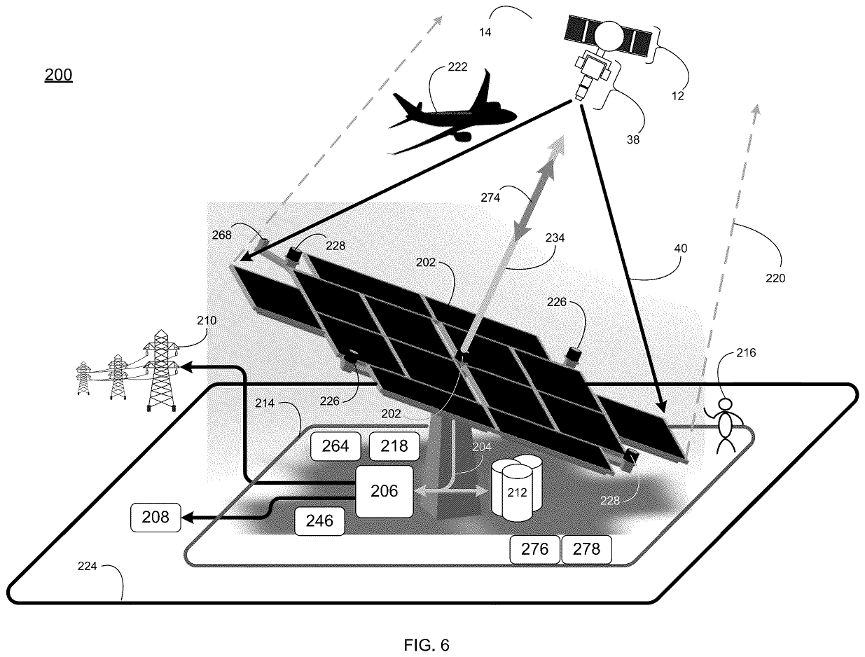

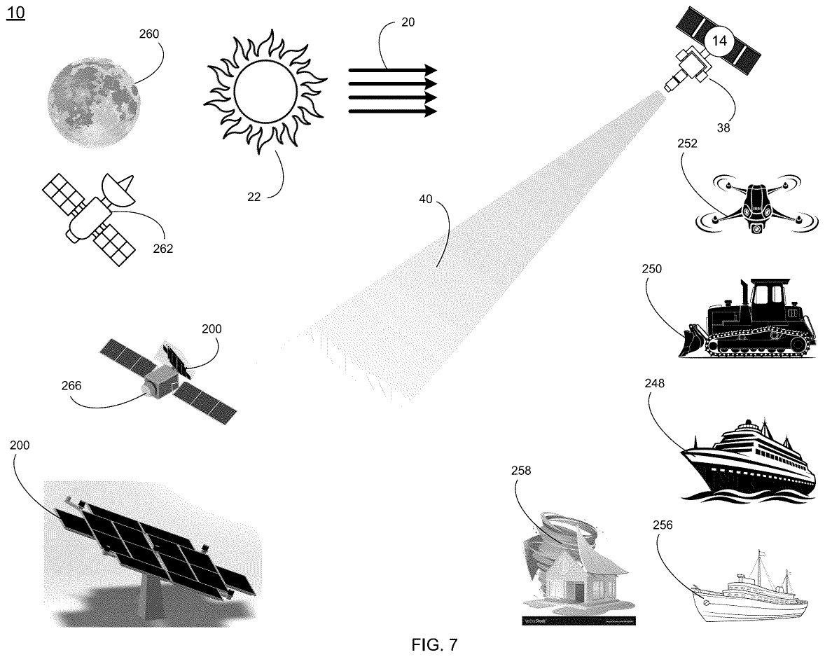

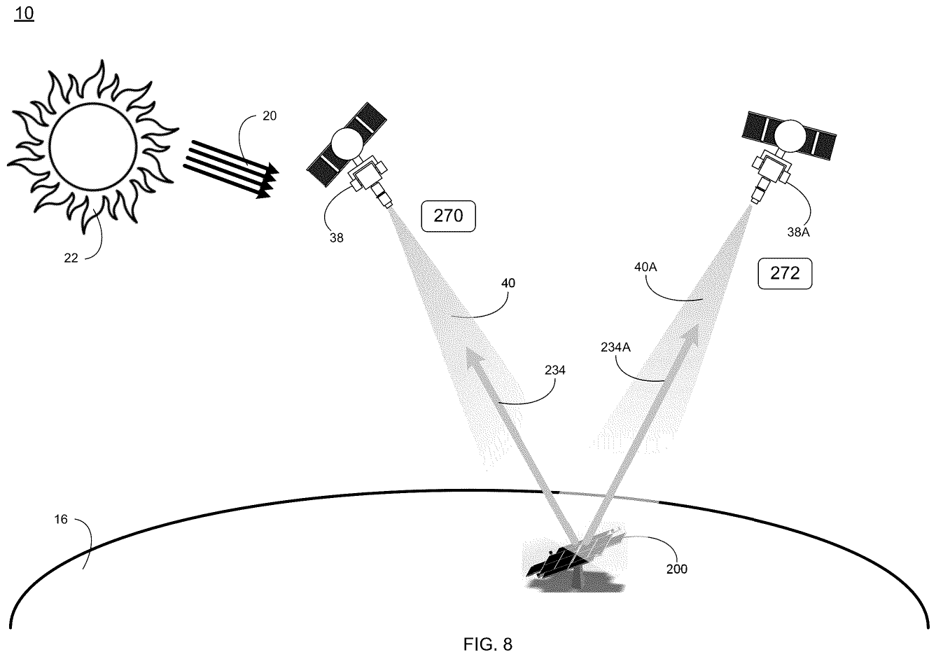

Referring also to FIGS. 6-8, the space-based energy system (e.g., space-based energy system 10) may include an electromagnetic radiation energy receiver (e.g., electromagnetic radiation energy receiver 200) including one or more energy receiving devices (e.g., energy receiving devices 202). The electromagnetic radiation energy receiver (e.g., electromagnetic radiation energy receiver 200) may be configured to receive at least a portion of the celestial energy beam (e.g., celestial energy beam 40) on the one or more energy receiving devices (e.g., energy receiving devices 202) and generate received electrical energy (e.g., received electrical energy 204).

The one or more energy receiving devices (e.g., energy receiving devices 202) of the electromagnetic radiation energy receiver (e.g., electromagnetic radiation energy receiver 200) may include one or more of: one or more photovoltaic cells; one or more photodiodes; one or more heat engines; and one or more rectenna arrays.

Photovoltaic cells, also known as solar cells, are devices that convert light directly into electricity through the photovoltaic effect. When photons enter the cell, which are typically made from semiconductor materials like silicon, they transfer their energy to electrons, knocking them loose from atoms. This creates an electric current as the freed electrons are directed through an external circuit. Photovoltaic cells are commonly used in solar panels to generate power from sunlight, but they can also be designed to respond to specific wavelengths, such as those emitted by lasers, making them useful for applications like wireless power transfer or space-based energy systems. Their efficiency depends on the material, light intensity, and spectral match between the light source and the cell.

Photodiodes are semiconductor devices that convert light into an electrical current, but unlike photovoltaic cells, they are primarily used as light sensors rather than power generators. When photons hit the photodiode's active region, they generate electron-hole pairs that produce a current proportional to the light intensity. Photodiodes operate quickly and with high sensitivity, making them ideal for detecting modulated light signals in applications such as optical communication, laser detection, and imaging systems. Some specialized photodiodes are optimized for specific wavelengths, including Infrared or ultraviolet light, depending on the application.

Heat engines are devices that convert heat energy into useful work. For example, such heat engines may be mechanical or solid-state in nature. Solid-state heat engines such as thermoelectric generators (TEGs) convert heat into electricity using the Seebeck effect, wherein a voltage is generated across two different conductors or semiconductors when there is a temperature difference between them. As heat flows from the hot side to the cold side, charge carriers in the material move, producing a current. TEGs have no moving parts and can operate in harsh environments, making them useful in remote or space-based applications where maintenance is difficult. They are often used in spacecraft, wearable devices, or industrial waste-heat recovery systems. However, their conversion efficiency is generally lower than that of photovoltaic or rectenna systems.

Rectennas, short for rectifying antennas, are devices that convert electromagnetic energy—such as microwaves or radio waves—into direct current (DC) electricity. They consist of an antenna that captures incoming electromagnetic waves and a rectifying circuit, usually containing high-speed diodes, that converts the alternating current (AC) signal into DC power. Rectennas are particularly useful in wireless power transmission systems, such as microwave-based space solar power, where energy is beamed from a satellite to a ground station. When arranged in large arrays, rectennas can collect significant amounts of power over wide areas. Their design can be tuned for different frequencies, and they offer high efficiency when matched well to the transmission system.

The electromagnetic radiation energy receiver (e.g., electromagnetic radiation energy receiver 200) may include: an energy distribution system (e.g., energy distribution system 206) configured to enable distribution of the received electrical energy (e.g., received electrical energy 204) to various devices/systems.

The energy distribution system (e.g., energy distribution system 206) may electrically couple a portion of the electromagnetic radiation energy receiver (e.g., electromagnetic radiation energy receiver 200)—which extracts received electrical energy 204 from celestial energy beam 40 (e.g., a laser or microwave beam) via the energy receiving devices (e.g., energy receiving devices 202)—to external electrical systems (e.g., external systems 208) by converting, conditioning, and regulating the received electrical energy (e.g., received electrical energy 204) to ensure compatibility with the downstream devices or infrastructure it powers. This electrical coupling may be crucial for enabling seamless integration of space-based power transmission (via celestial energy beam 40) into terrestrial systems, extraterrestrial systems, or space-based systems (e.g., collectively illustrated as external systems 208).

When the energy receiving devices 202 receives celestial energy beam 40 and extracts received electrical energy 204, this received electrical energy 204 may not be immediately suitable for use. For example, received electrical energy 204 may be at an unstable voltage or frequency, or received electrical energy 204 may be direct current (DC) when the load requires alternating current (AC), or vice versa.

To address this, the energy distribution system (e.g., energy distribution system 206) may route received electrical energy 204 through a power conditioning unit (PCU). The PCU may perform several functions (regulating the voltage and current levels, converting between AC and DC via inverters/rectifiers, filtering to remove electrical noise or fluctuations). The energy distribution system (e.g., energy distribution system 206) may be configured to enable distribution of the received electrical energy (e.g., received electrical energy 204) to a power distribution grid (e.g., power distribution grid 210). And in such a configuration, energy distribution system 206 may include transformers configured to step up the voltage of received electrical energy 204 to match the requirements of the power distribution grid (e.g., power distribution grid 210).

A power distribution grid (e.g., power distribution grid 210) is a network of electrical components designed to manage, route, and deliver electrical power from one or more sources to various loads or subsystems. In the context of receiving power from a celestial energy beam (e.g., celestial energy beam 40), such as a laser beam or microwave beam that is received on the electromagnetic radiation energy receiver (e.g., electromagnetic radiation energy receiver 200) from the electromagnetic radiation energy source (e.g., electromagnetic radiation energy source 38), the power distribution grid (e.g., power distribution grid 210) plays a critical role in converting, controlling, and distributing that energy safely and efficiently to its intended destinations.

In essence, the energy distribution system (e.g., energy distribution system 206) acts as the bridge between the celestial energy beam 40 and the electrical needs of the connected external systems (e.g., external systems 208). Examples of such external systems (e.g., external systems 208) may include but are not limited to earth-based systems, non-earth systems, space-based vessels, and terrestrial vessels, each of which is described below in greater detail:
Earth-Based Systems: Examples of such earth-based systems may include but are not limited to earth-based houses, factories, machinery, systems, portions of a distribution grid, remote installations, remote events, and areas in need (e.g., due to natural disasters) that may utilize the received electrical energy (e.g., received electrical energy 204) extracted from celestial energy beam 40. A typical earth-based system may be a remote research installation (e.g., a research facility in Antarctica) that is in need of electrical energy but is not readily connectible to a power source.
Non-Earth Systems: Examples of such non-earth systems may include but are not limited to non-earth houses, factories, machinery, systems, portions of a distribution grid, remote installations, remote events, and areas in need that may utilize the received electrical energy (e.g., received electrical energy 204) extracted from celestial energy beam 40. A typical non-earth system may be an extraterrestrial research installation (e.g., a research facility on the surface of the moon) that is in need of electrical energy but none is available.
Space-Based Vessels: Examples of such space-based vessels may include but are not limited to orbiting satellites and space stations that may utilize the received electrical energy (e.g., received electrical energy 204) extracted from celestial energy beam 40. A typical space-based vessel may be a orbiting research facility (e.g., the International Space Station) that is in need of electrical energy but none is available due to e.g., a solar panel failure.
Terrestrial Vessels: Examples of such terrestrial vessels may include but are not limited to various earth-based vessels (e.g., seagoing vessels, heavy construction vehicles, and mining equipment) that may utilize the received electrical energy (e.g., received electrical energy 204) extracted from celestial energy beam 40. A typical terrestrial vessel may be a drag line in a remote mining operation in Canada that is in need of electrical energy but is not readily connectible to a power source.

The electromagnetic radiation energy receiver (e.g., electromagnetic radiation energy receiver 200) may be a mobile electromagnetic radiation energy receiver (e.g., electromagnetic radiation energy receiver 200) that is configured to be temporarily attached to the power distribution grid (e.g., power distribution grid 210). For example, the electromagnetic radiation energy receiver (e.g., electromagnetic radiation energy receiver 200) may be mounted on a flatbed tractor trailer that may be moved to a place in need of power. Therefore, when New Orleans was struck by Hurricane Katrina in 2005, portions of New Orleans were without power for extended periods of time. Accordingly, such a mobile electromagnetic radiation energy receiver (e.g., electromagnetic radiation energy receiver 200) could have been brought to New Orleans and connected to the impacted power distribution grid (e.g., power distribution grid 210). And upon electromagnetic radiation energy receiver 200 receiving and processing celestial energy beam 40, the impacted portions of New Orleans would once again have electrical power.

Additionally/alternatively, the electromagnetic radiation energy receiver (e.g., electromagnetic radiation energy receiver 200) may be a permanent electromagnetic radiation energy receiver (e.g., electromagnetic radiation energy receiver 200) that is configured to be permanently attached to the power distribution grid (e.g., power distribution grid 210). Therefore, the electromagnetic radiation energy receiver (e.g., electromagnetic radiation energy receiver 200) may be available to provide a clean source of electrical energy to the power distribution grid (e.g., power distribution grid 210) during power outages, high levels of use, etc.

The electromagnetic radiation energy receiver (e.g., electromagnetic radiation energy receiver 200) may include: a received energy storage system (e.g., received energy storage system 212) configured to store at least a portion of the received electrical energy (e.g., received electrical energy 204) to enable distribution of the received electrical energy (e.g., received electrical energy 204) even when the celestial energy beam (e.g., celestial energy beam 40) is not being generated by the electromagnetic radiation energy source (e.g., electromagnetic radiation energy source 38).

Specifically, the received electrical energy (e.g., received electrical energy 204) is only generated if the solar energy (e.g., solar energy 20) striking the energy gathering devices (e.g., energy gathering devices 18) of solar energy gathering system 12 is sufficient to generate the gathered electrical energy (e.g., gathered electrical energy 34). And being this gathered electrical energy (e.g., gathered electrical energy 34) is utilized to generate the celestial energy beam (e.g., celestial energy beam 40), if the solar energy (e.g., solar energy 20) striking the energy gathering devices (e.g., energy gathering devices 18) is insufficient to generate such gathered electrical energy (e.g., gathered electrical energy 34), celestial energy beam 40 (and, therefore, received electrical energy 204) will not be generated. Accordingly, the received energy storage system (e.g., received energy storage system 212) may store at least a portion of the received electrical energy (e.g., received electrical energy 204) to enable distribution of the received electrical energy (e.g., received electrical energy 204) even when the solar energy (e.g., solar energy 20) is not sufficiently available.

Examples of such a received energy storage system (e.g., received energy storage system 212) may include but are not limited to:
Rechargeable Batteries: The most widely used energy storage systems are battery storage systems. Modern systems commonly use lithium-ion batteries because of their high energy density, long cycle life, and relatively low weight. Older systems often used nickel-cadmium (NiCd) or nickel-hydrogen (NiH₂) batteries, which offer excellent durability and tolerance to deep discharge but are heavier and less efficient than lithium-ion options.
Supercapacitors: Supercapacitors store energy electrostatically and are capable of rapid charge and discharge cycles. While they have lower energy density than batteries, they are highly effective for short-term power support, such as handling peak power loads or providing backup during power transitions. They are sometimes used in conjunction with rechargeable batteries for hybrid storage systems.
Flywheel Energy Storage Systems: Flywheels store energy mechanically by spinning a rotor at high speeds in a vacuum. This kinetic energy can be converted into electricity when needed. Flywheels offer high cycle life and fast response times. However, they have been studied for both power storage and attitude control.

As celestial energy beam 40 is being received by electromagnetic radiation energy receiver (e.g., electromagnetic radiation energy receiver 200), the electromagnetic radiation energy receiver (e.g., electromagnetic radiation energy receiver 200) may include: a security zone (e.g., security zone 214). Specifically and depending upon the energy density of celestial energy beam 40, it is foreseeable that an intruder (e.g., intruder 216) within the security zone (e.g., security zone 214) may be injured if the intruder (e.g., intruder 216) makes contact with celestial energy beam 40. This is especially important because the celestial energy beam (e.g., celestial energy beam 40) carries high levels of energy that can be hazardous to people and animals if they enter the beam path or come too close to the high-energy receiver components for a prolonged period of time. Accordingly, this security zone (e.g., security zone 214) may be monitored for the occurrence of a security event and, if such a security event is detected, remedial actions may be taken.

The security zone (e.g., security zone 214) may be defined via a physical barrier, wherein examples of such a physical barrier may include but are not limited to one or more of a fence and a wall. For example, physical barriers such as chain-link fences, privacy fences, brick walls, etc. may be used to physically define the security zone (e.g., security zone 214) to protect the electromagnetic radiation energy receiver (e.g., electromagnetic radiation energy receiver 200) by defining a physical perimeter around some or all of the electromagnetic radiation energy receiver (e.g., electromagnetic radiation energy receiver 200) to restrict unauthorized access and ensure safety during beam transmission.

Additionally/alternatively, the security zone (e.g., security zone 214) may be defined via an electronic barrier, wherein an example of such an electronic barrier may include but is not limited to a geofence barrier. A geofence barrier can be used to digitally define the security zone (e.g., security zone 214) to protect the electromagnetic radiation energy receiver (e.g., electromagnetic radiation energy receiver 200) by defining a virtual perimeter around some or all of the electromagnetic radiation energy receiver (e.g., electromagnetic radiation energy receiver 200) to restrict unauthorized access and ensure safety during beam transmission.

In practical terms, the security zone (e.g., security zone 214) may be defined via a combination of physical and virtual barriers to ensure the safe operation of the electromagnetic radiation energy receiver (e.g., electromagnetic radiation energy receiver 200).

As discussed above, the celestial energy beam (e.g., celestial energy beam 40) carries high levels of energy that can be hazardous to people, animals, or electronic systems if they enter the beam path or come too close to the high-energy receiver components for a prolonged period of time. Accordingly, the electromagnetic radiation energy receiver (e.g., electromagnetic radiation energy receiver 200) may include: a monitoring system (e.g., monitoring system 218) configured to monitor a monitored space (e.g., monitored space 220) to detect an intruding objects (e.g., intruding object 222). The monitored space (e.g., monitored space 220) may include a conical monitored space, where the celestial energy beam (e.g., celestial energy beam 40) is located along the longitudinal axis of symmetry of the conical monitored space (e.g., monitored space 220).

The monitoring system (e.g., monitoring system 218) may include one or more of: a LIDAR system; a radar system; and an optical system. A LIDAR system, radar system, and optical system can each be used to monitor and protect the monitored space (e.g., monitored space 220) around the celestial energy beam (e.g., celestial energy beam 40) by detecting objects, tracking movement, and ensuring that the path of celestial energy beam 40 is unobstructed. These systems serve as active and passive sensing tools to maintain safe operation, especially in environments where unintended exposure to celestial energy beam 40 could damage equipment, disrupt communications, or pose safety risks to aircraft and birds.

A LIDAR (Light Detection and Ranging) system uses pulsed laser light to scan the monitored space (e.g., monitored space 220) and measure distances to objects by calculating the time it takes for the light to bounce back. In the context of celestial energy beam 40, LIDAR can provide high-resolution, real-time 3D mapping of the beam's environment. It can detect any physical object—such as aircraft and birds—that may enter the beam's path. If an object is detected crossing a defined safety boundary, the LIDAR system may initiate remedial action (e.g., suspending celestial energy beam 40) to prevent interference or damage.

A Radar System (Radio Detection and Ranging) uses radio waves to detect and track objects, including those that may be too small, distant, or fast-moving to be reliably tracked by optical means. Radar is well-suited for long-range, all-weather detection, making it effective in scenarios where atmospheric conditions (clouds, fog, dust) would limit the performance of optical or LIDAR systems. In a beam protection role, radar can continuously monitor the monitored space (e.g., monitored space 220) for incoming aircraft and birds, providing early warnings so that remedial action (e.g., suspending celestial energy beam 40) may be implemented.

An Optical System uses visible or Infrared cameras, telescopes, and sensors to visually observe the monitored space (e.g., monitored space 220). These systems provide passive imaging, capturing data that can be analyzed by software to detect any physical object—such as aircraft and birds—that may enter the beam's path. Optical systems may supplement other systems like LIDAR and radar. While optical systems may be limited by visibility conditions (e.g., darkness or atmospheric interference), they are valuable for fine tracking/confirmation and the implementation of remedial action (e.g., suspending celestial energy beam 40), especially when combined with AI for object recognition and threat assessment.

When these systems (i.e., LIDAR systems, radar systems, and optical systems) are integrated, they may create a robust situational awareness platform for monitoring the space (e.g., monitored space 220) around the celestial energy beam (e.g., celestial energy beam 40). LIDAR provides precise, short-range detection; radar offers long-range and weather-independent tracking; and optical systems deliver visual confirmation and detailed imaging.

The electromagnetic radiation energy receiver (e.g., electromagnetic radiation energy receiver 200) may include: an energy absorbing system (e.g., energy absorbing system 224) configured to absorb at least a portion of the celestial energy beam (e.g., celestial energy beam 40) within the security zone (e.g., security zone 214).

To safely manage and utilize the power delivered by celestial energy beam 40, whether in the form of laser or microwave radiation, the energy absorbing system (e.g., energy absorbing system 224) may be employed. This system (e.g., energy absorbing system 224) is designed to dissipate incoming electromagnetic energy safely without damage. This energy absorbing system (e.g., energy absorbing system 224) may fall into two categories: energy absorbing coatings and energy absorbing structures, each tailored for the specific characteristics of celestial energy beam 40. For example, areas outside of the energy receiving devices 202 may be protected by energy absorbing system 224 so that electromagnetic radiation from celestial energy beam 40 that does not strike energy receiving devices 202 will be safely absorbed/dissipated by energy absorbing system 224.

Energy Absorbing Coatings: Laser-absorbing coatings are engineered materials applied to surfaces to efficiently absorb specific laser wavelengths. These coatings typically consist of layers of carbon black, ceramic-metal composites (cermets), or dielectric materials designed for optical interference absorption. The energy absorbed is converted into heat, which can either be dissipated or redirected. For microwave energy, coatings known as RAM (Radar Absorbing Materials) may be used. These materials are composed of ferromagnetic particles or dielectric composites that absorb and attenuate incoming microwave radiation by converting it into heat through magnetic and electric losses.

Energy Absorbing Structures: Thermal absorbing structures may be used to absorb the electromagnetic energy included within celestial energy beam 40. These structures are made of materials with high thermal conductivity (e.g., graphite, tungsten, or ceramics) and are designed to absorb the beam's energy as heat. The heat can then be transferred to a heat engine to produce electricity or dissipated through radiator panels. Advanced absorbing structures may also employ metamaterials-engineered materials with unique electromagnetic properties that enable them to absorb specific frequencies with minimal reflection or transmission. These can be designed for either laser or microwave energy and offer high levels of energy absorption.

The role of energy absorbing system 224 is to prevent damage to sensitive equipment, surrounding infrastructure, humans and animals by absorbing and dissipating the electromagnetic radiation within celestial energy beam 40 that fails to strike energy receiving devices 202. By using purpose-built coatings and structural absorbers, celestial energy beam 40 may be harnessed effectively, safely, and reliably.

The electromagnetic radiation energy receiver (e.g., electromagnetic radiation energy receiver 200) may include: one or more feedback devices (e.g., feedback devices 226). For example, these one or more feedback devices (e.g., feedback devices 226) may be interspersed within (or positioned proximate) energy receiving devices 202. For example, these one or more feedback devices (e.g., feedback devices 226) may include one or more of: a centrally-positioned feedback device (i.e., a feedback device that is centrally positioned within energy receiving devices 202); and a plurality of peripherally-positioned feedback devices (i.e., a plurality of feedback devices that are peripherally-positioned about the perimeter of energy receiving devices 202).

At least one of the feedback devices (e.g., feedback devices 226) may be a retroreflector. A retroreflector is a specialized feedback device or surface that reflects incoming electromagnetic radiation—such as portions of celestial energy beam 40—directly back toward its source (e.g., electromagnetic radiation energy source 38), regardless of the angle at which celestial energy beam 40 arrives. Unlike a standard mirror, which reflects light at an angle equal to the incident angle, a retroreflector is designed to return the beam along a near-exact path from which it came. This is typically achieved through geometric structures such as corner cubes, cat's-eye lenses, or Bragg gratings (for certain wavelengths).

In the context of celestial energy beam 40, a retroreflector can be strategically placed near or integrated into electromagnetic radiation energy receiver 200, wherein it may reflect a small portion of the incoming energy beam (e.g., celestial energy beam 40) back to its source (e.g., energy beam source 100), where it can be used to provide feedback to electromagnetic radiation energy source 38. Generally speaking, these retroreflectors may be “standard” off-the-shell retroreflectors or may be specially designed/engineered to provide any desired divergence characteristics (e.g., to spread the return signal sufficiently wide to have it register on a moving radiation energy source due to time of flight).

This feedback may prove valuable for several reasons:
Beam Alignment and Tracking: By monitoring the feedback signal, the transmitting system may determine if the beam is precisely hitting the target. If the retroreflected feedback becomes weak or misaligned, electromagnetic radiation energy source 38 may adjust the orientation or focus of celestial energy beam 40 to re-align celestial energy beam 40.
Power and Signal Integrity Monitoring: Measuring the reflected energy allows the source (e.g., energy beam source 100) to estimate the strength and quality of the energy beam (e.g., celestial energy beam 40) being received, which may help identify any issues like atmospheric interference, scattering, or system degradation.
Safety Verification: The presence or absence of retroreflected feedback may act as a safety interlock, confirming that electromagnetic radiation energy receiver 200 is properly aligned and ready to absorb celestial energy beam 40. Accordingly and if no feedback is returned, the source (e.g., energy beam source 100) may temporarily pause or redirect transmission of the beam (e.g., celestial energy beam 40) to prevent accidental exposure or waste.

In summary, a retroreflector may play a critical role in feedback and control for celestial energy beam 40, ensuring accurate targeting, reliable power transfer, and enhanced safety through continuous monitoring of the delivery path of the celestial energy beam (e.g., celestial energy beam 40).

While the feedback devices (e.g., feedback devices 226) are described above as being optical in nature, this is for illustrative purposes only and is not intended to be a limitation of this disclosure, as other configurations are possible and are considered to be within the scope of this disclosure.

For example, the feedback devices (e.g., feedback devices 226) may include an RF component. Specifically, feedback devices 226 may include a plurality of opto-electrical sensors, examples of which may include but are not limited to photodiodes, photodetectors and/or photovoltaic cells. As discussed above, these feedback devices (e.g., feedback devices 226) may be interspersed within (or positioned proximate) energy receiving devices 202. For example, feedback devices 226 may include a centrally-positioned feedback device (i.e., a feedback device that is centrally positioned within energy receiving devices 202) and a plurality of peripherally-positioned feedback devices (i.e., a plurality of feedback devices that are peripherally-positioned about the perimeter of energy receiving devices 202).

This plurality of sensors (e.g., feedback devices 226) may monitor the position of celestial energy beam 40 (as received on electromagnetic radiation energy receiver 200) that was provided from the electromagnetic radiation energy source (e.g., electromagnetic radiation energy source 38). Information concerning beam alignment (i.e., the manner in which celestial energy beam 40 is striking electromagnetic radiation energy receiver 200) may be provided to an RF transmitter (to be discussed below) that is included within electromagnetic radiation energy receiver 200 so that such information may be provided to the electromagnetic radiation energy source (e.g., electromagnetic radiation energy source 38), wherein the position of celestial energy beam 40 may be adjusted by beam aiming assembly 102 (if adjustment is needed).

For example, the RF transmitter (to be discussed below) that is included within electromagnetic radiation energy receiver 200 may establish an RF link between electromagnetic radiation energy receiver 200 and electromagnetic radiation energy source 38. Accordingly and when a portion of celestial energy beam 40 strikes feedback devices 226 (e.g., photodiodes, photodetectors and/or photovoltaic cells), information concerning the detection of celestial energy beam 40 may be provided via the RF transmitter (to be discussed below) included within/coupled to/available to electromagnetic radiation energy receiver 200 to the electromagnetic radiation energy source (e.g., electromagnetic radiation energy source 38). In response to receiving such information, electromagnetic radiation energy source 38 may adjust/align celestial energy beam 40 to center the same on electromagnetic radiation energy receiver 200.

The electromagnetic radiation energy receiver (e.g., electromagnetic radiation energy receiver 200) may include a jitter sensing system (e.g., jitter sensing system 228). An example of such a jitter sensing system (e.g., jitter sensing system 228) may include but is not limited to a pair of gyroscope-based jitter sensors. This jitter sensing system (e.g., jitter sensing system 228) may be positioned proximate energy receiving devices 202 and/or feedback devices 226 and may be configured to counteract vibrations of various portions of electromagnetic radiation energy receiver 200. Specifically and due to the time-delay associated with feedback travelling from energy receiving devices 202 to electromagnetic radiation energy source 38, such a jitter sensing system (e.g., jitter sensing system 228) may help ensure that drift does not occur due to sudden vibrational events of portions of electromagnetic radiation energy receiver 200.

As is known in the art, a jitter sensing system (e.g., jitter sensing system 228) is designed to detect and measure small, rapid, and often unpredictable fluctuations (i.e., jitter) in the position, angle, or stability of a signal or physical structure. In the context of electromagnetic radiation energy receiver 200, a jitter sensing system (e.g., jitter sensing system 228) may play a critical role in maintaining the precision and efficiency of energy reception, especially in systems where high-intensity beams (e.g., celestial energy beam 40) rely on accurate alignment with (in this example) energy receiving devices 202 and/or feedback devices 226. On electromagnetic radiation energy receiver 200, a jitter sensing system (e.g., jitter sensing system 228) may be used to monitor the stability of celestial energy beam 40 and detect slight deviations in its alignment or pointing accuracy. As discussed above, these deviations may be caused by vibrations, thermal distortions, platform motion (e.g., on a satellite or aircraft), or atmospheric interference. An example of such a jitter sensing system (e.g., jitter sensing system 228) may include but is not limited to a pair of gyroscope-based jitter sensors.

The electromagnetic radiation energy receiver (e.g., electromagnetic radiation energy receiver 200) may include a beam focusing system (e.g., beam focusing system 229) for receiving the celestial energy beam (e.g., celestial energy beam 40) and concentrating the same on the electromagnetic radiation energy receiver (e.g., electromagnetic radiation energy receiver 200). This beam focusing system (e.g., beam focusing system 229) may be crucial for concentrating celestial energy beam 40 onto electromagnetic radiation energy receiver 200 (which may include photovoltaic cell and/or rectenna) to maximize energy transfer efficiency. One example of beam focusing system 229 may include but is not limited to a convex lens, which bends parallel laser rays to a single focal point, increasing the energy density of celestial energy beam 40 at electromagnetic radiation energy receiver 200. These convex lenses may be made from materials like fused silica or BK7 glass, which may be chosen to match the wavelength of celestial energy beam 40 and minimize energy loss. For high-power or broadband celestial energy beams, beam focusing system 229 may include a parabolic mirror (e.g., an off-axis parabolic reflector) to focus celestial energy beam 40 without chromatic aberration and may handle greater thermal loads. In addition to simple focusing elements (e.g., such as lenses and mirrors), beam focusing system 229 may include beam collimators and expanders to prepare celestial energy beam 40 for focusing. By expanding and collimating celestial energy beam 40, such devices may allow for tighter and more precise focusing in the optical path. Additionally, beam focusing system 229 may include Fresnel lenses (which are flat and lightweight alternatives to traditional lenses) that may be used in space-constrained applications. For dynamic environments, beam focusing system 229 may utilize adaptive optics systems (e.g., deformable mirrors) to actively adjust the focus of celestial energy beam 40 in real time, thus enabling the compensation for atmospheric disturbances or motion between electromagnetic radiation energy source 38 and electromagnetic radiation energy receiver 200.

### Space-Based Energy Acquisition & Delivery Methodologies (General):

As discussed above, space-based energy system 10 includes solar energy gathering system 12, electromagnetic radiation energy source 38 and electromagnetic radiation energy receiver 200.

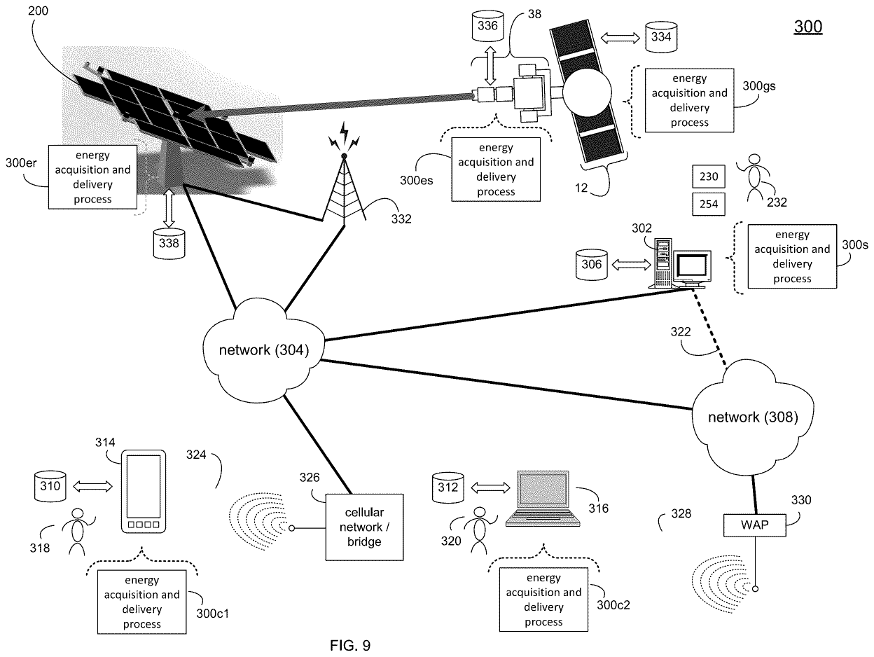

Referring to FIG. 9, there is shown energy acquisition and delivery process 300. As will be discussed below in greater detail, various portions of solar energy gathering system 12, electromagnetic radiation energy source 38 and electromagnetic radiation energy receiver 200 may be utilized to effectuate various methodologies and functionalities associated with the generation, processing and utilization of celestial energy beam 40.

Energy acquisition and delivery process 300 may be implemented as a server-side process, a client-side process, or a hybrid server-side/client-side process. For example, energy acquisition and delivery process 300 may be implemented as a purely server-side process via energy acquisition and delivery process 300s in combination with one or more of solar energy gathering system 12 (i.e., energy acquisition and delivery process 300gs), electromagnetic radiation energy source 38 (i.e., energy acquisition and delivery process 300es) and electromagnetic radiation energy receiver 200 (i.e., energy acquisition and delivery process 300er).

Alternatively, energy acquisition and delivery process 300 may be implemented as a purely client-side process via one or more of energy acquisition and delivery process 300cl and energy acquisition and delivery process 300c2 in combination with one or more of solar energy gathering system 12 (i.e., energy acquisition and delivery process 300gs), electromagnetic radiation energy source 38 (i.e., energy acquisition and delivery process 300es) and electromagnetic radiation energy receiver 200 (i.e., energy acquisition and delivery process 300er).

Alternatively still, energy acquisition and delivery process 300 may be implemented as a hybrid server-side/client-side process via energy acquisition and delivery process 300s and one or more of energy acquisition and delivery process 300cl and energy acquisition and delivery process 300c2 in combination with one or more of solar energy gathering system 12 (i.e., energy acquisition and delivery process 300gs), electromagnetic radiation energy source 38 (i.e., energy acquisition and delivery process 300es) and electromagnetic radiation energy receiver 200 (i.e., energy acquisition and delivery process 300er).

Accordingly, energy acquisition and delivery process 300 as used in this disclosure may include any combination of energy acquisition and delivery process 300s, energy acquisition and delivery process 300c1, energy acquisition and delivery process 300c2, solar energy gathering system 12 (i.e., energy acquisition and delivery process 300gs), electromagnetic radiation energy source 38 (i.e., energy acquisition and delivery process 300es) and electromagnetic radiation energy receiver 200 (i.e., energy acquisition and delivery process 300er).

Energy acquisition and delivery process 300s may be a server application and may reside on and may be executed by computing device 302, which may be connected to network 304 (e.g., the Internet or a local area network). Examples of computing device 302 may include, but are not limited to: a personal computer, a laptop computer, a server computer, a series of server computers, a mini computer, a mainframe computer, a cloud-based computing resource, or a dedicated network device.

The instruction sets and subroutines of energy acquisition and delivery process 300s, which may be stored on storage device 306 coupled to computing device 302, may be executed by one or more processors (not shown) and one or more memory architectures (not shown) included within computing device 302. Examples of storage device 306 may include but are not limited to: a hard disk drive; a tape drive; an optical drive; a RAID device; a random access memory (RAM); a read-only memory (ROM); and all forms of flash memory storage devices.

Network 304 may be connected to one or more secondary networks (e.g., secondary network 308), examples of which may include but are not limited to: a local area network; a wide area network; or an intranet, for example.

Examples of energy acquisition and delivery processes 300c1, 300c2 may include but are not limited to a web browser, a game console user interface, or a specialized application (e.g., an application running on e.g., the Android™ platform or the iPhone™ platform). The instruction sets and subroutines of energy acquisition and delivery processes 300c1, 300c2, which may be stored on storage devices 310, 312 (respectively) coupled to client electronic devices 314. 316 (respectively), may be executed by one or more processors (not shown) and one or more memory architectures (not shown) incorporated into client electronic devices 314, 316 (respectively). Examples of storage devices 310, 312 may include but are not limited to: hard disk drives; optical drives; RAID devices; random access memories (RAM); read-only memories (ROM), and all forms of flash memory storage devices.

Examples of client electronic devices 314. 316 may include, but are not limited to, data-enabled, cellular telephone 314, laptop computer 316, personal digital assistant (not shown), personal computer (not shown), a notebook computer (not shown), a server computer (not shown), a gaming console (not shown), a smart television (not shown), and a dedicated network device (not shown). Client electronic devices 314, 316 may each execute an operating system, examples of which may include but are not limited to Microsoft Windows™, Android™, WebOS™, iOS™, Redhat Linux™, or a custom operating system.

Users 318, 320 may access energy acquisition and delivery process 300 directly through network 304 or through secondary network 308. Further, energy acquisition and delivery process 300 may be connected to network 304 through secondary network 308, as illustrated with link line 322.

The various client electronic devices (e.g., client electronic devices 314, 316) may be directly or indirectly coupled to network 304 (or network 308). For example, data-enabled, cellular telephone 314 is shown wirelessly coupled to network 304 via wireless communication channel 324 established between data-enabled, cellular telephone 314 and cellular network/bridge 326, which is shown directly coupled to network 304. Further, laptop computer 316 is shown wirelessly coupled to network 308 via wireless communication channel 328 established between laptop computer 316 and wireless access point (i.e., WAP) 330, which is shown directly coupled to network 304.

WAP 330 may be, for example, an IEEE 802.11a, 802.11b, 802.11g, 802.11n, Wi-Fi, and/or Bluetooth device that is capable of establishing wireless communication channel 328 between laptop computer 316 and WAP 330. As is known in the art, IEEE 802.11x specifications may use Ethernet protocol and carrier sense multiple access with collision avoidance (i.e., CSMA/CA) for path sharing. The various 802.11x specifications may use phase-shift keying (i.e., PSK) modulation or complementary code keying (i.e., CCK) modulation, for example. As is known in the art, Bluetooth is a telecommunications industry specification that allows e.g., mobile phones, computers, and personal digital assistants to be interconnected using a short-range wireless connection.

Energy acquisition and delivery process 300gs may be an application and may reside on and may be executed by solar energy gathering system 12, which may be wirelessly coupled to network 304 (e.g., via a wireless communication system 332, examples of which may include but are not limited to an RF communication system, an optical communication system, and a microwave communication system).

The instruction sets and subroutines of energy acquisition and delivery process 300gs, which may be stored on storage device 334 coupled to solar energy gathering system 12, may be executed by one or more processors (not shown) and one or more memory architectures (not shown) included within solar energy gathering system 12. Examples of storage device 334 may include but are not limited to: a hard disk drive; an optical drive; a RAID device; a random access memory (RAM); a read-only memory (ROM); and all forms of flash memory storage devices.

Energy acquisition and delivery process 300es may be an application and may reside on and may be executed by electromagnetic radiation energy source 38, which may be wirelessly coupled to network 304 (e.g., via a wireless communication system 332, examples of which may include but are not limited to an RF communication system, an optical communication system, and a microwave communication system).

The instruction sets and subroutines of energy acquisition and delivery process 300es, which may be stored on storage device 336 coupled to energy acquisition and delivery process 300es, may be executed by one or more processors (not shown) and one or more memory architectures (not shown) included within energy acquisition and delivery process 300es. Examples of storage device 336 may include but are not limited to: a hard disk drive; an optical drive; a RAID device; a random access memory (RAM); a read-only memory (ROM); and all forms of flash memory storage devices.

Energy acquisition and delivery process 300er may be an application and may reside on and may be executed by electromagnetic radiation energy receiver 200, which may be wirelessly coupled to network 304 (e.g., via a wireless communication system 332, examples of which may include but are not limited to an RF communication system, an optical communication system, and a microwave communication system) or may be hardwired to network 304. Additionally/alternatively, wireless communication system 332 may be a portion of (or coupled to) electromagnetic radiation energy receiver 200, thus enabling electromagnetic radiation energy receiver 200 to transmit e.g., beam alignment information to electromagnetic radiation energy source 38.

The instruction sets and subroutines of energy acquisition and delivery process 300er, which may be stored on storage device 338 coupled to electromagnetic radiation energy receiver 200, may be executed by one or more processors (not shown) and one or more memory architectures (not shown) included within electromagnetic radiation energy receiver 200. Examples of storage device 338 may include but are not limited to: a hard disk drive; an optical drive; a RAID device; a random access memory (RAM); a read-only memory (ROM); and all forms of flash memory storage devices.

(7) Ground-Based Methodologies of Protecting Objects that May Pass Proximate the Transmission Beam.

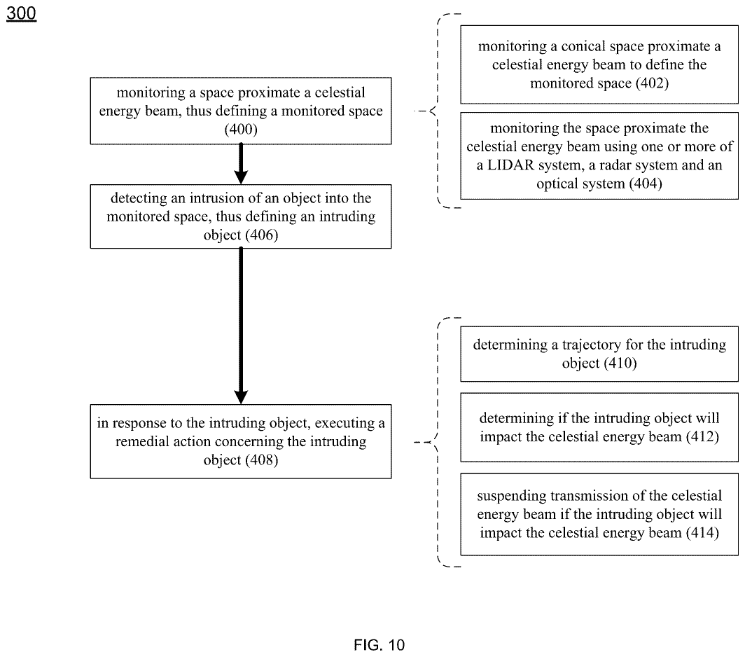

Referring also to FIG. 10, the following discussion concerns the manner in which energy acquisition and delivery process 300 may monitor a space proximate a celestial energy beam (e.g., celestial energy beam 40) using various monitoring technologies (e.g., LIDAR, Radar, optical) to detect objects that intrude the monitored space. And in the event that such an intruding object is detected, energy acquisition and delivery process 300 may execute a remedial action to avoid damage/injury to the intruding object.

As discussed above, the celestial energy beam (e.g., celestial energy beam 40) carries high levels of energy that can be hazardous to people, animals, or electronic systems if they enter the beam path or come too close to the high-energy receiver components for a prolonged period of time. Accordingly, energy acquisition and delivery process 300 may monitor 400 a space proximate a celestial energy beam (e.g., celestial energy beam 40), thus defining a monitored space (e.g., monitored space 220).

While this celestial energy beam (e.g., celestial energy beam 40) is typically transmitted from a space-based electromagnetic radiation energy source (e.g., electromagnetic radiation energy source 38) to a ground-based electromagnetic radiation energy receiver (e.g., electromagnetic radiation energy receiver 200), this is for illustrative purposes only and is not intended to be a limitation of this disclosure, as other configurations are possible and are considered to be within the scope of this disclosure. For example and in some configurations, this celestial energy beam (e.g., celestial energy beam 40) may be transmitted from a ground-based electromagnetic radiation energy source (e.g., electromagnetic radiation energy source 38G) to a space-based electromagnetic radiation energy receiver (e.g., electromagnetic radiation energy receiver 200S).

When monitoring 400 a space proximate a celestial energy beam (e.g., celestial energy beam 40), energy acquisition and delivery process 300 may monitor 402 a conical space proximate the celestial energy beam (e.g., celestial energy beam 40) to define the monitored space (e.g., monitored space 220).

For example, this monitored space (e.g., monitored space 220) may be a narrowly-focused conical space, and the celestial energy beam (e.g., celestial energy beam 40) may be positioned proximate the axis of the narrowly-focused conical space.

Alternatively, this monitored space (e.g., monitored space 220) may be a widely focused conical space; and the celestial energy beam (e.g., celestial energy beam 40) may be positioned proximate the axis of the widely focused conical space.

As discussed above, the monitoring system may include a LIDAR system, radar system, and optical system to observe and protect the space around a celestial energy beam by detecting objects, tracking movement, and ensuring the beam's path remains clear. A LIDAR system uses pulsed laser light to create high-resolution, real-time 3D maps of the environment and detect objects like aircraft and birds, triggering remedial action if necessary. A radar system uses radio waves for long-range, all-weather object detection, providing early warnings even in poor visibility conditions. An optical system uses cameras and sensors to passively capture images of the monitored space, offering fine tracking and confirmation, especially when enhanced with AI. When combined, these systems create a comprehensive situational awareness platform, with LIDAR offering precision detection, radar enabling broad and weather-resistant tracking, and optical systems providing visual verification.

Accordingly and when monitoring 400 a space proximate a celestial energy beam (e.g., celestial energy beam 40), energy acquisition and delivery process 300 may monitor 404 the space proximate the celestial energy beam (e.g., celestial energy beam 40) using one or more of a LIDAR system, a radar system and an optical system.

A ground-based LIDAR system, radar system, and optical system can be utilized together to monitor a conical space around celestial energy beam 40 by continuously detecting, tracking, and analyzing any objects that might enter the beam's path. The conical space (e.g., a three-dimensional area expanding outward from the beam's source or the beam's destination) is critical to monitor because any intrusion by aircraft, birds, drones, or debris could pose safety risks or interfere with the beam's operation.

A LIDAR system scans the conical space by emitting pulses of laser light and measuring the time it takes for those pulses to bounce back from objects. It creates high-resolution, real-time 3D maps of the monitored volume, detecting even small objects with great precision. LIDAR is particularly useful near the base of the cone where fine tracking of small, fast-moving objects is needed.

A radar system monitors the same conical volume using radio waves, which are less affected by weather conditions like clouds, rain, or fog. Radar provides long-range and wide-area detection, allowing early identification of fast-moving or distant objects that might be on a collision course with the beam. This ensures that threats can be detected even when visibility is poor.

An optical system (using cameras and telescopes operating in the visible or Infrared spectrum) provides visual confirmation of any objects detected by LIDAR or radar. Optical systems passively capture images and video of the monitored space, which can be analyzed to verify object types and assess potential risks. Though optical performance can be limited by lighting and weather, it offers valuable detail and verification for system operators.

Together, these three systems form a layered defense, with LIDAR offering precise, close-range detection, radar ensuring broad, all-weather coverage, and optical systems delivering detailed visual confirmation. This integrated monitoring approach ensures the conical space around the celestial energy beam remains clear and safe for continuous, reliable operation.

Energy acquisition and delivery process 300 may detect 406 an intrusion of an object into the monitored space (e.g., monitored space 220), thus defining an intruding object (e.g., intruding object 222). This detection may occur via one of the above-described LIDAR systems, radar systems, and optical systems. Examples of such an intruding object (e.g., intruding object 222) may include but are not limited to: commercial aircraft, recreational aircraft, military aircraft, drones, birds, and lighter than air objects (such as weather balloons).

In response to the intruding object (e.g., intruding object 222) being detected 406, energy acquisition and delivery process 300 may execute 408 a remedial action concerning the intruding object (e.g., intruding object 222).

When executing 408 a remedial action concerning the intruding object (e.g., intruding object 222), energy acquisition and delivery process 300 may:
determine 410 a trajectory for the intruding object (e.g., intruding object 222); and
determine 412 if the intruding object (e.g., intruding object 222) will impact the celestial energy beam (e.g., celestial energy beam 40).

Specifically and upon detecting 406 the intruding object (e.g., intruding object 222) within the monitored space (e.g., monitored space 220), the remedial action executed 408 by the energy acquisition and delivery process 300 may first determine 410 a trajectory for the intruding object (e.g., intruding object 222) so that a determination 412 may be made concerning whether the intruding object (e.g., intruding object 222) will impact the celestial energy beam (e.g., celestial energy beam 40).

To determine the trajectory of an intruding object (e.g., intruding object 222) within a monitored space (e.g., monitored space 220) using LIDAR, radar, or an optical system, the system must first detect the position of the object (e.g., intruding object 222) over time and then analyze its motion path.

With LIDAR, the system emits laser pulses and measures the time it takes for the light to return after reflecting off the object (e.g., intruding object 222). By scanning the space rapidly and repeatedly, LIDAR can produce a series of 3D point clouds that show the changing position of the object (e.g., intruding object 222). By analyzing these sequential position measurements, the system can calculate the velocity, direction, and future trajectory of the object (e.g., intruding object 222) with high spatial accuracy.

Using radar, the system sends out radio waves that bounce off the object (e.g., intruding object 222) and return to the receiver. Radar systems can measure not only the range (distance) of the object (e.g., intruding object 222) but also its velocity directly through the Doppler effect (i.e., a change in frequency due to the motion of the object (e.g., intruding object 222). Continuous radar tracking provides the changing position and speed of the object (e.g., intruding object 222), allowing software to project the likely future path of the intruding object (e.g., intruding object 222) even at long distances or in poor visibility.

With an optical system, such as a visible or Infrared camera, the system captures a series of images over time. By analyzing the pixel movement of the object (e.g., intruding object 222) across sequential frames and applying known calibration parameters (like lens properties and field of view), the system can estimate the real-world position, velocity, and trajectory of object (e.g., intruding object 222). Although optical tracking can be sensitive to lighting and visibility conditions, it can offer high-resolution imagery useful for identifying and classifying the object (e.g., intruding object 222) as well as predicting their motion. Accordingly, optical tracking may allow for the monitoring of various objects (e.g., manmade orbiting objects) that are currently proximate the celestial energy beam (e.g., celestial energy beam 40) or are moving toward the celestial energy beam (e.g., celestial energy beam 40).

In all three cases, the key is continuous tracking and time-based analysis of the position of the object (e.g., intruding object 222) to model and predict its trajectory through the monitored space (e.g., monitored space 220). More advanced systems may fuse data from multiple sensors (LIDAR, radar, and optical) to improve accuracy and reliability.

Logically, if it is determined 412 that the intruding object (e.g., intruding object 222) WILL NOT impact the celestial energy beam (e.g., celestial energy beam 40) and WILL safely pass through the monitored space (e.g., monitored space 220) WITHOUT impacting the celestial energy beam (e.g., celestial energy beam 40), energy acquisition and delivery process 300 may take no remedial action concerning the intruding object (e.g., intruding object 222).

However, if it is determined 412 that the intruding object (e.g., intruding object 222) WILL impact the celestial energy beam (e.g., celestial energy beam 40) and WILL NOT safely pass through the monitored space (e.g., monitored space 220), energy acquisition and delivery process 300 may execute 408 a remedial action to avoid injury to the intruding object (e.g., intruding object 222). Naturally, if an object is moving quickly enough, it may be able to safely pass though the monitored space (e.g., monitored space 220) even if such passage will result in the object impacting the celestial energy beam (e.g., celestial energy beam 40), as the amount of time that the celestial energy beam (e.g., celestial energy beam 40) is actually striking the object will be de minimis.

For example and when executing 408 a remedial action concerning the intruding object (e.g., intruding object 222), energy acquisition and delivery process 300 may suspend 414 transmission of the celestial energy beam (e.g., celestial energy beam 40) if the intruding object (e.g., intruding object 222) will impact the celestial energy beam (e.g., celestial energy beam 40).

Assume for this example that a recreational aircraft is travelling within an airspace proximate celestial energy beam 40. As discussed above, energy acquisition and delivery process 300 may monitor 400 the space proximate the celestial energy beam (e.g., celestial energy beam 40), namely the monitored space (e.g., monitored space 220). For this example, assume that monitored space 220 is a conical space, wherein the vertex of the conical space is positioned proximate the ground-based electromagnetic radiation energy receiver (e.g., electromagnetic radiation energy receiver 200) and celestial energy beam 40 is positioned proximate the longitudinal axis of symmetry of the conical monitored space (e.g., monitored space 220). Further assume for this example that the recreational aircraft enters the monitored space (e.g., monitored space 220), thus defining this recreational aircraft as an intruding object (e.g., intruding object 222).

Accordingly, energy acquisition and delivery process 300 may detect 406 an intrusion of the recreational aircraft (e.g., intruding object 222) into the monitored space (e.g., monitored space 220). In response to such a detection 406, energy acquisition and delivery process 300 may execute 408 a remedial action concerning the recreational aircraft (e.g., intruding object 222). For example and when executing 408 the remedial action concerning the recreational aircraft (e.g., intruding object 222), energy acquisition and delivery process 300 may: determine 410 a trajectory for the recreational aircraft (e.g., intruding object 222) so that it may determine 412 if the recreational aircraft (e.g., intruding object 222) will impact the celestial energy beam (e.g., celestial energy beam 40).

Naturally, if it is determined 412 that the recreational aircraft (e.g., intruding object 222) WILL NOT impact the celestial energy beam (e.g., celestial energy beam 40) and WILL safely pass through the monitored space (e.g., monitored space 220) WITHOUT impacting the celestial energy beam (e.g., celestial energy beam 40), energy acquisition and delivery process 300 may take no remedial action concerning the recreational aircraft (e.g., intruding object 222).

However, if it is determined 412 that the recreational aircraft (e.g., intruding object 222) WILL impact the celestial energy beam (e.g., celestial energy beam 40) and WILL NOT safely pass through the monitored space (e.g., monitored space 220), energy acquisition and delivery process 300 may execute 408 a remedial action to avoid injury to the recreational aircraft (e.g., intruding object 222). Naturally, if an object is moving quickly enough, it may be able to safely pass though the monitored space (e.g., monitored space 220) even if such passage will result in the object impacting the celestial energy beam (e.g., celestial energy beam 40), as the amount of time that the celestial energy beam (e.g., celestial energy beam 40) is actually striking the object will be de minimis. For example and when executing 408 a remedial action concerning the recreational aircraft (e.g., intruding object 222), energy acquisition and delivery process 300 may suspend 414 transmission of the celestial energy beam (e.g., celestial energy beam 40) if the recreational aircraft (e.g., intruding object 222) will impact the celestial energy beam (e.g., celestial energy beam 40). For example, celestial energy beam 40 may be completely deenergized (i.e., shut off) or may be deenergized to the point that it can no longer harm the recreational aircraft (e.g., intruding object 222).

Accordingly and in such a situation, once the recreational aircraft (e.g., intruding object 222) safely passes through the monitored space (e.g., monitored space 220), energy acquisition and delivery process 300 may resume transmission of (or reenergize) the celestial energy beam (e.g., celestial energy beam 40). While the following discussion concerned a system that monitors a portion of the airspace proximate the celestial energy beam (e.g., celestial energy beam 40), this is for illustrative purposes only and is not intended to be a limitation of this disclosure, as other configurations are possible and are considered to be within the scope of this disclosure. For example and instead of the monitoring-based approach described above, energy acquisition and delivery process 300 may take more of a data-driven approach, such as ensuring that the celestial energy beam (e.g., celestial energy beam 40) is not present within (or is deenergized if within) various “keep-out zones” (e.g., around aircraft and satellites), wherein these “keep-out zones” may be defined by various governmental organizations (e.g., the FAA, NASA, etc.) or private sector companies (e.g., SpaceX, Blue Origin, etc.). For example, assume that a SpaceX booster stage is going to be reentering the atmosphere at a certain date/time, wherein the trajectory of this returning booster stage is going to be passing through the monitored space (e.g., monitored space 220). Accordingly, SpaceX may request that the celestial energy beam (e.g., celestial energy beam 40) be powered down for e.g., a 30 minute period at a specific date/time. Accordingly and in response to such a request, energy acquisition and delivery process 300 may suspend 414 transmission of the celestial energy beam (e.g., celestial energy beam 40) during such a 30 minute period at the specific date/time.

### (8) Methodologies of Preventing Ground-Based Object Damage.

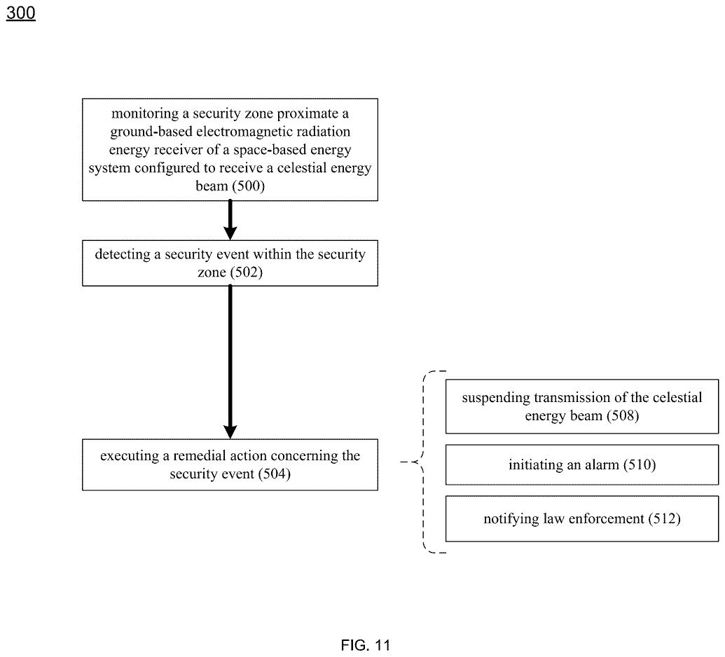

Referring also to FIG. 11, the following discussion concerns the manner in which energy acquisition and delivery process 300 may monitor a security zone proximate an electromagnetic radiation energy receiver (e.g., electromagnetic radiation energy receiver 200). And in the event that an intruder is detected within the security zone, energy acquisition and delivery process 300 may execute a remedial action to avoid damage/injury to the intruder.

As discussed above, the celestial energy beam (e.g., celestial energy beam 40) carries high levels of energy that can be hazardous to people, animals, or electronic systems if they enter the beam path or come too close to the high-energy receiver components for a prolonged period of time included within the electromagnetic radiation energy receiver (e.g., electromagnetic radiation energy receiver 200).

Accordingly, the electromagnetic radiation energy receiver (e.g., electromagnetic radiation energy receiver 200) may include: a security zone (e.g., security zone 214). This security zone (e.g., security zone 214) may be positioned proximate (e.g., surround) the electromagnetic radiation energy receiver (e.g., electromagnetic radiation energy receiver 200). For example, the security zone (e.g., security zone 214) may be a 100 foot radius circle that surrounds the electromagnetic radiation energy receiver (e.g., electromagnetic radiation energy receiver 200).

Specifically and depending upon the energy density of celestial energy beam 40, it is foreseeable that an intruder (e.g., intruder 216) within the security zone (e.g., security zone 214) may be injured if the intruder (e.g., intruder 216) makes contact with celestial energy beam 40. This is especially important because the celestial energy beam (e.g., celestial energy beam 40) carries high levels of energy that can be hazardous to people and animals if they enter the beam path or come too close to the high-energy receiver components for a prolonged period of time.

As discussed above, while this celestial energy beam (e.g., celestial energy beam 40) is typically transmitted from a space-based electromagnetic radiation energy source (e.g., electromagnetic radiation energy source 38) to a ground-based electromagnetic radiation energy receiver (e.g., electromagnetic radiation energy receiver 200), this is for illustrative purposes only and is not intended to be a limitation of this disclosure, as other configurations are possible and are considered to be within the scope of this disclosure. For example and in some configurations, this celestial energy beam (e.g., celestial energy beam 40) may be transmitted from a ground-based electromagnetic radiation energy source (e.g., electromagnetic radiation energy source 38G) to a space-based electromagnetic radiation energy receiver (e.g., electromagnetic radiation energy receiver 200S).

Accordingly, energy acquisition and delivery process 300 may monitor 500 the security zone (e.g., security zone 214) proximate the ground-based electromagnetic radiation energy receiver (e.g., electromagnetic radiation energy receiver 200) of the space-based energy system (e.g., space-based energy system 10) configured to receive a celestial energy beam (e.g., celestial energy beam 40). Specifically, this security zone (e.g., security zone 214) may be monitored for the occurrence of a security event and, if such a security event is detected, remedial actions may be taken.

As discussed above, this security zone (e.g., security zone 214) may be defined via a physical barrier, examples of which may include but are not limited to one or more of a fence and a wall. For example, physical barriers such as chain-link fences, privacy fences, brick walls, etc. may be used to physically define the security zone (e.g., security zone 214) to protect the electromagnetic radiation energy receiver (e.g., electromagnetic radiation energy receiver 200) by defining a physical perimeter around some or all of the electromagnetic radiation energy receiver (e.g., electromagnetic radiation energy receiver 200), restricting unauthorized access to the same, and ensuring safety during transmission of celestial energy beam 40.

Additionally/alternatively, the security zone (e.g., security zone 214) may be defined via an electronic barrier, wherein an example of such an electronic barrier may include but is not limited to a geofence barrier. A geofence barrier can be used to digitally define the security zone (e.g., security zone 214) to protect the electromagnetic radiation energy receiver (e.g., electromagnetic radiation energy receiver 200) by defining a virtual perimeter around some or all of the electromagnetic radiation energy receiver (e.g., electromagnetic radiation energy receiver 200) to restrict unauthorized access and ensure safety during beam transmission.

As discussed above and in practical terms, the security zone (e.g., security zone 214) may be defined via a combination of physical and electronic barriers to ensure the safe operation of the electromagnetic radiation energy receiver (e.g., electromagnetic radiation energy receiver 200). Accordingly, the above-referenced security event may be defined as the breaching the physical barrier and/or the breaching the electronic barrier that define the security zone (e.g., security zone 214).

Assume for this example that an intruder (e.g., intruder 216) breaches the physical barrier and/or the breaches the electronic barrier that define the security zone (e.g., security zone 214). For example, if the physical barrier includes a door or a gate, breaking the physical barrier may include the intruder (e.g., intruder 216) opening the door or gate (which may be detected via magnetic switches on the door/gate). If the physical barrier includes a wall, breaking the physical barrier may include the intruder (e.g., intruder 216) scaling the wall (which may be detected via motion detectors/Infrared beams). If the electronic barrier is a geofenced region, electronic surveillance may be used to detect intrusions within this space. For example, smart tags and RFID badges may be worn by authorized personnel, wherein a person entering the geofenced region without the appropriate smart tag/RFID badge may be deemed an intruder (e.g., intruder 216). Additionally/alternatively, more traditional electronic surveillance systems (e.g., motion detectors, Infrared beams, thermal imaging cameras, etc.) may be utilized to detect a breaching of the geofenced region (i.e., security zone 214).

Continuing with the example in which an intruder (e.g., intruder 216) breaches the physical barrier and/or the breaches the electronic barrier that define the security zone (e.g., security zone 214). Accordingly, energy acquisition and delivery process 300 may detect 502 a security event within the security zone (e.g., security zone 214) and, in response to such detection, may execute 504 a remedial action concerning the security event (e.g., intruder 216 breaching the physical barrier and/or the electronic barrier).

When executing 506 a remedial action concerning the security event, energy acquisition and delivery process 300 may: suspend 508 transmission of the celestial energy beam (e.g., celestial energy beam 40); initiate 510 an alarm; and/or notify 512 law enforcement.

Continuing with the example in which an intruder (e.g., intruder 216) breaches the physical barrier and/or the breaches the electronic barrier that define the security zone (e.g., security zone 214), energy acquisition and delivery process 300 may suspend 508 transmission of the celestial energy beam (e.g., celestial energy beam 40). For example, celestial energy beam 40 may be completely deenergized (i.e., shut off) or may be deenergized to the point that it can no longer harm the intruder (e.g., intruder 216).

Further, energy acquisition and delivery process 300 may initiate 510 an alarm. For example, celestial energy beam 40 may initiate 510 a silent alarm, an audible alarm, and/or a light-based alarm (e.g., illuminate security lights) in an attempt to frighten off the intruder (e.g., intruder 216).

Additionally, energy acquisition and delivery process 300 may notify 512 law enforcement. For example, celestial energy beam 40 may notify 512 security personnel, local law enforcement, state-level law enforcement and/or Federal level law enforcement.

In order to provide an enhanced level of safety, at least a portion of the security zone (e.g., security zone 214) may be configured to absorb at least a portion of the celestial energy beam (e.g., celestial energy beam 40). As discussed above and to safely manage the power from celestial energy beam 40, an energy absorbing system (e.g., energy absorbing system 224) may be used to safely dissipate excess electromagnetic energy without causing damage. Energy absorbing system 224 may include energy absorbing coatings and energy absorbing structures, each designed to handle the specific characteristics of celestial energy beam 40.

Areas outside of the primary energy receivers (e.g., energy receiving devices 202) may be protected by these energy absorbing systems (e.g., energy absorbing system 224) to capture stray radiation. Energy absorbing coatings include laser-absorbing materials like carbon black or cermets for lasers, and radar absorbing materials (RAM) for microwaves, both converting energy into heat. Energy absorbing structures use high thermal conductivity materials like graphite, tungsten, or ceramics to absorb energy and either transfer it to heat engines or dissipate it through radiator panels. Advanced structures may use metamaterials for high-efficiency absorption. Overall, the energy absorbing system (e.g., energy absorbing system 224) protects sensitive equipment, infrastructure, humans, and animals by ensuring stray beam energy is safely managed.

9) Methodology of Aligning a Celestial Energy Beam with a Receiver Using a Multistep Alignment Procedure.

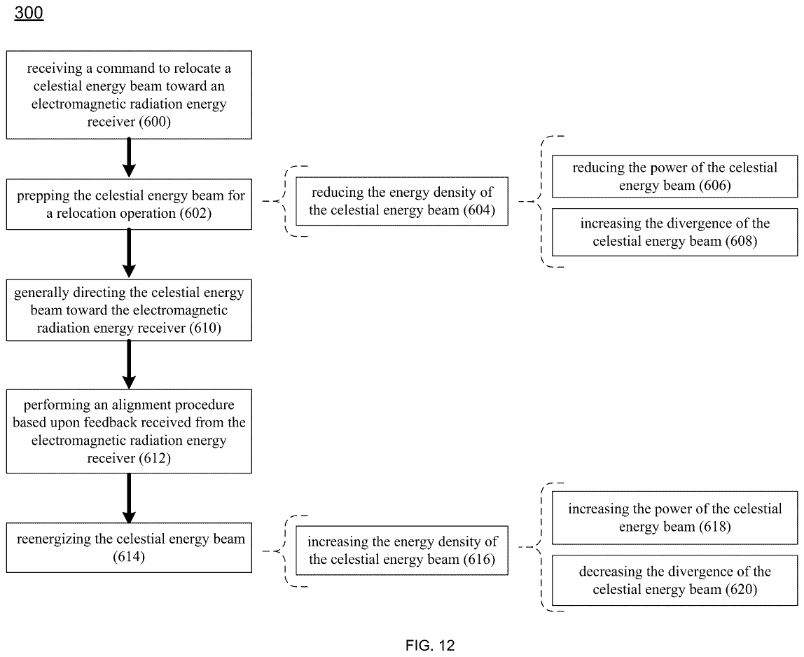

Referring also to FIG. 12, the following discussion concerns the manner in which energy acquisition and delivery process 300 may relocate a celestial energy beam (e.g., celestial energy beam 40) from one electromagnetic radiation energy receiver (e.g., electromagnetic radiation energy receiver 200A) to another electromagnetic radiation energy receiver (e.g., electromagnetic radiation energy receiver 200) and/or relocate a newly-generated celestial energy beam (e.g., celestial energy beam 40) to strike a electromagnetic radiation energy receiver (e.g., electromagnetic radiation energy receiver 200).

In the event that such a beam relocation operation is needed, a command (e.g., command 230) to effectuate the same may be generated. This command (e.g., command 230) may be automatically generated by energy acquisition and delivery process 300 . . . or may be manually generated by a user of energy acquisition and delivery process 300. For example, energy acquisition and delivery process 300 may monitor the utilization of various electromagnetic radiation energy receivers. And if (e.g., due to the rotation of the earth, cloud cover or any other reason) there is a need to relocate celestial energy beam 40, energy acquisition and delivery process 300 may automatically generate such a relocation command (e.g., command 230). Alternatively, such a relocation command (e.g., command 230) may be manually generated by a user (e.g., user 232) if e.g., celestial energy beam 40 needs to be directed toward a mobile electromagnetic radiation energy receiver (e.g., electromagnetic radiation energy receiver 200) that is temporarily coupled to the power distribution grid (e.g., power distribution grid 210) of an area in need of temporary power (e.g., an area struck by Superstorm Sandy).

Accordingly and regardless of its origin, energy acquisition and delivery process 300 may receive 600 this command (e.g., command 230) to relocate a celestial energy beam (e.g., celestial energy beam 40) toward an electromagnetic radiation energy receiver (e.g., electromagnetic radiation energy receiver 200). In response to receiving 600 such a command (e.g., command 230), energy acquisition and delivery process 300 may prep 602 the celestial energy beam (e.g., celestial energy beam 40) for a relocation operation.

As discussed above, while this celestial energy beam (e.g., celestial energy beam 40) is typically transmitted from a space-based electromagnetic radiation energy source (e.g., electromagnetic radiation energy source 38) to a ground-based electromagnetic radiation energy receiver (e.g., electromagnetic radiation energy receiver 200), this is for illustrative purposes only and is not intended to be a limitation of this disclosure, as other configurations are possible and are considered to be within the scope of this disclosure. For example and in some configurations, this celestial energy beam (e.g., celestial energy beam 40) may be transmitted from a ground-based electromagnetic radiation energy source (e.g., electromagnetic radiation energy source 38G) to a space-based electromagnetic radiation energy receiver (e.g., electromagnetic radiation energy receiver 200S).

When prepping 602 the celestial energy beam (e.g., celestial energy beam 40) for a relocation operation, energy acquisition and delivery process 300 may: reduce 604 the energy density of the celestial energy beam (e.g., celestial energy beam 40). This reduction in the energy density of celestial energy beam 40 may be performed in order to enhance safety and/or reduce the risk associated with the relocation of celestial energy beam 40.

When reducing 604 the energy density of the celestial energy beam (e.g., celestial energy beam 40), energy acquisition and delivery process 300 may: reduce 606 the power of the celestial energy beam (e.g., celestial energy beam 40) and/or increase 608 the divergence of the celestial energy beam (e.g., celestial energy beam 40).

The energy density of a celestial energy beam (e.g., celestial energy beam 40) refers to the amount of energy delivered per unit area of the celestial energy beam (e.g., celestial energy beam 40). To reduce the energy density of celestial energy beam 40, two main strategies may be used: reducing the power of celestial energy beam 40 and/or increasing the divergence of celestial energy beam 40.

Reducing Power: Reducing 606 the power of celestial energy beam 40 involves lowering the total amount of energy being transmitted. Such a power reduction may be effectuated by decreasing the power supplied to energy beam source 100 within electromagnetic radiation energy source 38, thus resulting in a less powerful celestial energy beam 40. Since energy density is directly related to the beam's total power, a lower-power beam naturally results in less energy being concentrated in any given area of the celestial energy beam. For example, if the beam power is cut in half, the energy density will also be cut in half, assuming the beam size remains the same.

Increasing Divergency: Increasing 608 the divergence of celestial energy beam 40 involves widening the beam as it travels through space. Such an increase may be effectuated via the beam forming package 104 within electromagnetic radiation energy source 38. A more divergent beam spreads its energy over a larger area, which decreases the energy concentration at any given point. Accordingly and even if the total power of the beam remains the same, the energy density of the beam will be reduced since the same amount of energy is distributed over a broader cross-sectional area.

In practical terms, reducing energy density by these methods can improve safety helping to prevent damage to equipment, minimizing risk to nearby humans, aircraft or animals, and easing the thermal and structural load on receiving systems. It also allows for more manageable interception or redirection of the beam if necessary.

Once the celestial energy beam (e.g., celestial energy beam 40) is prepped 602, energy acquisition and delivery process 300 may generally direct 610 the celestial energy beam (e.g., celestial energy beam 40) toward the electromagnetic radiation energy receiver (e.g., electromagnetic radiation energy receiver 200). Energy acquisition and delivery process 300 may then perform 612 an alignment procedure based upon feedback (e.g., feedback 234) received from the electromagnetic radiation energy receiver (e.g., electromagnetic radiation energy receiver 200).

Such feedback (e.g., feedback 234) may be received on feedback receiving devices (e.g., feedback receiving devices 128) included within electromagnetic radiation energy source 38. Examples of such feedback receiving devices (e.g., feedback receiving devices 128) may include but are not limited to one or more of: one or more photovoltaic cells; one or more photodiodes; one or more heat engines; and one or more rectenna arrays.

As discussed above, photovoltaic cells, or solar cells, convert light directly into electricity using the photovoltaic effect, where photons knock electrons loose in semiconductor materials like silicon to create an electric current. They are widely used in solar panels and can be designed to respond to specific light wavelengths, such as lasers, for wireless power transfer or space applications. Photodiodes, on the other hand, are light sensors that generate an electrical current when exposed to light, operating quickly and sensitively for applications like optical communications and laser detection, often tuned for specific wavelengths. Heat engines are devices that convert heat energy into useful work. For example, such heat engines may be mechanical or solid-state in nature. Solid-state heat engines such as thermoelectric generators (TEGs) produce electricity from heat using the Seebeck effect, generating voltage across different materials due to a temperature difference; they are durable, maintenance-free, and useful in harsh or remote environments, although less efficient than photovoltaic or rectenna systems. Rectennas, or rectifying antennas, convert electromagnetic waves like microwaves into DC electricity using an antenna and rectifying circuit. They are highly efficient for wireless power transmission, particularly in space-based solar power systems, and can collect large amounts of energy when deployed in arrays.

The feedback (e.g., feedback 234) received from the electromagnetic radiation energy receiver (e.g., electromagnetic radiation energy receiver 200) may include feedback reflected from one or more feedback devices (e.g., feedback devices 226) included within the electromagnetic radiation energy receiver (e.g., electromagnetic radiation energy receiver 200). For example, these one or more feedback devices (e.g., feedback devices 226) may be interspersed within (or positioned proximate) energy receiving devices 202 included within electromagnetic radiation energy receiver 200. Specifically, these one or more feedback devices (e.g., feedback devices 226) may include one or more of: a centrally-positioned feedback device (i.e., a feedback device that is centrally positioned within energy receiving devices 202 included within electromagnetic radiation energy receiver 200); and a plurality of peripherally-positioned feedback devices (i.e., a plurality of feedback devices that are peripherally-positioned about the perimeter of energy receiving devices 202 included within electromagnetic radiation energy receiver 200).

At least one of the feedback devices (e.g., feedback devices 226) may be a retroreflector. As discussed above, a retroreflector is a specialized feedback device or surface that reflects incoming electromagnetic radiation (e.g., a portion of celestial energy beam 40) directly back toward its source (e.g., electromagnetic radiation energy source 38), regardless of the angle at which celestial energy beam 40 arrives. Unlike a standard mirror, which reflects light at an angle equal to the incident angle, a retroreflector returns celestial energy beam 40 along a near-exact path from which it came through geometric structures (e.g., corner cubes, cat's-eye lenses, or Bragg gratings). In the context of celestial energy beam 40, a retroreflector can be strategically placed near or integrated into the electromagnetic radiation energy receiver 200, wherein it may reflect a small portion of the incoming energy beam (e.g., celestial energy beam 40) back to it source (e.g., energy beam source 100), where it can be used to provide feedback to electromagnetic radiation energy source 38.

As discussed above, the feedback devices (e.g., feedback devices 226) may include an RF component. Specifically, feedback devices 226 may include a plurality of opto-electrical sensors (e.g., photodiodes, photodetectors and/or photovoltaic cells). This plurality of sensors (e.g., feedback devices 226) may monitor the position of celestial energy beam 40, which is received on electromagnetic radiation energy receiver 200 from electromagnetic radiation energy source 38. This information concerning beam alignment (i.e., the manner in which celestial energy beam 40 is striking electromagnetic radiation energy receiver 200) may be provided to an RF transmitter (e.g., wireless communication system 332) that is included within/coupled to/available to electromagnetic radiation energy receiver 200 so that such information may be transmitted to the electromagnetic radiation energy source (e.g., electromagnetic radiation energy source 38). This information may then be used by electromagnetic radiation energy source 38 to reposition celestial energy beam 40 via beam aiming assembly 102 (if adjustment is needed).

Generally speaking, by looking at the intensity of the feedback (e.g., feedback 234) received from the centrally-positioned feedback device versus the peripherally-positioned feedback devices), energy acquisition and delivery process 300 may ascertain how well the incoming energy beam (e.g., celestial energy beam 40) is striking electromagnetic radiation energy receiver 200. For example:
TOTAL MISS: If no feedback (e.g., feedback 234) is received by electromagnetic radiation energy source 38, this situation may indicate that the celestial energy beam (e.g., celestial energy beam 40) is not striking electromagnetic radiation energy receiver 200 at all. Accordingly, celestial energy beam 40 may need to be relocated by electromagnetic radiation energy source 38.
PARTIAL HIT/PARTIAL MISS. If any feedback (e.g., feedback 234) is received by electromagnetic radiation energy source 38, this situation may indicate that the celestial energy beam (e.g., celestial energy beam 40) is at least partially striking electromagnetic radiation energy receiver 200. For example, if one or more of the peripherally-positioned feedback devices are providing a higher level of feedback (e.g., feedback 234) than the centrally-positioned feedback device, this situation may indicate that the celestial energy beam (e.g., celestial energy beam 40) is not centered on electromagnetic radiation energy receiver 200 and is partially striking energy receiving devices 202 included within electromagnetic radiation energy receiver 200 . . . but also partially missing energy receiving devices 202 included within electromagnetic radiation energy receiver 200.
TOTAL HIT: If the centrally-positioned feedback device is providing a higher level of feedback (e.g., feedback 234) while the peripherally-positioned feedback devices are providing a lower level of feedback (e.g., feedback 234), this situation may indicate that the celestial energy beam (e.g., celestial energy beam 40) is centered within energy receiving devices 202 included within electromagnetic radiation energy receiver 200. However, operational safety may be maximized when the celestial energy beam (e.g., celestial energy beam 40) is evenly distributed across the entirety of the energy receiving devices 202 included within electromagnetic radiation energy receiver 200 (as opposed to being concentrated in the center). Accordingly, energy acquisition and delivery process 300 may adjust the divergence of the celestial energy beam (e.g., celestial energy beam 40) to spread the beam evenly across all of the energy receiving devices 202 included within electromagnetic radiation energy receiver 200.

Accordingly, the feedback (e.g., feedback 234) received by electromagnetic radiation energy source 38 may be utilized to adjust the position and the divergence of the celestial energy beam (e.g., celestial energy beam 40).

As discussed above, by comparing the level of feedback (e.g., feedback 234) received from the centrally-positioned feedback device versus the peripherally-positioned feedback devices, the manner in which the celestial energy beam (e.g., celestial energy beam 40) is striking the electromagnetic radiation energy receiver 200 may be determined (e.g., total miss versus partial hit/partial miss versus total hit).

Accordingly, the feedback (e.g., feedback 234) received from the electromagnetic radiation energy receiver (e.g., electromagnetic radiation energy receiver 200) may include feedback encoded to identify the electromagnetic radiation energy receiver (e.g., electromagnetic radiation energy receiver 200) and/or identify the specific feedback devices interspersed within the energy receiving devices 202 included within electromagnetic radiation energy receiver 200. Through the use of such encoding and identification techniques, the level of feedback (e.g., feedback 234) received from the centrally-positioned feedback device versus the peripherally-positioned feedback devices may be compared to enable energy acquisition and delivery process 300 to perform 612 the alignment procedure described above.

These feedback devices (e.g., feedback devices 226) may be modulated to encode data (e.g., the identity of the electromagnetic radiation energy receiver and/or the identity of the specific feedback devices) within the feedback (e.g., feedback 234) by dynamically altering how these feedback devices (e.g., feedback devices 226) reflect incoming electromagnetic energy (e.g., celestial energy beam 40) over time. This encoding may be accomplished by modulating the intensity, phase, polarization, or timing of the reflected signal (e.g., feedback 234) in a controlled way, with the changes representing the encoded information.

One common method to achieve such encoding is through the use of a modulating feedback device (e.g., a modulating retroreflector), where the feedback device may be paired with a system/actuator that rapidly changes the optical properties of the feedback device. Some methods of achieving such modulation may include but are not limited to:
Mechanical Modulation: A small shutter, MEMS (microelectromechanical system) device, or vibrating mirror may physically open and close or change orientation of the feedback device (e.g., one or more of feedback devices 226) to modulate how much light is reflected, wherein these open/closed states may represent encoded binary data.
Electro-Optical Modulation: Materials like liquid crystals or electro-optic polymers placed in front of the feedback device (e.g., one or more of feedback devices 226) may change their optical properties (such as transparency, refractive index, or polarization) when voltage is applied, allowing fast, electronic control of the reflected beam's characteristics to represent encoded binary data.
Acousto-Optic Modulation: Sound waves may be used to modulate the surface of the feedback device (e.g., one or more of feedback devices 226) or an optical material may be placed in front of the feedback device (e.g., one or more of feedback devices 226), altering the properties of the reflected beam to encode binary data.
Thermal or Phase Modulation: The surface temperature or refractive index of the feedback device (e.g., one or more of feedback devices 226) may be slightly altered to create phase shifts in the reflected beam, which may be used to encode binary data.

By modulating the reflection characteristics of the feedback devices (e.g., one or more of feedback devices 226) in a precise, time-controlled manner, data (e.g., telemetry, identification signals, or communications) may be encoded within the reflected energy beam (e.g., feedback 234) without requiring the feedback device to generate its own signals.

As discussed above and through the use of such encoding and identification techniques, the level of feedback (e.g., feedback 234) received from the centrally-positioned feedback device (e.g., one or more of feedback devices 226) versus the peripherally-positioned feedback devices (e.g., one or more of feedback devices 226) may be compared to enable energy acquisition and delivery process 300 to perform 612 the alignment procedure described above.

Once celestial energy beam 40 is properly aligned with the electromagnetic radiation energy receiver (e.g., electromagnetic radiation energy receiver 200), energy acquisition and delivery process 300 may reenergize 614 the celestial energy beam (e.g., celestial energy beam 40). When reenergizing 614 the celestial energy beam (e.g., celestial energy beam 40), energy acquisition and delivery process 300 may increase 616 the energy density of the celestial energy beam (e.g., celestial energy beam 40). This increase in the energy density of celestial energy beam 40 may be performed in order to enhance the transmission efficiency of the celestial energy beam 40.

When increasing 616 the energy density of the celestial energy beam (e.g., celestial energy beam 40), energy acquisition and delivery process 300 may: increase 618 the power of the celestial energy beam (e.g., celestial energy beam 40) and/or decrease 620 the divergence of the celestial energy beam (e.g., celestial energy beam 40).

As discussed above, the energy density of a celestial energy beam (e.g., celestial energy beam 40) refers to the amount of energy delivered per unit area of the celestial energy beam (e.g., celestial energy beam 40). To increase the energy density of celestial energy beam 40, two main strategies may be used: increasing the power of celestial energy beam 40 and/or decreasing the divergence of celestial energy beam 40.

Increasing Power: Increasing 618 the power of celestial energy beam 40 involves increasing the total amount of energy being transmitted. Such a power increase may be effectuated by increasing the power supplied to energy beam source 100 within electromagnetic radiation energy source 38, thus resulting in a more powerful celestial energy beam 40. Since energy density is directly related to the beam's total power, a higher-power beam naturally results in more energy being concentrated in any given area of the celestial energy beam. For example, if the beam power is doubled, the energy density will also be doubled, assuming the beam size remains the same.

Decreasing Divergence: Decreasing 620 the divergence of celestial energy beam 40 involves narrowing the beam as it travels through space. Such a decrease may be effectuated via the beam forming package 104 within electromagnetic radiation energy source 38. A less divergent beam focuses its energy within a smaller area, which increases the energy concentration at any given point. Accordingly and even if the total power of the beam remains the same, the energy density of the beam will be increased since the same amount of energy is focused within a smaller cross-sectional area.

In practical terms, increasing energy density by these methods can improve transmission efficiency, ensuring that the celestial energy beam is focused on the electromagnetic radiation energy receiver.

### (11) Controlling the Divergence of a Celestial Energy Beam to Enhance Efficiency of a Ground-Based Receiver.

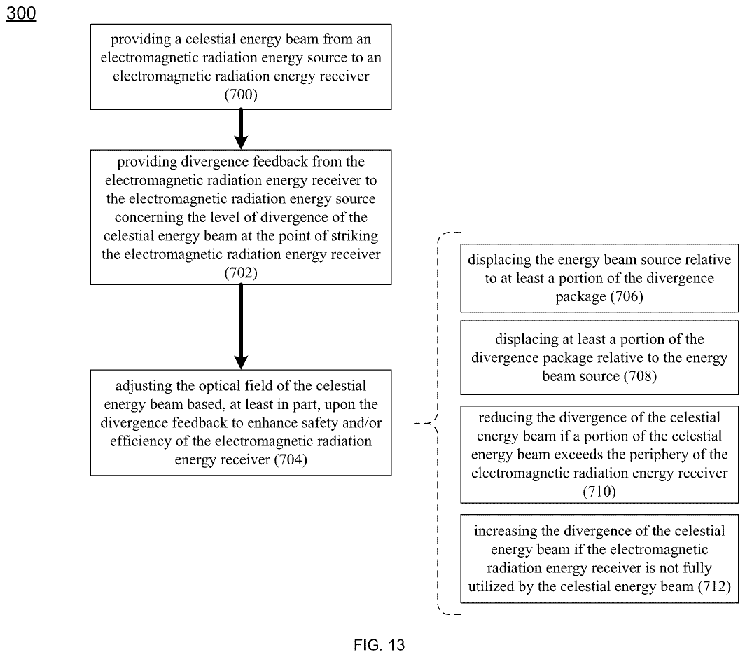

Referring also to FIG. 13, the following discussion concerns the manner in which energy acquisition and delivery process 300 may control the divergence of a celestial energy beam (e.g., celestial energy beam 40) to maximize the efficiency of an energy transfer while minimizing the risk of damage to equipment/injury to animals & people proximate the electromagnetic radiation energy receiver (e.g., electromagnetic radiation energy receiver 200).

Energy acquisition and delivery process 300 may provide 700 a celestial energy beam (e.g., celestial energy beam 40) from an electromagnetic radiation energy source (e.g., electromagnetic radiation energy source 38) to an electromagnetic radiation energy receiver (e.g., electromagnetic radiation energy receiver 200).

As discussed above and for providing 700 a celestial energy beam (e.g., celestial energy beam 40), the electromagnetic radiation energy source (e.g., electromagnetic radiation energy source 38) may include: an energy beam source (e.g., energy beam source 100) for generating the celestial energy beam (e.g., celestial energy beam 40); a beam aiming assembly (e.g., beam aiming assembly 102) for steering the celestial energy beam (e.g., celestial energy beam 40) toward a target; and a beam forming package (e.g., beam forming package 104) for forming the celestial energy beam (e.g., celestial energy beam 40).

The energy beam source (e.g., energy beam source 100) for generating the celestial energy beam (e.g., celestial energy beam 40) may include one or more of: a visible-light laser beam source; an Infrared laser beam source; a short wavelength Infrared laser beam source, a mid-Infrared laser beam source; a near-Infrared laser beam source; and a microwave beam source.

The beam forming package (e.g., beam forming package 104) for forming the celestial energy beam (e.g., celestial energy beam 40) may include: collimating optics (e.g., collimating optics 110); and focusing optics (e.g., focusing optics 112).

Collimating optics (e.g., collimating optics 110) are used to shape a celestial energy beam (e.g., celestial energy beam 40) so that its rays are parallel, resulting in a collimated beam i.e., one that doesn't spread out (diverge) significantly over distance. When a celestial energy beam (e.g., celestial energy beam 40) exits a source (e.g., energy beam source 100) like a diode, it typically diverges, meaning the beam spreads out as it travels. Collimating optics (e.g., collimating optics 110), such as a lens or a lens system, are placed in the beam path to correct this divergence. By focusing the light emerging from a point-like or narrow source, collimating optics (e.g., collimating optics 110) create a beam with minimal angular spread.

Focusing optics (e.g., focusing optics 112) do the opposite of collimating optics (e.g., collimating optics 110), as they take a celestial energy beam (e.g., celestial energy beam 40) and converge it to a point or a small spot. This is usually achieved with lenses or curved mirrors that bend the incoming rays inward, concentrating the beam's energy into a smaller area. When a collimated or diverging celestial energy beam (e.g., celestial energy beam 40) passes through focusing optics (e.g., focusing optics 112), the optics manipulate the beam's path so that all rays come together at a focal point.

As discussed above, while this celestial energy beam (e.g., celestial energy beam 40) is typically transmitted from a space-based electromagnetic radiation energy source (e.g., electromagnetic radiation energy source 38) to a ground-based electromagnetic radiation energy receiver (e.g., electromagnetic radiation energy receiver 200), this is for illustrative purposes only and is not intended to be a limitation of this disclosure, as other configurations are possible and are considered to be within the scope of this disclosure. For example and in some configurations, this celestial energy beam (e.g., celestial energy beam 40) may be transmitted from a ground-based electromagnetic radiation energy source (e.g., electromagnetic radiation energy source 38G) to a space-based electromagnetic radiation energy receiver (e.g., electromagnetic radiation energy receiver 200S).

Energy acquisition and delivery process 300 may provide 702 optical field feedback (e.g., feedback 234) from the electromagnetic radiation energy receiver (e.g., electromagnetic radiation energy receiver 200) to the electromagnetic radiation energy source (e.g., electromagnetic radiation energy source 38) concerning the level of divergence of the celestial energy beam (e.g., celestial energy beam 40) at the point of striking the electromagnetic radiation energy receiver (e.g., electromagnetic radiation energy receiver 200).

This optical field feedback (e.g., feedback 234) may be received on feedback receiving devices (e.g., feedback receiving devices 128) included within electromagnetic radiation energy source 38, wherein such feedback receiving devices (e.g., feedback receiving devices 128) may include but are not limited to one or more of: one or more photovoltaic cells; one or more photodiodes; one or more heat engines; and one or more rectenna arrays.

This optical field feedback (e.g., feedback 234) may be generated via one or more feedback devices (e.g., feedback devices 226) included within the electromagnetic radiation energy receiver (e.g., electromagnetic radiation energy receiver 200). As discussed above, the one or more feedback devices (e.g., feedback devices 226) included within the electromagnetic radiation energy receiver (e.g., electromagnetic radiation energy receiver 200) may include: a centrally-positioned feedback device within the electromagnetic radiation energy receiver (e.g., electromagnetic radiation energy receiver 200) and a plurality of peripherally-positioned feedback devices within the electromagnetic radiation energy receiver (e.g., electromagnetic radiation energy receiver 200).

At least one of the feedback devices (e.g., feedback devices 226) may be a retroreflector. As discussed above, a retroreflector is a specialized feedback device or surface that reflects incoming electromagnetic radiation (e.g., a portion of celestial energy beam 40) directly back toward its source (e.g., electromagnetic radiation energy source 38), regardless of the angle at which celestial energy beam 40 arrives. Unlike a standard mirror, which reflects light at an angle equal to the incident angle, a retroreflector returns celestial energy beam 40 along a near-exact path from which it came through geometric structures (e.g., corner cubes, cat's-eye lenses, or Bragg gratings).

As discussed above, the feedback devices (e.g., feedback devices 226) may include an RF component. Specifically, feedback devices 226 may include a plurality of opto-electrical sensors (e.g., photodiodes, photodetectors and/or photovoltaic cells). This plurality of sensors (e.g., feedback devices 226) may monitor the position of celestial energy beam 40, which is received on electromagnetic radiation energy receiver 200 from electromagnetic radiation energy source 38. This information concerning beam alignment (i.e., the manner in which celestial energy beam 40 is striking electromagnetic radiation energy receiver 200) may be provided to an RF transmitter (e.g., wireless communication system 332) that is included within/coupled to/available to electromagnetic radiation energy receiver 200 so that such information may be transmitted to the electromagnetic radiation energy source (e.g., electromagnetic radiation energy source 38). This information may then be used by electromagnetic radiation energy source 38 to reposition celestial energy beam 40 via beam aiming assembly 102 (if adjustment is needed).

Energy acquisition and delivery process 300 may adjust 704 the optical field of the celestial energy beam (e.g., celestial energy beam 40) based, at least in part, upon the optical field feedback (e.g., feedback 234) to enhance safety and/or efficiency of the electromagnetic radiation energy receiver (e.g., electromagnetic radiation energy receiver 200).

When adjusting 704 the optical field of the celestial energy beam (e.g., celestial energy beam 40) based, at least in part, upon the optical field feedback (e.g., feedback 234) to enhance safety and/or efficiency of the electromagnetic radiation energy receiver (e.g., electromagnetic radiation energy receiver 200), energy acquisition and delivery process 300 may:
displace 706 the energy beam source (e.g., energy beam source 100) relative to at least a portion of the beam forming package (e.g., beam forming package 104); and/or
displace 708 at least a portion of the beam forming package (e.g., beam forming package 104) relative to the energy beam source (e.g., energy beam source 100).

As discussed above, the electromagnetic radiation energy source (e.g., electromagnetic radiation energy source 38) may include: an energy beam source (e.g., energy beam source 100) for generating the celestial energy beam (e.g., celestial energy beam 40); and a beam forming package (e.g., beam forming package 104) for forming the celestial energy beam (e.g., celestial energy beam 40).

The energy beam source (e.g., energy beam source 100) for generating the celestial energy beam (e.g., celestial energy beam 40) may include one or more of: a visible-light laser beam source; an Infrared laser beam source; a short wavelength Infrared laser beam source, a mid-Infrared laser beam source; a near-Infrared laser beam source; and a microwave beam source, wherein the beam forming package (e.g., beam forming package 104) for forming the celestial energy beam (e.g., celestial energy beam 40) may include: collimating optics (e.g., collimating optics 110); and focusing optics (e.g., focusing optics 112).

Collimating optics (e.g., collimating optics 110) and/or focusing optics (e.g., focusing optics 112), such as lenses or mirrors, can be utilized to adjust the divergence of the celestial energy beam (e.g., celestial energy beam 40) by being displaced along the beam's propagation path. When the collimating optics (e.g., collimating optics 110) and/or focusing optics (e.g., focusing optics 112) are positioned closer to the energy beam source (e.g., energy beam source 100), the beam tends to converge more sharply to a focal point and then diverges rapidly after that point. Conversely, when the collimating optics (e.g., collimating optics 110) and/or focusing optics (e.g., focusing optics 112) are moved farther away from the energy beam source (e.g., energy beam source 100), the beam (e.g., celestial energy beam 40) can be made more collimated, maintaining a straighter, less divergent profile over a longer distance before eventually spreading.

By carefully adjusting the position of collimating optics (e.g., collimating optics 110) and/or focusing optics (e.g., focusing optics 112), where the beam (e.g., celestial energy beam 40) focuses and how wide or narrow the beam becomes after passing through the optics (e.g., collimating optics 110 and/or focusing optics 112) may be controlled. Even small displacements of the optics (e.g., collimating optics 110 and/or focusing optics 112) can cause significant changes in the divergence of the beam (e.g., celestial energy beam 40) at long distances, allowing for precise tuning based on target requirements. Mechanisms such as linear actuators or piezoelectric stages are often employed to move the optics (e.g., collimating optics 110 and/or focusing optics 112) dynamically, enabling real-time adjustment of the divergence of the beam (e.g., celestial energy beam 40) to match varying operational conditions. In this way, displacement of the optics (e.g., collimating optics 110 and/or focusing optics 112) provides a critical method for shaping the behavior of the celestial energy beam (e.g., celestial energy beam 40) and optimizing its effectiveness for different applications.

When adjusting 704 the optical field of the celestial energy beam (e.g., celestial energy beam 40) based, at least in part, upon the optical field feedback (e.g., feedback 234) to enhance safety and/or efficiency of the electromagnetic radiation energy receiver (e.g., electromagnetic radiation energy receiver 200), energy acquisition and delivery process 300 may:
reduce 710 the divergence of the celestial energy beam (e.g., celestial energy beam 40) if a portion of the celestial energy beam (e.g., celestial energy beam 40) exceeds the periphery of the electromagnetic radiation energy receiver (e.g., electromagnetic radiation energy receiver 200); and
increase 712 the divergence of the celestial energy beam (e.g., celestial energy beam 40) if the electromagnetic radiation energy receiver (e.g., electromagnetic radiation energy receiver 200) is not fully utilized by the celestial energy beam (e.g., celestial energy beam 40).

As discussed above, by looking at the intensity of the optical field feedback (e.g., feedback 234) received from the centrally-positioned feedback device versus the peripherally-positioned feedback devices), energy acquisition and delivery process 300 may ascertain how well the incoming energy beam (e.g., celestial energy beam 40) is striking electromagnetic radiation energy receiver 200. For example:
TOTAL MISS: If no optical field feedback (e.g., feedback 234) is received by electromagnetic radiation energy source 38, this situation may indicate that the celestial energy beam (e.g., celestial energy beam 40) is not striking electromagnetic radiation energy receiver 200 at all. Accordingly, celestial energy beam 40 may need to be relocated by electromagnetic radiation energy source 38.
PARTIAL HIT/PARTIAL MISS. If any optical field feedback (e.g., feedback 234) is received by electromagnetic radiation energy source 38, this situation may indicate that the celestial energy beam (e.g., celestial energy beam 40) is at least partially striking electromagnetic radiation energy receiver 200. For example, if one or more of the peripherally-positioned feedback devices are providing a higher level of feedback (e.g., feedback 234) than the centrally-positioned feedback device, this situation may indicate that the celestial energy beam (e.g., celestial energy beam 40) is not centered on electromagnetic radiation energy receiver 200 and is partially striking energy receiving devices 202 included within electromagnetic radiation energy receiver 200 . . . but also partially missing energy receiving devices 202 included within electromagnetic radiation energy receiver 200.
TOTAL HIT: If the centrally-positioned feedback device is providing a higher level of optical field feedback (e.g., feedback 234) while the peripherally-positioned feedback devices are providing a lower level of optical field feedback (e.g., feedback 234), this situation may indicate that the celestial energy beam (e.g., celestial energy beam 40) is centered within energy receiving devices 202 included within electromagnetic radiation energy receiver 200. However, operational safety may be maximized when the celestial energy beam (e.g., celestial energy beam 40) is evenly distributed across the entirety of the energy receiving devices 202 included within electromagnetic radiation energy receiver 200 (as opposed to being concentrated in the center). Accordingly, energy acquisition and delivery process 300 may adjust the divergence of the celestial energy beam (e.g., celestial energy beam 40) to spread the beam evenly across all of the energy receiving devices 202 included within electromagnetic radiation energy receiver 200.

As discussed above, electromagnetic radiation energy receiver (e.g., electromagnetic radiation energy receiver 200) may include one or more energy receiving devices (e.g., energy receiving devices 202). Further and as discussed above, operational safety may be maximized when the celestial energy beam (e.g., celestial energy beam 40) is evenly distributed across the entirety of these energy receiving devices 202 (as opposed to being concentrated in the center). Accordingly and in the situation where the centrally-positioned feedback device is providing a higher level of optical field feedback (e.g., feedback 234) then the peripherally-positioned feedback devices, energy acquisition and delivery process 300 may increase 712 the divergence of the celestial energy beam (e.g., celestial energy beam 40) to spread the beam evenly across all of the energy receiving devices 202 included within electromagnetic radiation energy receiver 200.

Conversely, if the celestial energy beam (e.g., celestial energy beam 40) is too diverged, the celestial energy beam (e.g., celestial energy beam 40) would extend outside the boundaries of the energy receiving devices 202, thus wasting energy and potentially injuring people and/or damaging property that is being struck by the portion of the energy beam (e.g., celestial energy beam 40) extending outside of the boundaries of the energy receiving devices 202. Accordingly and in such a situation, energy acquisition and delivery process 300 may reduce 710 the divergence of the celestial energy beam (e.g., celestial energy beam 40) so that the footprint of the celestial energy beam (e.g., celestial energy beam 40) is reduced to the point that it does not exceed the periphery of the electromagnetic radiation energy receivers (e.g., electromagnetic radiation energy receiver 200).

### (12) Methodologies for Iteratively Locating a Ground-Based Receiver.

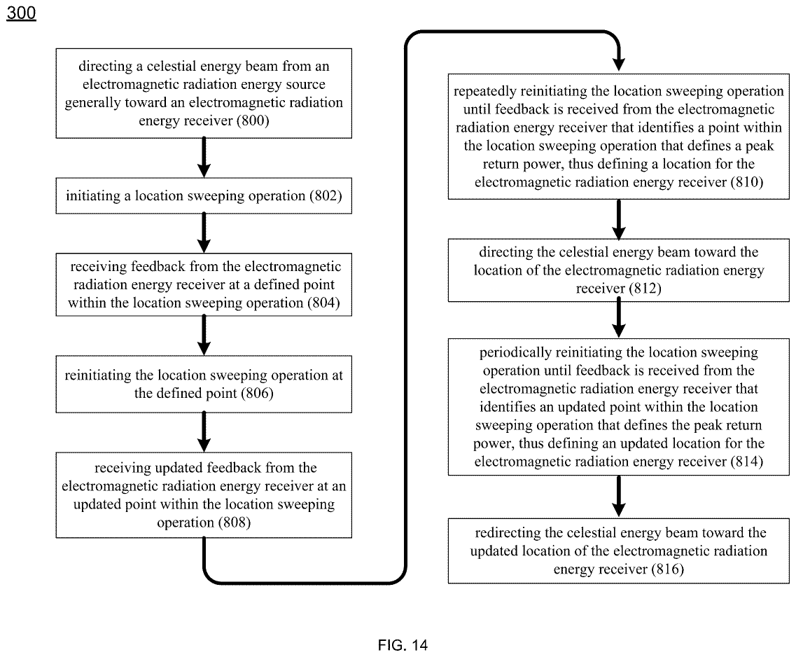

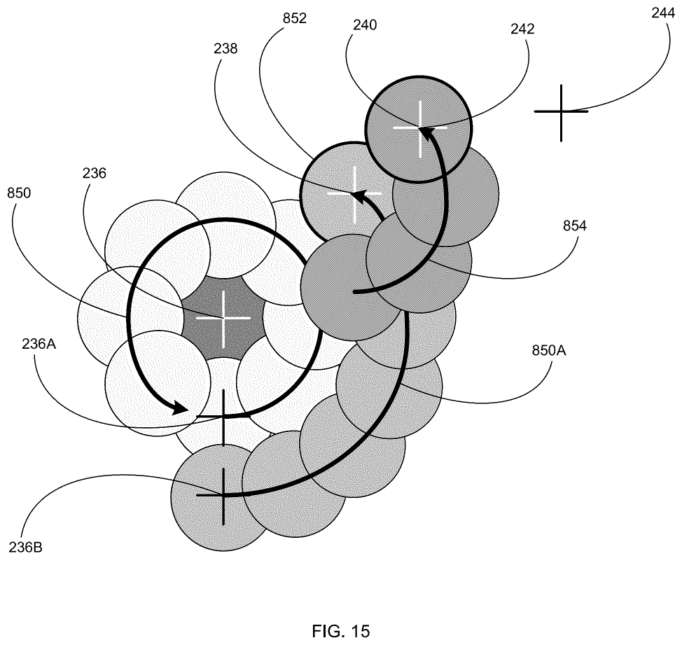

Referring also to FIGS. 14-15, the following discussion concerns the manner in which energy acquisition and delivery process 300 may locate an electromagnetic radiation energy receiver (e.g., electromagnetic radiation energy receiver 200) using a predefined sweeping pattern and received feedback in an iterative fashion.

Energy acquisition and delivery process 300 may direct 800 a celestial energy beam (e.g., celestial energy beam 40) from an electromagnetic radiation energy source (e.g., electromagnetic radiation energy source 38) generally toward an electromagnetic radiation energy receiver (e.g., electromagnetic radiation energy receiver 200). For example, energy acquisition and delivery process 300 may reduce the energy density of the celestial energy beam (e.g., celestial energy beam 40) and direct 800 the energy beam toward the general direction of an electromagnetic radiation energy receiver (e.g., electromagnetic radiation energy receiver 200).

As discussed above, while this celestial energy beam (e.g., celestial energy beam 40) is typically transmitted from a space-based electromagnetic radiation energy source (e.g., electromagnetic radiation energy source 38) to a ground-based electromagnetic radiation energy receiver (e.g., electromagnetic radiation energy receiver 200), this is for illustrative purposes only and is not intended to be a limitation of this disclosure, as other configurations are possible and are considered to be within the scope of this disclosure. For example and in some configurations, this celestial energy beam (e.g., celestial energy beam 40) may be transmitted from a ground-based electromagnetic radiation energy source (e.g., electromagnetic radiation energy source 38G) to a space-based electromagnetic radiation energy receiver (e.g., electromagnetic radiation energy receiver 200S).

As discussed above and for directing 800 a celestial energy beam (e.g., celestial energy beam 40), the electromagnetic radiation energy source (e.g., electromagnetic radiation energy source 38) may include: an energy beam source (e.g., energy beam source 100) for generating the celestial energy beam (e.g., celestial energy beam 40); a beam aiming assembly (e.g., beam aiming assembly 102) for steering the celestial energy beam (e.g., celestial energy beam 40) toward a target; and a beam forming package (e.g., beam forming package 104) for forming the celestial energy beam (e.g., celestial energy beam 40).

The energy beam source (e.g., energy beam source 100) for generating the celestial energy beam (e.g., celestial energy beam 40) may include one or more of: a visible-light laser beam source; an Infrared laser beam source; a short wavelength Infrared laser beam source, a mid-Infrared laser beam source; a near-Infrared laser beam source; and a microwave beam source.

The beam aiming assembly (e.g., beam aiming assembly 102) for steering the celestial energy beam (e.g., celestial energy beam 40) may include: a Gimbal mount assembly (e.g., Gimbal mount assembly 106) configured to direct the celestial energy beam (e.g., celestial energy beam 40) toward a target; a phased array assembly (e.g., phased array assembly 107) configured to direct the celestial energy beam (e.g., celestial energy beam 40) toward a target and/or a periscope assembly (e.g., periscope assembly 108) configured to direct the celestial energy beam (e.g., celestial energy beam 40) toward a target. A Gimbal mount assembly (e.g., Gimbal mount assembly 106), a phased array assembly (e.g., phased array assembly 107) and a periscope assembly (e.g., periscope assembly 108) can be effectively used in space-based energy systems to accurately direct a celestial energy beam (e.g., celestial energy beam 40), such as a laser or microwave beam, from a satellite (e.g., satellite 14) to a electromagnetic radiation energy receiver (e.g., electromagnetic radiation energy receiver 200).

The beam forming package (e.g., beam forming package 104) for forming the celestial energy beam (e.g., celestial energy beam 40) may include: collimating optics (e.g., collimating optics 110); and focusing optics (e.g., focusing optics 112). Collimating optics (e.g., collimating optics 110) are used to shape a celestial energy beam (e.g., celestial energy beam 40) so that its rays are parallel, resulting in a collimated beam i.e., one that doesn't spread out (diverge) significantly over distance. When a celestial energy beam (e.g., celestial energy beam 40) exits a source (e.g., energy beam source 100) like a diode, it typically diverges, meaning the beam spreads out as it travels.

Collimating optics (e.g., collimating optics 110), such as a lens or a lens system, are placed in the beam path to correct this divergence. By focusing the light emerging from a point-like or narrow source, collimating optics (e.g., collimating optics 110) create a beam with minimal angular spread. This is especially important for applications that require the beam to travel long distances (e.g., power transmission) or interact with precise optical components. In short, collimating optics (e.g., collimating optics 110) make a celestial energy beam (e.g., celestial energy beam 40) straighter and more focused over distance, improving its usability and efficiency in various optical systems.

Focusing optics (e.g., focusing optics 112) do the opposite of collimating optics (e.g., collimating optics 110), as they take a celestial energy beam (e.g., celestial energy beam 40) and converge it to a point or a small spot. This is usually achieved with lenses or curved mirrors that bend the incoming rays inward, concentrating the beam's energy into a smaller area. When a collimated or diverging celestial energy beam (e.g., celestial energy beam 40) passes through focusing optics (e.g., focusing optics 112), the optics manipulate the beam's path so that all rays come together at a focal point.

Energy acquisition and delivery process 300 may initiate 802 a location sweeping operation. The location sweeping operation may include a sweeping operation that initiates at an initial point (e.g., initial point 236) and spirals outwardly away from the initial point (e.g., initial point 236). Energy acquisition and delivery process 300 may receive 804 feedback (e.g., feedback 234) from the electromagnetic radiation energy receiver (e.g., electromagnetic radiation energy receiver 200) at a defined point (e.g., defined point 238) within the location sweeping operation.

This feedback (e.g., feedback 234) may be generated via one or more feedback devices (e.g., feedback devices 226) included within the electromagnetic radiation energy receiver (e.g., electromagnetic radiation energy receiver 200). As discussed above, the one or more feedback devices (e.g., feedback devices 226) included within the electromagnetic radiation energy receiver (e.g., electromagnetic radiation energy receiver 200) may include: a centrally-positioned feedback device within the electromagnetic radiation energy receiver (e.g., electromagnetic radiation energy receiver 200) and a plurality of peripherally-positioned feedback devices within the electromagnetic radiation energy receiver (e.g., electromagnetic radiation energy receiver 200).

At least one of the feedback devices (e.g., feedback devices 226) may be a retroreflector. As discussed above, a retroreflector is a specialized feedback device or surface that reflects incoming electromagnetic radiation (e.g., a portion of celestial energy beam 40) directly back toward its source (e.g., electromagnetic radiation energy source 38), regardless of the angle at which celestial energy beam 40 arrives. Unlike a standard mirror, which reflects light at an angle equal to the incident angle, a retroreflector returns celestial energy beam 40 along a near-exact path from which it came through geometric structures (e.g., corner cubes, cat's-eye lenses, or Bragg gratings).

As discussed above, the feedback devices (e.g., feedback devices 226) may include an RF component. Specifically, feedback devices 226 may include a plurality of opto-electrical sensors (e.g., photodiodes, photodetectors and/or photovoltaic cells). This plurality of sensors (e.g., feedback devices 226) may monitor the position of celestial energy beam 40, which is received on electromagnetic radiation energy receiver 200 from electromagnetic radiation energy source 38. This information concerning beam alignment (i.e., the manner in which celestial energy beam 40 is striking electromagnetic radiation energy receiver 200) may be provided to an RF transmitter (e.g., wireless communication system 332) that is included within/coupled to/available to electromagnetic radiation energy receiver 200 so that such information may be transmitted to the electromagnetic radiation energy source (e.g., electromagnetic radiation energy source 38). This information may then be used by electromagnetic radiation energy source 38 to reposition celestial energy beam 40 via beam aiming assembly 102 (if adjustment is needed).

This feedback (e.g., feedback 234) may be received on feedback receiving devices (e.g., feedback receiving devices 128) included within electromagnetic radiation energy source 38, wherein such feedback receiving devices (e.g., feedback receiving devices 128) may include but are not limited to one or more of: one or more photovoltaic cells; one or more photodiodes; one or more heat engines; and one or more rectenna arrays.

Energy acquisition and delivery process 300 may reinitiate 806 the location sweeping operation at the defined point (e.g., defined point 238). Energy acquisition and delivery process 300 may receive 808 updated feedback (e.g., feedback 234) from the electromagnetic radiation energy receiver (e.g., electromagnetic radiation energy receiver 200) at an updated point (e.g., updated point 240) within the location sweeping operation.

Energy acquisition and delivery process 300 may repeatedly reinitiate 810 the location sweeping operation until feedback (e.g., feedback 234) is received from the electromagnetic radiation energy receiver (e.g., electromagnetic radiation energy receiver 200) that identifies a point within the location sweeping operation that defines a peak return power, thus defining a location (e.g., receiver location 242) for the electromagnetic radiation energy receiver (e.g., electromagnetic radiation energy receiver 200).

Assume for illustrative purposes that energy acquisition and delivery process 300 initiates 802 the above-discussed location sweeping operation at initial point 236. Specifically, the sweeping operation at initial point 236 may be the scanning of a 500 foot diameter circle. If feedback (e.g., feedback 234) is not received 804 from electromagnetic radiation energy receiver 200 during this scanning operation, such a lack of feedback indicates that electromagnetic radiation energy receiver 200 is not located within the 500 foot diameter circle, thus the location sweeping operation may spiral outwardly away from initial point 236.

Specifically, energy acquisition and delivery process 300 may spiral outwardly away from initial point 236 and continue the location sweeping operation at a new point (e.g., point 236A) that is spaced radially away from initial point 236. For this example, assume that energy acquisition and delivery process 300 begins repeatedly scanning 500 foot diameter circles while moving in the direction of arrow 850 to form a ring around the initial 500 foot diameter circle (that is positioned at initial point 236). During each of these 500 foot diameter scans, energy acquisition and delivery process 300 may monitor for feedback (e.g., feedback 234) in an attempt to locate the electromagnetic radiation energy receiver (e.g., electromagnetic radiation energy receiver 200). Again, if feedback (e.g., feedback 234) is not received 804 from electromagnetic radiation energy receiver 200 during any of these scanning operations, such a lack of feedback would indicate that electromagnetic radiation energy receiver 200 is not positioned within the 500 foot diameter circle that is currently being scanned while moving along arrow 850.

Continuing with the above-stated example, assume that no feedback is received while scanning each of the 500 foot diameter circles positioned along arrow 850, thus indicating that electromagnetic radiation energy receiver 200 is not located within any of the 500 foot diameter circles that are positioned along arrow 850.

Accordingly, the location sweeping operation may spiral outwardly further away from initial point 236 and continue the location sweeping operation at a new point (e.g., point 238B) that is spaced further radially away from initial point 236. For this example, assume that energy acquisition and delivery process 300 begins repeatedly scanning 500 foot diameter circles while moving in the direction of arrow 850A to form a second (and more distal) ring around the initial 500 foot diameter circle positioned at initial point 236.

During each of these 500 foot diameter scans along arrow 850A, energy acquisition and delivery process 300 may monitor for feedback (e.g., feedback 234) in an attempt to locate the electromagnetic radiation energy receiver (e.g., electromagnetic radiation energy receiver 200). Again, if feedback (e.g., feedback 234) is not received 804 from electromagnetic radiation energy receiver 200 during a scanning operation, such a lack of feedback indicates that electromagnetic radiation energy receiver 200 is not positioned within the 500 foot diameter circles being scanned while moving in the direction of arrow 850A.

Continuing with the above-stated example, assume that upon scanning a specific 500 foot diameter circle (e.g., circle 852) along arrow 850A, feedback (e.g., feedback 234) is received from electromagnetic radiation energy receiver 200, thus indicating that electromagnetic radiation energy receiver 200 is positioned therein and identifying a defined point (e.g., defined point 238) within the location sweeping operation.

In response to such feedback, energy acquisition and delivery process 300 may reinitiate 806 the location sweeping operation at the defined point (e.g., defined point 238). Specifically, this new location sweeping operation may be centered about (and spiral outward from) defined point 238.

For this example, assume that energy acquisition and delivery process 300 begins repeatedly scanning 500 foot diameter circles while moving in the direction of arrow 854 to form a ring around circle 852 positioned at defined point 238. During each of these 500 foot diameter scans, energy acquisition and delivery process 300 may monitor for feedback (e.g., feedback 234) from the electromagnetic radiation energy receiver (e.g., electromagnetic radiation energy receiver 200). Assume that energy acquisition and delivery process 300 receives 808 updated feedback (e.g., feedback 234) from the electromagnetic radiation energy receiver (e.g., electromagnetic radiation energy receiver 200) at an updated point (e.g., updated point 240) within the location sweeping operation, further refining the location of the electromagnetic radiation energy receiver (e.g., electromagnetic radiation energy receiver 200).

As discussed above, energy acquisition and delivery process 300 may repeatedly reinitiate 810 the location sweeping operation until feedback (e.g., feedback 234) is received from the electromagnetic radiation energy receiver (e.g., electromagnetic radiation energy receiver 200) that identifies a point within the location sweeping operation that defines a peak return power. This point will define a location (e.g., receiver location 242) for the electromagnetic radiation energy receiver (e.g., electromagnetic radiation energy receiver 200). For example, each time new feedback (e.g., feedback 234) is received from electromagnetic radiation energy receiver 200, subsequent sweeping operations may be initiated by energy acquisition and delivery process 300 until the peak return power is identified, at which point the location of the electromagnetic radiation energy receiver (e.g., electromagnetic radiation energy receiver 200) will be deemed to be sufficiently defined. In the interest of brevity, assume that this location (e.g., receiver location 242) is updated point 240.

Accordingly and being the location of the electromagnetic radiation energy receiver (e.g., electromagnetic radiation energy receiver 200) has been defined, energy acquisition and delivery process 300 may direct 812 the celestial energy beam (e.g., celestial energy beam 40) toward the location (e.g., receiver location 242) of the electromagnetic radiation energy receiver (e.g., electromagnetic radiation energy receiver 200).

Energy acquisition and delivery process 300 may periodically reinitiate 814 the location sweeping operation until feedback (e.g., feedback 234) is received from the electromagnetic radiation energy receiver (e.g., electromagnetic radiation energy receiver 200) that identifies an updated point within the location sweeping operation that defines the peak return power, thus defining an updated location (e.g., updated location 244) for the electromagnetic radiation energy receiver (e.g., electromagnetic radiation energy receiver 200).

Energy acquisition and delivery process 300 may redirect 816 the celestial energy beam (e.g., celestial energy beam 40) toward the updated location (e.g., updated location 244) of the electromagnetic radiation energy receiver (e.g., electromagnetic radiation energy receiver 200).

### (13) Using an Initial Wide-Angle Cone-Based Transmission Pattern Directed Toward a Single Optical Component on the Ground-Based Distribution Component.

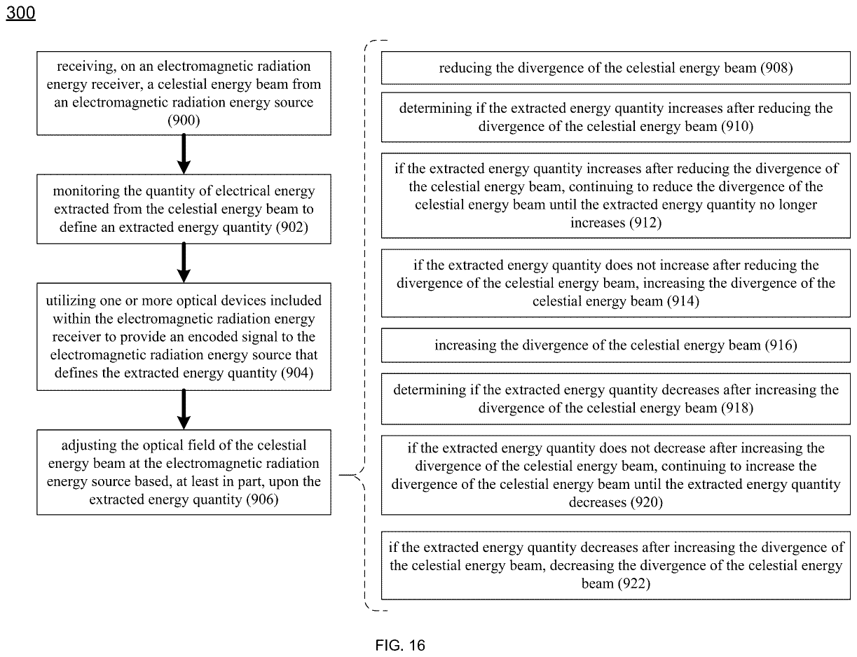

Referring also to FIG. 16, the following discussion concerns the manner in which energy acquisition and delivery process 300 may monitor the quantity of energy extracted from a celestial energy beam (e.g., celestial energy beam 40) and/or increase and/or decrease the divergence of the same to enhance energy transmission efficiency.

Energy acquisition and delivery process 300 may receive 900, on an electromagnetic radiation energy receiver (e.g., electromagnetic radiation energy receiver 200), a celestial energy beam (e.g., celestial energy beam 40) from an electromagnetic radiation energy source (e.g., electromagnetic radiation energy source 38).

As discussed above, while this celestial energy beam (e.g., celestial energy beam 40) is typically transmitted from a space-based electromagnetic radiation energy source (e.g., electromagnetic radiation energy source 38) to a ground-based electromagnetic radiation energy receiver (e.g., electromagnetic radiation energy receiver 200), this is for illustrative purposes only and is not intended to be a limitation of this disclosure, as other configurations are possible and are considered to be within the scope of this disclosure. For example and in some configurations, this celestial energy beam (e.g., celestial energy beam 40) may be transmitted from a ground-based electromagnetic radiation energy source (e.g., electromagnetic radiation energy source 38G) to a space-based electromagnetic radiation energy receiver (e.g., electromagnetic radiation energy receiver 200S).

Energy acquisition and delivery process 300 may monitor 902 the quantity of electrical energy extracted from the celestial energy beam (e.g., celestial energy beam 40) to define an extracted energy quantity (e.g., extracted energy quantity 246).

As discussed above, the electromagnetic radiation energy receiver (e.g., electromagnetic radiation energy receiver 200) may include one or more energy receiving devices (e.g., energy receiving devices 202). The electromagnetic radiation energy receiver (e.g., electromagnetic radiation energy receiver 200) may be configured to receive at least a portion of the celestial energy beam (e.g., celestial energy beam 40) on the one or more energy receiving devices (e.g., energy receiving devices 202) and generate received electrical energy (e.g., received electrical energy 204). Accordingly and when monitoring 902 the quantity of electrical energy extracted from the celestial energy beam (e.g., celestial energy beam 40) to define the extracted energy quantity (e.g., extracted energy quantity 246), energy acquisition and delivery process 300 may monitor the quantity of power included within received electrical energy 204. For example, a wattmeter may be utilized to define the total quantity of watts included within received electrical energy 204.

Energy acquisition and delivery process 300 may utilize 904 one or more feedback devices (e.g., feedback devices 226) included within the electromagnetic radiation energy receiver (e.g., electromagnetic radiation energy receiver 200) to provide an encoded signal (e.g., feedback 234) to the electromagnetic radiation energy source (e.g., electromagnetic radiation energy source 38) that defines the extracted energy quantity (e.g., extracted energy quantity 246).

As discussed above, the one or more feedback devices (e.g., feedback devices 226) included within the electromagnetic radiation energy receiver (e.g., electromagnetic radiation energy receiver 200) may include: a centrally-positioned feedback device within the electromagnetic radiation energy receiver (e.g., electromagnetic radiation energy receiver 200) and a plurality of peripherally-positioned feedback devices within the electromagnetic radiation energy receiver (e.g., electromagnetic radiation energy receiver 200).

At least one of the feedback devices (e.g., feedback devices 226) may be a retroreflector. As discussed above, a retroreflector is a specialized feedback device or surface that reflects incoming electromagnetic radiation (e.g., a portion of celestial energy beam 40) directly back toward its source (e.g., electromagnetic radiation energy source 38), regardless of the angle at which celestial energy beam 40 arrives. Unlike a standard mirror, which reflects light at an angle equal to the incident angle, a retroreflector returns celestial energy beam 40 along a near-exact path from which it came through geometric structures (e.g., corner cubes, cat's-eye lenses, or Bragg gratings).

As discussed above, the feedback devices (e.g., feedback devices 226) may include an RF component. Specifically, feedback devices 226 may include a plurality of opto-electrical sensors (e.g., photodiodes, photodetectors and/or photovoltaic cells). This plurality of sensors (e.g., feedback devices 226) may monitor the position of celestial energy beam 40, which is received on electromagnetic radiation energy receiver 200 from electromagnetic radiation energy source 38. This information concerning beam alignment (i.e., the manner in which celestial energy beam 40 is striking electromagnetic radiation energy receiver 200) may be provided to an RF transmitter (e.g., wireless communication system 332) that is included within/coupled to/available to electromagnetic radiation energy receiver 200 so that such information may be transmitted to the electromagnetic radiation energy source (e.g., electromagnetic radiation energy source 38). This information may then be used by electromagnetic radiation energy source 38 to reposition celestial energy beam 40 via beam aiming assembly 102 (if adjustment is needed).

Energy acquisition and delivery process 300 may modulate the feedback devices (e.g., feedback devices 226) to generate the encoded signal (e.g., feedback 234) that defines the extracted energy quantity (e.g., extracted energy quantity 246). This encoding may be accomplished by modulating the intensity, phase, polarization, or timing of the reflected signal (e.g., feedback 234) in a controlled way, with the changes representing the encoded information.

This encoded signal (e.g., feedback 234) may be received on feedback receiving devices (e.g., feedback receiving devices 128) included within electromagnetic radiation energy source 38, wherein such feedback receiving devices (e.g., feedback receiving devices 128) may include but are not limited to one or more of: one or more photovoltaic cells; one or more photodiodes; one or more heat engines; and one or more rectenna arrays.

As discussed above, data may be encoded within the encoded signal (e.g., feedback 234) by using modulating feedback devices, such as modulating retroreflectors, which dynamically alter their optical properties through various mechanisms. Mechanical modulation involves using shutters, MEMS devices, or vibrating mirrors to physically open, close, or change the orientation of the reflective surface, where the different states correspond to binary data. Electro-optical modulation employs materials like liquid crystals or electro-optic polymers that change transparency, refractive index, or polarization when a voltage is applied, allowing for fast, electronically controlled modulation. Acousto-optic modulation uses sound waves to alter either the surface of the feedback device or a material placed in front of it, affecting the reflected light to encode information. Thermal or phase modulation relies on subtle changes in surface temperature or refractive index to introduce phase shifts into the reflected beam, which can also represent binary data. Through precise and time-controlled modulation of the reflection properties, telemetry, identification codes, or communication signals can be embedded into the reflected beam without requiring the feedback device itself to generate an active transmission, enabling lightweight, low-power data communication systems.

Energy acquisition and delivery process 300 may adjust 906 the optical field of the celestial energy beam (e.g., celestial energy beam 40) at the electromagnetic radiation energy source (e.g., electromagnetic radiation energy source 38) based, at least in part, upon the extracted energy quantity (e.g., extracted energy quantity 246).

Initial Reduction in Divergence Methodology: When adjusting 906 the optical field of the celestial energy beam (e.g., celestial energy beam 40) at the electromagnetic radiation energy source (e.g., electromagnetic radiation energy source 38) based, at least in part, upon the extracted energy quantity (e.g., extracted energy quantity 246), energy acquisition and delivery process 300 may:
reduce 908 the divergence of the celestial energy beam (e.g., celestial energy beam 40);
determine 910 if the extracted energy quantity increases after reducing the divergence of the celestial energy beam (e.g., celestial energy beam 40);
if the extracted energy quantity increases after reducing the divergence of the celestial energy beam (e.g., celestial energy beam 40), continuing 912 to reduce the divergence of the celestial energy beam (e.g., celestial energy beam 40) until the extracted energy quantity no longer increases; and
if the extracted energy quantity does not increase after reducing the divergence of the celestial energy beam (e.g., celestial energy beam 40), increasing 914 the divergence of the celestial energy beam (e.g., celestial energy beam 40).

For this example, assume that the electromagnetic radiation energy receiver (e.g., electromagnetic radiation energy receiver 200) includes energy receiving devices (e.g., energy receiving devices 202) that are arranged to form an area 50 feet in diameter that is capable of receiving the celestial energy beam (e.g., celestial energy beam 40). However, assume that celestial energy beam 40 is currently 100 feet in diameter due to it being overly diverged, resulting in the majority of the footprint of celestial energy beam 40 striking the ground/structures/people/animals proximate electromagnetic radiation energy receiver 200, resulting in inefficient (and potentially hazardous) operation. Assume that in this current state, energy acquisition and delivery process 300 is sensing an extracted energy quantity (e.g., extracted energy quantity 246) of 32 kilowatts.

Accordingly, energy acquisition and delivery process 300 may reduce 908 the divergence of the celestial energy beam (e.g., celestial energy beam 40). Assume for this example that the divergence of the celestial energy beam (e.g., celestial energy beam 40) is reduced and the footprint of celestial energy beam 40 is now 75 feet in diameter. Energy acquisition and delivery process 300 may then determine 910 if the extracted energy quantity increases after reducing the divergence of the celestial energy beam (e.g., celestial energy beam 40). Assume for this example that in this new less-diverged state, energy acquisition and delivery process 300 is now sensing an extracted energy quantity (e.g., extracted energy quantity 246) of 48 kilowatts. Since in this example, the extracted energy quantity has increased after reducing the divergence of the celestial energy beam (e.g., celestial energy beam 40), energy acquisition and delivery process 300 may continue 912 to reduce the divergence of the celestial energy beam (e.g., celestial energy beam 40) until the extracted energy quantity no longer increases. Once the divergence of the celestial energy beam (e.g., celestial energy beam 40) is reduced to the point that the footprint of celestial energy beam 40 is below 50 feet in diameter (i.e., the diameter of energy receiving devices 202), the extracted energy quantity will no longer increase. Accordingly and in such a situation, energy acquisition and delivery process 300 may increase 914 the divergence of the celestial energy beam (e.g., celestial energy beam 40) to spread celestial energy beam 40 across all of energy receiving devices 202.

Initially Increasing Divergence Methodology: When adjusting 906 the optical field of the celestial energy beam (e.g., celestial energy beam 40) at the electromagnetic radiation energy source (e.g., electromagnetic radiation energy source 38) based, at least in part, upon the extracted energy quantity (e.g., extracted energy quantity 246), energy acquisition and delivery process 300 may:
increase 916 the divergence of the celestial energy beam (e.g., celestial energy beam 40);
determine 918 if the extracted energy quantity decreases after increasing the divergence of the celestial energy beam (e.g., celestial energy beam 40);
if the extracted energy quantity does not decrease after increasing the divergence of the celestial energy beam (e.g., celestial energy beam 40), continuing 920 to increase the divergence of the celestial energy beam (e.g., celestial energy beam 40) until the extracted energy quantity decreases; and
if the extracted energy quantity decreases after increasing the divergence of the celestial energy beam (e.g., celestial energy beam 40), decreasing 922 the divergence of the celestial energy beam (e.g., celestial energy beam 40).

Again for this example, assume that the electromagnetic radiation energy receiver (e.g., electromagnetic radiation energy receiver 200) includes energy receiving devices (e.g., energy receiving devices 202) that are arranged to form an area 50 feet in diameter that is capable of receiving the celestial energy beam (e.g., celestial energy beam 40). However, assume that celestial energy beam 40 is currently 20 feet in diameter due to it being underly diverged, resulting in the majority of the 50 foot diameter energy receiving area being unused, resulting in inefficient use of energy receiving devices 202. Assume that in this current state, energy acquisition and delivery process 300 is sensing an extracted energy quantity (e.g., extracted energy quantity 246) of 75 kilowatts.

Accordingly, energy acquisition and delivery process 300 may increase 916 the divergence of the celestial energy beam (e.g., celestial energy beam 40). Assume for this example that the divergence of the celestial energy beam (e.g., celestial energy beam 40) is increased and the footprint of celestial energy beam 40 is now 40 feet in diameter (still within the 50 foot diameter energy receiving area of electromagnetic radiation energy receiver 200). Energy acquisition and delivery process 300 may then determine 918 if the extracted energy quantity decreased after increasing the divergence of the celestial energy beam (e.g., celestial energy beam 40). Assume for this example that in this new more-diverged state, energy acquisition and delivery process 300 is still sensing an extracted energy quantity (e.g., extracted energy quantity 246) of 75 kilowatts. Since in this example, the extracted energy quantity did not decrease after increasing the divergence of the celestial energy beam (e.g., celestial energy beam 40), energy acquisition and delivery process 300 may continue 920 to increase the divergence of the celestial energy beam (e.g., celestial energy beam 40) until the extracted energy quantity decreases. Once the divergence of the celestial energy beam (e.g., celestial energy beam 40) is increased to the point that the footprint of celestial energy beam 40 exceeds 50 feet in diameter (i.e., the diameter of energy receiving devices 202), the extracted energy quantity will begin to decrease. Accordingly and if the extracted energy quantity decreases after increasing the divergence of the celestial energy beam (e.g., celestial energy beam 40), energy acquisition and delivery process 300 may decrease 922 the divergence of the celestial energy beam (e.g., celestial energy beam 40) to ensure that the entire footprint of celestial energy beam 40 is striking the 50 foot diameter energy receiving area of electromagnetic radiation energy receiver 200.

### (14) Using an Initial Wide-Angle Cone-Based Transmission Pattern Directed Toward Multiple Optical Components on the Ground-Based Distribution Component.

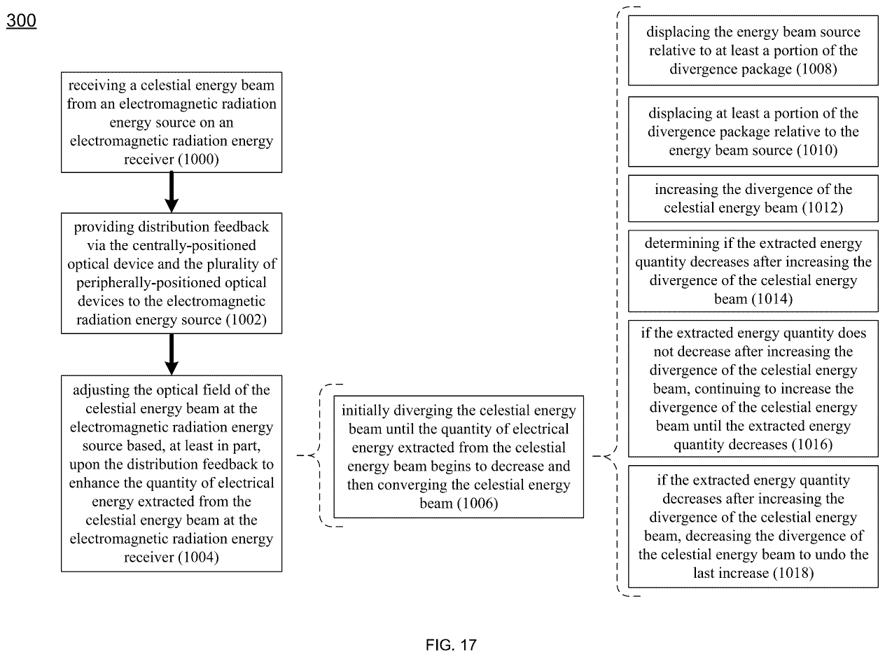

Referring also to FIG. 17, the following discussion concerns the manner in which energy acquisition and delivery process 300 may monitor the quantity of energy extracted from a celestial energy beam (e.g., celestial energy beam 40) and incrementally increase the divergence of the same until a drop in extracted energy is noted; wherein the last increase is then undone to enhance energy transmission efficiency.

Energy acquisition and delivery process 300 may receive 1000 a celestial energy beam (e.g., celestial energy beam 40) from an electromagnetic radiation energy source (e.g., electromagnetic radiation energy source 38) on an electromagnetic radiation energy receiver (e.g., electromagnetic radiation energy receiver 200).

As discussed above, the electromagnetic radiation energy source (e.g., electromagnetic radiation energy source 38) may include: an energy beam source (e.g., energy beam source 100) for generating the celestial energy beam (e.g., celestial energy beam 40); a beam aiming assembly (e.g., beam aiming assembly 102) for steering the celestial energy beam (e.g., celestial energy beam 40) toward a target; and a beam forming package (e.g., beam forming package 104) for forming the celestial energy beam (e.g., celestial energy beam 40).

The energy beam source (e.g., energy beam source 100) for generating the celestial energy beam (e.g., celestial energy beam 40) may include one or more of: a visible-light laser beam source; an Infrared laser beam source; a short wavelength Infrared laser beam source, a mid-Infrared laser beam source; a near-Infrared laser beam source; and a microwave beam source.

The beam aiming assembly (e.g., beam aiming assembly 102) for steering the celestial energy beam (e.g., celestial energy beam 40) may include: a Gimbal mount assembly (e.g., Gimbal mount assembly 106) configured to direct the celestial energy beam (e.g., celestial energy beam 40) toward a target; a phased array assembly (e.g., phased array assembly 107) configured to direct the celestial energy beam (e.g., celestial energy beam 40) toward a target and/or a periscope assembly (e.g., periscope assembly 108) configured to direct the celestial energy beam (e.g., celestial energy beam 40) toward a target. A Gimbal mount assembly (e.g., Gimbal mount assembly 106), a phased array assembly (e.g., phased array assembly 107) and a periscope assembly (e.g., periscope assembly 108) can be effectively used in space-based energy systems to accurately direct a celestial energy beam (e.g., celestial energy beam 40), such as a laser or microwave beam, from a satellite (e.g., satellite 14) to a electromagnetic radiation energy receiver (e.g., electromagnetic radiation energy receiver 200).

The beam forming package (e.g., beam forming package 104) for forming the celestial energy beam (e.g., celestial energy beam 40) may include: collimating optics (e.g., collimating optics 110); and focusing optics (e.g., focusing optics 112). Collimating optics (e.g., collimating optics 110) are used to shape a celestial energy beam (e.g., celestial energy beam 40) so that its rays are parallel, resulting in a collimated beam i.e., one that doesn't spread out (diverge) significantly over distance. When a celestial energy beam (e.g., celestial energy beam 40) exits a source (e.g., energy beam source 100) like a diode, it typically diverges, meaning the beam spreads out as it travels.

Collimating optics (e.g., collimating optics 110), such as a lens or a lens system, are placed in the beam path to correct this divergence. By focusing the light emerging from a point-like or narrow source, collimating optics (e.g., collimating optics 110) create a beam with minimal angular spread. This is especially important for applications that require the beam to travel long distances (e.g., power transmission) or interact with precise optical components. In short, collimating optics (e.g., collimating optics 110) make a celestial energy beam (e.g., celestial energy beam 40) straighter and more focused over distance, improving its usability and efficiency in various optical systems.

Focusing optics (e.g., focusing optics 112) do the opposite of collimating optics (e.g., collimating optics 110), as they take a celestial energy beam (e.g., celestial energy beam 40) and converge it to a point or a small spot. This is usually achieved with lenses or curved mirrors that bend the incoming rays inward, concentrating the beam's energy into a smaller area. When a collimated or diverging celestial energy beam (e.g., celestial energy beam 40) passes through focusing optics (e.g., focusing optics 112), the optics manipulate the beam's path so that all rays come together at a focal point.

The electromagnetic radiation energy receiver (e.g., electromagnetic radiation energy receiver 200) may include: a centrally-positioned feedback device within the electromagnetic radiation energy receiver (e.g., electromagnetic radiation energy receiver 200) and a plurality of peripherally-positioned feedback devices within the electromagnetic radiation energy receiver (e.g., electromagnetic radiation energy receiver 200).

At least one of the feedback devices (e.g., feedback devices 226) may be a retroreflector. As discussed above, a retroreflector is a specialized feedback device or surface that reflects incoming electromagnetic radiation (e.g., a portion of celestial energy beam 40) directly back toward its source (e.g., electromagnetic radiation energy source 38), regardless of the angle at which celestial energy beam 40 arrives. Unlike a standard mirror, which reflects light at an angle equal to the incident angle, a retroreflector returns celestial energy beam 40 along a near-exact path from which it came through geometric structures (e.g., corner cubes, cat's-eye lenses, or Bragg gratings).

As discussed above, the feedback devices (e.g., feedback devices 226) may include an RF component. Specifically, feedback devices 226 may include a plurality of opto-electrical sensors (e.g., photodiodes, photodetectors and/or photovoltaic cells). This plurality of sensors (e.g., feedback devices 226) may monitor the position of celestial energy beam 40, which is received on electromagnetic radiation energy receiver 200 from electromagnetic radiation energy source 38. This information concerning beam alignment (i.e., the manner in which celestial energy beam 40 is striking electromagnetic radiation energy receiver 200) may be provided to an RF transmitter (e.g., wireless communication system 332) that is included within/coupled to/available to electromagnetic radiation energy receiver 200 so that such information may be transmitted to the electromagnetic radiation energy source (e.g., electromagnetic radiation energy source 38). This information may then be used by electromagnetic radiation energy source 38 to reposition celestial energy beam 40 via beam aiming assembly 102 (if adjustment is needed).

Energy acquisition and delivery process 300 may provide 1002 distribution feedback (e.g., feedback 234) via the centrally-positioned feedback device and the plurality of peripherally-positioned feedback devices to the electromagnetic radiation energy source, wherein the distribution feedback (e.g., feedback 234) may be indicative of the distribution of the celestial energy beam (e.g., celestial energy beam 40) on the electromagnetic radiation energy receiver (e.g., electromagnetic radiation energy receiver 200).

As discussed above, by looking at the intensity of the distribution feedback (e.g., feedback 234) received from the centrally-positioned feedback device versus the peripherally-positioned feedback devices), energy acquisition and delivery process 300 may ascertain how well the incoming energy beam (e.g., celestial energy beam 40) is striking electromagnetic radiation energy receiver 200. For example:
TOTAL MISS: If no feedback (e.g., feedback 234) is received by electromagnetic radiation energy source 38, this situation may indicate that the celestial energy beam (e.g., celestial energy beam 40) is not striking electromagnetic radiation energy receiver 200 at all. Accordingly, celestial energy beam 40 may need to be relocated by electromagnetic radiation energy source 38.
PARTIAL HIT/PARTIAL MISS. If any distribution feedback (e.g., feedback 234) is received by electromagnetic radiation energy source 38, this situation may indicate that the celestial energy beam (e.g., celestial energy beam 40) is at least partially striking electromagnetic radiation energy receiver 200. For example, if one or more of the peripherally-positioned feedback devices are providing a higher level of distribution feedback (e.g., feedback 234) than the centrally-positioned feedback device, this situation may indicate that the celestial energy beam (e.g., celestial energy beam 40) is not centered on electromagnetic radiation energy receiver 200 and is partially striking energy receiving devices 202 included within electromagnetic radiation energy receiver 200 . . . but also partially missing energy receiving devices 202 included within electromagnetic radiation energy receiver 200.
TOTAL HIT: If the centrally-positioned feedback device is providing a higher level of distribution feedback (e.g., feedback 234) while the peripherally-positioned feedback devices are providing a lower level of distribution feedback (e.g., feedback 234), this situation may indicate that the celestial energy beam (e.g., celestial energy beam 40) is centered within energy receiving devices 202 included within electromagnetic radiation energy receiver 200. However, operational safety may be maximized when the celestial energy beam (e.g., celestial energy beam 40) is evenly distributed across the entirety of the energy receiving devices 202 included within electromagnetic radiation energy receiver 200 (as opposed to being concentrated in the center). Accordingly, energy acquisition and delivery process 300 may adjust the divergence of the celestial energy beam (e.g., celestial energy beam 40) to spread the beam evenly across all of the energy receiving devices 202 included within electromagnetic radiation energy receiver 200.

As discussed above, electromagnetic radiation energy receiver (e.g., electromagnetic radiation energy receiver 200) may include one or more energy receiving devices (e.g., energy receiving devices 202). Further and as discussed above, operational safety may be maximized when the celestial energy beam (e.g., celestial energy beam 40) is evenly distributed across the entirety of these energy receiving devices 202 (as opposed to being concentrated in the center). Additionally and as discussed above, operational efficiency is enhanced by ensuring that the footprint of the celestial energy beam (e.g., celestial energy beam 40) does not exceed the energy receiving area of electromagnetic radiation energy receiver 200 (which is defined by energy receiving devices 202).

Accordingly, energy acquisition and delivery process 300 may adjust 1004 the optical field of the celestial energy beam (e.g., celestial energy beam 40) at the electromagnetic radiation energy source (e.g., electromagnetic radiation energy source 38) based, at least in part, upon the distribution feedback (e.g., feedback 234) to enhance the quantity of electrical energy extracted (e.g., extracted energy quantity 246) from the celestial energy beam (e.g., celestial energy beam 40) at the electromagnetic radiation energy receiver (e.g., electromagnetic radiation energy receiver 200).

Therefore, if the celestial energy beam (e.g., celestial energy beam 40) is not diverged enough and is generally striking the center of the energy receiving area (which is defined by energy receiving devices 202 of electromagnetic radiation energy receiver 200), energy acquisition and delivery process 300 may increase the divergence of the celestial energy beam (e.g., celestial energy beam 40) to ensure that the celestial energy beam (e.g., celestial energy beam 40) is evenly distributed across the energy receiving area of electromagnetic radiation energy receiver 200. Further and if the celestial energy beam (e.g., celestial energy beam 40) is too diverged and is exceeding the outer boundaries of the energy receiving area (which is defined by energy receiving devices 202 of electromagnetic radiation energy receiver 200), energy acquisition and delivery process 300 may decrease the divergence of he celestial energy beam (e.g., celestial energy beam 40) to ensure that all of the celestial energy beam (e.g., celestial energy beam 40) is striking the energy receiving area of electromagnetic radiation energy receiver 200.

When adjusting 1004 the optical field of the celestial energy beam (e.g., celestial energy beam 40) at the electromagnetic radiation energy source (e.g., electromagnetic radiation energy source 38) based, at least in part, upon the distribution feedback (e.g., feedback 234) to enhance the quantity of electrical energy extracted from the celestial energy beam (e.g., celestial energy beam 40) at the electromagnetic radiation energy receiver (e.g., electromagnetic radiation energy receiver 200), energy acquisition and delivery process 300 may: initially diverge 1006 the celestial energy beam (e.g., celestial energy beam 40) until the quantity of electrical energy extracted (e.g., extracted energy quantity 246) from the celestial energy beam (e.g., celestial energy beam 40) begins to decrease and then converging the celestial energy beam (e.g., celestial energy beam 40).

When initially diverging 1006 the celestial energy beam (e.g., celestial energy beam 40) until the quantity of electrical energy extracted from the celestial energy beam (e.g., celestial energy beam 40) begins to decrease and then converging the celestial energy beam (e.g., celestial energy beam 40), energy acquisition and delivery process 300 may:
displace 1008 the energy beam source (e.g., energy beam source 100) relative to at least a portion of the beam forming package (e.g., beam forming package 104); and/or
displace 1010 at least a portion of the beam forming package (e.g., beam forming package 104) relative to the energy beam source (e.g., energy beam source 100).

As discussed above, the electromagnetic radiation energy source (e.g., electromagnetic radiation energy source 38) may include: an energy beam source (e.g., energy beam source 100) for generating the celestial energy beam (e.g., celestial energy beam 40); and a beam forming package (e.g., beam forming package 104) for forming the celestial energy beam (e.g., celestial energy beam 40).

The energy beam source (e.g., energy beam source 100) for generating the celestial energy beam (e.g., celestial energy beam 40) may include one or more of: a visible-light laser beam source; an Infrared laser beam source; a short wavelength Infrared laser beam source, a mid-Infrared laser beam source; a near-Infrared laser beam source; and a microwave beam source, wherein the beam forming package (e.g., beam forming package 104) for forming the celestial energy beam (e.g., celestial energy beam 40) may include: collimating optics (e.g., collimating optics 110); and focusing optics (e.g., focusing optics 112).

Collimating optics (e.g., collimating optics 110) and/or focusing optics (e.g., focusing optics 112), such as lenses or mirrors, can be utilized to adjust the divergence of the celestial energy beam (e.g., celestial energy beam 40) by being displaced along the beam's propagation path. When the collimating optics (e.g., collimating optics 110) and/or focusing optics (e.g., focusing optics 112) are positioned closer to the energy beam source (e.g., energy beam source 100), the beam tends to converge more sharply to a focal point and then diverges rapidly after that point. Conversely, when the collimating optics (e.g., collimating optics 110) and/or focusing optics (e.g., focusing optics 112) are moved farther away from the energy beam source (e.g., energy beam source 100), the beam (e.g., celestial energy beam 40) can be made more collimated, maintaining a straighter, less divergent profile over a longer distance before eventually spreading.

By carefully adjusting the position of collimating optics (e.g., collimating optics 110) and/or focusing optics (e.g., focusing optics 112), where the beam (e.g., celestial energy beam 40) focuses and how wide or narrow the beam becomes after passing through the optics (e.g., collimating optics 110 and/or focusing optics 112) may be controlled. Even small displacements of the optics (e.g., collimating optics 110 and/or focusing optics 112) can cause significant changes in the divergence of the beam (e.g., celestial energy beam 40) at long distances, allowing for precise tuning based on target requirements. Mechanisms such as linear actuators or piezoelectric stages are often employed to move the optics (e.g., collimating optics 110 and/or focusing optics 112) dynamically, enabling real-time adjustment of the divergence of the beam (e.g., celestial energy beam 40) to match varying operational conditions. In this way, displacement of the optics (e.g., collimating optics 110 and/or focusing optics 112) provides a critical method for shaping the behavior of the celestial energy beam (e.g., celestial energy beam 40) and optimizing its effectiveness for different applications.

As will be explained below in greater detail, when initially diverging 1006 the celestial energy beam (e.g., celestial energy beam 40) until the quantity of electrical energy extracted (e.g., extracted energy quantity 246) from the celestial energy beam (e.g., celestial energy beam 40) begins to decrease and then converging the celestial energy beam (e.g., celestial energy beam 40), energy acquisition and delivery process 300 may:
increase 1012 the divergence of the celestial energy beam (e.g., celestial energy beam 40).
determine 1014 if the extracted energy quantity (e.g., extracted energy quantity 246) decreases after increasing the divergence of the celestial energy beam (e.g., celestial energy beam 40).
if the extracted energy quantity (e.g., extracted energy quantity 246) does not decrease after increasing the divergence of the celestial energy beam (e.g., celestial energy beam 40), continuing 1016 to increase the divergence of the celestial energy beam (e.g., celestial energy beam 40) until the extracted energy quantity decreases.
if the extracted energy quantity (e.g., extracted energy quantity 246) decreases after increasing the divergence of the celestial energy beam (e.g., celestial energy beam 40), decrease 1018 the divergence of the celestial energy beam (e.g., celestial energy beam 40) to undo the last increase.

For the following example, assume that the electromagnetic radiation energy receiver (e.g., electromagnetic radiation energy receiver 200) includes energy receiving devices (e.g., energy receiving devices 202) that are arranged to form an area 50 feet in diameter that is capable of receiving the celestial energy beam (e.g., celestial energy beam 40). Further assume that celestial energy beam 40 is currently 30 feet in diameter and is, therefore, underly diverged. This situation may cause a large portion of the 50 foot diameter energy receiving area being unused, resulting in inefficient use of energy receiving devices 202. Assume that in this current state, energy acquisition and delivery process 300 is sensing an extracted energy quantity (e.g., extracted energy quantity 246) of 85 kilowatts.

Continuing with the above-stated example, energy acquisition and delivery process 300 may: increase 1012 the divergence of the celestial energy beam (e.g., celestial energy beam 40). Accordingly, assume that energy acquisition and delivery process 300 increases 1012 the divergence of the celestial energy beam (e.g., celestial energy beam 40), resulting in the footprint of celestial energy beam 40 increasing from 30 feet in diameter to 50 feet in diameter. Accordingly, the footprint of celestial energy beam 40 now totally covers the 50 foot diameter energy receiving area of electromagnetic radiation energy receiver 200.

Energy acquisition and delivery process 300 may now determine 1014 if the extracted energy quantity (e.g., extracted energy quantity 246) decreases after increasing the divergence of the celestial energy beam (e.g., celestial energy beam 40). Being the footprint of celestial energy beam 40 does not exceed the outer boundaries of the 50 foot diameter energy receiving area of electromagnetic radiation energy receiver 200, energy acquisition and delivery process 300 may determine 1014 that the extracted energy quantity (e.g., extracted energy quantity 246) remains the same, at 85 kilowatts.

Being the extracted energy quantity (e.g., extracted energy quantity 246) did not decrease after the divergence of the celestial energy beam (e.g., celestial energy beam 40) was increased and the footprint of celestial energy beam 40 increased from 30 feet in diameter to 50 feet in diameter, energy acquisition and delivery process 300 may continue 1016 to increase the divergence of the celestial energy beam (e.g., celestial energy beam 40) until the extracted energy quantity (e.g., extracted energy quantity 246) decreases.

Continuing with the above-stated example, energy acquisition and delivery process 300 may: once again increase 1012 the divergence of the celestial energy beam (e.g., celestial energy beam 40). Accordingly, assume that energy acquisition and delivery process 300 increases 1012 the divergence of the celestial energy beam (e.g., celestial energy beam 40), resulting in the footprint of celestial energy beam 40 increasing from 50 feet in diameter to 70 feet in diameter. Accordingly, the 70 foot diameter footprint of celestial energy beam 40 now exceeds the perimeter of the 50 foot diameter energy receiving area of electromagnetic radiation energy receiver 200.

Energy acquisition and delivery process 300 may once again determine 1014 if the extracted energy quantity (e.g., extracted energy quantity 246) decreases after increasing the divergence of the celestial energy beam (e.g., celestial energy beam 40). Being the footprint of celestial energy beam 40 (at 70 feet) now exceeds the outer boundaries of the 50 foot diameter energy receiving area of electromagnetic radiation energy receiver 200, energy acquisition and delivery process 300 may determine 1014 that the extracted energy quantity (e.g., extracted energy quantity 246) has dropped from 85 kilowatts to 60 kilowatts (as a sizeable portion of celestial energy beam 40 is being wasted, as it is striking something other than the energy receiving devices (e.g., energy receiving devices 202).

Accordingly and since the extracted energy quantity (e.g., extracted energy quantity 246) has decreased (from 85 kilowatts to 60 kilowatts) after increasing the divergence of the celestial energy beam (e.g., celestial energy beam 40) to increase the footprint of celestial energy beam 40 from 50 feet in diameter to 70 feet in diameter, energy acquisition and delivery process 300 may decrease 1018 the divergence of the celestial energy beam (e.g., celestial energy beam 40) to undo the last increase, resulting in the footprint of celestial energy beam 40 being reduced from 70 feet in diameter to 50 feet in diameter and the extracted energy quantity (e.g., extracted energy quantity 246) increasing from 60 kilowatts to 85 kilowatts.

### (15) Methodologies of Providing Power to Ships.

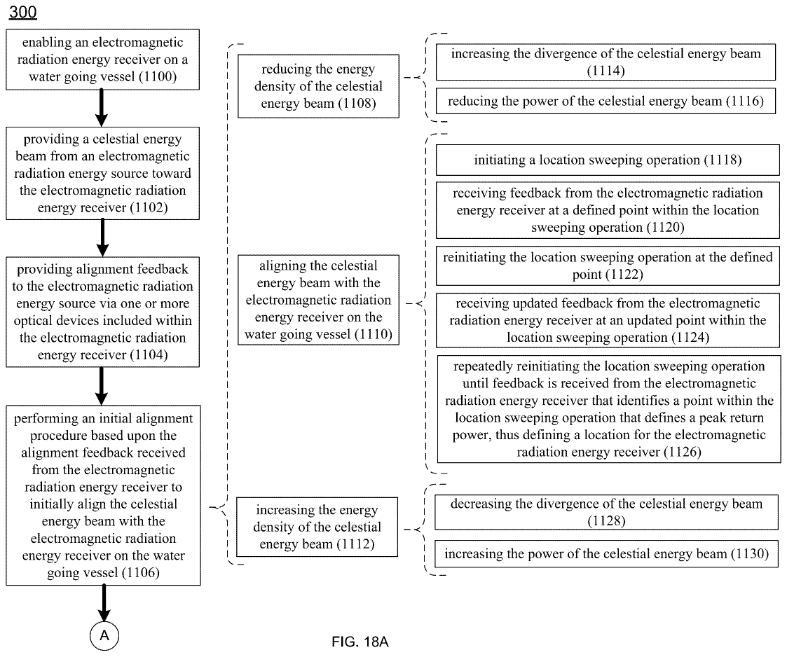

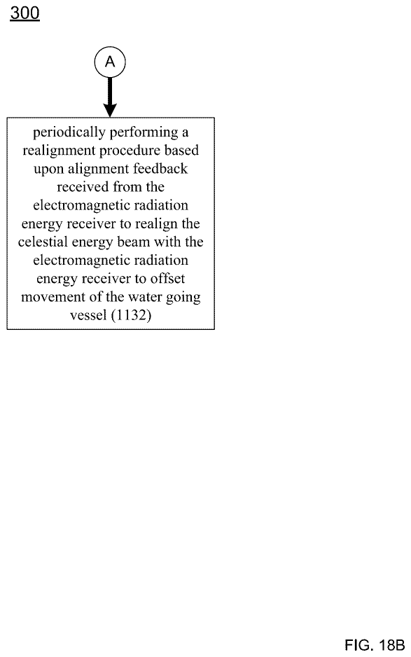

Referring also to FIGS. 18A-18B, the following discussion concerns the manner in which energy acquisition and delivery process 300 may provide electrical energy to a water going vessel via a celestial energy beam (e.g., celestial energy beam 40) that is provided by an electromagnetic radiation energy source (e.g., electromagnetic radiation energy source 38) to an electromagnetic radiation energy receiver (e.g., electromagnetic radiation energy receiver 200) on the water going vessel.

Energy acquisition and delivery process 300 may enable 1100 an electromagnetic radiation energy receiver (e.g., electromagnetic radiation energy receiver 200) on a water going vessel (e.g., water going vessel 248). Examples of the water going vessel (e.g., water going vessel 248) may include but are not limited to cargo ships, container ships, cruise ships, and oil tankers.

For example and when enabling 1100 an electromagnetic radiation energy receiver (e.g., electromagnetic radiation energy receiver 200) on a water going vessel (e.g., water going vessel 248), energy acquisition and delivery process 300 may energize and/or provide power to the electromagnetic radiation energy receiver (e.g., electromagnetic radiation energy receiver 200). For example, it is foreseeable that the water going vessel (e.g., water going vessel 248) would usually be powered by fossil fuels (such as diesel fuel). Accordingly and during most operations, electromagnetic radiation energy receiver (e.g., electromagnetic radiation energy receiver 200) on the water going vessel (e.g., water going vessel 248) may be powered down. Additionally/alternatively and when enabling 1100 an electromagnetic radiation energy receiver (e.g., electromagnetic radiation energy receiver 200) on the water going vessel (e.g., water going vessel 248), the electromagnetic radiation energy receiver (e.g., electromagnetic radiation energy receiver 200) may be configured to receive a particular type of celestial energy beam, such as laser or microwave.

Once enabled 1100, energy acquisition and delivery process 300 may provide 1102 a celestial energy beam (e.g., celestial energy beam 40) from an electromagnetic radiation energy source (e.g., electromagnetic radiation energy source 38) toward the electromagnetic radiation energy receiver (e.g., electromagnetic radiation energy receiver 200).

As discussed above and for providing 1102 a celestial energy beam (e.g., celestial energy beam 40), the electromagnetic radiation energy source (e.g., electromagnetic radiation energy source 38) may include: an energy beam source (e.g., energy beam source 100) for generating the celestial energy beam (e.g., celestial energy beam 40); a beam aiming assembly (e.g., beam aiming assembly 102) for steering the celestial energy beam (e.g., celestial energy beam 40) toward a target; and a beam forming package (e.g., beam forming package 104) for forming the celestial energy beam (e.g., celestial energy beam 40).

The energy beam source (e.g., energy beam source 100) for generating the celestial energy beam (e.g., celestial energy beam 40) may include one or more of: a visible-light laser beam source; an Infrared laser beam source; a short wavelength Infrared laser beam source, a mid-Infrared laser beam source; a near-Infrared laser beam source; and a microwave beam source.

The beam aiming assembly (e.g., beam aiming assembly 102) for steering the celestial energy beam (e.g., celestial energy beam 40) may include: a Gimbal mount assembly (e.g., Gimbal mount assembly 106) configured to direct the celestial energy beam (e.g., celestial energy beam 40) toward a target; a phased array assembly (e.g., phased array assembly 107) configured to direct the celestial energy beam (e.g., celestial energy beam 40) toward a target and/or a periscope assembly (e.g., periscope assembly 108) configured to direct the celestial energy beam (e.g., celestial energy beam 40) toward a target. A Gimbal mount assembly (e.g., Gimbal mount assembly 106), a phased array assembly (e.g., phased array assembly 107) and a periscope assembly (e.g., periscope assembly 108) can be effectively used in space-based energy systems to accurately direct a celestial energy beam (e.g., celestial energy beam 40), such as a laser or microwave beam, from a satellite (e.g., satellite 14) to a electromagnetic radiation energy receiver (e.g., electromagnetic radiation energy receiver 200).

The beam forming package (e.g., beam forming package 104) for forming the celestial energy beam (e.g., celestial energy beam 40) may include: collimating optics (e.g., collimating optics 110); and focusing optics (e.g., focusing optics 112). Collimating optics (e.g., collimating optics 110) are used to shape a celestial energy beam (e.g., celestial energy beam 40) so that its rays are parallel, resulting in a collimated beam i.e., one that doesn't spread out (diverge) significantly over distance. When a celestial energy beam (e.g., celestial energy beam 40) exits a source (e.g., energy beam source 100) like a diode, it typically diverges, meaning the beam spreads out as it travels.

Collimating optics (e.g., collimating optics 110), such as a lens or a lens system, are placed in the beam path to correct this divergence. By focusing the light emerging from a point-like or narrow source, collimating optics (e.g., collimating optics 110) create a beam with minimal angular spread. This is especially important for applications that require the beam to travel long distances (e.g., power transmission) or interact with precise optical components. In short, collimating optics (e.g., collimating optics 110) make a celestial energy beam (e.g., celestial energy beam 40) straighter and more focused over distance, improving its usability and efficiency in various optical systems.

Focusing optics (e.g., focusing optics 112) do the opposite of collimating optics (e.g., collimating optics 110), as they take a celestial energy beam (e.g., celestial energy beam 40) and converge it to a point or a small spot. This is usually achieved with lenses or curved mirrors that bend the incoming rays inward, concentrating the beam's energy into a smaller area. When a collimated or diverging celestial energy beam (e.g., celestial energy beam 40) passes through focusing optics (e.g., focusing optics 112), the optics manipulate the beam's path so that all rays come together at a focal point.

Energy acquisition and delivery process 300 may provide 1104 alignment feedback (e.g., feedback 234) to the electromagnetic radiation energy source (e.g., electromagnetic radiation energy source 38) via one or more feedback devices (e.g., feedback devices 226) included within the electromagnetic radiation energy receiver (e.g., electromagnetic radiation energy receiver 200).

As discussed above, the one or more feedback devices (e.g., feedback devices 226) included within the electromagnetic radiation energy receiver (e.g., electromagnetic radiation energy receiver 200) may include: a centrally-positioned feedback device within the electromagnetic radiation energy receiver (e.g., electromagnetic radiation energy receiver 200) and a plurality of peripherally-positioned feedback devices within the electromagnetic radiation energy receiver (e.g., electromagnetic radiation energy receiver 200).

At least one of the feedback devices (e.g., feedback devices 226) may be a retroreflector. As discussed above, a retroreflector is a specialized feedback device or surface that reflects incoming electromagnetic radiation (e.g., a portion of celestial energy beam 40) directly back toward its source (e.g., electromagnetic radiation energy source 38), regardless of the angle at which celestial energy beam 40 arrives. Unlike a standard mirror, which reflects light at an angle equal to the incident angle, a retroreflector returns celestial energy beam 40 along a near-exact path from which it came through geometric structures (e.g., corner cubes, cat's-eye lenses, or Bragg gratings).

As discussed above, the feedback devices (e.g., feedback devices 226) may include an RF component. Specifically, feedback devices 226 may include a plurality of opto-electrical sensors (e.g., photodiodes, photodetectors and/or photovoltaic cells). This plurality of sensors (e.g., feedback devices 226) may monitor the position of celestial energy beam 40, which is received on electromagnetic radiation energy receiver 200 from electromagnetic radiation energy source 38. This information concerning beam alignment (i.e., the manner in which celestial energy beam 40 is striking electromagnetic radiation energy receiver 200) may be provided to an RF transmitter (e.g., wireless communication system 332) that is included within/coupled to/available to electromagnetic radiation energy receiver 200 so that such information may be transmitted to the electromagnetic radiation energy source (e.g., electromagnetic radiation energy source 38). This information may then be used by electromagnetic radiation energy source 38 to reposition celestial energy beam 40 via beam aiming assembly 102 (if adjustment is needed).

Energy acquisition and delivery process 300 may perform 1106 an initial alignment procedure based upon the alignment feedback (e.g., feedback 234) received from the electromagnetic radiation energy receiver (e.g., electromagnetic radiation energy receiver 200) to initially align the celestial energy beam (e.g., celestial energy beam 40) with the electromagnetic radiation energy receiver (e.g., electromagnetic radiation energy receiver 200) on the water going vessel (e.g., water going vessel 248).

When performing 1106 an initial alignment procedure based upon the alignment feedback (e.g., feedback 234) received from the electromagnetic radiation energy receiver (e.g., electromagnetic radiation energy receiver 200) to initially align the celestial energy beam (e.g., celestial energy beam 40) with the electromagnetic radiation energy receiver (e.g., electromagnetic radiation energy receiver 200) on the water going vessel (e.g., water going vessel 248), energy acquisition and delivery process 300 may:
reduce 1108 the energy density of the celestial energy beam (e.g., celestial energy beam 40);
align 1110 the celestial energy beam (e.g., celestial energy beam 40) with the electromagnetic radiation energy receiver (e.g., electromagnetic radiation energy receiver 200) on the water going vessel (e.g., water going vessel 248); and
increase 1112 the energy density of the celestial energy beam (e.g., celestial energy beam 40).

When reducing 1108 the energy density of the celestial energy beam (e.g., celestial energy beam 40), energy acquisition and delivery process 300 may: increase 1114 the divergence of the celestial energy beam (e.g., celestial energy beam 40); and/or reduce 1116 the power of the celestial energy beam (e.g., celestial energy beam 40).

As discussed above, the energy density of a celestial energy beam (e.g., celestial energy beam 40) refers to the amount of energy delivered per unit area of the celestial energy beam (e.g., celestial energy beam 40). To reduce the energy density of celestial energy beam 40, two main strategies may be used: increasing the divergence of celestial energy beam 40 and/or reducing the power of celestial energy beam 40.

Increasing Divergency: Increasing 1114 the divergence of celestial energy beam 40 involves widening the beam as it travels through space. Such an increase may be effectuated via the beam forming package 104 within electromagnetic radiation energy source 38. A more divergent beam spreads its energy over a larger area, which decreases the energy concentration at any given point. Accordingly and even if the total power of the beam remains the same, the energy density of the beam will be reduced since the same amount of energy is distributed over a broader cross-sectional area.

Reducing Power: Reducing 1116 the power of celestial energy beam 40 involves lowering the total amount of energy being transmitted. Such a power reduction may be effectuated by decreasing the power supplied to energy beam source 100 within electromagnetic radiation energy source 38, thus resulting in a less powerful celestial energy beam 40. Since energy density is directly related to the beam's total power, a lower-power beam naturally results in less energy being concentrated in any given area of the celestial energy beam. For example, if the beam power is cut in half, the energy density will also be cut in half, assuming the beam size remains the same.

In practical terms, reducing energy density by these methods can improve safety helping to prevent damage to equipment, minimizing risk to nearby humans, aircraft or animals, and easing the thermal and structural load on receiving systems. It also allows for more manageable interception or redirection of the beam if necessary.

When aligning 1110 the celestial energy beam (e.g., celestial energy beam 40) with the electromagnetic radiation energy receiver (e.g., electromagnetic radiation energy receiver 200) on the water going vessel (e.g., water going vessel 248), energy acquisition and delivery process 300 may: initiate 1118 a location sweeping operation; receive 1120 feedback (e.g., feedback 234) from the electromagnetic radiation energy receiver (e.g., electromagnetic radiation energy receiver 200) at a defined point (e.g., defined point 238) within the location sweeping operation; reinitiate 1122 the location sweeping operation at the defined point (e.g., defined point 238); and receive 1124 updated feedback (e.g., feedback 234) from the electromagnetic radiation energy receiver (e.g., electromagnetic radiation energy receiver 200) at an updated point (e.g., updated point 240) within the location sweeping operation.

Energy acquisition and delivery process 300 may initiate 1118 a location sweeping operation. The location sweeping operation may include a sweeping operation that initiates at an initial point (e.g., initial point 236) and spirals outwardly away from the initial point (e.g., initial point 236), as shown in FIG. 15. Energy acquisition and delivery process 300 may receive 1120 feedback (e.g., feedback 234) from the electromagnetic radiation energy receiver (e.g., electromagnetic radiation energy receiver 200) at a defined point (e.g., defined point 238) within the location sweeping operation.

As discussed above, this feedback (e.g., feedback 234) may be generated via one or more feedback devices (e.g., feedback devices 226) included within the electromagnetic radiation energy receiver (e.g., electromagnetic radiation energy receiver 200). As discussed above, the one or more feedback devices (e.g., feedback devices 226) included within the electromagnetic radiation energy receiver (e.g., electromagnetic radiation energy receiver 200) may include: a centrally-positioned feedback device within the electromagnetic radiation energy receiver (e.g., electromagnetic radiation energy receiver 200) and a plurality of peripherally-positioned feedback devices within the electromagnetic radiation energy receiver (e.g., electromagnetic radiation energy receiver 200).

As discussed above, at least one of the feedback devices (e.g., feedback devices 226) may be a retroreflector. As discussed above, a retroreflector is a specialized feedback device or surface that reflects incoming electromagnetic radiation (e.g., a portion of celestial energy beam 40) directly back toward its source (e.g., electromagnetic radiation energy source 38), regardless of the angle at which celestial energy beam 40 arrives. Unlike a standard mirror, which reflects light at an angle equal to the incident angle, a retroreflector returns celestial energy beam 40 along a near-exact path from which it came through geometric structures (e.g., corner cubes, cat's-eye lenses, or Bragg gratings).

As discussed above, the feedback devices (e.g., feedback devices 226) may include an RF component. Specifically, feedback devices 226 may include a plurality of opto-electrical sensors (e.g., photodiodes, photodetectors and/or photovoltaic cells). This plurality of sensors (e.g., feedback devices 226) may monitor the position of celestial energy beam 40, which is received on electromagnetic radiation energy receiver 200 from electromagnetic radiation energy source 38. This information concerning beam alignment (i.e., the manner in which celestial energy beam 40 is striking electromagnetic radiation energy receiver 200) may be provided to an RF transmitter (e.g., wireless communication system 332) that is included within/coupled to/available to electromagnetic radiation energy receiver 200 so that such information may be transmitted to the electromagnetic radiation energy source (e.g., electromagnetic radiation energy source 38). This information may then be used by electromagnetic radiation energy source 38 to reposition celestial energy beam 40 via beam aiming assembly 102 (if adjustment is needed).

As discussed above, this feedback (e.g., feedback 234) may be received on feedback receiving devices (e.g., feedback receiving devices 128) included within electromagnetic radiation energy source 38, wherein such feedback receiving devices (e.g., feedback receiving devices 128) may include but are not limited to one or more of: one or more photovoltaic cells; one or more photodiodes; one or more heat engines; and one or more rectenna arrays.

Energy acquisition and delivery process 300 may reinitiate 1122 the location sweeping operation at the defined point (e.g., defined point 238). Energy acquisition and delivery process 300 may receive 1124 updated feedback (e.g., feedback 234) from the electromagnetic radiation energy receiver (e.g., electromagnetic radiation energy receiver 200) at an updated point (e.g., updated point 240) within the location sweeping operation.

Energy acquisition and delivery process 300 may: repeatedly reinitiate 1126 the location sweeping operation until feedback (e.g., feedback 234) is received from the electromagnetic radiation energy receiver (e.g., electromagnetic radiation energy receiver 200) that identifies a point within the location sweeping operation that defines a peak return power, thus defining a location for the electromagnetic radiation energy receiver (e.g., electromagnetic radiation energy receiver 200).

As discussed above, assume that energy acquisition and delivery process 300 initiates the above-discussed location sweeping operation at initial point 236 by scanning of a 500 foot diameter circle. If feedback (e.g., feedback 234) is not received from electromagnetic radiation energy receiver 200 during this scanning operation, this lack of feedback indicates that electromagnetic radiation energy receiver 200 is not located within the 500 foot diameter circle and the location sweeping operation may spiral outwardly away from initial point 236.

As discussed above, energy acquisition and delivery process 300 may spiral outwardly away from initial point 236 and continue the location sweeping operation from a new point (e.g., point 236A) that is spaced radially away from initial point 236. Again, assume that energy acquisition and delivery process 300 begins repeatedly scanning 500 foot diameter circles while moving in the direction of arrow 850 to form a ring around the initial 500 foot diameter circle (that is positioned at initial point 236). During each of these 500 foot diameter scans, energy acquisition and delivery process 300 may monitor for feedback (e.g., feedback 234) in an attempt to locate the electromagnetic radiation energy receiver (e.g., electromagnetic radiation energy receiver 200). As discussed above, if feedback (e.g., feedback 234) is not received from electromagnetic radiation energy receiver 200 during any of these scanning operations, such a lack of feedback indicates that electromagnetic radiation energy receiver 200 is not positioned within the 500 foot diameter circle that is currently being scanned while moving along arrow 850.

As stated above, assume that no feedback is received while scanning each of the 500 foot diameter circles positioned along arrow 850, thus indicating that electromagnetic radiation energy receiver 200 is not located within any of these 500 foot diameter circles. Again, the location sweeping operation may spiral outwardly further away from initial point 236 and continue the location sweeping operation at a new point (e.g., point 238B) that is spaced even further radially away from initial point 236. For this example, assume that energy acquisition and delivery process 300 begins repeatedly scanning 500 foot diameter circles while moving in the direction of arrow 850A to form a second (and more distal) ring around the initial 500 foot diameter circle positioned at initial point 236.

During each of these 500 foot diameter scans along arrow 850A, energy acquisition and delivery process 300 may monitor for feedback (e.g., feedback 234) in an attempt to locate the electromagnetic radiation energy receiver (e.g., electromagnetic radiation energy receiver 200). Again, if feedback (e.g., feedback 234) is not received from electromagnetic radiation energy receiver 200 during a scanning operation, such a lack of feedback indicates that electromagnetic radiation energy receiver 200 is not positioned within the 500 foot diameter circles being scanned while moving in the direction of arrow 850A.

Continuing with the above-stated example, assume that upon scanning a specific 500 foot diameter circle (e.g., circle 852) along arrow 850A, feedback (e.g., feedback 234) is received from electromagnetic radiation energy receiver 200, thus indicating that electromagnetic radiation energy receiver 200 is positioned therein and identifying a defined point (e.g., defined point 238) within the location sweeping operation.

In response to such feedback being received, energy acquisition and delivery process 300 may reinitiate the location sweeping operation at the defined point (e.g., defined point 238). Specifically, this new location sweeping operation may be centered about (and spiral outwardly from) defined point 238. For this example, assume that energy acquisition and delivery process 300 begins repeatedly scanning 500 foot diameter circles while moving in the direction of arrow 854 to form a ring around circle 852 positioned at defined point 238. During each of these 500 foot diameter scans, energy acquisition and delivery process 300 may monitor for feedback (e.g., feedback 234) from the electromagnetic radiation energy receiver (e.g., electromagnetic radiation energy receiver 200). Assume that energy acquisition and delivery process 300 receives updated feedback (e.g., feedback 234) from the electromagnetic radiation energy receiver (e.g., electromagnetic radiation energy receiver 200) at an updated point (e.g., updated point 240) within the location sweeping operation, further refining the location of the electromagnetic radiation energy receiver (e.g., electromagnetic radiation energy receiver 200).

As discussed above, energy acquisition and delivery process 300 may repeatedly reinitiate the location sweeping operation until feedback (e.g., feedback 234) is received from the electromagnetic radiation energy receiver (e.g., electromagnetic radiation energy receiver 200) that identifies a point within the location sweeping operation that defines a peak return power. This point will define a location (e.g., receiver location 242) for the electromagnetic radiation energy receiver (e.g., electromagnetic radiation energy receiver 200). For example, each time new feedback (e.g., feedback 234) is received from electromagnetic radiation energy receiver 200, subsequent sweeping operations may be initiated by energy acquisition and delivery process 300 until the peak return power is identified, at which point the location of the electromagnetic radiation energy receiver (e.g., electromagnetic radiation energy receiver 200) will be deemed to be sufficiently defined. In the interest of brevity, assume that this location (e.g., receiver location 242) is updated point 240.

Once aligned 1110, energy acquisition and delivery process 300 may direct the celestial energy beam (e.g., celestial energy beam 40) toward the location (e.g., receiver location 242) of the electromagnetic radiation energy receiver (e.g., electromagnetic radiation energy receiver 200).

When increasing 1112 the energy density of the celestial energy beam (e.g., celestial energy beam 40), energy acquisition and delivery process 300 may: decrease 1128 the divergence of the celestial energy beam (e.g., celestial energy beam 40); and/or increase 1130 the power of the celestial energy beam (e.g., celestial energy beam 40).

As discussed above, the energy density of a celestial energy beam (e.g., celestial energy beam 40) refers to the amount of energy delivered per unit area of the celestial energy beam (e.g., celestial energy beam 40). To increase the energy density of celestial energy beam 40, two main strategies may be used: decreasing the divergence of celestial energy beam 40 and/or increasing the power of celestial energy beam 40.

Decreasing Divergence: Decreasing 1128 the divergence of celestial energy beam 40 involves narrowing the beam as it travels through space. Such a decrease may be effectuated via the beam forming package 104 within electromagnetic radiation energy source 38. A less divergent beam focuses its energy within a smaller area, which increases the energy concentration at any given point. Accordingly and even if the total power of the beam remains the same, the energy density of the beam will be increased since the same amount of energy is focused within a smaller cross-sectional area.

Increasing Power: Increasing 1130 the power of celestial energy beam 40 involves increasing the total amount of energy being transmitted. Such a power increase may be effectuated by increasing the power supplied to energy beam source 100 within electromagnetic radiation energy source 38, thus resulting in a more powerful celestial energy beam 40. Since energy density is directly related to the beam's total power, a higher-power beam naturally results in more energy being concentrated in any given area of the celestial energy beam. For example, if the beam power is doubled, the energy density will also be doubled, assuming the beam size remains the same.

Energy acquisition and delivery process 300 may periodically perform 1132 a realignment procedure based upon alignment feedback (e.g., feedback 234) received from the electromagnetic radiation energy receiver (e.g., electromagnetic radiation energy receiver 200) to realign the celestial energy beam (e.g., celestial energy beam 40) with the electromagnetic radiation energy receiver (e.g., electromagnetic radiation energy receiver 200) to offset movement of the water going vessel (e.g., water going vessel 248).

### (16) Methodologies of Providing Power to a Terrestrial Vehicle.

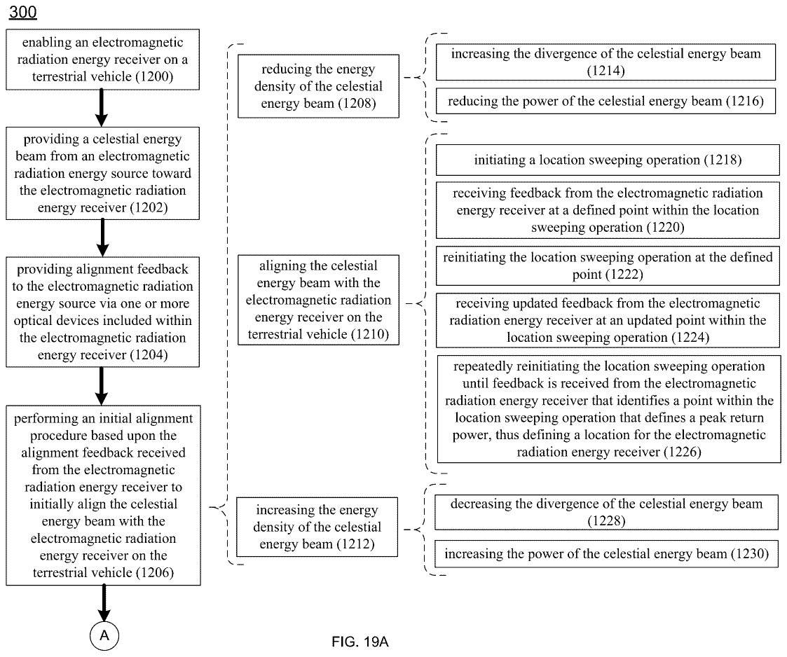

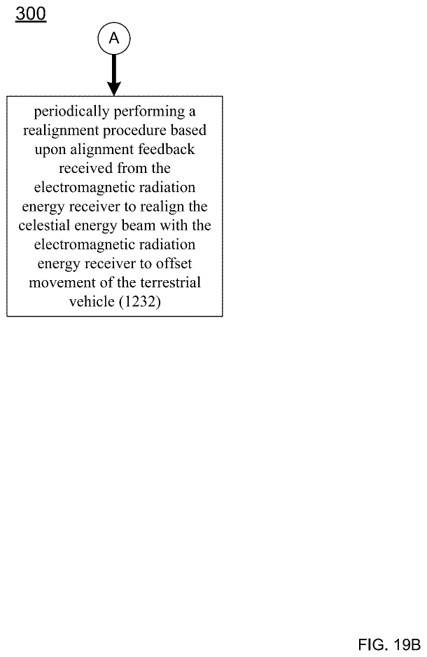

Referring also to FIGS. 19A-19B, the following discussion concerns the manner in which energy acquisition and delivery process 300 may provide electrical energy to a terrestrial vehicle via a celestial energy beam (e.g., celestial energy beam 40) that is provided by an electromagnetic radiation energy source (e.g., electromagnetic radiation energy source 38) to an electromagnetic radiation energy receiver (e.g., electromagnetic radiation energy receiver 200) on the terrestrial vehicle.

Energy acquisition and delivery process 300 may enable 1200 an electromagnetic radiation energy receiver (e.g., electromagnetic radiation energy receiver 200) on a terrestrial vehicle (e.g., terrestrial vehicle 250). Examples of the terrestrial vehicle (e.g., terrestrial vehicle 250) may include but are not limited to: heavy construction equipment, mining equipment, and transportation equipment.

For example and when enabling 1200 an electromagnetic radiation energy receiver (e.g., electromagnetic radiation energy receiver 200) on a terrestrial vehicle (e.g., terrestrial vehicle 250), energy acquisition and delivery process 300 may energize and/or provide power to the electromagnetic radiation energy receiver (e.g., electromagnetic radiation energy receiver 200). For example, it is foreseeable that the terrestrial vehicle (e.g., terrestrial vehicle 250) would usually be powered by fossil fuels (such as diesel fuel or gasoline). Accordingly and during most operations, electromagnetic radiation energy receiver (e.g., electromagnetic radiation energy receiver 200) on the terrestrial vehicle (e.g., terrestrial vehicle 250) may be powered down. Additionally/alternatively and when enabling 1200 an electromagnetic radiation energy receiver (e.g., electromagnetic radiation energy receiver 200) on the terrestrial vehicle (e.g., terrestrial vehicle 250), the electromagnetic radiation energy receiver (e.g., electromagnetic radiation energy receiver 200) may be configured to receive a particular type of celestial energy beam, such as laser or microwave.

Once enabled 1200, energy acquisition and delivery process 300 may provide 1202 a celestial energy beam (e.g., celestial energy beam 40) from an electromagnetic radiation energy source (e.g., electromagnetic radiation energy source 38) toward the electromagnetic radiation energy receiver (e.g., electromagnetic radiation energy receiver 200).

As discussed above and for providing 1202 a celestial energy beam (e.g., celestial energy beam 40), the electromagnetic radiation energy source (e.g., electromagnetic radiation energy source 38) may include: an energy beam source (e.g., energy beam source 100) for generating the celestial energy beam (e.g., celestial energy beam 40); a beam aiming assembly (e.g., beam aiming assembly 102) for steering the celestial energy beam (e.g., celestial energy beam 40) toward a target; and a beam forming package (e.g., beam forming package 104) for forming the celestial energy beam (e.g., celestial energy beam 40).

The energy beam source (e.g., energy beam source 100) for generating the celestial energy beam (e.g., celestial energy beam 40) may include one or more of: a visible-light laser beam source; an Infrared laser beam source; a short wavelength Infrared laser beam source, a mid-Infrared laser beam source; a near-Infrared laser beam source; and a microwave beam source.

The beam aiming assembly (e.g., beam aiming assembly 102) for steering the celestial energy beam (e.g., celestial energy beam 40) may include: a Gimbal mount assembly (e.g., Gimbal mount assembly 106) configured to direct the celestial energy beam (e.g., celestial energy beam 40) toward a target; a phased array assembly (e.g., phased array assembly 107) configured to direct the celestial energy beam (e.g., celestial energy beam 40) toward a target and/or a periscope assembly (e.g., periscope assembly 108) configured to direct the celestial energy beam (e.g., celestial energy beam 40) toward a target. A Gimbal mount assembly (e.g., Gimbal mount assembly 106), a phased array assembly (e.g., phased array assembly 107) and a periscope assembly (e.g., periscope assembly 108) can be effectively used in space-based energy systems to accurately direct a celestial energy beam (e.g., celestial energy beam 40), such as a laser or microwave beam, from a satellite (e.g., satellite 14) to a electromagnetic radiation energy receiver (e.g., electromagnetic radiation energy receiver 200).

The beam forming package (e.g., beam forming package 104) for forming the celestial energy beam (e.g., celestial energy beam 40) may include: collimating optics (e.g., collimating optics 110); and focusing optics (e.g., focusing optics 112). Collimating optics (e.g., collimating optics 110) are used to shape a celestial energy beam (e.g., celestial energy beam 40) so that its rays are parallel, resulting in a collimated beam i.e., one that doesn't spread out (diverge) significantly over distance. When a celestial energy beam (e.g., celestial energy beam 40) exits a source (e.g., energy beam source 100) like a diode, it typically diverges, meaning the beam spreads out as it travels.

Collimating optics (e.g., collimating optics 110), such as a lens or a lens system, are placed in the beam path to correct this divergence. By focusing the light emerging from a point-like or narrow source, collimating optics (e.g., collimating optics 110) create a beam with minimal angular spread. This is especially important for applications that require the beam to travel long distances (e.g., power transmission) or interact with precise optical components. In short, collimating optics (e.g., collimating optics 110) make a celestial energy beam (e.g., celestial energy beam 40) straighter and more focused over distance, improving its usability and efficiency in various optical systems.

Focusing optics (e.g., focusing optics 112) do the opposite of collimating optics (e.g., collimating optics 110), as they take a celestial energy beam (e.g., celestial energy beam 40) and converge it to a point or a small spot. This is usually achieved with lenses or curved mirrors that bend the incoming rays inward, concentrating the beam's energy into a smaller area. When a collimated or diverging celestial energy beam (e.g., celestial energy beam 40) passes through focusing optics (e.g., focusing optics 112), the optics manipulate the beam's path so that all rays come together at a focal point.

Energy acquisition and delivery process 300 may provide 1204 alignment feedback (e.g., feedback 234) to the electromagnetic radiation energy source (e.g., electromagnetic radiation energy source 38) via one or more feedback devices (e.g., feedback devices 226) included within the electromagnetic radiation energy receiver (e.g., electromagnetic radiation energy receiver 200).

As discussed above, the one or more feedback devices (e.g., feedback devices 226) included within the electromagnetic radiation energy receiver (e.g., electromagnetic radiation energy receiver 200) may include: a centrally-positioned feedback device within the electromagnetic radiation energy receiver (e.g., electromagnetic radiation energy receiver 200) and a plurality of peripherally-positioned feedback devices within the electromagnetic radiation energy receiver (e.g., electromagnetic radiation energy receiver 200).

At least one of the feedback devices (e.g., feedback devices 226) may be a retroreflector. As discussed above, a retroreflector is a specialized feedback device or surface that reflects incoming electromagnetic radiation (e.g., a portion of celestial energy beam 40) directly back toward its source (e.g., electromagnetic radiation energy source 38), regardless of the angle at which celestial energy beam 40 arrives. Unlike a standard mirror, which reflects light at an angle equal to the incident angle, a retroreflector returns celestial energy beam 40 along a near-exact path from which it came through geometric structures (e.g., corner cubes, cat's-eye lenses, or Bragg gratings).

As discussed above, the feedback devices (e.g., feedback devices 226) may include an RF component. Specifically, feedback devices 226 may include a plurality of opto-electrical sensors (e.g., photodiodes, photodetectors and/or photovoltaic cells). This plurality of sensors (e.g., feedback devices 226) may monitor the position of celestial energy beam 40, which is received on electromagnetic radiation energy receiver 200 from electromagnetic radiation energy source 38. This information concerning beam alignment (i.e., the manner in which celestial energy beam 40 is striking electromagnetic radiation energy receiver 200) may be provided to an RF transmitter (e.g., wireless communication system 332) that is included within/coupled to/available to electromagnetic radiation energy receiver 200 so that such information may be transmitted to the electromagnetic radiation energy source (e.g., electromagnetic radiation energy source 38). This information may then be used by electromagnetic radiation energy source 38 to reposition celestial energy beam 40 via beam aiming assembly 102 (if adjustment is needed).

Energy acquisition and delivery process 300 may perform 1206 an initial alignment procedure based upon the alignment feedback (e.g., feedback 234) received from the electromagnetic radiation energy receiver (e.g., electromagnetic radiation energy receiver 200) to initially align the celestial energy beam (e.g., celestial energy beam 40) with the electromagnetic radiation energy receiver (e.g., electromagnetic radiation energy receiver 200) on the terrestrial vehicle (e.g., terrestrial vehicle 250).

When performing 1206 an initial alignment procedure based upon the alignment feedback (e.g., feedback 234) received from the electromagnetic radiation energy receiver (e.g., electromagnetic radiation energy receiver 200) to initially align the celestial energy beam (e.g., celestial energy beam 40) with the electromagnetic radiation energy receiver (e.g., electromagnetic radiation energy receiver 200) on the terrestrial vehicle (e.g., terrestrial vehicle 250), energy acquisition and delivery process 300 may:
reduce 1208 the energy density of the celestial energy beam (e.g., celestial energy beam 40);
align 1210 the celestial energy beam (e.g., celestial energy beam 40) with the electromagnetic radiation energy receiver (e.g., electromagnetic radiation energy receiver 200) on the terrestrial vehicle (e.g., terrestrial vehicle 250); and
increase 1212 the energy density of the celestial energy beam (e.g., celestial energy beam 40).

When reducing 1208 the energy density of the celestial energy beam (e.g., celestial energy beam 40), energy acquisition and delivery process 300 may: increase 1214 the divergence of the celestial energy beam (e.g., celestial energy beam 40); and/or reduce 1216 the power of the celestial energy beam (e.g., celestial energy beam 40).

As discussed above, the energy density of a celestial energy beam (e.g., celestial energy beam 40) refers to the amount of energy delivered per unit area of the celestial energy beam (e.g., celestial energy beam 40). To reduce the energy density of celestial energy beam 40, two main strategies may be used: increasing the divergence of celestial energy beam 40 and/or reducing the power of celestial energy beam 40.

Increasing Divergency: Increasing 1214 the divergence of celestial energy beam 40 involves widening the beam as it travels through space. Such an increase may be effectuated via the beam forming package 104 within electromagnetic radiation energy source 38. A more divergent beam spreads its energy over a larger area, which decreases the energy concentration at any given point. Accordingly and even if the total power of the beam remains the same, the energy density of the beam will be reduced since the same amount of energy is distributed over a broader cross-sectional area.

Reducing Power: Reducing 1216 the power of celestial energy beam 40 involves lowering the total amount of energy being transmitted. Such a power reduction may be effectuated by decreasing the power supplied to energy beam source 100 within electromagnetic radiation energy source 38, thus resulting in a less powerful celestial energy beam 40. Since energy density is directly related to the beam's total power, a lower-power beam naturally results in less energy being concentrated in any given area of the celestial energy beam. For example, if the beam power is cut in half, the energy density will also be cut in half, assuming the beam size remains the same.

In practical terms, reducing energy density by these methods can improve safety helping to prevent damage to equipment, minimizing risk to nearby humans, aircraft or animals, and easing the thermal and structural load on receiving systems. It also allows for more manageable interception or redirection of the beam if necessary.

When aligning 1210 the celestial energy beam (e.g., celestial energy beam 40) with the electromagnetic radiation energy receiver (e.g., electromagnetic radiation energy receiver 200) on the terrestrial vehicle (e.g., terrestrial vehicle 250), energy acquisition and delivery process 300 may: initiate 1218 a location sweeping operation; receive 1220 feedback (e.g., feedback 234) from the electromagnetic radiation energy receiver (e.g., electromagnetic radiation energy receiver 200) at a defined point (e.g., defined point 238) within the location sweeping operation; reinitiate 1222 the location sweeping operation at the defined point (e.g., defined point 238); and receive 1224 updated feedback (e.g., feedback 234) from the electromagnetic radiation energy receiver (e.g., electromagnetic radiation energy receiver 200) at an updated point (e.g., updated point 240) within the location sweeping operation.

Energy acquisition and delivery process 300 may initiate 1218 a location sweeping operation. The location sweeping operation may include a sweeping operation that initiates at an initial point (e.g., initial point 236) and spirals outwardly away from the initial point (e.g., initial point 236), as shown in FIG. 15. Energy acquisition and delivery process 300 may receive 1220 feedback (e.g., feedback 234) from the electromagnetic radiation energy receiver (e.g., electromagnetic radiation energy receiver 200) at a defined point (e.g., defined point 238) within the location sweeping operation.

As discussed above, this feedback (e.g., feedback 234) may be generated via one or more feedback devices (e.g., feedback devices 226) included within the electromagnetic radiation energy receiver (e.g., electromagnetic radiation energy receiver 200). As discussed above, the one or more feedback devices (e.g., feedback devices 226) included within the electromagnetic radiation energy receiver (e.g., electromagnetic radiation energy receiver 200) may include: a centrally-positioned feedback device within the electromagnetic radiation energy receiver (e.g., electromagnetic radiation energy receiver 200) and a plurality of peripherally-positioned feedback devices within the electromagnetic radiation energy receiver (e.g., electromagnetic radiation energy receiver 200).

As discussed above, at least one of the feedback devices (e.g., feedback devices 226) may be a retroreflector. As discussed above, a retroreflector is a specialized feedback device or surface that reflects incoming electromagnetic radiation (e.g., a portion of celestial energy beam 40) directly back toward its source (e.g., electromagnetic radiation energy source 38), regardless of the angle at which celestial energy beam 40 arrives. Unlike a standard mirror, which reflects light at an angle equal to the incident angle, a retroreflector returns celestial energy beam 40 along a near-exact path from which it came through geometric structures (e.g., corner cubes, cat's-eye lenses, or Bragg gratings).

As discussed above, the feedback devices (e.g., feedback devices 226) may include an RF component. Specifically, feedback devices 226 may include a plurality of opto-electrical sensors (e.g., photodiodes, photodetectors and/or photovoltaic cells). This plurality of sensors (e.g., feedback devices 226) may monitor the position of celestial energy beam 40, which is received on electromagnetic radiation energy receiver 200 from electromagnetic radiation energy source 38. This information concerning beam alignment (i.e., the manner in which celestial energy beam 40 is striking electromagnetic radiation energy receiver 200) may be provided to an RF transmitter (e.g., wireless communication system 332) that is included within/coupled to/available to electromagnetic radiation energy receiver 200 so that such information may be transmitted to the electromagnetic radiation energy source (e.g., electromagnetic radiation energy source 38). This information may then be used by electromagnetic radiation energy source 38 to reposition celestial energy beam 40 via beam aiming assembly 102 (if adjustment is needed).

As discussed above, this feedback (e.g., feedback 234) may be received on feedback receiving devices (e.g., feedback receiving devices 128) included within electromagnetic radiation energy source 38, wherein such feedback receiving devices (e.g., feedback receiving devices 128) may include but are not limited to one or more of: one or more photovoltaic cells; one or more photodiodes; one or more heat engines; and one or more rectenna arrays.

Energy acquisition and delivery process 300 may reinitiate 1222 the location sweeping operation at the defined point (e.g., defined point 238). Energy acquisition and delivery process 300 may receive 1224 updated feedback (e.g., feedback 234) from the electromagnetic radiation energy receiver (e.g., electromagnetic radiation energy receiver 200) at an updated point (e.g., updated point 240) within the location sweeping operation.

Energy acquisition and delivery process 300 may: repeatedly reinitiate 1226 the location sweeping operation until feedback (e.g., feedback 234) is received from the electromagnetic radiation energy receiver (e.g., electromagnetic radiation energy receiver 200) that identifies a point within the location sweeping operation that defines a peak return power, thus defining a location for the electromagnetic radiation energy receiver (e.g., electromagnetic radiation energy receiver 200).

As discussed above, assume that energy acquisition and delivery process 300 initiates the above-discussed location sweeping operation at initial point 236 by scanning of a 500 foot diameter circle. If feedback (e.g., feedback 234) is not received from electromagnetic radiation energy receiver 200 during this scanning operation, this lack of feedback indicates that electromagnetic radiation energy receiver 200 is not located within the 500 foot diameter circle and the location sweeping operation may spiral outwardly away from initial point 236.

As discussed above, energy acquisition and delivery process 300 may spiral outwardly away from initial point 236 and continue the location sweeping operation from a new point (e.g., point 236A) that is spaced radially away from initial point 236. Again, assume that energy acquisition and delivery process 300 begins repeatedly scanning 500 foot diameter circles while moving in the direction of arrow 850 to form a ring around the initial 500 foot diameter circle (that is positioned at initial point 236). During each of these 500 foot diameter scans, energy acquisition and delivery process 300 may monitor for feedback (e.g., feedback 234) in an attempt to locate the electromagnetic radiation energy receiver (e.g., electromagnetic radiation energy receiver 200). As discussed above, if feedback (e.g., feedback 234) is not received from electromagnetic radiation energy receiver 200 during any of these scanning operations, such a lack of feedback indicates that electromagnetic radiation energy receiver 200 is not positioned within the 500 foot diameter circle that is currently being scanned while moving along arrow 850.

As stated above, assume that no feedback is received while scanning each of the 500 foot diameter circles positioned along arrow 850, thus indicating that electromagnetic radiation energy receiver 200 is not located within any of these 500 foot diameter circles. Again, the location sweeping operation may spiral outwardly further away from initial point 236 and continue the location sweeping operation at a new point (e.g., point 238B) that is spaced even further radially away from initial point 236. For this example, assume that energy acquisition and delivery process 300 begins repeatedly scanning 500 foot diameter circles while moving in the direction of arrow 850A to form a second (and more distal) ring around the initial 500 foot diameter circle positioned at initial point 236.

During each of these 500 foot diameter scans along arrow 850A, energy acquisition and delivery process 300 may monitor for feedback (e.g., feedback 234) in an attempt to locate the electromagnetic radiation energy receiver (e.g., electromagnetic radiation energy receiver 200). Again, if feedback (e.g., feedback 234) is not received from electromagnetic radiation energy receiver 200 during a scanning operation, such a lack of feedback indicates that electromagnetic radiation energy receiver 200 is not positioned within the 500 foot diameter circles being scanned while moving in the direction of arrow 850A.

Continuing with the above-stated example, assume that upon scanning a specific 500 foot diameter circle (e.g., circle 852) along arrow 850A, feedback (e.g., feedback 234) is received from electromagnetic radiation energy receiver 200, thus indicating that electromagnetic radiation energy receiver 200 is positioned therein and identifying a defined point (e.g., defined point 238) within the location sweeping operation.

In response to such feedback being received, energy acquisition and delivery process 300 may reinitiate the location sweeping operation at the defined point (e.g., defined point 238). Specifically, this new location sweeping operation may be centered about (and spiral outwardly from) defined point 238. For this example, assume that energy acquisition and delivery process 300 begins repeatedly scanning 500 foot diameter circles while moving in the direction of arrow 854 to form a ring around circle 852 positioned at defined point 238. During each of these 500 foot diameter scans, energy acquisition and delivery process 300 may monitor for feedback (e.g., feedback 234) from the electromagnetic radiation energy receiver (e.g., electromagnetic radiation energy receiver 200). Assume that energy acquisition and delivery process 300 receives updated feedback (e.g., feedback 234) from the electromagnetic radiation energy receiver (e.g., electromagnetic radiation energy receiver 200) at an updated point (e.g., updated point 240) within the location sweeping operation, further refining the location of the electromagnetic radiation energy receiver (e.g., electromagnetic radiation energy receiver 200).

As discussed above, energy acquisition and delivery process 300 may repeatedly reinitiate the location sweeping operation until feedback (e.g., feedback 234) is received from the electromagnetic radiation energy receiver (e.g., electromagnetic radiation energy receiver 200) that identifies a point within the location sweeping operation that defines a peak return power. This point will define a location (e.g., receiver location 242) for the electromagnetic radiation energy receiver (e.g., electromagnetic radiation energy receiver 200). For example, each time new feedback (e.g., feedback 234) is received from electromagnetic radiation energy receiver 200, subsequent sweeping operations may be initiated by energy acquisition and delivery process 300 until the peak return power is identified, at which point the location of the electromagnetic radiation energy receiver (e.g., electromagnetic radiation energy receiver 200) will be deemed to be sufficiently defined. In the interest of brevity, assume that this location (e.g., receiver location 242) is updated point 240.

Once aligned 1210, energy acquisition and delivery process 300 may direct the celestial energy beam (e.g., celestial energy beam 40) toward the location (e.g., receiver location 242) of the electromagnetic radiation energy receiver (e.g., electromagnetic radiation energy receiver 200).

When increasing 1212 the energy density of the celestial energy beam (e.g., celestial energy beam 40), energy acquisition and delivery process 300 may: decrease 1228 the divergence of the celestial energy beam (e.g., celestial energy beam 40); and/or increase 1230 the power of the celestial energy beam (e.g., celestial energy beam 40).

As discussed above, the energy density of a celestial energy beam (e.g., celestial energy beam 40) refers to the amount of energy delivered per unit area of the celestial energy beam (e.g., celestial energy beam 40). To increase the energy density of celestial energy beam 40, two main strategies may be used: decreasing the divergence of celestial energy beam 40 and/or increasing the power of celestial energy beam 40. Decreasing Divergence: Decreasing 1228 the divergence of celestial energy beam 40 involves narrowing the beam as it travels through space. Such a decrease may be effectuated via the beam forming package 104 within electromagnetic radiation energy source 38. A less divergent beam focuses its energy within a smaller area, which increases the energy concentration at any given point. Accordingly and even if the total power of the beam remains the same, the energy density of the beam will be increased since the same amount of energy is focused within a smaller cross-sectional area.

Increasing Power: Increasing 1230 the power of celestial energy beam 40 involves increasing the total amount of energy being transmitted. Such a power increase may be effectuated by increasing the power supplied to energy beam source 100 within electromagnetic radiation energy source 38, thus resulting in a more powerful celestial energy beam 40. Since energy density is directly related to the beam's total power, a higher-power beam naturally results in more energy being concentrated in any given area of the celestial energy beam. For example, if the beam power is doubled, the energy density will also be doubled, assuming the beam size remains the same.

Energy acquisition and delivery process 300 may periodically perform 1232 a realignment procedure based upon alignment feedback (e.g., feedback 234) received from the electromagnetic radiation energy receiver (e.g., electromagnetic radiation energy receiver 200) to realign the celestial energy beam (e.g., celestial energy beam 40) with the electromagnetic radiation energy receiver (e.g., electromagnetic radiation energy receiver 200) to offset movement of the terrestrial vehicle (e.g., terrestrial vehicle 250).

### (17) Methodologies of Providing Power to Drones.

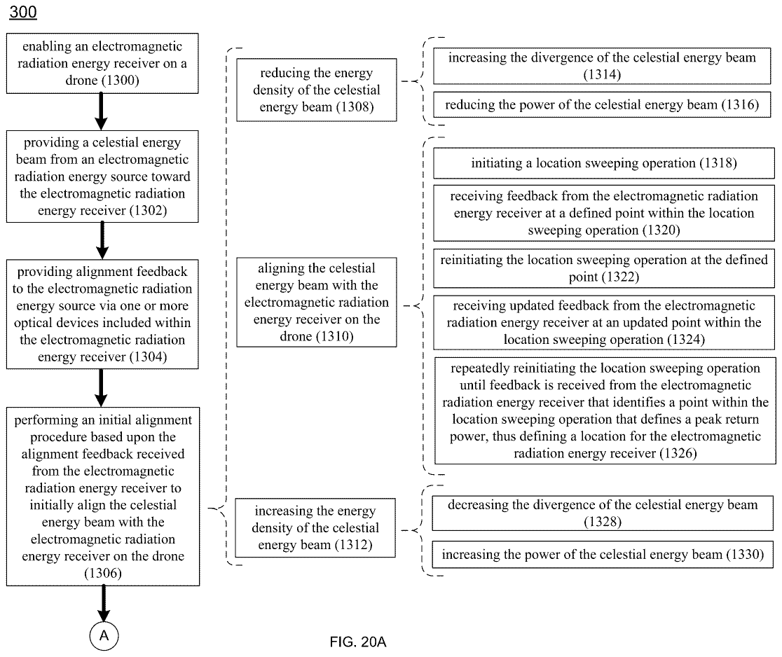

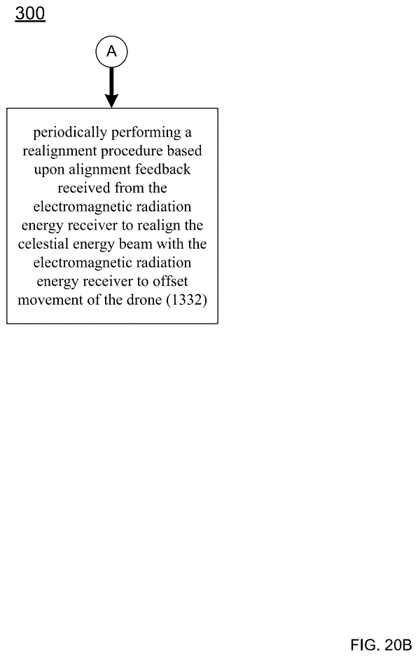

Referring also to FIGS. 20A-20B, the following discussion concerns the manner in which energy acquisition and delivery process 300 may provide electrical energy to a drone via a celestial energy beam (e.g., celestial energy beam 40) that is provided by an electromagnetic radiation energy source (e.g., electromagnetic radiation energy source 38) to an electromagnetic radiation energy receiver (e.g., electromagnetic radiation energy receiver 200) on the drone.

Energy acquisition and delivery process 300 may enable 1300 an electromagnetic radiation energy receiver (e.g., electromagnetic radiation energy receiver 200) on a drone (e.g., drone 252). Examples of drone (e.g., drone 252) may include but are not limited to: personal drones, commercial drones, and transportation drones.

For example and when enabling 1300 an electromagnetic radiation energy receiver (e.g., electromagnetic radiation energy receiver 200) on a drone (e.g., drone 252), energy acquisition and delivery process 300 may energize and/or provide power to the electromagnetic radiation energy receiver (e.g., electromagnetic radiation energy receiver 200). For example, it is foreseeable that the drone (e.g., drone 252) would usually be powered by internal energy sources (such as internal batteries). Accordingly and during most operations, electromagnetic radiation energy receiver (e.g., electromagnetic radiation energy receiver 200) on the drone (e.g., drone 252) may be powered down. Additionally/alternatively and when enabling 1300 an electromagnetic radiation energy receiver (e.g., electromagnetic radiation energy receiver 200) on the drone (e.g., drone 252), the electromagnetic radiation energy receiver (e.g., electromagnetic radiation energy receiver 200) may be configured to receive a particular type of celestial energy beam, such as laser or microwave.

Once enabled 1300, energy acquisition and delivery process 300 may provide 1302 a celestial energy beam (e.g., celestial energy beam 40) from an electromagnetic radiation energy source (e.g., electromagnetic radiation energy source 38) toward the electromagnetic radiation energy receiver (e.g., electromagnetic radiation energy receiver 200).

As discussed above and for providing 1302 a celestial energy beam (e.g., celestial energy beam 40), the electromagnetic radiation energy source (e.g., electromagnetic radiation energy source 38) may include: an energy beam source (e.g., energy beam source 100) for generating the celestial energy beam (e.g., celestial energy beam 40); a beam aiming assembly (e.g., beam aiming assembly 102) for steering the celestial energy beam (e.g., celestial energy beam 40) toward a target; and a beam forming package (e.g., beam forming package 104) for forming the celestial energy beam (e.g., celestial energy beam 40).

The energy beam source (e.g., energy beam source 100) for generating the celestial energy beam (e.g., celestial energy beam 40) may include one or more of: a visible-light laser beam source; an Infrared laser beam source; a short wavelength Infrared laser beam source, a mid-Infrared laser beam source; a near-Infrared laser beam source; and a microwave beam source.

The beam aiming assembly (e.g., beam aiming assembly 102) for steering the celestial energy beam (e.g., celestial energy beam 40) may include: a Gimbal mount assembly (e.g., Gimbal mount assembly 106) configured to direct the celestial energy beam (e.g., celestial energy beam 40) toward a target; a phased array assembly (e.g., phased array assembly 107) configured to direct the celestial energy beam (e.g., celestial energy beam 40) toward a target and/or a periscope assembly (e.g., periscope assembly 108) configured to direct the celestial energy beam (e.g., celestial energy beam 40) toward a target. A Gimbal mount assembly (e.g., Gimbal mount assembly 106), a phased array assembly (e.g., phased array assembly 107) and a periscope assembly (e.g., periscope assembly 108) can be effectively used in space-based energy systems to accurately direct a celestial energy beam (e.g., celestial energy beam 40), such as a laser or microwave beam, from a satellite (e.g., satellite 14) to a electromagnetic radiation energy receiver (e.g., electromagnetic radiation energy receiver 200).

The beam forming package (e.g., beam forming package 104) for forming the celestial energy beam (e.g., celestial energy beam 40) may include: collimating optics (e.g., collimating optics 110); and focusing optics (e.g., focusing optics 112). Collimating optics (e.g., collimating optics 110) are used to shape a celestial energy beam (e.g., celestial energy beam 40) so that its rays are parallel, resulting in a collimated beam i.e., one that doesn't spread out (diverge) significantly over distance. When a celestial energy beam (e.g., celestial energy beam 40) exits a source (e.g., energy beam source 100) like a diode, it typically diverges, meaning the beam spreads out as it travels.

Collimating optics (e.g., collimating optics 110), such as a lens or a lens system, are placed in the beam path to correct this divergence. By focusing the light emerging from a point-like or narrow source, collimating optics (e.g., collimating optics 110) create a beam with minimal angular spread. This is especially important for applications that require the beam to travel long distances (e.g., power transmission) or interact with precise optical components. In short, collimating optics (e.g., collimating optics 110) make a celestial energy beam (e.g., celestial energy beam 40) straighter and more focused over distance, improving its usability and efficiency in various optical systems.

Focusing optics (e.g., focusing optics 112) do the opposite of collimating optics (e.g., collimating optics 110), as they take a celestial energy beam (e.g., celestial energy beam 40) and converge it to a point or a small spot. This is usually achieved with lenses or curved mirrors that bend the incoming rays inward, concentrating the beam's energy into a smaller area. When a collimated or diverging celestial energy beam (e.g., celestial energy beam 40) passes through focusing optics (e.g., focusing optics 112), the optics manipulate the beam's path so that all rays come together at a focal point.

Energy acquisition and delivery process 300 may provide 1304 alignment feedback (e.g., feedback 234) to the electromagnetic radiation energy source (e.g., electromagnetic radiation energy source 38) via one or more feedback devices (e.g., feedback devices 226) included within the electromagnetic radiation energy receiver (e.g., electromagnetic radiation energy receiver 200).

As discussed above, the one or more feedback devices (e.g., feedback devices 226) included within the electromagnetic radiation energy receiver (e.g., electromagnetic radiation energy receiver 200) may include: a centrally-positioned feedback device within the electromagnetic radiation energy receiver (e.g., electromagnetic radiation energy receiver 200) and a plurality of peripherally-positioned feedback devices within the electromagnetic radiation energy receiver (e.g., electromagnetic radiation energy receiver 200).

At least one of the feedback devices (e.g., feedback devices 226) may be a retroreflector. As discussed above, a retroreflector is a specialized feedback device or surface that reflects incoming electromagnetic radiation (e.g., a portion of celestial energy beam 40) directly back toward its source (e.g., electromagnetic radiation energy source 38), regardless of the angle at which celestial energy beam 40 arrives. Unlike a standard mirror, which reflects light at an angle equal to the incident angle, a retroreflector returns celestial energy beam 40 along a near-exact path from which it came through geometric structures (e.g., corner cubes, cat's-eye lenses, or Bragg gratings).

As discussed above, the feedback devices (e.g., feedback devices 226) may include an RF component. Specifically, feedback devices 226 may include a plurality of opto-electrical sensors (e.g., photodiodes, photodetectors and/or photovoltaic cells). This plurality of sensors (e.g., feedback devices 226) may monitor the position of celestial energy beam 40, which is received on electromagnetic radiation energy receiver 200 from electromagnetic radiation energy source 38. This information concerning beam alignment (i.e., the manner in which celestial energy beam 40 is striking electromagnetic radiation energy receiver 200) may be provided to an RF transmitter (e.g., wireless communication system 332) that is included within/coupled to/available to electromagnetic radiation energy receiver 200 so that such information may be transmitted to the electromagnetic radiation energy source (e.g., electromagnetic radiation energy source 38). This information may then be used by electromagnetic radiation energy source 38 to reposition celestial energy beam 40 via beam aiming assembly 102 (if adjustment is needed).

Energy acquisition and delivery process 300 may perform 1306 an initial alignment procedure based upon the alignment feedback (e.g., feedback 234) received from the electromagnetic radiation energy receiver (e.g., electromagnetic radiation energy receiver 200) to initially align the celestial energy beam (e.g., celestial energy beam 40) with the electromagnetic radiation energy receiver (e.g., electromagnetic radiation energy receiver 200) on the drone (e.g., drone 252).

When performing 1306 an initial alignment procedure based upon the alignment feedback (e.g., feedback 234) received from the electromagnetic radiation energy receiver (e.g., electromagnetic radiation energy receiver 200) to initially align the celestial energy beam (e.g., celestial energy beam 40) with the electromagnetic radiation energy receiver (e.g., electromagnetic radiation energy receiver 200) on the drone (e.g., drone 252), energy acquisition and delivery process 300 may:
reduce 1308 the energy density of the celestial energy beam (e.g., celestial energy beam 40);
align 1310 the celestial energy beam (e.g., celestial energy beam 40) with the electromagnetic radiation energy receiver (e.g., electromagnetic radiation energy receiver 200) on the drone (e.g., drone 252); and
increase 1312 the energy density of the celestial energy beam (e.g., celestial energy beam 40).

When reducing 1308 the energy density of the celestial energy beam (e.g., celestial energy beam 40), energy acquisition and delivery process 300 may: increase 1314 the divergence of the celestial energy beam (e.g., celestial energy beam 40); and/or reduce 1316 the power of the celestial energy beam (e.g., celestial energy beam 40).

As discussed above, the energy density of a celestial energy beam (e.g., celestial energy beam 40) refers to the amount of energy delivered per unit area of the celestial energy beam (e.g., celestial energy beam 40). To reduce the energy density of celestial energy beam 40, two main strategies may be used: increasing the divergence of celestial energy beam 40 and/or reducing the power of celestial energy beam 40.

Increasing Divergency: Increasing 1314 the divergence of celestial energy beam 40 involves widening the beam as it travels through space. Such an increase may be effectuated via the beam forming package 104 within electromagnetic radiation energy source 38. A more divergent beam spreads its energy over a larger area, which decreases the energy concentration at any given point. Accordingly and even if the total power of the beam remains the same, the energy density of the beam will be reduced since the same amount of energy is distributed over a broader cross-sectional area.

Reducing Power: Reducing 1316 the power of celestial energy beam 40 involves lowering the total amount of energy being transmitted. Such a power reduction may be effectuated by decreasing the power supplied to energy beam source 100 within electromagnetic radiation energy source 38, thus resulting in a less powerful celestial energy beam 40. Since energy density is directly related to the beam's total power, a lower-power beam naturally results in less energy being concentrated in any given area of the celestial energy beam. For example, if the beam power is cut in half, the energy density will also be cut in half, assuming the beam size remains the same.

In practical terms, reducing energy density by these methods can improve safety helping to prevent damage to equipment, minimizing risk to nearby humans, aircraft or animals, and easing the thermal and structural load on receiving systems. It also allows for more manageable interception or redirection of the beam if necessary.

When aligning 1310 the celestial energy beam (e.g., celestial energy beam 40) with the electromagnetic radiation energy receiver (e.g., electromagnetic radiation energy receiver 200) on the drone (e.g., drone 252), energy acquisition and delivery process 300 may: initiate 1318 a location sweeping operation; receive 1320 feedback (e.g., feedback 234) from the electromagnetic radiation energy receiver (e.g., electromagnetic radiation energy receiver 200) at a defined point (e.g., defined point 238) within the location sweeping operation; reinitiate 1322 the location sweeping operation at the defined point (e.g., defined point 238); and receive 1324 updated feedback (e.g., feedback 234) from the electromagnetic radiation energy receiver (e.g., electromagnetic radiation energy receiver 200) at an updated point (e.g., updated point 240) within the location sweeping operation.

Energy acquisition and delivery process 300 may initiate 1318 a location sweeping operation. The location sweeping operation may include a sweeping operation that initiates at an initial point (e.g., initial point 236) and spirals outwardly away from the initial point (e.g., initial point 236), as shown in FIG. 15. Energy acquisition and delivery process 300 may receive 1320 feedback (e.g., feedback 234) from the electromagnetic radiation energy receiver (e.g., electromagnetic radiation energy receiver 200) at a defined point (e.g., defined point 238) within the location sweeping operation.

As discussed above, this feedback (e.g., feedback 234) may be generated via one or more feedback devices (e.g., feedback devices 226) included within the electromagnetic radiation energy receiver (e.g., electromagnetic radiation energy receiver 200). As discussed above, the one or more feedback devices (e.g., feedback devices 226) included within the electromagnetic radiation energy receiver (e.g., electromagnetic radiation energy receiver 200) may include: a centrally-positioned feedback device within the electromagnetic radiation energy receiver (e.g., electromagnetic radiation energy receiver 200) and a plurality of peripherally-positioned feedback devices within the electromagnetic radiation energy receiver (e.g., electromagnetic radiation energy receiver 200).

As discussed above, at least one of the feedback devices (e.g., feedback devices 226) may be a retroreflector. As discussed above, a retroreflector is a specialized feedback device or surface that reflects incoming electromagnetic radiation (e.g., a portion of celestial energy beam 40) directly back toward its source (e.g., electromagnetic radiation energy source 38), regardless of the angle at which celestial energy beam 40 arrives. Unlike a standard mirror, which reflects light at an angle equal to the incident angle, a retroreflector returns celestial energy beam 40 along a near-exact path from which it came through geometric structures (e.g., corner cubes, cat's-eye lenses, or Bragg gratings).

As discussed above, the feedback devices (e.g., feedback devices 226) may include an RF component. Specifically, feedback devices 226 may include a plurality of opto-electrical sensors (e.g., photodiodes, photodetectors and/or photovoltaic cells). This plurality of sensors (e.g., feedback devices 226) may monitor the position of celestial energy beam 40, which is received on electromagnetic radiation energy receiver 200 from electromagnetic radiation energy source 38. This information concerning beam alignment (i.e., the manner in which celestial energy beam 40 is striking electromagnetic radiation energy receiver 200) may be provided to an RF transmitter (e.g., wireless communication system 332) that is included within/coupled to/available to electromagnetic radiation energy receiver 200 so that such information may be transmitted to the electromagnetic radiation energy source (e.g., electromagnetic radiation energy source 38). This information may then be used by electromagnetic radiation energy source 38 to reposition celestial energy beam 40 via beam aiming assembly 102 (if adjustment is needed).

As discussed above, this feedback (e.g., feedback 234) may be received on feedback receiving devices (e.g., feedback receiving devices 128) included within electromagnetic radiation energy source 38, wherein such feedback receiving devices (e.g., feedback receiving devices 128) may include but are not limited to one or more of: one or more photovoltaic cells; one or more photodiodes; one or more heat engines; and one or more rectenna arrays.

Energy acquisition and delivery process 300 may reinitiate 1322 the location sweeping operation at the defined point (e.g., defined point 238). Energy acquisition and delivery process 300 may receive 1324 updated feedback (e.g., feedback 234) from the electromagnetic radiation energy receiver (e.g., electromagnetic radiation energy receiver 200) at an updated point (e.g., updated point 240) within the location sweeping operation.

Energy acquisition and delivery process 300 may: repeatedly reinitiate 1326 the location sweeping operation until feedback (e.g., feedback 234) is received from the electromagnetic radiation energy receiver (e.g., electromagnetic radiation energy receiver 200) that identifies a point within the location sweeping operation that defines a peak return power, thus defining a location for the electromagnetic radiation energy receiver (e.g., electromagnetic radiation energy receiver 200).

As discussed above, assume that energy acquisition and delivery process 300 initiates the above-discussed location sweeping operation at initial point 236 by scanning of a 500 foot diameter circle. If feedback (e.g., feedback 234) is not received from electromagnetic radiation energy receiver 200 during this scanning operation, this lack of feedback indicates that electromagnetic radiation energy receiver 200 is not located within the 500 foot diameter circle and the location sweeping operation may spiral outwardly away from initial point 236.

As discussed above, energy acquisition and delivery process 300 may spiral outwardly away from initial point 236 and continue the location sweeping operation from a new point (e.g., point 236A) that is spaced radially away from initial point 236. Again, assume that energy acquisition and delivery process 300 begins repeatedly scanning 500 foot diameter circles while moving in the direction of arrow 850 to form a ring around the initial 500 foot diameter circle (that is positioned at initial point 236). During each of these 500 foot diameter scans, energy acquisition and delivery process 300 may monitor for feedback (e.g., feedback 234) in an attempt to locate the electromagnetic radiation energy receiver (e.g., electromagnetic radiation energy receiver 200). As discussed above, if feedback (e.g., feedback 234) is not received from electromagnetic radiation energy receiver 200 during any of these scanning operations, such a lack of feedback indicates that electromagnetic radiation energy receiver 200 is not positioned within the 500 foot diameter circle that is currently being scanned while moving along arrow 850.

As stated above, assume that no feedback is received while scanning each of the 500 foot diameter circles positioned along arrow 850, thus indicating that electromagnetic radiation energy receiver 200 is not located within any of these 500 foot diameter circles. Again, the location sweeping operation may spiral outwardly further away from initial point 236 and continue the location sweeping operation at a new point (e.g., point 238B) that is spaced even further radially away from initial point 236. For this example, assume that energy acquisition and delivery process 300 begins repeatedly scanning 500 foot diameter circles while moving in the direction of arrow 850A to form a second (and more distal) ring around the initial 500 foot diameter circle positioned at initial point 236.

During each of these 500 foot diameter scans along arrow 850A, energy acquisition and delivery process 300 may monitor for feedback (e.g., feedback 234) in an attempt to locate the electromagnetic radiation energy receiver (e.g., electromagnetic radiation energy receiver 200). Again, if feedback (e.g., feedback 234) is not received from electromagnetic radiation energy receiver 200 during a scanning operation, such a lack of feedback indicates that electromagnetic radiation energy receiver 200 is not positioned within the 500 foot diameter circles being scanned while moving in the direction of arrow 850A.

Continuing with the above-stated example, assume that upon scanning a specific 500 foot diameter circle (e.g., circle 852) along arrow 850A, feedback (e.g., feedback 234) is received from electromagnetic radiation energy receiver 200, thus indicating that electromagnetic radiation energy receiver 200 is positioned therein and identifying a defined point (e.g., defined point 238) within the location sweeping operation.

In response to such feedback being received, energy acquisition and delivery process 300 may reinitiate the location sweeping operation at the defined point (e.g., defined point 238). Specifically, this new location sweeping operation may be centered about (and spiral outwardly from) defined point 238. For this example, assume that energy acquisition and delivery process 300 begins repeatedly scanning 500 foot diameter circles while moving in the direction of arrow 854 to form a ring around circle 852 positioned at defined point 238. During each of these 500 foot diameter scans, energy acquisition and delivery process 300 may monitor for feedback (e.g., feedback 234) from the electromagnetic radiation energy receiver (e.g., electromagnetic radiation energy receiver 200). Assume that energy acquisition and delivery process 300 receives updated feedback (e.g., feedback 234) from the electromagnetic radiation energy receiver (e.g., electromagnetic radiation energy receiver 200) at an updated point (e.g., updated point 240) within the location sweeping operation, further refining the location of the electromagnetic radiation energy receiver (e.g., electromagnetic radiation energy receiver 200).

As discussed above, energy acquisition and delivery process 300 may repeatedly reinitiate the location sweeping operation until feedback (e.g., feedback 234) is received from the electromagnetic radiation energy receiver (e.g., electromagnetic radiation energy receiver 200) that identifies a point within the location sweeping operation that defines a peak return power. This point will define a location (e.g., receiver location 242) for the electromagnetic radiation energy receiver (e.g., electromagnetic radiation energy receiver 200). For example, each time new feedback (e.g., feedback 234) is received from electromagnetic radiation energy receiver 200, subsequent sweeping operations may be initiated by energy acquisition and delivery process 300 until the peak return power is identified, at which point the location of the electromagnetic radiation energy receiver (e.g., electromagnetic radiation energy receiver 200) will be deemed to be sufficiently defined. In the interest of brevity, assume that this location (e.g., receiver location 242) is updated point 240.

Once aligned 1310, energy acquisition and delivery process 300 may direct the celestial energy beam (e.g., celestial energy beam 40) toward the location (e.g., receiver location 242) of the electromagnetic radiation energy receiver (e.g., electromagnetic radiation energy receiver 200).

When increasing 1312 the energy density of the celestial energy beam (e.g., celestial energy beam 40), energy acquisition and delivery process 300 may: decrease 1328 the divergence of the celestial energy beam (e.g., celestial energy beam 40); and/or increase 1330 the power of the celestial energy beam (e.g., celestial energy beam 40).

As discussed above, the energy density of a celestial energy beam (e.g., celestial energy beam 40) refers to the amount of energy delivered per unit area of the celestial energy beam (e.g., celestial energy beam 40). To increase the energy density of celestial energy beam 40, two main strategies may be used: decreasing the divergence of celestial energy beam 40 and/or increasing the power of celestial energy beam 40.

Decreasing Divergence: Decreasing 1328 the divergence of celestial energy beam 40 involves narrowing the beam as it travels through space. Such a decrease may be effectuated via the beam forming package 104 within electromagnetic radiation energy source 38. A less divergent beam focuses its energy within a smaller area, which increases the energy concentration at any given point. Accordingly and even if the total power of the beam remains the same, the energy density of the beam will be increased since the same amount of energy is focused within a smaller cross-sectional area.

Increasing Power: Increasing 1330 the power of celestial energy beam 40 involves increasing the total amount of energy being transmitted. Such a power increase may be effectuated by increasing the power supplied to energy beam source 100 within electromagnetic radiation energy source 38, thus resulting in a more powerful celestial energy beam 40. Since energy density is directly related to the beam's total power, a higher-power beam naturally results in more energy being concentrated in any given area of the celestial energy beam. For example, if the beam power is doubled, the energy density will also be doubled, assuming the beam size remains the same.

Energy acquisition and delivery process 300 may periodically perform 1332 a realignment procedure based upon alignment feedback (e.g., feedback 234) received from the electromagnetic radiation energy receiver (e.g., electromagnetic radiation energy receiver 200) to realign the celestial energy beam (e.g., celestial energy beam 40) with the electromagnetic radiation energy receiver (e.g., electromagnetic radiation energy receiver 200) to offset movement of the drone (e.g., drone 252).

### (18) Methodologies for Providing Power on an Emergency Basis to an Object in Need.

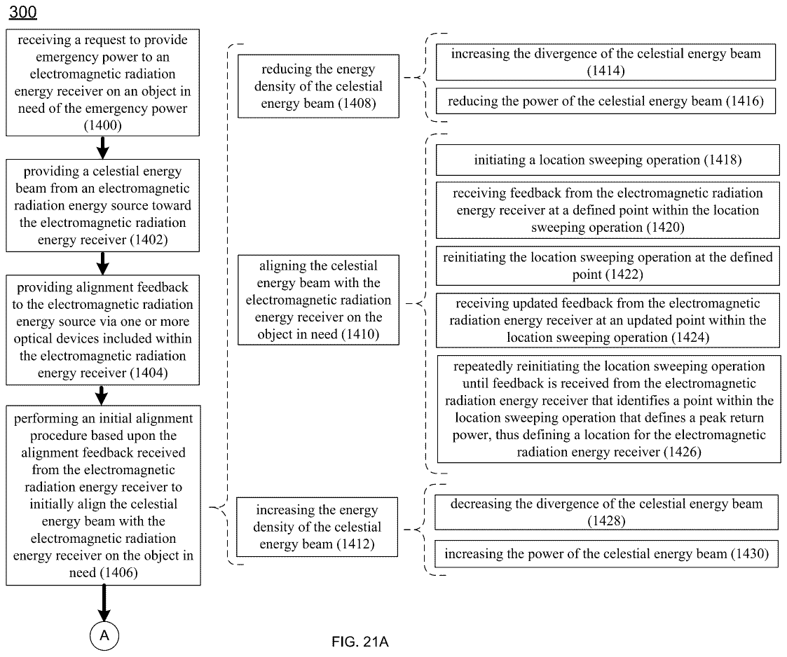

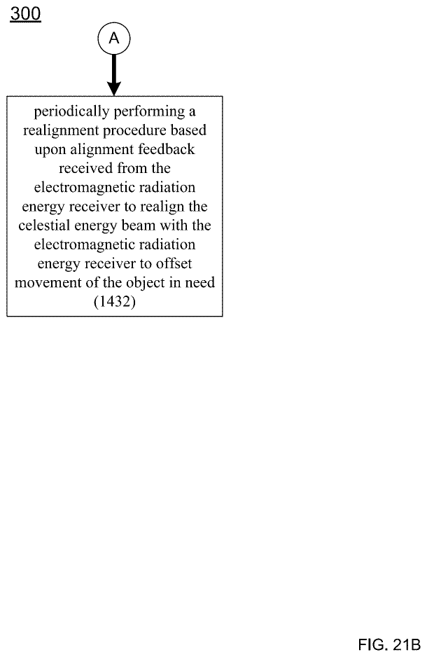

Referring also to FIGS. 21A-21B, the following discussion concerns the manner in which energy acquisition and delivery process 300 may provide electrical energy to an object in need via a celestial energy beam (e.g., celestial energy beam 40) that is provided by an electromagnetic radiation energy source (e.g., electromagnetic radiation energy source 38) to an electromagnetic radiation energy receiver (e.g., electromagnetic radiation energy receiver 200) on the object in need.

Energy acquisition and delivery process 300 may receive 1400 a request (e.g., request 254) to provide emergency power to an electromagnetic radiation energy receiver (e.g., electromagnetic radiation energy receiver 200) on an object in need (e.g., object in need 256) of the emergency power. Examples of such an object in need (e.g., object in need 256) of the emergency power may include but are not limited to: a ship (e.g., water going vessel 248) stranded at sea, a portion of a power distribution grid (e.g., power distribution grid 210) that is without power due to a natural disaster, a research facility (e.g., a research facility in Antarctica) that ran out of fuel, and a space station that is without power due to a solar panel failure.

Once request (e.g., request 254) is received 1400, energy acquisition and delivery process 300 may provide 1402 a celestial energy beam (e.g., celestial energy beam 40) from an electromagnetic radiation energy source (e.g., electromagnetic radiation energy source 38) toward the electromagnetic radiation energy receiver (e.g., electromagnetic radiation energy receiver 200).

As discussed above and for providing 1402 a celestial energy beam (e.g., celestial energy beam 40), the electromagnetic radiation energy source (e.g., electromagnetic radiation energy source 38) may include: an energy beam source (e.g., energy beam source 100) for generating the celestial energy beam (e.g., celestial energy beam 40); a beam aiming assembly (e.g., beam aiming assembly 102) for steering the celestial energy beam (e.g., celestial energy beam 40) toward a target; and a beam forming package (e.g., beam forming package 104) for forming the celestial energy beam (e.g., celestial energy beam 40).

The energy beam source (e.g., energy beam source 100) for generating the celestial energy beam (e.g., celestial energy beam 40) may include one or more of: a visible-light laser beam source; an Infrared laser beam source; a short wavelength Infrared laser beam source, a mid-Infrared laser beam source; a near-Infrared laser beam source; and a microwave beam source.

The beam aiming assembly (e.g., beam aiming assembly 102) for steering the celestial energy beam (e.g., celestial energy beam 40) may include: a Gimbal mount assembly (e.g., Gimbal mount assembly 106) configured to direct the celestial energy beam (e.g., celestial energy beam 40) toward a target; a phased array assembly (e.g., phased array assembly 107) configured to direct the celestial energy beam (e.g., celestial energy beam 40) toward a target and/or a periscope assembly (e.g., periscope assembly 108) configured to direct the celestial energy beam (e.g., celestial energy beam 40) toward a target. A Gimbal mount assembly (e.g., Gimbal mount assembly 106), a phased array assembly (e.g., phased array assembly 107) and a periscope assembly (e.g., periscope assembly 108) can be effectively used in space-based energy systems to accurately direct a celestial energy beam (e.g., celestial energy beam 40), such as a laser or microwave beam, from a satellite (e.g., satellite 14) to a electromagnetic radiation energy receiver (e.g., electromagnetic radiation energy receiver 200).

The beam forming package (e.g., beam forming package 104) for forming the celestial energy beam (e.g., celestial energy beam 40) may include: collimating optics (e.g., collimating optics 110); and focusing optics (e.g., focusing optics 112). Collimating optics (e.g., collimating optics 110) are used to shape a celestial energy beam (e.g., celestial energy beam 40) so that its rays are parallel, resulting in a collimated beam i.e., one that doesn't spread out (diverge) significantly over distance. When a celestial energy beam (e.g., celestial energy beam 40) exits a source (e.g., energy beam source 100) like a diode, it typically diverges, meaning the beam spreads out as it travels.

Collimating optics (e.g., collimating optics 110), such as a lens or a lens system, are placed in the beam path to correct this divergence. By focusing the light emerging from a point-like or narrow source, collimating optics (e.g., collimating optics 110) create a beam with minimal angular spread. This is especially important for applications that require the beam to travel long distances (e.g., power transmission) or interact with precise optical components. In short, collimating optics (e.g., collimating optics 110) make a celestial energy beam (e.g., celestial energy beam 40) straighter and more focused over distance, improving its usability and efficiency in various optical systems.

Focusing optics (e.g., focusing optics 112) do the opposite of collimating optics (e.g., collimating optics 110), as they take a celestial energy beam (e.g., celestial energy beam 40) and converge it to a point or a small spot. This is usually achieved with lenses or curved mirrors that bend the incoming rays inward, concentrating the beam's energy into a smaller area. When a collimated or diverging celestial energy beam (e.g., celestial energy beam 40) passes through focusing optics (e.g., focusing optics 112), the optics manipulate the beam's path so that all rays come together at a focal point.

Energy acquisition and delivery process 300 may provide 1404 alignment feedback (e.g., feedback 234) to the electromagnetic radiation energy source (e.g., electromagnetic radiation energy source 38) via one or more feedback devices (e.g., feedback devices 226) included within the electromagnetic radiation energy receiver (e.g., electromagnetic radiation energy receiver 200).

As discussed above, the one or more feedback devices (e.g., feedback devices 226) included within the electromagnetic radiation energy receiver (e.g., electromagnetic radiation energy receiver 200) may include: a centrally-positioned feedback device within the electromagnetic radiation energy receiver (e.g., electromagnetic radiation energy receiver 200) and a plurality of peripherally-positioned feedback devices within the electromagnetic radiation energy receiver (e.g., electromagnetic radiation energy receiver 200).

At least one of the feedback devices (e.g., feedback devices 226) may be a retroreflector. As discussed above, a retroreflector is a specialized feedback device or surface that reflects incoming electromagnetic radiation (e.g., a portion of celestial energy beam 40) directly back toward its source (e.g., electromagnetic radiation energy source 38), regardless of the angle at which celestial energy beam 40 arrives. Unlike a standard mirror, which reflects light at an angle equal to the incident angle, a retroreflector returns celestial energy beam 40 along a near-exact path from which it came through geometric structures (e.g., corner cubes, cat's-eye lenses, or Bragg gratings).

As discussed above, the feedback devices (e.g., feedback devices 226) may include an RF component. Specifically, feedback devices 226 may include a plurality of opto-electrical sensors (e.g., photodiodes, photodetectors and/or photovoltaic cells). This plurality of sensors (e.g., feedback devices 226) may monitor the position of celestial energy beam 40, which is received on electromagnetic radiation energy receiver 200 from electromagnetic radiation energy source 38. This information concerning beam alignment (i.e., the manner in which celestial energy beam 40 is striking electromagnetic radiation energy receiver 200) may be provided to an RF transmitter (e.g., wireless communication system 332) that is included within/coupled to/available to electromagnetic radiation energy receiver 200 so that such information may be transmitted to the electromagnetic radiation energy source (e.g., electromagnetic radiation energy source 38). This information may then be used by electromagnetic radiation energy source 38 to reposition celestial energy beam 40 via beam aiming assembly 102 (if adjustment is needed).

Energy acquisition and delivery process 300 may perform 1406 an initial alignment procedure based upon the alignment feedback (e.g., feedback 234) received from the electromagnetic radiation energy receiver (e.g., electromagnetic radiation energy receiver 200) to initially align the celestial energy beam (e.g., celestial energy beam 40) with the electromagnetic radiation energy receiver (e.g., electromagnetic radiation energy receiver 200) on the object in need (e.g., object in need 256).

When performing 1406 an initial alignment procedure based upon the alignment feedback (e.g., feedback 234) received from the electromagnetic radiation energy receiver (e.g., electromagnetic radiation energy receiver 200) to initially align the celestial energy beam (e.g., celestial energy beam 40) with the electromagnetic radiation energy receiver (e.g., electromagnetic radiation energy receiver 200) on the object in need (e.g., object in need 256), energy acquisition and delivery process 300 may:
reduce 1408 the energy density of the celestial energy beam (e.g., celestial energy beam 40);
align 1410 the celestial energy beam (e.g., celestial energy beam 40) with the electromagnetic radiation energy receiver (e.g., electromagnetic radiation energy receiver 200) on the object in need (e.g., object in need 256); and
increase 1412 the energy density of the celestial energy beam (e.g., celestial energy beam 40).

When reducing 1408 the energy density of the celestial energy beam (e.g., celestial energy beam 40), energy acquisition and delivery process 300 may: increase 1414 the divergence of the celestial energy beam (e.g., celestial energy beam 40); and/or reduce 1416 the power of the celestial energy beam (e.g., celestial energy beam 40).

As discussed above, the energy density of a celestial energy beam (e.g., celestial energy beam 40) refers to the amount of energy delivered per unit area of the celestial energy beam (e.g., celestial energy beam 40). To reduce the energy density of celestial energy beam 40, two main strategies may be used: increasing the divergence of celestial energy beam 40 and/or reducing the power of celestial energy beam 40.

Increasing Divergency: Increasing 1414 the divergence of celestial energy beam 40 involves widening the beam as it travels through space. Such an increase may be effectuated via the beam forming package 104 within electromagnetic radiation energy source 38. A more divergent beam spreads its energy over a larger area, which decreases the energy concentration at any given point. Accordingly and even if the total power of the beam remains the same, the energy density of the beam will be reduced since the same amount of energy is distributed over a broader cross-sectional area.

Reducing Power: Reducing 1416 the power of celestial energy beam 40 involves lowering the total amount of energy being transmitted. Such a power reduction may be effectuated by decreasing the power supplied to energy beam source 100 within electromagnetic radiation energy source 38, thus resulting in a less powerful celestial energy beam 40. Since energy density is directly related to the beam's total power, a lower-power beam naturally results in less energy being concentrated in any given area of the celestial energy beam. For example, if the beam power is cut in half, the energy density will also be cut in half, assuming the beam size remains the same.

In practical terms, reducing energy density by these methods can improve safety helping to prevent damage to equipment, minimizing risk to nearby humans, aircraft or animals, and easing the thermal and structural load on receiving systems. It also allows for more manageable interception or redirection of the beam if necessary.

When aligning 1410 the celestial energy beam (e.g., celestial energy beam 40) with the electromagnetic radiation energy receiver (e.g., electromagnetic radiation energy receiver 200) on the object in need (e.g., object in need 256), energy acquisition and delivery process 300 may: initiate 1418 a location sweeping operation; receive 1420 feedback (e.g., feedback 234) from the electromagnetic radiation energy receiver (e.g., electromagnetic radiation energy receiver 200) at a defined point (e.g., defined point 238) within the location sweeping operation; reinitiate 1422 the location sweeping operation at the defined point (e.g., defined point 238); and receive 1424 updated feedback (e.g., feedback 234) from the electromagnetic radiation energy receiver (e.g., electromagnetic radiation energy receiver 200) at an updated point (e.g., updated point 240) within the location sweeping operation.

Energy acquisition and delivery process 300 may initiate 1418 a location sweeping operation. The location sweeping operation may include a sweeping operation that initiates at an initial point (e.g., initial point 236) and spirals outwardly away from the initial point (e.g., initial point 236), as shown in FIG. 15. Energy acquisition and delivery process 300 may receive 1420 feedback (e.g., feedback 234) from the electromagnetic radiation energy receiver (e.g., electromagnetic radiation energy receiver 200) at a defined point (e.g., defined point 238) within the location sweeping operation.

As discussed above, this feedback (e.g., feedback 234) may be generated via one or more feedback devices (e.g., feedback devices 226) included within the electromagnetic radiation energy receiver (e.g., electromagnetic radiation energy receiver 200). As discussed above, the one or more feedback devices (e.g., feedback devices 226) included within the electromagnetic radiation energy receiver (e.g., electromagnetic radiation energy receiver 200) may include: a centrally-positioned feedback device within the electromagnetic radiation energy receiver (e.g., electromagnetic radiation energy receiver 200) and a plurality of peripherally-positioned feedback devices within the electromagnetic radiation energy receiver (e.g., electromagnetic radiation energy receiver 200).

As discussed above, at least one of the feedback devices (e.g., feedback devices 226) may be a retroreflector. As discussed above, a retroreflector is a specialized feedback device or surface that reflects incoming electromagnetic radiation (e.g., a portion of celestial energy beam 40) directly back toward its source (e.g., electromagnetic radiation energy source 38), regardless of the angle at which celestial energy beam 40 arrives. Unlike a standard mirror, which reflects light at an angle equal to the incident angle, a retroreflector returns celestial energy beam 40 along a near-exact path from which it came through geometric structures (e.g., corner cubes, cat's-eye lenses, or Bragg gratings).

As discussed above, the feedback devices (e.g., feedback devices 226) may include an RF component. Specifically, feedback devices 226 may include a plurality of opto-electrical sensors (e.g., photodiodes, photodetectors and/or photovoltaic cells). This plurality of sensors (e.g., feedback devices 226) may monitor the position of celestial energy beam 40, which is received on electromagnetic radiation energy receiver 200 from electromagnetic radiation energy source 38. This information concerning beam alignment (i.e., the manner in which celestial energy beam 40 is striking electromagnetic radiation energy receiver 200) may be provided to an RF transmitter (e.g., wireless communication system 332) that is included within/coupled to/available to electromagnetic radiation energy receiver 200 so that such information may be transmitted to the electromagnetic radiation energy source (e.g., electromagnetic radiation energy source 38). This information may then be used by electromagnetic radiation energy source 38 to reposition celestial energy beam 40 via beam aiming assembly 102 (if adjustment is needed).

As discussed above, this feedback (e.g., feedback 234) may be received on feedback receiving devices (e.g., feedback receiving devices 128) included within electromagnetic radiation energy source 38, wherein such feedback receiving devices (e.g., feedback receiving devices 128) may include but are not limited to one or more of: one or more photovoltaic cells; one or more photodiodes; one or more heat engines; and one or more rectenna arrays.

Energy acquisition and delivery process 300 may reinitiate 1422 the location sweeping operation at the defined point (e.g., defined point 238). Energy acquisition and delivery process 300 may receive 1424 updated feedback (e.g., feedback 234) from the electromagnetic radiation energy receiver (e.g., electromagnetic radiation energy receiver 200) at an updated point (e.g., updated point 240) within the location sweeping operation.

Energy acquisition and delivery process 300 may: repeatedly reinitiate 1426 the location sweeping operation until feedback (e.g., feedback 234) is received from the electromagnetic radiation energy receiver (e.g., electromagnetic radiation energy receiver 200) that identifies a point within the location sweeping operation that defines a peak return power, thus defining a location for the electromagnetic radiation energy receiver (e.g., electromagnetic radiation energy receiver 200).

As discussed above, assume that energy acquisition and delivery process 300 initiates the above-discussed location sweeping operation at initial point 236 by scanning of a 500 foot diameter circle. If feedback (e.g., feedback 234) is not received from electromagnetic radiation energy receiver 200 during this scanning operation, this lack of feedback indicates that electromagnetic radiation energy receiver 200 is not located within the 500 foot diameter circle and the location sweeping operation may spiral outwardly away from initial point 236.

As discussed above, energy acquisition and delivery process 300 may spiral outwardly away from initial point 236 and continue the location sweeping operation from a new point (e.g., point 236A) that is spaced radially away from initial point 236. Again, assume that energy acquisition and delivery process 300 begins repeatedly scanning 500 foot diameter circles while moving in the direction of arrow 850 to form a ring around the initial 500 foot diameter circle (that is positioned at initial point 236). During each of these 500 foot diameter scans, energy acquisition and delivery process 300 may monitor for feedback (e.g., feedback 234) in an attempt to locate the electromagnetic radiation energy receiver (e.g., electromagnetic radiation energy receiver 200). As discussed above, if feedback (e.g., feedback 234) is not received from electromagnetic radiation energy receiver 200 during any of these scanning operations, such a lack of feedback indicates that electromagnetic radiation energy receiver 200 is not positioned within the 500 foot diameter circle that is currently being scanned while moving along arrow 850.

As stated above, assume that no feedback is received while scanning each of the 500 foot diameter circles positioned along arrow 850, thus indicating that electromagnetic radiation energy receiver 200 is not located within any of these 500 foot diameter circles. Again, the location sweeping operation may spiral outwardly further away from initial point 236 and continue the location sweeping operation at a new point (e.g., point 238B) that is spaced even further radially away from initial point 236. For this example, assume that energy acquisition and delivery process 300 begins repeatedly scanning 500 foot diameter circles while moving in the direction of arrow 850A to form a second (and more distal) ring around the initial 500 foot diameter circle positioned at initial point 236.

During each of these 500 foot diameter scans along arrow 850A, energy acquisition and delivery process 300 may monitor for feedback (e.g., feedback 234) in an attempt to locate the electromagnetic radiation energy receiver (e.g., electromagnetic radiation energy receiver 200). Again, if feedback (e.g., feedback 234) is not received from electromagnetic radiation energy receiver 200 during a scanning operation, such a lack of feedback indicates that electromagnetic radiation energy receiver 200 is not positioned within the 500 foot diameter circles being scanned while moving in the direction of arrow 850A.

Continuing with the above-stated example, assume that upon scanning a specific 500 foot diameter circle (e.g., circle 852) along arrow 850A, feedback (e.g., feedback 234) is received from electromagnetic radiation energy receiver 200, thus indicating that electromagnetic radiation energy receiver 200 is positioned therein and identifying a defined point (e.g., defined point 238) within the location sweeping operation.

In response to such feedback being received, energy acquisition and delivery process 300 may reinitiate the location sweeping operation at the defined point (e.g., defined point 238). Specifically, this new location sweeping operation may be centered about (and spiral outwardly from) defined point 238. For this example, assume that energy acquisition and delivery process 300 begins repeatedly scanning 500 foot diameter circles while moving in the direction of arrow 854 to form a ring around circle 852 positioned at defined point 238. During each of these 500 foot diameter scans, energy acquisition and delivery process 300 may monitor for feedback (e.g., feedback 234) from the electromagnetic radiation energy receiver (e.g., electromagnetic radiation energy receiver 200). Assume that energy acquisition and delivery process 300 receives updated feedback (e.g., feedback 234) from the electromagnetic radiation energy receiver (e.g., electromagnetic radiation energy receiver 200) at an updated point (e.g., updated point 240) within the location sweeping operation, further refining the location of the electromagnetic radiation energy receiver (e.g., electromagnetic radiation energy receiver 200).

As discussed above, energy acquisition and delivery process 300 may repeatedly reinitiate the location sweeping operation until feedback (e.g., feedback 234) is received from the electromagnetic radiation energy receiver (e.g., electromagnetic radiation energy receiver 200) that identifies a point within the location sweeping operation that defines a peak return power. This point will define a location (e.g., receiver location 242) for the electromagnetic radiation energy receiver (e.g., electromagnetic radiation energy receiver 200). For example, each time new feedback (e.g., feedback 234) is received from electromagnetic radiation energy receiver 200, subsequent sweeping operations may be initiated by energy acquisition and delivery process 300 until the peak return power is identified, at which point the location of the electromagnetic radiation energy receiver (e.g., electromagnetic radiation energy receiver 200) will be deemed to be sufficiently defined. In the interest of brevity, assume that this location (e.g., receiver location 242) is updated point 240.

Once aligned 1410, energy acquisition and delivery process 300 may direct the celestial energy beam (e.g., celestial energy beam 40) toward the location (e.g., receiver location 242) of the electromagnetic radiation energy receiver (e.g., electromagnetic radiation energy receiver 200).

When increasing 1412 the energy density of the celestial energy beam (e.g., celestial energy beam 40), energy acquisition and delivery process 300 may: decrease 1428 the divergence of the celestial energy beam (e.g., celestial energy beam 40); and/or increase 1430 the power of the celestial energy beam (e.g., celestial energy beam 40).

As discussed above, the energy density of a celestial energy beam (e.g., celestial energy beam 40) refers to the amount of energy delivered per unit area of the celestial energy beam (e.g., celestial energy beam 40). To increase the energy density of celestial energy beam 40, two main strategies may be used: decreasing the divergence of celestial energy beam 40 and/or increasing the power of celestial energy beam 40.

Decreasing Divergence: Decreasing 1428 the divergence of celestial energy beam 40 involves narrowing the beam as it travels through space. Such a decrease may be effectuated via the beam forming package 104 within electromagnetic radiation energy source 38. A less divergent beam focuses its energy within a smaller area, which increases the energy concentration at any given point. Accordingly and even if the total power of the beam remains the same, the energy density of the beam will be increased since the same amount of energy is focused within a smaller cross-sectional area.

Increasing Power: Increasing 1430 the power of celestial energy beam 40 involves increasing the total amount of energy being transmitted. Such a power increase may be effectuated by increasing the power supplied to energy beam source 100 within electromagnetic radiation energy source 38, thus resulting in a more powerful celestial energy beam 40. Since energy density is directly related to the beam's total power, a higher-power beam naturally results in more energy being concentrated in any given area of the celestial energy beam. For example, if the beam power is doubled, the energy density will also be doubled, assuming the beam size remains the same.

Energy acquisition and delivery process 300 may periodically perform 1432 a realignment procedure based upon alignment feedback (e.g., feedback 234) received from the electromagnetic radiation energy receiver (e.g., electromagnetic radiation energy receiver 200) to realign the celestial energy beam (e.g., celestial energy beam 40) with the electromagnetic radiation energy receiver (e.g., electromagnetic radiation energy receiver 200) to offset movement of the object in need (e.g., object in need 256).

### (19) Methodologies of Generating Power on Earth, Beaming it to a Space-Based Reflector, and Bouncing it Down to an Earth-Based Receiver.

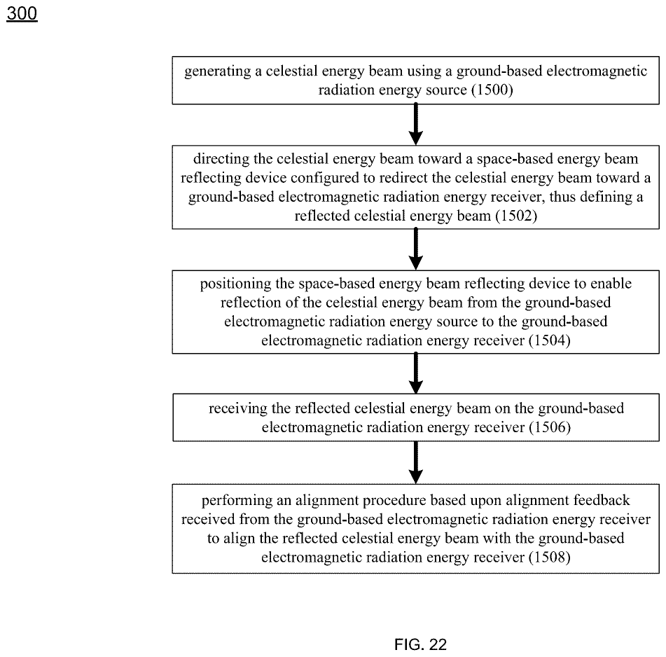

Referring also to FIG. 22, the following discussion concerns the manner in which energy acquisition and delivery process 300 may generate electrical power on an earth-based electromagnetic radiation energy source (e.g., electromagnetic radiation energy source 38G) that is provided to an earth-based electromagnetic radiation energy receiver (e.g., electromagnetic radiation energy receiver 200) via a celestial energy beam (e.g., celestial energy beam 40) that is reflected off of a space-based energy beam reflecting device.

Energy acquisition and delivery process 300 may generate 1500 a celestial energy beam (e.g., celestial energy beam 40) using a ground-based electromagnetic radiation energy source (e.g., electromagnetic radiation energy source 38G).

As discussed above and for generating 1500 a celestial energy beam (e.g., celestial energy beam 40), the ground-based electromagnetic radiation energy source (e.g., electromagnetic radiation energy source 38G) may include: an energy beam source (e.g., energy beam source 100) for generating the celestial energy beam (e.g., celestial energy beam 40); a beam aiming assembly (e.g., beam aiming assembly 102) for steering the celestial energy beam (e.g., celestial energy beam 40) toward a target; and a beam forming package (e.g., beam forming package 104) for forming the celestial energy beam (e.g., celestial energy beam 40).

The energy beam source (e.g., energy beam source 100) for generating the celestial energy beam (e.g., celestial energy beam 40) may include one or more of: a visible-light laser beam source; an Infrared laser beam source; a short wavelength Infrared laser beam source, a mid-Infrared laser beam source; a near-Infrared laser beam source; and a microwave beam source.

The beam aiming assembly (e.g., beam aiming assembly 102) for steering the celestial energy beam (e.g., celestial energy beam 40) may include: a Gimbal mount assembly (e.g., Gimbal mount assembly 106) configured to direct the celestial energy beam (e.g., celestial energy beam 40) toward a target; a phased array assembly (e.g., phased array assembly 107) configured to direct the celestial energy beam (e.g., celestial energy beam 40) toward a target and/or a periscope assembly (e.g., periscope assembly 108) configured to direct the celestial energy beam (e.g., celestial energy beam 40) toward a target. A Gimbal mount assembly (e.g., Gimbal mount assembly 106), a phased array assembly (e.g., phased array assembly 107) and a periscope assembly (e.g., periscope assembly 108) can be effectively used in space-based energy systems to accurately direct a celestial energy beam (e.g., celestial energy beam 40), such as a laser or microwave beam, from a satellite (e.g., satellite 14) to a electromagnetic radiation energy receiver (e.g., electromagnetic radiation energy receiver 200).

The beam forming package (e.g., beam forming package 104) for forming the celestial energy beam (e.g., celestial energy beam 40) may include: collimating optics (e.g., collimating optics 110); and focusing optics (e.g., focusing optics 112). Collimating optics (e.g., collimating optics 110) are used to shape a celestial energy beam (e.g., celestial energy beam 40) so that its rays are parallel, resulting in a collimated beam i.e., one that doesn't spread out (diverge) significantly over distance. When a celestial energy beam (e.g., celestial energy beam 40) exits a source (e.g., energy beam source 100) like a diode, it typically diverges, meaning the beam spreads out as it travels.

Collimating optics (e.g., collimating optics 110), such as a lens or a lens system, are placed in the beam path to correct this divergence. By focusing the light emerging from a point-like or narrow source, collimating optics (e.g., collimating optics 110) create a beam with minimal angular spread. This is especially important for applications that require the beam to travel long distances (e.g., power transmission) or interact with precise optical components. In short, collimating optics (e.g., collimating optics 110) make a celestial energy beam (e.g., celestial energy beam 40) straighter and more focused over distance, improving its usability and efficiency in various optical systems.

Focusing optics (e.g., focusing optics 112) do the opposite of collimating optics (e.g., collimating optics 110), as they take a celestial energy beam (e.g., celestial energy beam 40) and converge it to a point or a small spot. This is usually achieved with lenses or curved mirrors that bend the incoming rays inward, concentrating the beam's energy into a smaller area. When a collimated or diverging celestial energy beam (e.g., celestial energy beam 40) passes through focusing optics (e.g., focusing optics 112), the optics manipulate the beam's path so that all rays come together at a focal point.

Energy acquisition and delivery process 300 may direct 1502 the celestial energy beam (e.g., celestial energy beam 40) toward a space-based energy beam reflecting device (e.g., space-based energy beam reflecting device 130) configured to redirect the celestial energy beam (e.g., celestial energy beam 40) toward a ground-based electromagnetic radiation energy receiver (e.g., electromagnetic radiation energy receiver 200), thus defining a reflected celestial energy beam (e.g., celestial energy beam 40).

The space-based energy beam reflecting device (e.g., space-based energy beam reflecting device 130) may be configured to intercept a celestial energy beam (e.g., celestial energy beam 40) emitted from a ground-based electromagnetic radiation energy source (e.g., electromagnetic radiation energy source 38G) and reflect it toward a designated ground-based electromagnetic radiation energy receiver (e.g., electromagnetic radiation energy receiver 200). This device (e.g., space-based energy beam reflecting device 130) effectively creates a relay in space, enabling energy redirection over vast distances or around obstructions such as terrain or atmospheric interference. This device (e.g., space-based energy beam reflecting device 130) must be precisely aligned to ensure efficient redirection of celestial energy beam 40. The space-based energy beam reflecting device (e.g., space-based energy beam reflecting device 130) remains in a stable orbit or geosynchronous position to maintain consistent line-of-sight with both the source (e.g., electromagnetic radiation energy source 38G) and the receiver (e.g., electromagnetic radiation energy receiver 200).

There are several configurations for the space-based energy beam reflecting device (e.g., space-based energy beam reflecting device 130), each leveraging different materials and optical principles:
Reflective Mirror Space-Based Energy Beam Reflecting Device: This configuration uses a high-quality optical mirror with a reflective coating, often composed of aluminum or silver, to redirect celestial energy beam 40. These mirrors are typically mounted on adjustable platforms or Gimbals for fine orientation control, wherein they offer high reflectivity across a broad spectral range (e.g., including laser-based and microwave energy beams). The effectiveness of the space-based energy beam reflecting device (e.g., space-based energy beam reflecting device 130) depends upon surface smoothness and reflectivity, making them ideal for applications where beam integrity must be preserved.
Polished Metal Space-Based Energy Beam Reflecting Device: This configuration uses a large, highly polished metallic surface—often aluminum or gold-coated materials—that relies on specular reflection. While similar in function to optical mirrors, these devices may not have the same finely tuned coatings but instead rely on the inherent reflectivity of the metal. Such devices may be robust, durable, and capable of reflecting microwave or laser beams with high efficiency. Unfortunately, they may suffer from minor scattering losses if surface imperfections exist. This configuration is well-suited for applications involving longer wavelengths, such as microwave energy transmission.
Dielectric Mirror Space-Based Energy Beam Reflecting Device: Dielectric mirrors, also known as Bragg mirrors, consist of multiple thin layers of dielectric materials with alternating refractive indices. These mirrors are engineered to reflect specific wavelengths with very high efficiency by exploiting constructive interference. They are especially useful for reflecting narrow-band laser beams, such as near-Infrared or visible light, and can achieve reflectivity greater than 99.9% at their design wavelength. Dielectric mirrors are also lightweight and resistant to degradation in space environments, making them highly attractive for laser-based space power systems.

Each of these configurations allows the space-based energy beam reflecting device (e.g., space-based energy beam reflecting device 130) to act as a passive energy relay station. By choosing the appropriate reflecting material and design, the device (e.g., space-based energy beam reflecting device 130) may be optimized for different types of celestial energy beams (e.g., celestial energy beam 40), whether microwave or laser-based, ensuring high efficiency, reliability, and alignment accuracy in power transmission from source (e.g., electromagnetic radiation energy source 38G) to receiver (e.g., electromagnetic radiation energy receiver 200).

Being space-based energy beam reflecting device 130 is a reflective device, energy acquisition and delivery process 300 may position 1504 the space-based energy beam reflecting device (e.g., space-based energy beam reflecting device 130) to enable reflection of the celestial energy beam (e.g., celestial energy beam 40) from the ground-based electromagnetic radiation energy source (e.g., electromagnetic radiation energy source 38G) to the ground-based electromagnetic radiation energy receiver (e.g., electromagnetic radiation energy receiver 200). Specifically, energy acquisition and delivery process 300 may position 1504 the space-based energy beam reflecting device (e.g., space-based energy beam reflecting device 130) to enable line-of-sight optical communication between space-based energy beam reflecting device 130 and each of electromagnetic radiation energy source 38G and electromagnetic radiation energy receiver 200.

Energy acquisition and delivery process 300 may receive 1506 the reflected celestial energy beam (e.g., celestial energy beam 40) on the ground-based electromagnetic radiation energy receiver (e.g., electromagnetic radiation energy receiver 200). As discussed above, the electromagnetic radiation energy receiver (e.g., electromagnetic radiation energy receiver 200) may include one or more energy receiving devices (e.g., energy receiving devices 202). Examples of the energy receiving devices (e.g., energy receiving devices 202) may include but are not limited to one or more of: a photovoltaic cell; a photodiode; a heat engine; and a rectenna array. The electromagnetic radiation energy receiver (e.g., electromagnetic radiation energy receiver 200) may be configured to receive at least a portion of the celestial energy beam (e.g., celestial energy beam 40) on the one or more energy receiving devices (e.g., energy receiving devices 202) and generate received electrical energy (e.g., received electrical energy 204).

Energy acquisition and delivery process 300 may perform 1508 an alignment procedure based upon alignment feedback (e.g., feedback 234) received from the ground-based electromagnetic radiation energy receiver (e.g., electromagnetic radiation energy receiver 200) to align the reflected celestial energy beam (e.g., celestial energy beam 40) with the ground-based electromagnetic radiation energy receiver (e.g., electromagnetic radiation energy receiver 200).

As discussed above, such feedback (e.g., feedback 234) may be received on feedback receiving devices (e.g., feedback receiving devices 128) included within electromagnetic radiation energy source 38G. Examples of such feedback receiving devices (e.g., feedback receiving devices 128) may include but are not limited to one or more of: one or more photovoltaic cells; one or more photodiodes; one or more heat engines; and one or more rectenna arrays.

As discussed above, the feedback (e.g., feedback 234) received from the electromagnetic radiation energy receiver (e.g., electromagnetic radiation energy receiver 200) may include feedback reflected from one or more feedback devices (e.g., feedback devices 226) included within the electromagnetic radiation energy receiver (e.g., electromagnetic radiation energy receiver 200). For example, these one or more feedback devices (e.g., feedback devices 226) may be interspersed within (or positioned proximate) energy receiving devices 202 included within electromagnetic radiation energy receiver 200. Specifically, these one or more feedback devices (e.g., feedback devices 226) may include one or more of: a centrally-positioned feedback device (i.e., a feedback device that is centrally positioned within energy receiving devices 202 included within electromagnetic radiation energy receiver 200); and a plurality of peripherally-positioned feedback devices (i.e., a plurality of feedback devices that are peripherally-positioned about the perimeter of energy receiving devices 202 included within electromagnetic radiation energy receiver 200).

At least one of the feedback devices (e.g., feedback devices 226) may be a retroreflector. As discussed above, a retroreflector is a specialized feedback device or surface that reflects incoming electromagnetic radiation (e.g., a portion of celestial energy beam 40) directly back toward its source (e.g., electromagnetic radiation energy source 38), regardless of the angle at which celestial energy beam 40 arrives. Unlike a standard mirror, which reflects light at an angle equal to the incident angle, a retroreflector returns celestial energy beam 40 along a near-exact path from which it came through geometric structures (e.g., corner cubes, cat's-eye lenses, or Bragg gratings). In the context of celestial energy beam 40, a retroreflector can be strategically placed near or integrated into the electromagnetic radiation energy receiver 200, wherein it may reflect a small portion of the incoming energy beam (e.g., celestial energy beam 40) back to it source (e.g., energy beam source 100), where it can be used to provide feedback to electromagnetic radiation energy source 38.

As discussed above, the feedback devices (e.g., feedback devices 226) may include an RF component. Specifically, feedback devices 226 may include a plurality of opto-electrical sensors (e.g., photodiodes, photodetectors and/or photovoltaic cells). This plurality of sensors (e.g., feedback devices 226) may monitor the position of celestial energy beam 40, which is received on electromagnetic radiation energy receiver 200 from electromagnetic radiation energy source 38. This information concerning beam alignment (i.e., the manner in which celestial energy beam 40 is striking electromagnetic radiation energy receiver 200) may be provided to an RF transmitter (e.g., wireless communication system 332) that is included within/coupled to/available to electromagnetic radiation energy receiver 200 so that such information may be transmitted to the electromagnetic radiation energy source (e.g., electromagnetic radiation energy source 38). This information may then be used by electromagnetic radiation energy source 38 to reposition celestial energy beam 40 via beam aiming assembly 102 (if adjustment is needed).

As discussed above, when performing 1508 an alignment procedure based upon alignment feedback (e.g., feedback 234), energy acquisition and delivery process 300 may: initiate a location sweeping operation; receive feedback (e.g., feedback 234) from the electromagnetic radiation energy receiver (e.g., electromagnetic radiation energy receiver 200) at a defined point (e.g., defined point 238) within the location sweeping operation; reinitiate the location sweeping operation at the defined point (e.g., defined point 238); and receive updated feedback (e.g., feedback 234) from the electromagnetic radiation energy receiver (e.g., electromagnetic radiation energy receiver 200) at an updated point (e.g., updated point 240) within the location sweeping operation.

Specifically, energy acquisition and delivery process 300 may initiate a location sweeping operation that initiates at an initial point (e.g., initial point 236) and spirals outwardly away from the initial point (e.g., initial point 236), as shown in FIG. 15. Energy acquisition and delivery process 300 may receive feedback (e.g., feedback 234) from the electromagnetic radiation energy receiver (e.g., electromagnetic radiation energy receiver 200) at a defined point (e.g., defined point 238) within the location sweeping operation. Energy acquisition and delivery process 300 may then reinitiate the location sweeping operation at the defined point (e.g., defined point 238). Energy acquisition and delivery process 300 may then receive updated feedback (e.g., feedback 234) from the electromagnetic radiation energy receiver (e.g., electromagnetic radiation energy receiver 200) at an updated point (e.g., updated point 240) within the location sweeping operation.

As discussed above, energy acquisition and delivery process 300 may: repeatedly reinitiate the location sweeping operation until feedback (e.g., feedback 234) is received from the electromagnetic radiation energy receiver (e.g., electromagnetic radiation energy receiver 200) that identifies a point within the location sweeping operation that defines a peak return power, thus defining a location for the electromagnetic radiation energy receiver (e.g., electromagnetic radiation energy receiver 200).

### (20) Methodologies of Generating Power in Space, Beaming it to a Space-Based Reflector, and Bouncing it Down to an Earth-Based Receiver.

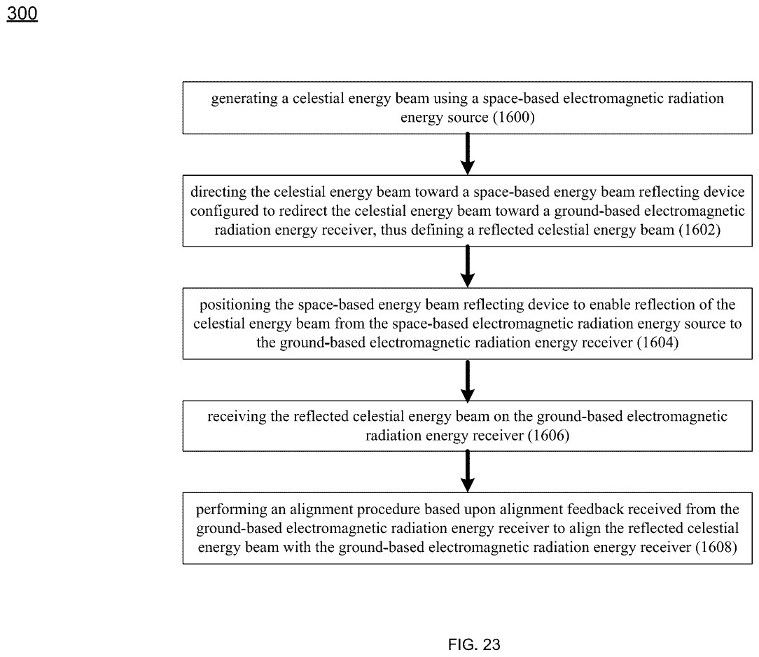

Referring also to FIG. 23, the following discussion concerns the manner in which energy acquisition and delivery process 300 may generate electrical power on a space-based electromagnetic radiation energy source (e.g., electromagnetic radiation energy source 38) that is provided to an earth-based electromagnetic radiation energy receiver (e.g., electromagnetic radiation energy receiver 200) via a celestial energy beam (e.g., celestial energy beam 40) that is reflected off of a space-based energy beam reflecting device.

Energy acquisition and delivery process 300 may generate 1600 a celestial energy beam (e.g., celestial energy beam 40) using a space-based electromagnetic radiation energy source (e.g., electromagnetic radiation energy source 38).

As discussed above and for generating 1600 a celestial energy beam (e.g., celestial energy beam 40), the electromagnetic radiation energy source (e.g., electromagnetic radiation energy source 38) may include: an energy beam source (e.g., energy beam source 100) for generating the celestial energy beam (e.g., celestial energy beam 40); a beam aiming assembly (e.g., beam aiming assembly 102) for steering the celestial energy beam (e.g., celestial energy beam 40) toward a target; and a beam forming package (e.g., beam forming package 104) for forming the celestial energy beam (e.g., celestial energy beam 40).

The energy beam source (e.g., energy beam source 100) for generating the celestial energy beam (e.g., celestial energy beam 40) may include one or more of: a visible-light laser beam source; an Infrared laser beam source; a short wavelength Infrared laser beam source, a mid-Infrared laser beam source; a near-Infrared laser beam source; and a microwave beam source.

The beam aiming assembly (e.g., beam aiming assembly 102) for steering the celestial energy beam (e.g., celestial energy beam 40) may include: a Gimbal mount assembly (e.g., Gimbal mount assembly 106) configured to direct the celestial energy beam (e.g., celestial energy beam 40) toward a target; a phased array assembly (e.g., phased array assembly 107) configured to direct the celestial energy beam (e.g., celestial energy beam 40) toward a target and/or a periscope assembly (e.g., periscope assembly 108) configured to direct the celestial energy beam (e.g., celestial energy beam 40) toward a target. A Gimbal mount assembly (e.g., Gimbal mount assembly 106), a phased array assembly (e.g., phased array assembly 107) and a periscope assembly (e.g., periscope assembly 108) can be effectively used in space-based energy systems to accurately direct a celestial energy beam (e.g., celestial energy beam 40), such as a laser or microwave beam, from a satellite (e.g., satellite 14) to a electromagnetic radiation energy receiver (e.g., electromagnetic radiation energy receiver 200).

The beam forming package (e.g., beam forming package 104) for forming the celestial energy beam (e.g., celestial energy beam 40) may include: collimating optics (e.g., collimating optics 110); and focusing optics (e.g., focusing optics 112). Collimating optics (e.g., collimating optics 110) are used to shape a celestial energy beam (e.g., celestial energy beam 40) so that its rays are parallel, resulting in a collimated beam i.e., one that doesn't spread out (diverge) significantly over distance. When a celestial energy beam (e.g., celestial energy beam 40) exits a source (e.g., energy beam source 100) like a diode, it typically diverges, meaning the beam spreads out as it travels.

Collimating optics (e.g., collimating optics 110), such as a lens or a lens system, are placed in the beam path to correct this divergence. By focusing the light emerging from a point-like or narrow source, collimating optics (e.g., collimating optics 110) create a beam with minimal angular spread. This is especially important for applications that require the beam to travel long distances (e.g., power transmission) or interact with precise optical components. In short, collimating optics (e.g., collimating optics 110) make a celestial energy beam (e.g., celestial energy beam 40) straighter and more focused over distance, improving its usability and efficiency in various optical systems.

Focusing optics (e.g., focusing optics 112) do the opposite of collimating optics (e.g., collimating optics 110), as they take a celestial energy beam (e.g., celestial energy beam 40) and converge it to a point or a small spot. This is usually achieved with lenses or curved mirrors that bend the incoming rays inward, concentrating the beam's energy into a smaller area. When a collimated or diverging celestial energy beam (e.g., celestial energy beam 40) passes through focusing optics (e.g., focusing optics 112), the optics manipulate the beam's path so that all rays come together at a focal point.

Energy acquisition and delivery process 300 may direct 1602 the celestial energy beam (e.g., celestial energy beam 40) toward a space-based energy beam reflecting device (e.g., space-based energy beam reflecting device 130) configured to redirect the celestial energy beam (e.g., celestial energy beam 40) toward a ground-based electromagnetic radiation energy receiver (e.g., electromagnetic radiation energy receiver 200), thus defining a reflected celestial energy beam (e.g., celestial energy beam 40).

As discussed above, the space-based energy beam reflecting device (e.g., space-based energy beam reflecting device 130) may be configured to intercept a celestial energy beam (e.g., celestial energy beam 40) emitted from a space-based electromagnetic radiation energy source (e.g., electromagnetic radiation energy source 38) and reflect it toward a designated ground-based electromagnetic radiation energy receiver (e.g., electromagnetic radiation energy receiver 200). This device (e.g., space-based energy beam reflecting device 130) effectively creates a relay in space, enabling energy redirection over vast distances or around obstructions such as terrain or atmospheric interference. This device (e.g., space-based energy beam reflecting device 130) must be precisely aligned to ensure efficient redirection of celestial energy beam 40. The space-based energy beam reflecting device (e.g., space-based energy beam reflecting device 130) remains in a stable orbit or geosynchronous position to maintain consistent line-of-sight with both the source (e.g., electromagnetic radiation energy source 38) and the receiver (e.g., electromagnetic radiation energy receiver 200).

As discussed above, there are several configurations for the space-based energy beam reflecting device (e.g., space-based energy beam reflecting device 130), examples of which may include but are not limited to: Reflective Mirror Space-Based Energy Beam Reflecting Device: Polished Metal Space-Based Energy Beam Reflecting Device: and Dielectric Mirror Space-Based Energy Beam Reflecting Device:
Being space-based energy beam reflecting device 130 is a reflective device, energy acquisition and delivery process 300 may position 1604 the space-based energy beam reflecting device (e.g., space-based energy beam reflecting device 130) to enable reflection of the celestial energy beam (e.g., celestial energy beam 40) from the space-based electromagnetic radiation energy source (e.g., electromagnetic radiation energy source 38) to the ground-based electromagnetic radiation energy receiver (e.g., electromagnetic radiation energy receiver 200). Specifically, energy acquisition and delivery process 300 may position 1604 the space-based energy beam reflecting device (e.g., space-based energy beam reflecting device 130) to enable line-of-sight optical communication between space-based energy beam reflecting device 130 and each of electromagnetic radiation energy source 38 and electromagnetic radiation energy receiver 200.

Energy acquisition and delivery process 300 may receive 1606 the reflected celestial energy beam (e.g., celestial energy beam 40) on the ground-based electromagnetic radiation energy receiver (e.g., electromagnetic radiation energy receiver 200). As discussed above, the electromagnetic radiation energy receiver (e.g., electromagnetic radiation energy receiver 200) may include one or more energy receiving devices (e.g., energy receiving devices 202). Examples of the energy receiving devices (e.g., energy receiving devices 202) may include but are not limited to one or more of: a photovoltaic cell; a photodiode; a heat engine; and a rectenna array. The electromagnetic radiation energy receiver (e.g., electromagnetic radiation energy receiver 200) may be configured to receive at least a portion of the celestial energy beam (e.g., celestial energy beam 40) on the one or more energy receiving devices (e.g., energy receiving devices 202) and generate received electrical energy (e.g., received electrical energy 204).

Energy acquisition and delivery process 300 may perform 1608 an alignment procedure based upon alignment feedback (e.g., feedback 234) received from the ground-based electromagnetic radiation energy receiver (e.g., electromagnetic radiation energy receiver 200) to align the reflected celestial energy beam (e.g., celestial energy beam 40) with the ground-based electromagnetic radiation energy receiver (e.g., electromagnetic radiation energy receiver 200).

As discussed above, such feedback (e.g., feedback 234) may be received on feedback receiving devices (e.g., feedback receiving devices 128) included within electromagnetic radiation energy source 38G. Examples of such feedback receiving devices (e.g., feedback receiving devices 128) may include but are not limited to one or more of: one or more photovoltaic cells; one or more photodiodes; one or more heat engines; and one or more rectenna arrays.

As discussed above, the feedback (e.g., feedback 234) received from the electromagnetic radiation energy receiver (e.g., electromagnetic radiation energy receiver 200) may include feedback reflected from one or more feedback devices (e.g., feedback devices 226) included within the electromagnetic radiation energy receiver (e.g., electromagnetic radiation energy receiver 200). For example, these one or more feedback devices (e.g., feedback devices 226) may be interspersed within (or positioned proximate) energy receiving devices 202 included within electromagnetic radiation energy receiver 200. Specifically, these one or more feedback devices (e.g., feedback devices 226) may include one or more of: a centrally-positioned feedback device (i.e., a feedback device that is centrally positioned within energy receiving devices 202 included within electromagnetic radiation energy receiver 200); and a plurality of peripherally-positioned feedback devices (i.e., a plurality of feedback devices that are peripherally-positioned about the perimeter of energy receiving devices 202 included within electromagnetic radiation energy receiver 200).

At least one of the feedback devices (e.g., feedback devices 226) may be a retroreflector. As discussed above, a retroreflector is a specialized feedback device or surface that reflects incoming electromagnetic radiation (e.g., a portion of celestial energy beam 40) directly back toward its source (e.g., electromagnetic radiation energy source 38), regardless of the angle at which celestial energy beam 40 arrives. Unlike a standard mirror, which reflects light at an angle equal to the incident angle, a retroreflector returns celestial energy beam 40 along a near-exact path from which it came through geometric structures (e.g., corner cubes, cat's-eye lenses, or Bragg gratings). In the context of celestial energy beam 40, a retroreflector can be strategically placed near or integrated into the electromagnetic radiation energy receiver 200, wherein it may reflect a small portion of the incoming energy beam (e.g., celestial energy beam 40) back to it source (e.g., energy beam source 100), where it can be used to provide feedback to electromagnetic radiation energy source 38.

As discussed above, the feedback devices (e.g., feedback devices 226) may include an RF component. Specifically, feedback devices 226 may include a plurality of opto-electrical sensors (e.g., photodiodes, photodetectors and/or photovoltaic cells). This plurality of sensors (e.g., feedback devices 226) may monitor the position of celestial energy beam 40, which is received on electromagnetic radiation energy receiver 200 from electromagnetic radiation energy source 38. This information concerning beam alignment (i.e., the manner in which celestial energy beam 40 is striking electromagnetic radiation energy receiver 200) may be provided to an RF transmitter (e.g., wireless communication system 332) that is included within/coupled to/available to electromagnetic radiation energy receiver 200 so that such information may be transmitted to the electromagnetic radiation energy source (e.g., electromagnetic radiation energy source 38). This information may then be used by electromagnetic radiation energy source 38 to reposition celestial energy beam 40 via beam aiming assembly 102 (if adjustment is needed).

As discussed above, when performing 1608 an alignment procedure based upon alignment feedback (e.g., feedback 234), energy acquisition and delivery process 300 may: initiate a location sweeping operation; receive feedback (e.g., feedback 234) from the electromagnetic radiation energy receiver (e.g., electromagnetic radiation energy receiver 200) at a defined point (e.g., defined point 238) within the location sweeping operation; reinitiate the location sweeping operation at the defined point (e.g., defined point 238); and receive updated feedback (e.g., feedback 234) from the electromagnetic radiation energy receiver (e.g., electromagnetic radiation energy receiver 200) at an updated point (e.g., updated point 240) within the location sweeping operation.

Specifically, energy acquisition and delivery process 300 may initiate a location sweeping operation that initiates at an initial point (e.g., initial point 236) and spirals outwardly away from the initial point (e.g., initial point 236), as shown in FIG. 15. Energy acquisition and delivery process 300 may receive feedback (e.g., feedback 234) from the electromagnetic radiation energy receiver (e.g., electromagnetic radiation energy receiver 200) at a defined point (e.g., defined point 238) within the location sweeping operation. Energy acquisition and delivery process 300 may then reinitiate the location sweeping operation at the defined point (e.g., defined point 238). Energy acquisition and delivery process 300 may then receive updated feedback (e.g., feedback 234) from the electromagnetic radiation energy receiver (e.g., electromagnetic radiation energy receiver 200) at an updated point (e.g., updated point 240) within the location sweeping operation.

As discussed above, energy acquisition and delivery process 300 may: repeatedly reinitiate the location sweeping operation until feedback (e.g., feedback 234) is received from the electromagnetic radiation energy receiver (e.g., electromagnetic radiation energy receiver 200) that identifies a point within the location sweeping operation that defines a peak return power, thus defining a location for the electromagnetic radiation energy receiver (e.g., electromagnetic radiation energy receiver 200).

### (21) Methodologies of Providing Power to an Area in Need to Additional Power.

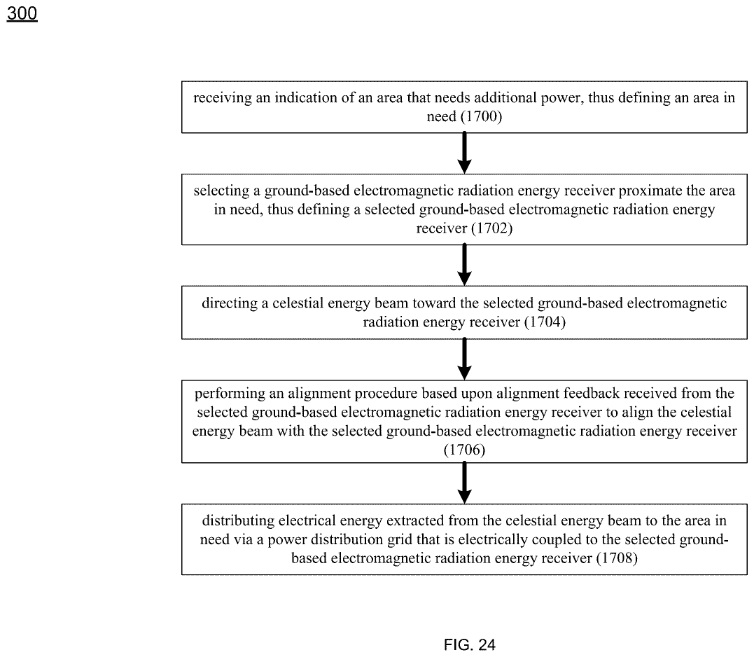

Referring also to FIG. 24, the following discussion concerns the manner in which energy acquisition and delivery process 300 may provide electrical energy to an area in need of additional power via a celestial energy beam (e.g., celestial energy beam 40) that is provided by an electromagnetic radiation energy source (e.g., electromagnetic radiation energy source 38) to an electromagnetic radiation energy receiver (e.g., electromagnetic radiation energy receiver 200) proximate the area in need.

Energy acquisition and delivery process 300 may receive 1700 an indication of an area that needs additional power, thus defining an area in need (e.g., area in need 258). Example of an area in need may include but are not limited to: an area stuck by a natural disaster that no longer has power (e.g., an area that was struck by an ice storm that took down power distribution lines); an area that is undersupplied with power (e.g., a town in California that is experiencing a heat wave and their local power distribution grid cannot supply enough power); and an area that temporarily needs supplemental power (e.g., a remote concert venue that is in a sparsely populated area).

Energy acquisition and delivery process 300 may select 1702 a ground-based electromagnetic radiation energy receiver (e.g., electromagnetic radiation energy receiver 200) proximate the area in need (e.g., area in need 258), thus defining a selected ground-based electromagnetic radiation energy receiver (e.g., electromagnetic radiation energy receiver 200).

The selected ground-based electromagnetic radiation energy receiver (e.g., electromagnetic radiation energy receiver 200) may be a mobile electromagnetic radiation energy receiver (e.g., electromagnetic radiation energy receiver 200) that is configured to be temporarily attached to the power distribution grid (e.g., power distribution grid 210). For example, the electromagnetic radiation energy receiver (e.g., electromagnetic radiation energy receiver 200) may be mounted on a flatbed tractor trailer that may be moved to the area in need (e.g., area in need 258). For example, the Burning Man Festival is held in Black Rock City, a temporary community built in the middle of the Black Rock Desert in northwestern Nevada. Accordingly, a considerable amount of power is needed for this festival, which is held in an area that has very little utility resources. Therefore, such a mobile electromagnetic radiation energy receiver (e.g., electromagnetic radiation energy receiver 200) may be brought to Black Rock City and connected to a distribution grid to provide power to the festival.

Additionally/alternatively, the selected ground-based electromagnetic radiation energy receiver (e.g., electromagnetic radiation energy receiver 200) may be a permanent electromagnetic radiation energy receiver (e.g., electromagnetic radiation energy receiver 200) that is configured to be permanently attached to the power distribution grid (e.g., power distribution grid 210). Therefore, the electromagnetic radiation energy receiver (e.g., electromagnetic radiation energy receiver 200) may be available to provide a clean source of electrical energy to the power distribution grid (e.g., power distribution grid 210) during power outages, high levels of use, etc.

Energy acquisition and delivery process 300 may direct 1704 a celestial energy beam (e.g., celestial energy beam 40) toward the selected ground-based electromagnetic radiation energy receiver (e.g., electromagnetic radiation energy receiver 200).

As discussed above and for directing 1704 a celestial energy beam (e.g., celestial energy beam 40), the electromagnetic radiation energy source (e.g., electromagnetic radiation energy source 38) may include: an energy beam source (e.g., energy beam source 100) for generating the celestial energy beam (e.g., celestial energy beam 40); a beam aiming assembly (e.g., beam aiming assembly 102) for steering the celestial energy beam (e.g., celestial energy beam 40) toward a target; and a beam forming package (e.g., beam forming package 104) for forming the celestial energy beam (e.g., celestial energy beam 40).

The energy beam source (e.g., energy beam source 100) for generating the celestial energy beam (e.g., celestial energy beam 40) may include one or more of: a visible-light laser beam source; an Infrared laser beam source; a short wavelength Infrared laser beam source, a mid-Infrared laser beam source; a near-Infrared laser beam source; and a microwave beam source.

The beam aiming assembly (e.g., beam aiming assembly 102) for steering the celestial energy beam (e.g., celestial energy beam 40) may include: a Gimbal mount assembly (e.g., Gimbal mount assembly 106) configured to direct the celestial energy beam (e.g., celestial energy beam 40) toward a target; a phased array assembly (e.g., phased array assembly 107) configured to direct the celestial energy beam (e.g., celestial energy beam 40) toward a target and/or a periscope assembly (e.g., periscope assembly 108) configured to direct the celestial energy beam (e.g., celestial energy beam 40) toward a target. A Gimbal mount assembly (e.g., Gimbal mount assembly 106), a phased array assembly (e.g., phased array assembly 107) and a periscope assembly (e.g., periscope assembly 108) can be effectively used in space-based energy systems to accurately direct a celestial energy beam (e.g., celestial energy beam 40), such as a laser or microwave beam, from a satellite (e.g., satellite 14) to a electromagnetic radiation energy receiver (e.g., electromagnetic radiation energy receiver 200).

The beam forming package (e.g., beam forming package 104) for forming the celestial energy beam (e.g., celestial energy beam 40) may include: collimating optics (e.g., collimating optics 110); and focusing optics (e.g., focusing optics 112). Collimating optics (e.g., collimating optics 110) are used to shape a celestial energy beam (e.g., celestial energy beam 40) so that its rays are parallel, resulting in a collimated beam i.e., one that doesn't spread out (diverge) significantly over distance. When a celestial energy beam (e.g., celestial energy beam 40) exits a source (e.g., energy beam source 100) like a diode, it typically diverges, meaning the beam spreads out as it travels.

Collimating optics (e.g., collimating optics 110), such as a lens or a lens system, are placed in the beam path to correct this divergence. By focusing the light emerging from a point-like or narrow source, collimating optics (e.g., collimating optics 110) create a beam with minimal angular spread. This is especially important for applications that require the beam to travel long distances (e.g., power transmission) or interact with precise optical components. In short, collimating optics (e.g., collimating optics 110) make a celestial energy beam (e.g., celestial energy beam 40) straighter and more focused over distance, improving its usability and efficiency in various optical systems.

Focusing optics (e.g., focusing optics 112) do the opposite of collimating optics (e.g., collimating optics 110), as they take a celestial energy beam (e.g., celestial energy beam 40) and converge it to a point or a small spot. This is usually achieved with lenses or curved mirrors that bend the incoming rays inward, concentrating the beam's energy into a smaller area. When a collimated or diverging celestial energy beam (e.g., celestial energy beam 40) passes through focusing optics (e.g., focusing optics 112), the optics manipulate the beam's path so that all rays come together at a focal point.

Energy acquisition and delivery process 300 may perform 1706 an alignment procedure based upon alignment feedback (e.g., feedback 234) received from the selected ground-based electromagnetic radiation energy receiver (e.g., electromagnetic radiation energy receiver 200) to align the celestial energy beam (e.g., celestial energy beam 40) with the selected ground-based electromagnetic radiation energy receiver (e.g., electromagnetic radiation energy receiver 200).

The alignment feedback (e.g., feedback 234) may be provided to an electromagnetic radiation energy source (e.g., electromagnetic radiation energy source 38) that is generating the celestial energy beam (e.g., celestial energy beam 40) via one or more feedback devices (e.g., feedback devices 226) included in the selected ground-based electromagnetic radiation energy receiver (e.g., electromagnetic radiation energy receiver 200).

The one or more feedback devices (e.g., feedback devices 226) may be interspersed within (or positioned proximate) energy receiving devices 202 included within electromagnetic radiation energy receiver 200. Specifically, these one or more feedback devices (e.g., feedback devices 226) may include one or more of: a centrally-positioned feedback device (i.e., a feedback device that is centrally positioned within energy receiving devices 202 included within electromagnetic radiation energy receiver 200); and a plurality of peripherally-positioned feedback devices (i.e., a plurality of feedback devices that are peripherally-positioned about the perimeter of energy receiving devices 202 included within electromagnetic radiation energy receiver 200).

At least one of the feedback devices (e.g., feedback devices 226) may be a retroreflector. As discussed above, a retroreflector is a specialized feedback device or surface that reflects incoming electromagnetic radiation (e.g., a portion of celestial energy beam 40) directly back toward its source (e.g., electromagnetic radiation energy source 38), regardless of the angle at which celestial energy beam 40 arrives. Unlike a standard mirror, which reflects light at an angle equal to the incident angle, a retroreflector returns celestial energy beam 40 along a near-exact path from which it came through geometric structures (e.g., corner cubes, cat's-eye lenses, or Bragg gratings). In the context of celestial energy beam 40, a retroreflector can be strategically placed near or integrated into the electromagnetic radiation energy receiver 200, wherein it may reflect a small portion of the incoming energy beam (e.g., celestial energy beam 40) back to it source (e.g., energy beam source 100), where it can be used to provide feedback to electromagnetic radiation energy source 38.

As discussed above, the feedback devices (e.g., feedback devices 226) may include an RF component. Specifically, feedback devices 226 may include a plurality of opto-electrical sensors (e.g., photodiodes, photodetectors and/or photovoltaic cells). This plurality of sensors (e.g., feedback devices 226) may monitor the position of celestial energy beam 40, which is received on electromagnetic radiation energy receiver 200 from electromagnetic radiation energy source 38. This information concerning beam alignment (i.e., the manner in which celestial energy beam 40 is striking electromagnetic radiation energy receiver 200) may be provided to an RF transmitter (e.g., wireless communication system 332) that is included within/coupled to/available to electromagnetic radiation energy receiver 200 so that such information may be transmitted to the electromagnetic radiation energy source (e.g., electromagnetic radiation energy source 38). This information may then be used by electromagnetic radiation energy source 38 to reposition celestial energy beam 40 via beam aiming assembly 102 (if adjustment is needed).

As discussed above, such feedback (e.g., feedback 234) may be received on feedback receiving devices (e.g., feedback receiving devices 128) included within electromagnetic radiation energy source 38, examples of which may include but are not limited to: a ground-based electromagnetic radiation energy source and a space-based electromagnetic radiation energy source. Examples of such feedback receiving devices (e.g., feedback receiving devices 128) may include but are not limited to one or more of: one or more photovoltaic cells; one or more photodiodes; one or more heat engines; and one or more rectenna arrays.

As discussed above, when performing 1706 an alignment procedure based upon alignment feedback (e.g., feedback 234), energy acquisition and delivery process 300 may: initiate a location sweeping operation; receive feedback (e.g., feedback 234) from the electromagnetic radiation energy receiver (e.g., electromagnetic radiation energy receiver 200) at a defined point (e.g., defined point 238) within the location sweeping operation; reinitiate the location sweeping operation at the defined point (e.g., defined point 238); and receive updated feedback (e.g., feedback 234) from the electromagnetic radiation energy receiver (e.g., electromagnetic radiation energy receiver 200) at an updated point (e.g., updated point 240) within the location sweeping operation.

Specifically, energy acquisition and delivery process 300 may initiate a location sweeping operation that initiates at an initial point (e.g., initial point 236) and spirals outwardly away from the initial point (e.g., initial point 236), as shown in FIG. 15. Energy acquisition and delivery process 300 may receive feedback (e.g., feedback 234) from the electromagnetic radiation energy receiver (e.g., electromagnetic radiation energy receiver 200) at a defined point (e.g., defined point 238) within the location sweeping operation. Energy acquisition and delivery process 300 may then reinitiate the location sweeping operation at the defined point (e.g., defined point 238). Energy acquisition and delivery process 300 may then receive updated feedback (e.g., feedback 234) from the electromagnetic radiation energy receiver (e.g., electromagnetic radiation energy receiver 200) at an updated point (e.g., updated point 240) within the location sweeping operation.

As discussed above, energy acquisition and delivery process 300 may: repeatedly reinitiate the location sweeping operation until feedback (e.g., feedback 234) is received from the electromagnetic radiation energy receiver (e.g., electromagnetic radiation energy receiver 200) that identifies a point within the location sweeping operation that defines a peak return power, thus defining a location for the electromagnetic radiation energy receiver (e.g., electromagnetic radiation energy receiver 200).

Once aligned 1706, energy acquisition and delivery process 300 may distribute 1708 electrical energy extracted (e.g., received electrical energy 204) from the celestial energy beam (e.g., celestial energy beam 40) to the area in need (e.g., area in need 258) via a power distribution grid (e.g., power distribution grid 210) that is electrically coupled to the selected ground-based electromagnetic radiation energy receiver (e.g., electromagnetic radiation energy receiver 200).

### (22) Methodologies of Providing Power to a Remote Celestial Body-Based Receiver Via a Satellite Orbiting the Celestial Body.

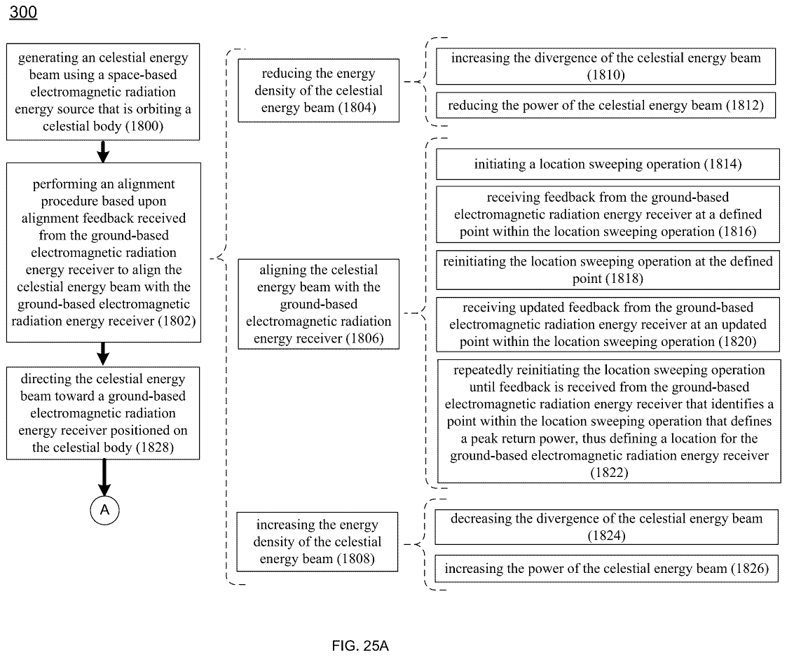

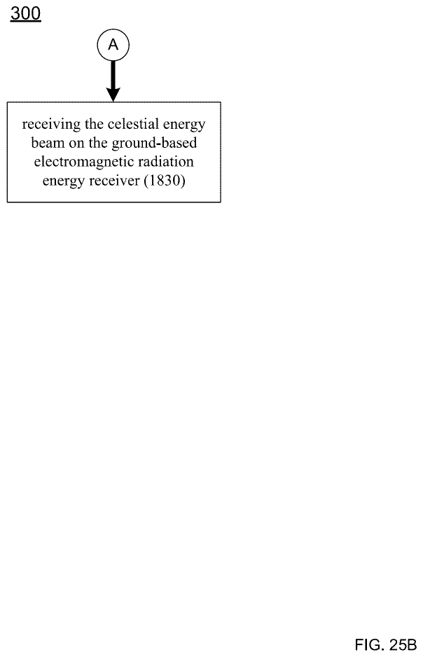

Referring also to FIGS. 25A-25B, the following discussion concerns the manner in which energy acquisition and delivery process 300 may provide electrical energy from a space-based electromagnetic radiation energy source to an electromagnetic radiation energy receiver located on a celestial body (e.g., a planet within our solar system, a moon within our solar system, an asteroid, or a distal celestial body).

Energy acquisition and delivery process 300 may generate 1800 an celestial energy beam (e.g., celestial energy beam 40) using a space-based electromagnetic radiation energy source (e.g., electromagnetic radiation energy source 38) that is orbiting a celestial body (e.g., celestial body 260). Celestial energy beams (e.g., celestial energy beam 40), such as laser or microwave beams, may be directed toward a variety of celestial bodies for numerous scientific, exploratory, or operational purposes, examples of which may include but are not limited to: a planet within our solar system, a moon within our solar system, an asteroid, or a distal celestial body

As discussed above and for generating 1800 a celestial energy beam (e.g., celestial energy beam 40), the electromagnetic radiation energy source (e.g., electromagnetic radiation energy source 38) may include: an energy beam source (e.g., energy beam source 100) for generating the celestial energy beam (e.g., celestial energy beam 40); a beam aiming assembly (e.g., beam aiming assembly 102) for steering the celestial energy beam (e.g., celestial energy beam 40) toward a target; and a beam forming package (e.g., beam forming package 104) for forming the celestial energy beam (e.g., celestial energy beam 40).

The energy beam source (e.g., energy beam source 100) for generating the celestial energy beam (e.g., celestial energy beam 40) may include one or more of: a visible-light laser beam source; an Infrared laser beam source; a short wavelength Infrared laser beam source, a mid-Infrared laser beam source; a near-Infrared laser beam source; and a microwave beam source.

The beam aiming assembly (e.g., beam aiming assembly 102) for steering the celestial energy beam (e.g., celestial energy beam 40) may include: a Gimbal mount assembly (e.g., Gimbal mount assembly 106) configured to direct the celestial energy beam (e.g., celestial energy beam 40) toward a target; a phased array assembly (e.g., phased array assembly 107) configured to direct the celestial energy beam (e.g., celestial energy beam 40) toward a target and/or a periscope assembly (e.g., periscope assembly 108) configured to direct the celestial energy beam (e.g., celestial energy beam 40) toward a target. A Gimbal mount assembly (e.g., Gimbal mount assembly 106), a phased array assembly (e.g., phased array assembly 107) and a periscope assembly (e.g., periscope assembly 108) can be effectively used in space-based energy systems to accurately direct a celestial energy beam (e.g., celestial energy beam 40), such as a laser or microwave beam, from a satellite (e.g., satellite 14) to a electromagnetic radiation energy receiver (e.g., electromagnetic radiation energy receiver 200).

The beam forming package (e.g., beam forming package 104) for forming the celestial energy beam (e.g., celestial energy beam 40) may include: collimating optics (e.g., collimating optics 110); and focusing optics (e.g., focusing optics 112). Collimating optics (e.g., collimating optics 110) are used to shape a celestial energy beam (e.g., celestial energy beam 40) so that its rays are parallel, resulting in a collimated beam i.e., one that doesn't spread out (diverge) significantly over distance. When a celestial energy beam (e.g., celestial energy beam 40) exits a source (e.g., energy beam source 100) like a diode, it typically diverges, meaning the beam spreads out as it travels.

Collimating optics (e.g., collimating optics 110), such as a lens or a lens system, are placed in the beam path to correct this divergence. By focusing the light emerging from a point-like or narrow source, collimating optics (e.g., collimating optics 110) create a beam with minimal angular spread. This is especially important for applications that require the beam to travel long distances (e.g., power transmission) or interact with precise optical components. In short, collimating optics (e.g., collimating optics 110) make a celestial energy beam (e.g., celestial energy beam 40) straighter and more focused over distance, improving its usability and efficiency in various optical systems.

Focusing optics (e.g., focusing optics 112) do the opposite of collimating optics (e.g., collimating optics 110), as they take a celestial energy beam (e.g., celestial energy beam 40) and converge it to a point or a small spot. This is usually achieved with lenses or curved mirrors that bend the incoming rays inward, concentrating the beam's energy into a smaller area. When a collimated or diverging celestial energy beam (e.g., celestial energy beam 40) passes through focusing optics (e.g., focusing optics 112), the optics manipulate the beam's path so that all rays come together at a focal point.

Energy acquisition and delivery process 300 may perform 1802 an alignment procedure based upon alignment feedback (e.g., feedback 234) received from the ground-based electromagnetic radiation energy receiver (e.g., electromagnetic radiation energy receiver 200) to align the celestial energy beam (e.g., celestial energy beam 40) with the ground-based electromagnetic radiation energy receiver (e.g., electromagnetic radiation energy receiver 200).

As discussed above, such feedback (e.g., feedback 234) may be received on feedback receiving devices (e.g., feedback receiving devices 128) included within electromagnetic radiation energy source 38. Examples of such feedback receiving devices (e.g., feedback receiving devices 128) may include but are not limited to one or more of: one or more photovoltaic cells; one or more photodiodes; one or more heat engines; and one or more rectenna arrays.

The alignment feedback (e.g., feedback 234) received on the electromagnetic radiation energy source (e.g., electromagnetic radiation energy source 38) may be generated via one or more feedback devices (e.g., feedback devices 226) included within the electromagnetic radiation energy receiver (e.g., electromagnetic radiation energy receiver 200).

As discussed above, the one or more feedback devices (e.g., feedback devices 226) included within the electromagnetic radiation energy receiver (e.g., electromagnetic radiation energy receiver 200) may include: a centrally-positioned feedback device within the electromagnetic radiation energy receiver (e.g., electromagnetic radiation energy receiver 200) and a plurality of peripherally-positioned feedback devices within the electromagnetic radiation energy receiver (e.g., electromagnetic radiation energy receiver 200).

At least one of the feedback devices (e.g., feedback devices 226) may be a retroreflector. As discussed above, a retroreflector is a specialized feedback device or surface that reflects incoming electromagnetic radiation (e.g., a portion of celestial energy beam 40) directly back toward its source (e.g., electromagnetic radiation energy source 38), regardless of the angle at which celestial energy beam 40 arrives. Unlike a standard mirror, which reflects light at an angle equal to the incident angle, a retroreflector returns celestial energy beam 40 along a near-exact path from which it came through geometric structures (e.g., corner cubes, cat's-eye lenses, or Bragg gratings).

As discussed above, the feedback devices (e.g., feedback devices 226) may include an RF component. Specifically, feedback devices 226 may include a plurality of opto-electrical sensors (e.g., photodiodes, photodetectors and/or photovoltaic cells). This plurality of sensors (e.g., feedback devices 226) may monitor the position of celestial energy beam 40, which is received on electromagnetic radiation energy receiver 200 from electromagnetic radiation energy source 38. This information concerning beam alignment (i.e., the manner in which celestial energy beam 40 is striking electromagnetic radiation energy receiver 200) may be provided to an RF transmitter (e.g., wireless communication system 332) that is included within/coupled to/available to electromagnetic radiation energy receiver 200 so that such information may be transmitted to the electromagnetic radiation energy source (e.g., electromagnetic radiation energy source 38). This information may then be used by electromagnetic radiation energy source 38 to reposition celestial energy beam 40 via beam aiming assembly 102 (if adjustment is needed).

When performing 1802 an alignment procedure based upon alignment feedback (e.g., feedback 234) received from the ground-based electromagnetic radiation energy receiver (e.g., electromagnetic radiation energy receiver 200) to align the celestial energy beam (e.g., celestial energy beam 40) with the ground-based electromagnetic radiation energy receiver (e.g., electromagnetic radiation energy receiver 200), energy acquisition and delivery process 300 may:
reduce 1804 the energy density of the celestial energy beam (e.g., celestial energy beam 40);
align 1806 the celestial energy beam (e.g., celestial energy beam 40) with the ground-based electromagnetic radiation energy receiver (e.g., electromagnetic radiation energy receiver 200); and
increase 1808 the energy density of the celestial energy beam (e.g., celestial energy beam 40).

When reducing 1804 the energy density of the celestial energy beam (e.g., celestial energy beam 40), energy acquisition and delivery process 300 may: increase 1810 the divergence of the celestial energy beam (e.g., celestial energy beam 40); and/or reduce 1812 the power of the celestial energy beam (e.g., celestial energy beam 40).

As discussed above, the energy density of a celestial energy beam (e.g., celestial energy beam 40) refers to the amount of energy delivered per unit area of the celestial energy beam (e.g., celestial energy beam 40). To reduce the energy density of celestial energy beam 40, two main strategies may be used: increasing the divergence of celestial energy beam 40 and/or reducing the power of celestial energy beam 40.

Increasing Divergency: Increasing 1810 the divergence of celestial energy beam 40 involves widening the beam as it travels through space. Such an increase may be effectuated via the beam forming package 104 within electromagnetic radiation energy source 38. A more divergent beam spreads its energy over a larger area, which decreases the energy concentration at any given point. Accordingly and even if the total power of the beam remains the same, the energy density of the beam will be reduced since the same amount of energy is distributed over a broader cross-sectional area.

Reducing Power: Reducing 1812 the power of celestial energy beam 40 involves lowering the total amount of energy being transmitted. Such a power reduction may be effectuated by decreasing the power supplied to energy beam source 100 within electromagnetic radiation energy source 38, thus resulting in a less powerful celestial energy beam 40. Since energy density is directly related to the beam's total power, a lower-power beam naturally results in less energy being concentrated in any given area of the celestial energy beam. For example, if the beam power is cut in half, the energy density will also be cut in half, assuming the beam size remains the same.

In practical terms, reducing energy density by these methods can improve safety helping to prevent damage to equipment, minimizing risk to nearby humans, aircraft or animals, and easing the thermal and structural load on receiving systems. It also allows for more manageable interception or redirection of the beam if necessary.

When aligning 1806 the celestial energy beam (e.g., celestial energy beam 40) with the ground-based electromagnetic radiation energy receiver (e.g., electromagnetic radiation energy receiver 200), energy acquisition and delivery process 300 may: initiate 1814 a location sweeping operation; receive 1816 feedback (e.g., feedback 234) from the ground-based electromagnetic radiation energy receiver (e.g., electromagnetic radiation energy receiver 200) at a defined point (e.g., defined point 238) within the location sweeping operation; reinitiate 1818 the location sweeping operation at the defined point (e.g., defined point 238); and receive 1820 updated feedback (e.g., feedback 234) from the ground-based electromagnetic radiation energy receiver (e.g., electromagnetic radiation energy receiver 200) at an updated point (e.g., updated point 240) within the location sweeping operation.

Energy acquisition and delivery process 300 may initiate 1814 a location sweeping operation. The location sweeping operation may include a sweeping operation that initiates at an initial point (e.g., initial point 236) and spirals outwardly away from the initial point (e.g., initial point 236), as shown in FIG. 15. Energy acquisition and delivery process 300 may receive 1816 feedback (e.g., feedback 234) from the electromagnetic radiation energy receiver (e.g., electromagnetic radiation energy receiver 200) at a defined point (e.g., defined point 238) within the location sweeping operation.

As discussed above, this feedback (e.g., feedback 234) may be generated via one or more feedback devices (e.g., feedback devices 226) included within the electromagnetic radiation energy receiver (e.g., electromagnetic radiation energy receiver 200).

Energy acquisition and delivery process 300 may reinitiate 1818 the location sweeping operation at the defined point (e.g., defined point 238). Energy acquisition and delivery process 300 may receive 1820 updated feedback (e.g., feedback 234) from the electromagnetic radiation energy receiver (e.g., electromagnetic radiation energy receiver 200) at an updated point (e.g., updated point 240) within the location sweeping operation.

When aligning 1806 the celestial energy beam (e.g., celestial energy beam 40) with the ground-based electromagnetic radiation energy receiver (e.g., electromagnetic radiation energy receiver 200), energy acquisition and delivery process 300 may: repeatedly reinitiate 1822 the location sweeping operation until feedback (e.g., feedback 234) is received from the ground-based electromagnetic radiation energy receiver (e.g., electromagnetic radiation energy receiver 200) that identifies a point within the location sweeping operation that defines a peak return power, thus defining a location for the ground-based electromagnetic radiation energy receiver (e.g., electromagnetic radiation energy receiver 200).

When increasing 1808 the energy density of the celestial energy beam (e.g., celestial energy beam 40), energy acquisition and delivery process 300 may: decrease 1824 the divergence of the celestial energy beam (e.g., celestial energy beam 40); and/or increase 1826 the power of the celestial energy beam (e.g., celestial energy beam 40).

As discussed above, the energy density of a celestial energy beam (e.g., celestial energy beam 40) refers to the amount of energy delivered per unit area of the celestial energy beam (e.g., celestial energy beam 40). To increase the energy density of celestial energy beam 40, two main strategies may be used: decreasing the divergence of celestial energy beam 40 and/or increasing the power of celestial energy beam 40.

Decreasing Divergence: Decreasing 1824 the divergence of celestial energy beam 40 involves narrowing the beam as it travels through space. Such a decrease may be effectuated via the beam forming package 104 within electromagnetic radiation energy source 38. A less divergent beam focuses its energy within a smaller area, which increases the energy concentration at any given point. Accordingly and even if the total power of the beam remains the same, the energy density of the beam will be increased since the same amount of energy is focused within a smaller cross-sectional area.

Increasing Power: Increasing 1826 the power of celestial energy beam 40 involves increasing the total amount of energy being transmitted. Such a power increase may be effectuated by increasing the power supplied to energy beam source 100 within electromagnetic radiation energy source 38, thus resulting in a more powerful celestial energy beam 40. Since energy density is directly related to the beam's total power, a higher-power beam naturally results in more energy being concentrated in any given area of the celestial energy beam. For example, if the beam power is doubled, the energy density will also be doubled, assuming the beam size remains the same.

Once aligned 1806, energy acquisition and delivery process 300 may direct 1828 the celestial energy beam (e.g., celestial energy beam 40) toward a ground-based electromagnetic radiation energy receiver (e.g., electromagnetic radiation energy receiver 200) positioned on the celestial body (e.g., celestial body 260).

Energy acquisition and delivery process 300 may receive 1830 the celestial energy beam (e.g., celestial energy beam 40) on the ground-based electromagnetic radiation energy receiver (e.g., electromagnetic radiation energy receiver 200). As discussed above, the electromagnetic radiation energy receiver (e.g., electromagnetic radiation energy receiver 200) may include one or more energy receiving devices (e.g., energy receiving devices 202). The electromagnetic radiation energy receiver (e.g., electromagnetic radiation energy receiver 200) may be configured to receive at least a portion of the celestial energy beam (e.g., celestial energy beam 40) on the one or more energy receiving devices (e.g., energy receiving devices 202) and generate received electrical energy (e.g., received electrical energy 204).

### (23) Methodologies of Providing Power to a Manmade Orbiting Object.

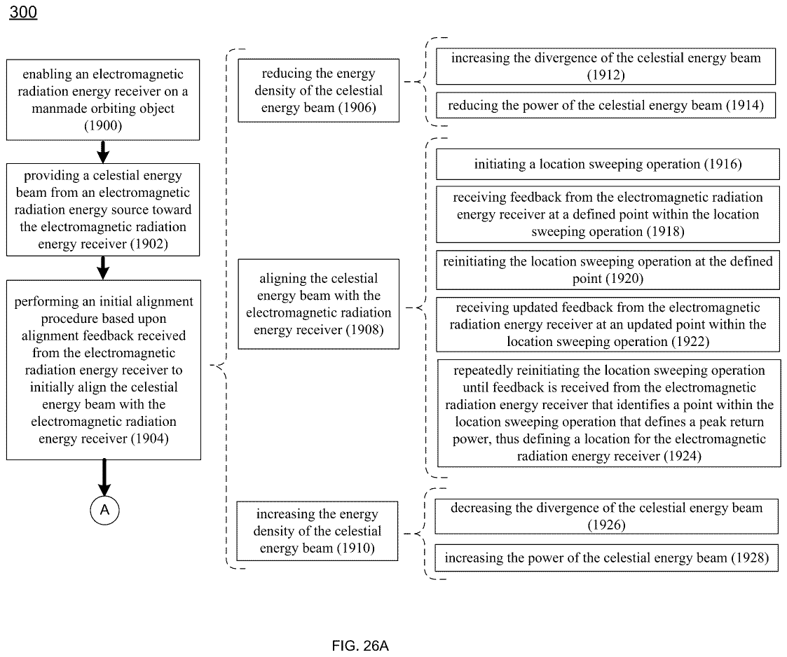

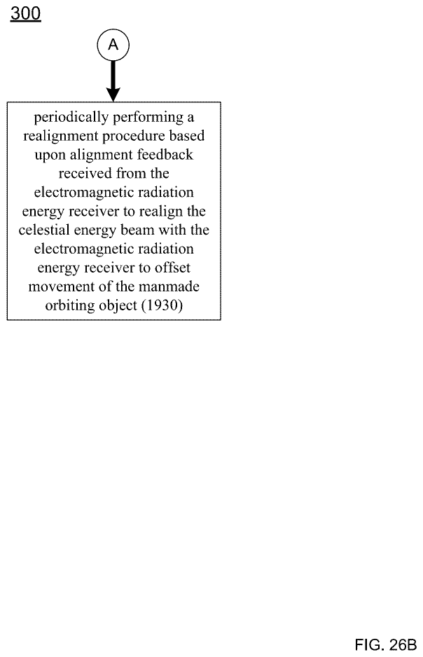

Referring also to FIGS. 26A-26B, the following discussion concerns the manner in which energy acquisition and delivery process 300 may provide electrical energy (in the form of a celestial energy beam) from an electromagnetic radiation energy source to a manmade orbiting object, examples of which may include but are not limited to orbiting spacecraft, such as satellites, space stations, and reflecting devices.

Energy acquisition and delivery process 300 may enable 1900 an electromagnetic radiation energy receiver (e.g., electromagnetic radiation energy receiver 200) on a manmade orbiting object (e.g., manmade orbiting object 260).

For example and when enabling 1900 an electromagnetic radiation energy receiver (e.g., electromagnetic radiation energy receiver 200) on a manmade orbiting object (e.g., manmade orbiting object 260), energy acquisition and delivery process 300 may energize and/or provide power to the electromagnetic radiation energy receiver (e.g., electromagnetic radiation energy receiver 200). For example, it is foreseeable that the manmade orbiting object (e.g., manmade orbiting object 260) would usually be powered by internal energy sources (such as internal batteries). Accordingly and during most operations, electromagnetic radiation energy receiver (e.g., electromagnetic radiation energy receiver 200) on the manmade orbiting object (e.g., manmade orbiting object 260) may be powered down. Additionally/alternatively and when enabling 1900 an electromagnetic radiation energy receiver (e.g., electromagnetic radiation energy receiver 200) on the manmade orbiting object (e.g., manmade orbiting object 260), the electromagnetic radiation energy receiver (e.g., electromagnetic radiation energy receiver 200) may be configured to receive a particular type of celestial energy beam, such as laser or microwave.

Once enabled 1900, energy acquisition and delivery process 300 may provide 1902 a celestial energy beam (e.g., celestial energy beam 40) from an electromagnetic radiation energy source (e.g., electromagnetic radiation energy source 38) toward the electromagnetic radiation energy receiver (e.g., electromagnetic radiation energy receiver 200).

As discussed above and for providing 1902 a celestial energy beam (e.g., celestial energy beam 40), the electromagnetic radiation energy source (e.g., electromagnetic radiation energy source 38) may include: an energy beam source (e.g., energy beam source 100) for generating the celestial energy beam (e.g., celestial energy beam 40); a beam aiming assembly (e.g., beam aiming assembly 102) for steering the celestial energy beam (e.g., celestial energy beam 40) toward a target; and a beam forming package (e.g., beam forming package 104) for forming the celestial energy beam (e.g., celestial energy beam 40).

The energy beam source (e.g., energy beam source 100) for generating the celestial energy beam (e.g., celestial energy beam 40) may include one or more of: a visible-light laser beam source; an Infrared laser beam source; a short wavelength Infrared laser beam source, a mid-Infrared laser beam source; a near-Infrared laser beam source; and a microwave beam source.

The beam aiming assembly (e.g., beam aiming assembly 102) for steering the celestial energy beam (e.g., celestial energy beam 40) may include: a Gimbal mount assembly (e.g., Gimbal mount assembly 106) configured to direct the celestial energy beam (e.g., celestial energy beam 40) toward a target; a phased array assembly (e.g., phased array assembly 107) configured to direct the celestial energy beam (e.g., celestial energy beam 40) toward a target and/or a periscope assembly (e.g., periscope assembly 108) configured to direct the celestial energy beam (e.g., celestial energy beam 40) toward a target. A Gimbal mount assembly (e.g., Gimbal mount assembly 106), a phased array assembly (e.g., phased array assembly 107) and a periscope assembly (e.g., periscope assembly 108) can be effectively used in space-based energy systems to accurately direct a celestial energy beam (e.g., celestial energy beam 40), such as a laser or microwave beam, from a satellite (e.g., satellite 14) to a electromagnetic radiation energy receiver (e.g., electromagnetic radiation energy receiver 200).

The beam forming package (e.g., beam forming package 104) for forming the celestial energy beam (e.g., celestial energy beam 40) may include: collimating optics (e.g., collimating optics 110); and focusing optics (e.g., focusing optics 112). Collimating optics (e.g., collimating optics 110) are used to shape a celestial energy beam (e.g., celestial energy beam 40) so that its rays are parallel, resulting in a collimated beam i.e., one that doesn't spread out (diverge) significantly over distance. When a celestial energy beam (e.g., celestial energy beam 40) exits a source (e.g., energy beam source 100) like a diode, it typically diverges, meaning the beam spreads out as it travels.

Collimating optics (e.g., collimating optics 110), such as a lens or a lens system, are placed in the beam path to correct this divergence. By focusing the light emerging from a point-like or narrow source, collimating optics (e.g., collimating optics 110) create a beam with minimal angular spread. This is especially important for applications that require the beam to travel long distances (e.g., power transmission) or interact with precise optical components. In short, collimating optics (e.g., collimating optics 110) make a celestial energy beam (e.g., celestial energy beam 40) straighter and more focused over distance, improving its usability and efficiency in various optical systems.

Focusing optics (e.g., focusing optics 112) do the opposite of collimating optics (e.g., collimating optics 110), as they take a celestial energy beam (e.g., celestial energy beam 40) and converge it to a point or a small spot. This is usually achieved with lenses or curved mirrors that bend the incoming rays inward, concentrating the beam's energy into a smaller area. When a collimated or diverging celestial energy beam (e.g., celestial energy beam 40) passes through focusing optics (e.g., focusing optics 112), the optics manipulate the beam's path so that all rays come together at a focal point.

The celestial energy beam (e.g., celestial energy beam 40) provided to the electromagnetic radiation energy receiver (e.g., electromagnetic radiation energy receiver 200) on the manmade orbiting object (e.g., manmade orbiting object 260) may be transmitted from a space-based electromagnetic radiation energy source (e.g., electromagnetic radiation energy source 38) or a ground-based electromagnetic radiation energy source (e.g., electromagnetic radiation energy source 38G).

Energy acquisition and delivery process 300 may perform 1904 an initial alignment procedure based upon alignment feedback (e.g., feedback 234) received from the electromagnetic radiation energy receiver (e.g., electromagnetic radiation energy receiver 200) to initially align the celestial energy beam (e.g., celestial energy beam 40) with the electromagnetic radiation energy receiver (e.g., electromagnetic radiation energy receiver 200).

As discussed above, such feedback (e.g., feedback 234) may be received on feedback receiving devices (e.g., feedback receiving devices 128) included within electromagnetic radiation energy source 38. Examples of such feedback receiving devices (e.g., feedback receiving devices 128) may include but are not limited to one or more of: one or more photovoltaic cells; one or more photodiodes; one or more heat engines; and one or more rectenna arrays. Additionally/alternatively, such feedback may be optical in nature so that the celestial energy beam (e.g., celestial energy beam 40) is tracked via reflection or radiative emittance (e.g., via images by a camera with a large zoom lens/telescope).

The alignment feedback (e.g., feedback 234) received on the electromagnetic radiation energy source (e.g., electromagnetic radiation energy source 38) may be generated via one or more feedback devices (e.g., feedback devices 226) included within the electromagnetic radiation energy receiver (e.g., electromagnetic radiation energy receiver 200).

As discussed above, the one or more feedback devices (e.g., feedback devices 226) included within the electromagnetic radiation energy receiver (e.g., electromagnetic radiation energy receiver 200) may include: a centrally-positioned feedback device within the electromagnetic radiation energy receiver (e.g., electromagnetic radiation energy receiver 200) and a plurality of peripherally-positioned feedback devices within the electromagnetic radiation energy receiver (e.g., electromagnetic radiation energy receiver 200).

At least one of the feedback devices (e.g., feedback devices 226) may be a retroreflector. As discussed above, a retroreflector is a specialized feedback device or surface that reflects incoming electromagnetic radiation (e.g., a portion of celestial energy beam 40) directly back toward its source (e.g., electromagnetic radiation energy source 38), regardless of the angle at which celestial energy beam 40 arrives. Unlike a standard mirror, which reflects light at an angle equal to the incident angle, a retroreflector returns celestial energy beam 40 along a near-exact path from which it came through geometric structures (e.g., corner cubes, cat's-eye lenses, or Bragg gratings).

As discussed above, the feedback devices (e.g., feedback devices 226) may include an RF component. Specifically, feedback devices 226 may include a plurality of opto-electrical sensors (e.g., photodiodes, photodetectors and/or photovoltaic cells). This plurality of sensors (e.g., feedback devices 226) may monitor the position of celestial energy beam 40, which is received on electromagnetic radiation energy receiver 200 from electromagnetic radiation energy source 38. This information concerning beam alignment (i.e., the manner in which celestial energy beam 40 is striking electromagnetic radiation energy receiver 200) may be provided to an RF transmitter (e.g., wireless communication system 332) that is included within/coupled to/available to electromagnetic radiation energy receiver 200 so that such information may be transmitted to the electromagnetic radiation energy source (e.g., electromagnetic radiation energy source 38). This information may then be used by electromagnetic radiation energy source 38 to reposition celestial energy beam 40 via beam aiming assembly 102 (if adjustment is needed).

When performing 1904 an initial alignment procedure based upon alignment feedback (e.g., feedback 234) received from the electromagnetic radiation energy receiver (e.g., electromagnetic radiation energy receiver 200) to initially align the celestial energy beam (e.g., celestial energy beam 40) with the electromagnetic radiation energy receiver (e.g., electromagnetic radiation energy receiver 200), energy acquisition and delivery process 300 may:
reduce 1906 the energy density of the celestial energy beam (e.g., celestial energy beam 40);
align 1908 the celestial energy beam (e.g., celestial energy beam 40) with the electromagnetic radiation energy receiver (e.g., electromagnetic radiation energy receiver 200); and
increase 1910 the energy density of the celestial energy beam (e.g., celestial energy beam 40).

As discussed above, the energy density of a celestial energy beam (e.g., celestial energy beam 40) refers to the amount of energy delivered per unit area of the celestial energy beam (e.g., celestial energy beam 40). Also and as discussed above, when reducing 1906 the energy density of the celestial energy beam (e.g., celestial energy beam 40), energy acquisition and delivery process 300 may: increase 1912 the divergence of the celestial energy beam (e.g., celestial energy beam 40); and/or reduce 1914 the power of the celestial energy beam (e.g., celestial energy beam 40).

As stated above and when aligning 1908 the celestial energy beam (e.g., celestial energy beam 40) with the electromagnetic radiation energy receiver (e.g., electromagnetic radiation energy receiver 200), energy acquisition and delivery process 300 may: initiate 1916 a location sweeping operation; receive 1918 feedback (e.g., feedback 234) from the electromagnetic radiation energy receiver (e.g., electromagnetic radiation energy receiver 200) at a defined point (e.g., defined point 238) within the location sweeping operation; reinitiate 1920 the location sweeping operation at the defined point (e.g., defined point 238); and receive 1922 updated feedback (e.g., feedback 234) from the electromagnetic radiation energy receiver (e.g., electromagnetic radiation energy receiver 200) at an updated point (e.g., updated point 240) within the location sweeping operation.

As stated above and when aligning 1908 the celestial energy beam (e.g., celestial energy beam 40) with the electromagnetic radiation energy receiver (e.g., electromagnetic radiation energy receiver 200), energy acquisition and delivery process 300 may: repeatedly reinitiate 1924 the location sweeping operation until feedback (e.g., feedback 234) is received from the electromagnetic radiation energy receiver (e.g., electromagnetic radiation energy receiver 200) that identifies a point within the location sweeping operation that defines a peak return power, thus defining a location for the electromagnetic radiation energy receiver (e.g., electromagnetic radiation energy receiver 200).

As discussed above, when increasing 1910 the energy density of the celestial energy beam (e.g., celestial energy beam 40), energy acquisition and delivery process 300 may: decrease 1926 the divergence of the celestial energy beam (e.g., celestial energy beam 40); and/or increase 1928 the power of the celestial energy beam (e.g., celestial energy beam 40).

Energy acquisition and delivery process 300 may periodically perform 1930 a realignment procedure based upon alignment feedback (e.g., feedback 234) received from the electromagnetic radiation energy receiver (e.g., electromagnetic radiation energy receiver 200) to realign the celestial energy beam (e.g., celestial energy beam 40) with the electromagnetic radiation energy receiver (e.g., electromagnetic radiation energy receiver 200) to offset movement of the manmade orbiting object (e.g., manmade orbiting object 262).

(24) A Single Sided Method of Locking on a Receiver by Using a Wide Beam to Quickly Obtain a Feedback Signal that Precisely Locates the Receiver so the Beam can be Aimed and Narrowed.

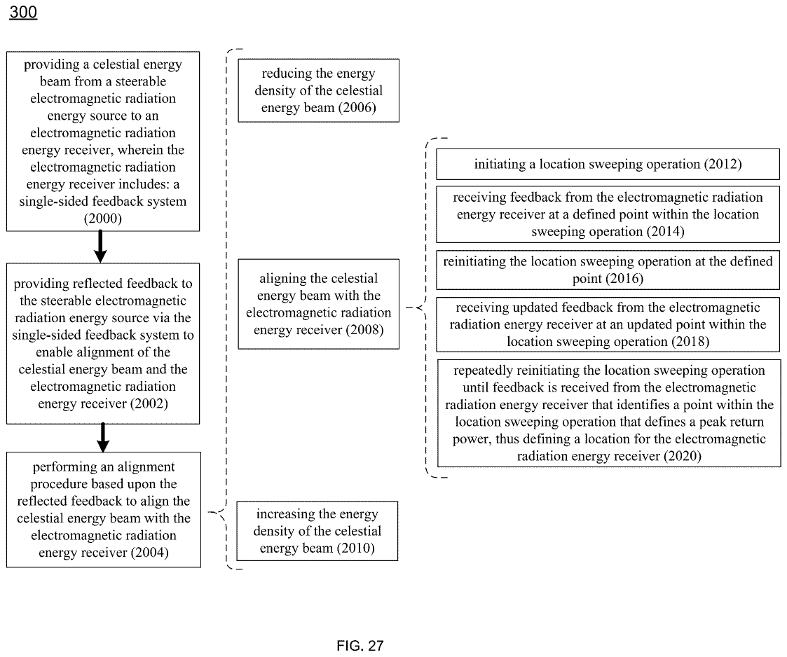

Referring also to FIG. 27, the following discussion concerns the manner in which energy acquisition and delivery process 300 may provide electrical energy (in the form of a celestial energy beam) from an electromagnetic radiation energy source to an electromagnetic radiation energy receiver that includes a single-sided feedback system that is used to align the energy source and the energy receiver.

Energy acquisition and delivery process 300 may provide 2000 a celestial energy beam (e.g., celestial energy beam 40) from a steerable electromagnetic radiation energy source (e.g., electromagnetic radiation energy source 38) to an electromagnetic radiation energy receiver (e.g., electromagnetic radiation energy receiver 200), wherein the electromagnetic radiation energy receiver (e.g., electromagnetic radiation energy receiver 200) includes: a single-sided feedback system (e.g., single-sided feedback system 264).

As discussed above and for providing 2000 a celestial energy beam (e.g., celestial energy beam 40), the electromagnetic radiation energy source (e.g., electromagnetic radiation energy source 38) may include: an energy beam source (e.g., energy beam source 100) for generating the celestial energy beam (e.g., celestial energy beam 40); a beam aiming assembly (e.g., beam aiming assembly 102) for steering the celestial energy beam (e.g., celestial energy beam 40) toward a target; and a beam forming package (e.g., beam forming package 104) for forming the celestial energy beam (e.g., celestial energy beam 40).

The energy beam source (e.g., energy beam source 100) for generating the celestial energy beam (e.g., celestial energy beam 40) may include one or more of: a visible-light laser beam source; an Infrared laser beam source; a short wavelength Infrared laser beam source, a mid-Infrared laser beam source; a near-Infrared laser beam source; and a microwave beam source.

The beam aiming assembly (e.g., beam aiming assembly 102) for steering the celestial energy beam (e.g., celestial energy beam 40) may include: a Gimbal mount assembly (e.g., Gimbal mount assembly 106) configured to direct the celestial energy beam (e.g., celestial energy beam 40) toward a target; a phased array assembly (e.g., phased array assembly 107) configured to direct the celestial energy beam (e.g., celestial energy beam 40) toward a target and/or a periscope assembly (e.g., periscope assembly 108) configured to direct the celestial energy beam (e.g., celestial energy beam 40) toward a target. A Gimbal mount assembly (e.g., Gimbal mount assembly 106), a phased array assembly (e.g., phased array assembly 107) and a periscope assembly (e.g., periscope assembly 108) can be effectively used in space-based energy systems to accurately direct a celestial energy beam (e.g., celestial energy beam 40), such as a laser or microwave beam, from a satellite (e.g., satellite 14) to a electromagnetic radiation energy receiver (e.g., electromagnetic radiation energy receiver 200).

The beam forming package (e.g., beam forming package 104) for forming the celestial energy beam (e.g., celestial energy beam 40) may include: collimating optics (e.g., collimating optics 110); and focusing optics (e.g., focusing optics 112). Collimating optics (e.g., collimating optics 110) are used to shape a celestial energy beam (e.g., celestial energy beam 40) so that its rays are parallel, resulting in a collimated beam i.e., one that doesn't spread out (diverge) significantly over distance. When a celestial energy beam (e.g., celestial energy beam 40) exits a source (e.g., energy beam source 100) like a diode, it typically diverges, meaning the beam spreads out as it travels.

Collimating optics (e.g., collimating optics 110), such as a lens or a lens system, are placed in the beam path to correct this divergence. By focusing the light emerging from a point-like or narrow source, collimating optics (e.g., collimating optics 110) create a beam with minimal angular spread. This is especially important for applications that require the beam to travel long distances (e.g., power transmission) or interact with precise optical components. In short, collimating optics (e.g., collimating optics 110) make a celestial energy beam (e.g., celestial energy beam 40) straighter and more focused over distance, improving its usability and efficiency in various optical systems.

Focusing optics (e.g., focusing optics 112) do the opposite of collimating optics (e.g., collimating optics 110), as they take a celestial energy beam (e.g., celestial energy beam 40) and converge it to a point or a small spot. This is usually achieved with lenses or curved mirrors that bend the incoming rays inward, concentrating the beam's energy into a smaller area. When a collimated or diverging celestial energy beam (e.g., celestial energy beam 40) passes through focusing optics (e.g., focusing optics 112), the optics manipulate the beam's path so that all rays come together at a focal point.

Energy acquisition and delivery process 300 may provide 2002 feedback (e.g., feedback 234) to the steerable electromagnetic radiation energy source (e.g., electromagnetic radiation energy source 38) via the single-sided feedback system (e.g., single-sided feedback system 264) to enable alignment of the celestial energy beam (e.g., celestial energy beam 40) and the electromagnetic radiation energy receiver (e.g., electromagnetic radiation energy receiver 200).

The single-sided feedback system (e.g., single-sided feedback system 264) may include one or more feedback devices (e.g., feedback devices 226), wherein the one or more feedback devices (e.g., feedback devices 226) may include one or more of: a centrally-positioned feedback device; and a plurality of peripherally-positioned feedback devices.

At least one of the feedback devices (e.g., feedback devices 226) may be a retroreflector. As discussed above, a retroreflector is a specialized feedback device or surface that reflects incoming electromagnetic radiation (e.g., a portion of celestial energy beam 40) directly back toward its source (e.g., electromagnetic radiation energy source 38), regardless of the angle at which celestial energy beam 40 arrives. Unlike a standard mirror, which reflects light at an angle equal to the incident angle, a retroreflector returns celestial energy beam 40 along a near-exact path from which it came through geometric structures (e.g., corner cubes, cat's-eye lenses, or Bragg gratings).

As discussed above, the feedback devices (e.g., feedback devices 226) may include an RF component. Specifically, feedback devices 226 may include a plurality of opto-electrical sensors (e.g., photodiodes, photodetectors and/or photovoltaic cells). This plurality of sensors (e.g., feedback devices 226) may monitor the position of celestial energy beam 40, which is received on electromagnetic radiation energy receiver 200 from electromagnetic radiation energy source 38. This information concerning beam alignment (i.e., the manner in which celestial energy beam 40 is striking electromagnetic radiation energy receiver 200) may be provided to an RF transmitter (e.g., wireless communication system 332) that is included within/coupled to/available to electromagnetic radiation energy receiver 200 so that such information may be transmitted to the electromagnetic radiation energy source (e.g., electromagnetic radiation energy source 38). This information may then be used by electromagnetic radiation energy source 38 to reposition celestial energy beam 40 via beam aiming assembly 102 (if adjustment is needed).

The feedback (e.g., feedback 234) provided to the steerable electromagnetic radiation energy source (e.g., electromagnetic radiation energy source 38) may include a reflected portion of the celestial energy beam (e.g., celestial energy beam 40). For example, the feedback (e.g., feedback 234) provided to the steerable electromagnetic radiation energy source (e.g., electromagnetic radiation energy source 38) may be encoded to identify the electromagnetic radiation energy receiver (e.g., electromagnetic radiation energy receiver 200) and/or identify the one or more feedback devices (e.g., feedback devices 226).

As discussed above, the feedback devices (e.g., feedback devices 226) that are included within the single-sided feedback system (e.g., single-sided feedback system 264) may be modulated to encode data (e.g., the identity of the electromagnetic radiation energy receiver and/or the identity of the specific feedback devices) within the feedback (e.g., feedback 234) by dynamically altering how these feedback devices (e.g., feedback devices 226) reflect incoming electromagnetic energy (e.g., celestial energy beam 40) over time. This encoding may be accomplished by modulating the intensity, phase, polarization, or timing of the reflected signal (e.g., feedback 234) in a controlled way, with the changes representing the encoded information.

One common method to achieve such encoding is through the use of a modulating feedback device (e.g., a modulating retroreflector), where the feedback device may be paired with a system/actuator that rapidly changes the optical properties of the feedback device. Some methods of achieving such modulation may include but are not limited to:
Mechanical Modulation: A small shutter, MEMS (microelectromechanical system) device, or vibrating mirror may physically open and close or change orientation of the feedback device (e.g., one or more of feedback devices 226) to modulate how much light is reflected, wherein these open/closed states may represent encoded binary data.
Electro-Optical Modulation: Materials like liquid crystals or electro-optic polymers placed in front of the feedback device (e.g., one or more of feedback devices 226) may change their optical properties (such as transparency, refractive index, or polarization) when voltage is applied, allowing fast, electronic control of the reflected beam's characteristics to represent encoded binary data.
Acousto-Optic Modulation: Sound waves may be used to modulate the surface of the feedback device (e.g., one or more of feedback devices 226) or an optical material may be placed in front of the feedback device (e.g., one or more of feedback devices 226), altering the properties of the reflected beam to encode binary data.
Thermal or Phase Modulation: The surface temperature or refractive index of the feedback device (e.g., one or more of feedback devices 226) may be slightly altered to create phase shifts in the reflected beam, which may be used to encode binary data.

By modulating the reflection characteristics of the feedback devices (e.g., one or more of feedback devices 226) that are included within the single-sided feedback system (e.g., single-sided feedback system 264) in a precise, time-controlled manner, data (e.g., telemetry, identification signals, or communications) may be encoded within the reflected energy beam (e.g., feedback 234) without requiring the feedback device to generate its own signals.

Energy acquisition and delivery process 300 may perform 2004 an alignment procedure based upon the feedback (e.g., feedback 234) to align the celestial energy beam (e.g., celestial energy beam 40) with the electromagnetic radiation energy receiver (e.g., electromagnetic radiation energy receiver 200).

When performing 2004 an alignment procedure based upon the feedback (e.g., feedback 234) to align the celestial energy beam (e.g., celestial energy beam 40) with the electromagnetic radiation energy receiver (e.g., electromagnetic radiation energy receiver 200), energy acquisition and delivery process 300 may:
reduce 2006 the energy density of the celestial energy beam (e.g., celestial energy beam 40);
align 2008 the celestial energy beam (e.g., celestial energy beam 40) with the electromagnetic radiation energy receiver (e.g., electromagnetic radiation energy receiver 200); and
increase 2010 the energy density of the celestial energy beam (e.g., celestial energy beam 40).

As discussed above, the energy density of a celestial energy beam (e.g., celestial energy beam 40) refers to the amount of energy delivered per unit area of the celestial energy beam (e.g., celestial energy beam 40). Also and as discussed above, when reducing 2006 the energy density of the celestial energy beam (e.g., celestial energy beam 40), energy acquisition and delivery process 300 may: increase the divergence of the celestial energy beam (e.g., celestial energy beam 40); and/or reduce the power of the celestial energy beam (e.g., celestial energy beam 40).

As discussed above and when aligning 2008 the celestial energy beam (e.g., celestial energy beam 40) with the electromagnetic radiation energy receiver (e.g., electromagnetic radiation energy receiver 200), energy acquisition and delivery process 300 may: initiate 2012 a location sweeping operation; receive 2014 feedback (e.g., feedback 234) from the electromagnetic radiation energy receiver (e.g., electromagnetic radiation energy receiver 200) at a defined point (e.g., defined point 238) within the location sweeping operation; reinitiate 2016 the location sweeping operation at the defined point (e.g., defined point 238); receive 2018 updated feedback (e.g., feedback 234) from the electromagnetic radiation energy receiver (e.g., electromagnetic radiation energy receiver 200) at an updated point (e.g., updated point 240) within the location sweeping operation; and repeatedly reinitiate 2020 the location sweeping operation until feedback (e.g., feedback 234) is received from the electromagnetic radiation energy receiver (e.g., electromagnetic radiation energy receiver 200) that identifies a point within the location sweeping operation that defines a peak return power, thus defining a location for the electromagnetic radiation energy receiver (e.g., electromagnetic radiation energy receiver 200).

As discussed above, when increasing 2010 the energy density of the celestial energy beam (e.g., celestial energy beam 40), energy acquisition and delivery process 300 may: decrease the divergence of the celestial energy beam (e.g., celestial energy beam 40); and/or increase the power of the celestial energy beam (e.g., celestial energy beam 40).

(25) Methodologies of Storing Received Energy in the Ground-Based Distribution Component for Use when Solar Energy is not Available.

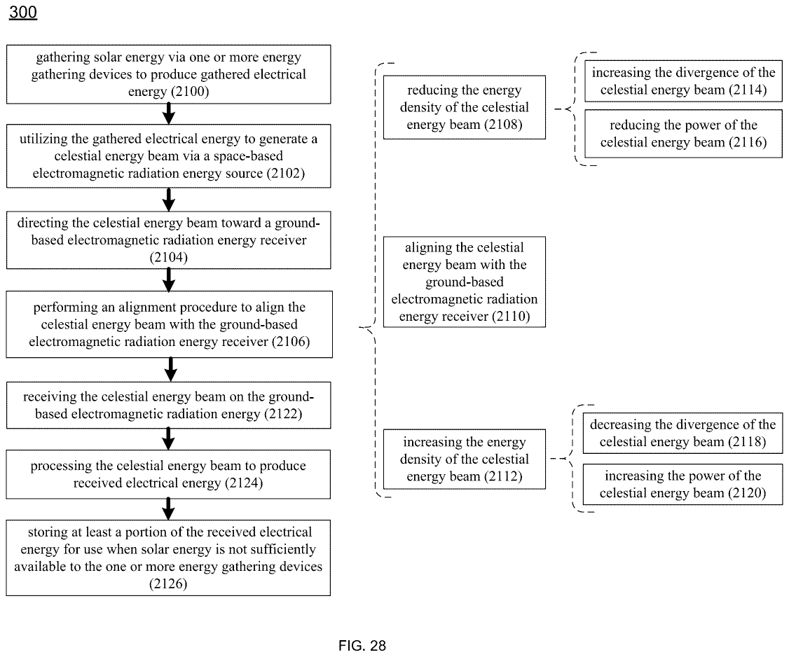

Referring also to FIG. 28, the following discussion concerns the manner in which energy acquisition and delivery process 300 may provide electrical energy (in the form of a celestial energy beam) from an electromagnetic radiation energy source to an electromagnetic radiation energy receiver that includes a storage system configured to store a portion of the received electrical energy.

Energy acquisition and delivery process 300 may gather 2100 solar energy (e.g., solar energy 20) via one or more energy gathering devices (e.g., energy gathering devices 18) to produce gathered electrical energy (e.g., gathered electrical energy 34). As discussed above, the one or more energy gathering devices may include one or more of: one or more photovoltaic cells; one or more photodiodes; one or more heat engines; and one or more rectenna arrays.

As discussed above, the solar energy gathering system (e.g., solar energy gathering system 12), which includes the one or more energy gathering devices (e.g., energy gathering devices 18), may include an electrical coupling system (e.g., electrical coupling system 36) configured to electrically couple the solar energy gathering system (e.g., solar energy gathering system 12) to an electromagnetic radiation energy source (e.g., electromagnetic radiation energy source 38) and enable the transfer of the gathered electrical energy (e.g., gathered electrical energy 34) to the electromagnetic radiation energy source (e.g., electromagnetic radiation energy source 38),

Energy acquisition and delivery process 300 may utilize 2102 the gathered electrical energy (e.g., gathered electrical energy 34) to generate a celestial energy beam (e.g., celestial energy beam 40) via a space-based electromagnetic radiation energy source (e.g., electromagnetic radiation energy source 38).

Energy acquisition and delivery process 300 may direct 2104 the celestial energy beam (e.g., celestial energy beam 40) toward a ground-based electromagnetic radiation energy receiver (e.g., electromagnetic radiation energy receiver 200).

As discussed above and for directing 2104 a celestial energy beam (e.g., celestial energy beam 40), the electromagnetic radiation energy source (e.g., electromagnetic radiation energy source 38) may include: an energy beam source (e.g., energy beam source 100) for generating the celestial energy beam (e.g., celestial energy beam 40); a beam aiming assembly (e.g., beam aiming assembly 102) for steering the celestial energy beam (e.g., celestial energy beam 40) toward a target; and a beam forming package (e.g., beam forming package 104) for forming the celestial energy beam (e.g., celestial energy beam 40).

The energy beam source (e.g., energy beam source 100) for generating the celestial energy beam (e.g., celestial energy beam 40) may include one or more of: a visible-light laser beam source; an Infrared laser beam source; a short wavelength Infrared laser beam source, a mid-Infrared laser beam source; a near-Infrared laser beam source; and a microwave beam source.

The beam aiming assembly (e.g., beam aiming assembly 102) for steering the celestial energy beam (e.g., celestial energy beam 40) may include: a Gimbal mount assembly (e.g., Gimbal mount assembly 106) configured to direct the celestial energy beam (e.g., celestial energy beam 40) toward a target; a phased array assembly (e.g., phased array assembly 107) configured to direct the celestial energy beam (e.g., celestial energy beam 40) toward a target and/or a periscope assembly (e.g., periscope assembly 108) configured to direct the celestial energy beam (e.g., celestial energy beam 40) toward a target. A Gimbal mount assembly (e.g., Gimbal mount assembly 106), a phased array assembly (e.g., phased array assembly 107) and a periscope assembly (e.g., periscope assembly 108) can be effectively used in space-based energy systems to accurately direct a celestial energy beam (e.g., celestial energy beam 40), such as a laser or microwave beam, from a satellite (e.g., satellite 14) to a electromagnetic radiation energy receiver (e.g., electromagnetic radiation energy receiver 200).

The beam forming package (e.g., beam forming package 104) for forming the celestial energy beam (e.g., celestial energy beam 40) may include: collimating optics (e.g., collimating optics 110); and focusing optics (e.g., focusing optics 112). Collimating optics (e.g., collimating optics 110) are used to shape a celestial energy beam (e.g., celestial energy beam 40) so that its rays are parallel, resulting in a collimated beam i.e., one that doesn't spread out (diverge) significantly over distance. When a celestial energy beam (e.g., celestial energy beam 40) exits a source (e.g., energy beam source 100) like a diode, it typically diverges, meaning the beam spreads out as it travels.

Collimating optics (e.g., collimating optics 110), such as a lens or a lens system, are placed in the beam path to correct this divergence. By focusing the light emerging from a point-like or narrow source, collimating optics (e.g., collimating optics 110) create a beam with minimal angular spread. This is especially important for applications that require the beam to travel long distances (e.g., power transmission) or interact with precise optical components. In short, collimating optics (e.g., collimating optics 110) make a celestial energy beam (e.g., celestial energy beam 40) straighter and more focused over distance, improving its usability and efficiency in various optical systems.

Focusing optics (e.g., focusing optics 112) do the opposite of collimating optics (e.g., collimating optics 110), as they take a celestial energy beam (e.g., celestial energy beam 40) and converge it to a point or a small spot. This is usually achieved with lenses or curved mirrors that bend the incoming rays inward, concentrating the beam's energy into a smaller area. When a collimated or diverging celestial energy beam (e.g., celestial energy beam 40) passes through focusing optics (e.g., focusing optics 112), the optics manipulate the beam's path so that all rays come together at a focal point.

Energy acquisition and delivery process 300 may perform 2106 an alignment procedure to align the celestial energy beam (e.g., celestial energy beam 40) with the ground-based electromagnetic radiation energy receiver (e.g., electromagnetic radiation energy receiver 200).

When performing 2106 an alignment procedure to align the celestial energy beam (e.g., celestial energy beam 40) with the ground-based electromagnetic radiation energy receiver (e.g., electromagnetic radiation energy receiver 200), energy acquisition and delivery process 300 may:
reduce 2108 the energy density of the celestial energy beam (e.g., celestial energy beam 40);
align 2110 the celestial energy beam (e.g., celestial energy beam 40) with the ground-based electromagnetic radiation energy receiver (e.g., electromagnetic radiation energy receiver 200), and
increase 2112 the energy density of the celestial energy beam (e.g., celestial energy beam 40).

As discussed above, the energy density of a celestial energy beam (e.g., celestial energy beam 40) refers to the amount of energy delivered per unit area of the celestial energy beam (e.g., celestial energy beam 40). Also and as discussed above, when reducing 2108 the energy density of the celestial energy beam (e.g., celestial energy beam 40), energy acquisition and delivery process 300 may: increase 2114 the divergence of the celestial energy beam (e.g., celestial energy beam 40); and/or reduce 2116 the power of the celestial energy beam (e.g., celestial energy beam 40).

As discussed above and when aligning 2110 the celestial energy beam (e.g., celestial energy beam 40) with the electromagnetic radiation energy receiver (e.g., electromagnetic radiation energy receiver 200), energy acquisition and delivery process 300 may: initiate a location sweeping operation; receive feedback (e.g., feedback 234) from the electromagnetic radiation energy receiver (e.g., electromagnetic radiation energy receiver 200) at a defined point (e.g., defined point 238) within the location sweeping operation; reinitiate the location sweeping operation at the defined point (e.g., defined point 238); receive updated feedback (e.g., feedback 234) from the electromagnetic radiation energy receiver (e.g., electromagnetic radiation energy receiver 200) at an updated point (e.g., updated point 240) within the location sweeping operation; and repeatedly reinitiate the location sweeping operation until feedback (e.g., feedback 234) is received from the electromagnetic radiation energy receiver (e.g., electromagnetic radiation energy receiver 200) that identifies a point within the location sweeping operation that defines a peak return power, thus defining a location for the electromagnetic radiation energy receiver (e.g., electromagnetic radiation energy receiver 200).

The electromagnetic radiation energy receiver (e.g., electromagnetic radiation energy receiver 200) includes: a single-sided feedback system (e.g., single-sided feedback system 264), wherein the single-sided feedback system (e.g., single-sided feedback system 264) may be configured to generate the feedback (e.g., feedback 234).

The single-sided feedback system (e.g., single-sided feedback system 264) may include one or more feedback devices (e.g., feedback devices 226), wherein the one or more feedback devices (e.g., feedback devices 226) may include one or more of: a centrally-positioned feedback device; and a plurality of peripherally-positioned feedback devices.

At least one of the feedback devices (e.g., feedback devices 226) may be a retroreflector. As discussed above, a retroreflector is a specialized feedback device or surface that reflects incoming electromagnetic radiation (e.g., a portion of celestial energy beam 40) directly back toward its source (e.g., electromagnetic radiation energy source 38), regardless of the angle at which celestial energy beam 40 arrives. Unlike a standard mirror, which reflects light at an angle equal to the incident angle, a retroreflector returns celestial energy beam 40 along a near-exact path from which it came through geometric structures (e.g., corner cubes, cat's-eye lenses, or Bragg gratings).

As discussed above, the feedback devices (e.g., feedback devices 226) may include an RF component. Specifically, feedback devices 226 may include a plurality of opto-electrical sensors (e.g., photodiodes, photodetectors and/or photovoltaic cells). This plurality of sensors (e.g., feedback devices 226) may monitor the position of celestial energy beam 40, which is received on electromagnetic radiation energy receiver 200 from electromagnetic radiation energy source 38. This information concerning beam alignment (i.e., the manner in which celestial energy beam 40 is striking electromagnetic radiation energy receiver 200) may be provided to an RF transmitter (e.g., wireless communication system 332) that is included within/coupled to/available to electromagnetic radiation energy receiver 200 so that such information may be transmitted to the electromagnetic radiation energy source (e.g., electromagnetic radiation energy source 38). This information may then be used by electromagnetic radiation energy source 38 to reposition celestial energy beam 40 via beam aiming assembly 102 (if adjustment is needed).

As discussed above, when increasing 2112 the energy density of the celestial energy beam (e.g., celestial energy beam 40), energy acquisition and delivery process 300 may: decrease 2118 the divergence of the celestial energy beam (e.g., celestial energy beam 40); and/or increase 2120 the power of the celestial energy beam (e.g., celestial energy beam 40).

Energy acquisition and delivery process 300 may receive 2122 the celestial energy beam (e.g., celestial energy beam 40) on the ground-based electromagnetic radiation energy receiver (e.g., electromagnetic radiation energy receiver 200) and process 2124 the celestial energy beam (e.g., celestial energy beam 40) to produce received electrical energy (e.g., received electrical energy 204).

As discussed above, the electromagnetic radiation energy receiver (e.g., electromagnetic radiation energy receiver 200) may include one or more energy receiving devices (e.g., energy receiving devices 202), wherein the electromagnetic radiation energy receiver (e.g., electromagnetic radiation energy receiver 200) may be configured to receive at least a portion of the celestial energy beam (e.g., celestial energy beam 40) on the one or more energy receiving devices (e.g., energy receiving devices 202) and generate received electrical energy (e.g., received electrical energy 204).

As discussed above, the electromagnetic radiation energy receiver (e.g., electromagnetic radiation energy receiver 200) may include: a received energy storage system (e.g., received energy storage system 212) configured to store at least a portion of the received electrical energy (e.g., received electrical energy 204) to enable distribution of the received electrical energy (e.g., received electrical energy 204) even when the celestial energy beam (e.g., celestial energy beam 40) is not being generated by the electromagnetic radiation energy source (e.g., electromagnetic radiation energy source 38).

Specifically, the received electrical energy (e.g., received electrical energy 204) is only generated if the solar energy (e.g., solar energy 20) striking the energy gathering devices (e.g., energy gathering devices 18) of solar energy gathering system 12 is sufficient to generate the gathered electrical energy (e.g., gathered electrical energy 34). And being this gathered electrical energy (e.g., gathered electrical energy 34) is utilized to generate the celestial energy beam (e.g., celestial energy beam 40), if the solar energy (e.g., solar energy 20) striking the energy gathering devices (e.g., energy gathering devices 18) is insufficient to generate such gathered electrical energy (e.g., gathered electrical energy 34), celestial energy beam 40 (and, therefore, received electrical energy 204) will not be generated.

Energy acquisition and delivery process 300 may store 2126 at least a portion of the received electrical energy (e.g., received electrical energy 204) for use when solar energy (e.g., solar energy 20) is not sufficiently available to the one or more energy gathering devices (e.g., energy gathering devices 18), wherein such received electrical energy (e.g., received electrical energy 204), or a portion thereof, may be stored on the received energy storage system (e.g., received energy storage system 212).

As discussed above, examples of such a received energy storage system (e.g., received energy storage system 212) may include but are not limited to:
Rechargeable Batteries: The most widely used energy storage systems are battery storage systems. Modern systems commonly use lithium-ion batteries because of their high energy density, long cycle life, and relatively low weight. Older systems often used nickel-cadmium (NiCd) or nickel-hydrogen (NiH₂) batteries, which offer excellent durability and tolerance to deep discharge but are heavier and less efficient than lithium-ion options.
Supercapacitors: Supercapacitors store energy electrostatically and are capable of rapid charge and discharge cycles. While they have lower energy density than batteries, they are highly effective for short-term power support, such as handling peak power loads or providing backup during power transitions. They are sometimes used in conjunction with rechargeable batteries for hybrid storage systems.
Flywheel Energy Storage Systems: Flywheels store energy mechanically by spinning a rotor at high speeds in a vacuum. This kinetic energy can be converted into electricity when needed. Flywheels offer high cycle life and fast response times. However, they have been studied for both power storage and attitude control.

As discussed above, the electromagnetic radiation energy receiver (e.g., electromagnetic radiation energy receiver 200) may include: an energy distribution system (e.g., energy distribution system 206) configured to enable distribution of the received electrical energy (e.g., received electrical energy 204) to various devices/systems.

(26) Methodologies of Storing Received Energy in the Space-Based Transmission Component for Use when Solar Energy is not Available.

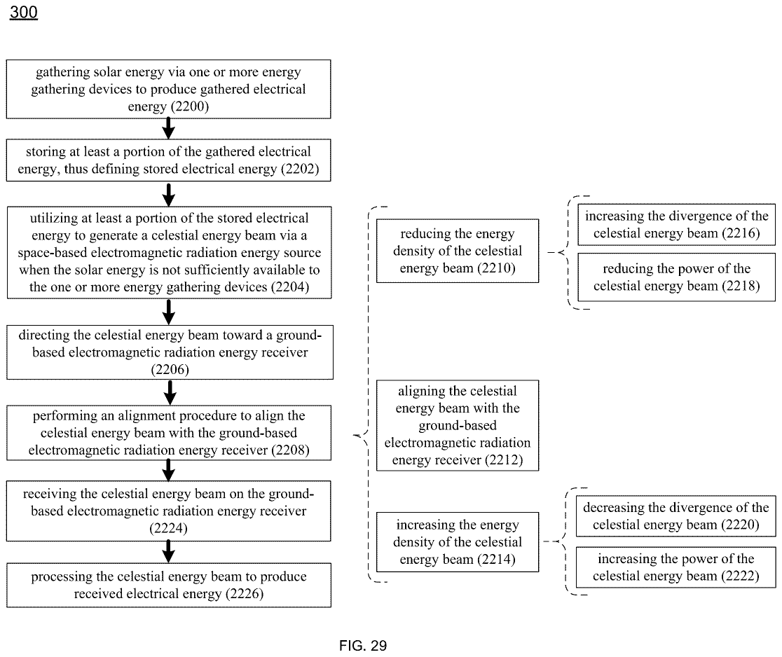

Referring also to FIG. 29, the following discussion concerns the manner in which energy acquisition and delivery process 300 may provide electrical energy (in the form of a celestial energy beam) to an electromagnetic radiation energy receiver from an electromagnetic radiation energy source that includes a storage system configured to store a portion of the electrical energy.

Energy acquisition and delivery process 300 may gather 2200 solar energy (e.g., solar energy 20) via one or more energy gathering devices (e.g., energy gathering devices 18) to produce gathered electrical energy (e.g., gathered electrical energy 34). As discussed above, the one or more energy gathering devices may include one or more of: one or more photovoltaic cells; one or more photodiodes; one or more heat engines; and one or more rectenna arrays.

As discussed above, the solar energy gathering system (e.g., solar energy gathering system 12), which includes the one or more energy gathering devices (e.g., energy gathering devices 18), may include an electrical coupling system (e.g., electrical coupling system 36) configured to electrically couple the solar energy gathering system (e.g., solar energy gathering system 12) to an electromagnetic radiation energy source (e.g., electromagnetic radiation energy source 38) and enable the transfer of the gathered electrical energy (e.g., gathered electrical energy 34) to the electromagnetic radiation energy source (e.g., electromagnetic radiation energy source 38),

As discussed above, the electromagnetic radiation energy source (e.g., electromagnetic radiation energy source 38) may include: a gathered energy storage system (e.g., gathered energy storage system 126) configured to store at least a portion of the gathered electrical energy (e.g., gathered electrical energy 34) to enable generation of the celestial energy beam (e.g., celestial energy beam 40) even when the solar energy (e.g., solar energy 20) is not sufficiently available. Specifically, the gathered electrical energy (e.g., gathered electrical energy 34) is only generated if the solar energy (e.g., solar energy 20) striking the energy gathering devices (e.g., energy gathering devices 18) is sufficient to generate such gathered electrical energy (e.g., gathered electrical energy 34). And being this gathered electrical energy (e.g., gathered electrical energy 34) is utilized to generate the celestial energy beam (e.g., celestial energy beam 40), if the solar energy (e.g., solar energy 20) striking the energy gathering devices (e.g., energy gathering devices 18) is insufficient to generate such gathered electrical energy (e.g., gathered electrical energy 34), the celestial energy beam (e.g., celestial energy beam 40) will not be generated. Accordingly, the gathered energy storage system (e.g., gathered energy storage system 126) may store at least a portion of the gathered electrical energy (e.g., gathered electrical energy 34) to enable generation of the celestial energy beam (e.g., celestial energy beam 40) even when the solar energy (e.g., solar energy 20) is not sufficiently available.

Examples of such a gathered energy storage system (e.g., gathered energy storage system 126) may include but are not limited to:
Rechargeable Batteries: The most widely used energy storage systems in satellites are battery storage systems. Modern satellites commonly use lithium-ion batteries because of their high energy density, long cycle life, and relatively low weight. Older systems often used nickel-cadmium (NiCd) or nickel-hydrogen (NiH₂) batteries, which offer excellent durability and tolerance to deep discharge but are heavier and less efficient than lithium-ion options.
Supercapacitors: Supercapacitors store energy electrostatically and are capable of rapid charge and discharge cycles. While they have lower energy density than batteries, they are highly effective for short-term power support, such as handling peak power loads or providing backup during power transitions. They are sometimes used in conjunction with rechargeable batteries for hybrid storage systems.
Flywheel Energy Storage Systems: Flywheels store energy mechanically by spinning a rotor at high speeds in a vacuum. This kinetic energy can be converted into electricity when needed. Flywheels offer high cycle life and fast response times, but they are more complex and less common in most modern satellites. However, they have been studied for both power storage and attitude control.

Accordingly and through the use of such a gathered energy storage system (e.g., gathered energy storage system 126). energy acquisition and delivery process 300 may store 2202 at least a portion of the gathered electrical energy (e.g., gathered electrical energy 34), thus defining stored electrical energy (e.g., stored electrical energy 132).

Energy acquisition and delivery process 300 may utilize 2204 at least a portion of the stored electrical energy (e.g., stored electrical energy 132) to generate a celestial energy beam (e.g., celestial energy beam 40) via a space-based electromagnetic radiation energy source (e.g., electromagnetic radiation energy source 38) when the solar energy (e.g., solar energy 20) is not sufficiently available to the one or more energy gathering devices (e.g., energy gathering devices 18).

Energy acquisition and delivery process 300 may direct 2206 the celestial energy beam (e.g., celestial energy beam 40) toward a ground-based electromagnetic radiation energy receiver (e.g., electromagnetic radiation energy receiver 200).

As discussed above and for directing 2206 a celestial energy beam (e.g., celestial energy beam 40), the electromagnetic radiation energy source (e.g., electromagnetic radiation energy source 38) may include: an energy beam source (e.g., energy beam source 100) for generating the celestial energy beam (e.g., celestial energy beam 40); a beam aiming assembly (e.g., beam aiming assembly 102) for steering the celestial energy beam (e.g., celestial energy beam 40) toward a target; and a beam forming package (e.g., beam forming package 104) for forming the celestial energy beam (e.g., celestial energy beam 40).

The energy beam source (e.g., energy beam source 100) for generating the celestial energy beam (e.g., celestial energy beam 40) may include one or more of: a visible-light laser beam source; an Infrared laser beam source; a short wavelength Infrared laser beam source, a mid-Infrared laser beam source; a near-Infrared laser beam source; and a microwave beam source.

The beam aiming assembly (e.g., beam aiming assembly 102) for steering the celestial energy beam (e.g., celestial energy beam 40) may include: a Gimbal mount assembly (e.g., Gimbal mount assembly 106) configured to direct the celestial energy beam (e.g., celestial energy beam 40) toward a target; a phased array assembly (e.g., phased array assembly 107) configured to direct the celestial energy beam (e.g., celestial energy beam 40) toward a target and/or a periscope assembly (e.g., periscope assembly 108) configured to direct the celestial energy beam (e.g., celestial energy beam 40) toward a target. A Gimbal mount assembly (e.g., Gimbal mount assembly 106), a phased array assembly (e.g., phased array assembly 107) and a periscope assembly (e.g., periscope assembly 108) can be effectively used in space-based energy systems to accurately direct a celestial energy beam (e.g., celestial energy beam 40), such as a laser or microwave beam, from a satellite (e.g., satellite 14) to a electromagnetic radiation energy receiver (e.g., electromagnetic radiation energy receiver 200).

The beam forming package (e.g., beam forming package 104) for forming the celestial energy beam (e.g., celestial energy beam 40) may include: collimating optics (e.g., collimating optics 110); and focusing optics (e.g., focusing optics 112). Collimating optics (e.g., collimating optics 110) are used to shape a celestial energy beam (e.g., celestial energy beam 40) so that its rays are parallel, resulting in a collimated beam i.e., one that doesn't spread out (diverge) significantly over distance. When a celestial energy beam (e.g., celestial energy beam 40) exits a source (e.g., energy beam source 100) like a diode, it typically diverges, meaning the beam spreads out as it travels.

Collimating optics (e.g., collimating optics 110), such as a lens or a lens system, are placed in the beam path to correct this divergence. By focusing the light emerging from a point-like or narrow source, collimating optics (e.g., collimating optics 110) create a beam with minimal angular spread. This is especially important for applications that require the beam to travel long distances (e.g., power transmission) or interact with precise optical components. In short, collimating optics (e.g., collimating optics 110) make a celestial energy beam (e.g., celestial energy beam 40) straighter and more focused over distance, improving its usability and efficiency in various optical systems.

Focusing optics (e.g., focusing optics 112) do the opposite of collimating optics (e.g., collimating optics 110), as they take a celestial energy beam (e.g., celestial energy beam 40) and converge it to a point or a small spot. This is usually achieved with lenses or curved mirrors that bend the incoming rays inward, concentrating the beam's energy into a smaller area. When a collimated or diverging celestial energy beam (e.g., celestial energy beam 40) passes through focusing optics (e.g., focusing optics 112), the optics manipulate the beam's path so that all rays come together at a focal point.

Energy acquisition and delivery process 300 may perform 2208 an alignment procedure to align the celestial energy beam (e.g., celestial energy beam 40) with the ground-based electromagnetic radiation energy receiver (e.g., electromagnetic radiation energy receiver 200).

When performing 2208 an alignment procedure to align the celestial energy beam (e.g., celestial energy beam 40) with the ground-based electromagnetic radiation energy receiver (e.g., electromagnetic radiation energy receiver 200), energy acquisition and delivery process 300 may:
reduce 2210 the energy density of the celestial energy beam (e.g., celestial energy beam 40);
align 2212 the celestial energy beam (e.g., celestial energy beam 40) with the ground-based electromagnetic radiation energy receiver (e.g., electromagnetic radiation energy receiver 200), and
increase 2214 the energy density of the celestial energy beam (e.g., celestial energy beam 40).

As discussed above, the energy density of a celestial energy beam (e.g., celestial energy beam 40) refers to the amount of energy delivered per unit area of the celestial energy beam (e.g., celestial energy beam 40). Also and as discussed above, when reducing 2210 the energy density of the celestial energy beam (e.g., celestial energy beam 40), energy acquisition and delivery process 300 may: increase 2216 the divergence of the celestial energy beam (e.g., celestial energy beam 40); and/or reduce 2218 the power of the celestial energy beam (e.g., celestial energy beam 40).

As discussed above and when aligning 2212 the celestial energy beam (e.g., celestial energy beam 40) with the electromagnetic radiation energy receiver (e.g., electromagnetic radiation energy receiver 200), energy acquisition and delivery process 300 may: initiate a location sweeping operation; receive feedback (e.g., feedback 234) from the electromagnetic radiation energy receiver (e.g., electromagnetic radiation energy receiver 200) at a defined point (e.g., defined point 238) within the location sweeping operation; reinitiate the location sweeping operation at the defined point (e.g., defined point 238); receive updated feedback (e.g., feedback 234) from the electromagnetic radiation energy receiver (e.g., electromagnetic radiation energy receiver 200) at an updated point (e.g., updated point 240) within the location sweeping operation; and repeatedly reinitiate the location sweeping operation until feedback (e.g., feedback 234) is received from the electromagnetic radiation energy receiver (e.g., electromagnetic radiation energy receiver 200) that identifies a point within the location sweeping operation that defines a peak return power, thus defining a location for the electromagnetic radiation energy receiver (e.g., electromagnetic radiation energy receiver 200).

The electromagnetic radiation energy receiver (e.g., electromagnetic radiation energy receiver 200) includes: a single-sided feedback system (e.g., single-sided feedback system 264), wherein the single-sided feedback system (e.g., single-sided feedback system 264) may be configured to generate the feedback (e.g., feedback 234).

The single-sided feedback system (e.g., single-sided feedback system 264) may include one or more feedback devices (e.g., feedback devices 226), wherein the one or more feedback devices (e.g., feedback devices 226) may include one or more of: a centrally-positioned feedback device; and a plurality of peripherally-positioned feedback devices.

At least one of the feedback devices (e.g., feedback devices 226) may be a retroreflector. As discussed above, a retroreflector is a specialized feedback device or surface that reflects incoming electromagnetic radiation (e.g., a portion of celestial energy beam 40) directly back toward its source (e.g., electromagnetic radiation energy source 38), regardless of the angle at which celestial energy beam 40 arrives. Unlike a standard mirror, which reflects light at an angle equal to the incident angle, a retroreflector returns celestial energy beam 40 along a near-exact path from which it came through geometric structures (e.g., corner cubes, cat's-eye lenses, or Bragg gratings).

As discussed above, the feedback devices (e.g., feedback devices 226) may include an RF component. Specifically, feedback devices 226 may include a plurality of opto-electrical sensors (e.g., photodiodes, photodetectors and/or photovoltaic cells). This plurality of sensors (e.g., feedback devices 226) may monitor the position of celestial energy beam 40, which is received on electromagnetic radiation energy receiver 200 from electromagnetic radiation energy source 38. This information concerning beam alignment (i.e., the manner in which celestial energy beam 40 is striking electromagnetic radiation energy receiver 200) may be provided to an RF transmitter (e.g., wireless communication system 332) that is included within/coupled to/available to electromagnetic radiation energy receiver 200 so that such information may be transmitted to the electromagnetic radiation energy source (e.g., electromagnetic radiation energy source 38). This information may then be used by electromagnetic radiation energy source 38 to reposition celestial energy beam 40 via beam aiming assembly 102 (if adjustment is needed).

As discussed above, when increasing 2214 the energy density of the celestial energy beam (e.g., celestial energy beam 40), energy acquisition and delivery process 300 may: decrease 2220 the divergence of the celestial energy beam (e.g., celestial energy beam 40); and/or increase 2222 the power of the celestial energy beam (e.g., celestial energy beam 40).

Energy acquisition and delivery process 300 may receive 2224 the celestial energy beam (e.g., celestial energy beam 40) on the ground-based electromagnetic radiation energy receiver (e.g., electromagnetic radiation energy receiver 200) and process 2226 the celestial energy beam (e.g., celestial energy beam 40) to produce received electrical energy.

As discussed above, the electromagnetic radiation energy receiver (e.g., electromagnetic radiation energy receiver 200) may include one or more energy receiving devices (e.g., energy receiving devices 202), wherein the electromagnetic radiation energy receiver (e.g., electromagnetic radiation energy receiver 200) may be configured to receive at least a portion of the celestial energy beam (e.g., celestial energy beam 40) on the one or more energy receiving devices (e.g., energy receiving devices 202) and generate received electrical energy (e.g., received electrical energy 204).

As discussed above, the electromagnetic radiation energy receiver (e.g., electromagnetic radiation energy receiver 200) may include: an energy distribution system (e.g., energy distribution system 206) configured to enable distribution of the received electrical energy (e.g., received electrical energy 204) to various devices/systems.

### (28) Methodologies of Inter-Satellite Electromagnetic Radiation-Based Power Transmission.

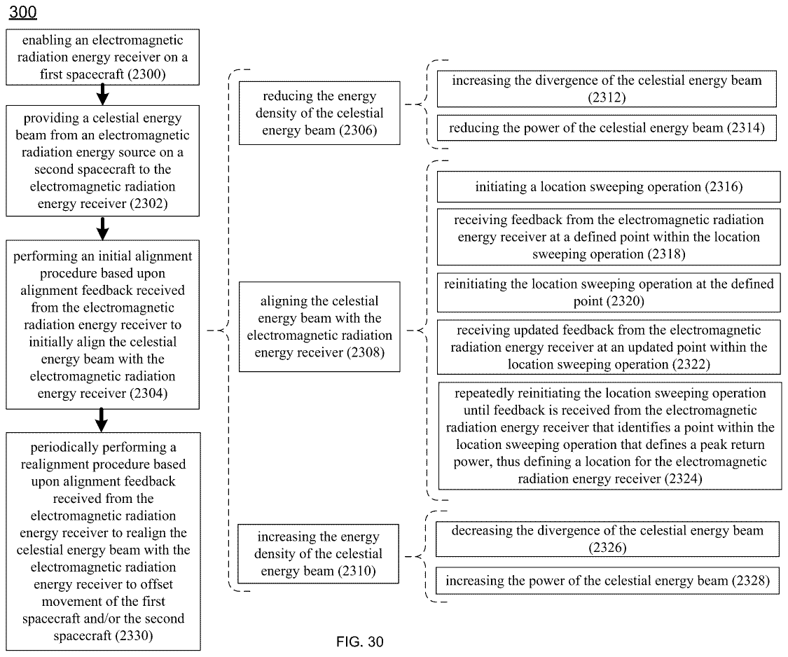

Referring also to FIG. 30, the following discussion concerns the manner in which energy acquisition and delivery process 300 may provide electrical energy (in the form of a celestial energy beam) from a space-based electromagnetic radiation energy source to a space-based electromagnetic radiation energy receiver.

Energy acquisition and delivery process 300 may enable 2300 an electromagnetic radiation energy receiver (e.g., electromagnetic radiation energy receiver 200) on a first spacecraft (e.g., first spacecraft 266). Examples of such a first spacecraft (e.g., first spacecraft 266) may include but are not limited to orbiting spacecraft, such as satellites, space stations, and reflecting devices.

For example and when enabling 2300 an electromagnetic radiation energy receiver (e.g., electromagnetic radiation energy receiver 200) on a first spacecraft (e.g., first spacecraft 266), energy acquisition and delivery process 300 may energize and/or provide power to the electromagnetic radiation energy receiver (e.g., electromagnetic radiation energy receiver 200). For example, it is foreseeable that the first spacecraft (e.g., first spacecraft 266) would usually be powered by internal energy sources (such as internal batteries). Accordingly and during most operations, electromagnetic radiation energy receiver (e.g., electromagnetic radiation energy receiver 200) on the first spacecraft (e.g., first spacecraft 266) may be powered down. Additionally/alternatively and when enabling 2300 an electromagnetic radiation energy receiver (e.g., electromagnetic radiation energy receiver 200) on the first spacecraft (e.g., first spacecraft 266), the electromagnetic radiation energy receiver (e.g., electromagnetic radiation energy receiver 200) may be configured to receive a particular type of celestial energy beam, such as laser or microwave.

Energy acquisition and delivery process 300 may provide 2302 a celestial energy beam (e.g., celestial energy beam 40) from an electromagnetic radiation energy source (e.g., electromagnetic radiation energy source 38) on a second spacecraft (e.g., satellite 14) to the electromagnetic radiation energy receiver (e.g., electromagnetic radiation energy receiver 200).

As discussed above and for providing 2302 a celestial energy beam (e.g., celestial energy beam 40), the electromagnetic radiation energy source (e.g., electromagnetic radiation energy source 38) may include: an energy beam source (e.g., energy beam source 100) for generating the celestial energy beam (e.g., celestial energy beam 40); a beam aiming assembly (e.g., beam aiming assembly 102) for steering the celestial energy beam (e.g., celestial energy beam 40) toward a target; and a beam forming package (e.g., beam forming package 104) for forming the celestial energy beam (e.g., celestial energy beam 40).

The energy beam source (e.g., energy beam source 100) for generating the celestial energy beam (e.g., celestial energy beam 40) may include one or more of: a visible-light laser beam source; an Infrared laser beam source; a short wavelength Infrared laser beam source, a mid-Infrared laser beam source; a near-Infrared laser beam source; and a microwave beam source.

The beam aiming assembly (e.g., beam aiming assembly 102) for steering the celestial energy beam (e.g., celestial energy beam 40) may include: a Gimbal mount assembly (e.g., Gimbal mount assembly 106) configured to direct the celestial energy beam (e.g., celestial energy beam 40) toward a target; a phased array assembly (e.g., phased array assembly 107) configured to direct the celestial energy beam (e.g., celestial energy beam 40) toward a target and/or a periscope assembly (e.g., periscope assembly 108) configured to direct the celestial energy beam (e.g., celestial energy beam 40) toward a target. A Gimbal mount assembly (e.g., Gimbal mount assembly 106), a phased array assembly (e.g., phased array assembly 107) and a periscope assembly (e.g., periscope assembly 108) can be effectively used in space-based energy systems to accurately direct a celestial energy beam (e.g., celestial energy beam 40), such as a laser or microwave beam, from a satellite (e.g., satellite 14) to a electromagnetic radiation energy receiver (e.g., electromagnetic radiation energy receiver 200).

The beam forming package (e.g., beam forming package 104) for forming the celestial energy beam (e.g., celestial energy beam 40) may include: collimating optics (e.g., collimating optics 110); and focusing optics (e.g., focusing optics 112). Collimating optics (e.g., collimating optics 110) are used to shape a celestial energy beam (e.g., celestial energy beam 40) so that its rays are parallel, resulting in a collimated beam i.e., one that doesn't spread out (diverge) significantly over distance. When a celestial energy beam (e.g., celestial energy beam 40) exits a source (e.g., energy beam source 100) like a diode, it typically diverges, meaning the beam spreads out as it travels.

Collimating optics (e.g., collimating optics 110), such as a lens or a lens system, are placed in the beam path to correct this divergence. By focusing the light emerging from a point-like or narrow source, collimating optics (e.g., collimating optics 110) create a beam with minimal angular spread. This is especially important for applications that require the beam to travel long distances (e.g., power transmission) or interact with precise optical components. In short, collimating optics (e.g., collimating optics 110) make a celestial energy beam (e.g., celestial energy beam 40) straighter and more focused over distance, improving its usability and efficiency in various optical systems.

Focusing optics (e.g., focusing optics 112) do the opposite of collimating optics (e.g., collimating optics 110), as they take a celestial energy beam (e.g., celestial energy beam 40) and converge it to a point or a small spot. This is usually achieved with lenses or curved mirrors that bend the incoming rays inward, concentrating the beam's energy into a smaller area. When a collimated or diverging celestial energy beam (e.g., celestial energy beam 40) passes through focusing optics (e.g., focusing optics 112), the optics manipulate the beam's path so that all rays come together at a focal point.

Energy acquisition and delivery process 300 may perform 2304 an initial alignment procedure based upon alignment feedback (e.g., feedback 234) received from the electromagnetic radiation energy receiver (e.g., electromagnetic radiation energy receiver 200) to initially align the celestial energy beam (e.g., celestial energy beam 40) with the electromagnetic radiation energy receiver (e.g., electromagnetic radiation energy receiver 200).

As discussed above, such feedback (e.g., feedback 234) may be received on feedback receiving devices (e.g., feedback receiving devices 128) included within electromagnetic radiation energy source 38. Examples of such feedback receiving devices (e.g., feedback receiving devices 128) may include but are not limited to one or more of: one or more photovoltaic cells; one or more photodiodes; one or more heat engines; and one or more rectenna arrays.

The alignment feedback (e.g., feedback 234) received on the electromagnetic radiation energy source (e.g., electromagnetic radiation energy source 38) may be generated via one or more feedback devices (e.g., feedback devices 226) included within the electromagnetic radiation energy receiver (e.g., electromagnetic radiation energy receiver 200).

As discussed above, the one or more feedback devices (e.g., feedback devices 226) included within the electromagnetic radiation energy receiver (e.g., electromagnetic radiation energy receiver 200) may include: a centrally-positioned feedback device within the electromagnetic radiation energy receiver (e.g., electromagnetic radiation energy receiver 200) and a plurality of peripherally-positioned feedback devices within the electromagnetic radiation energy receiver (e.g., electromagnetic radiation energy receiver 200).

At least one of the feedback devices (e.g., feedback devices 226) may be a retroreflector. As discussed above, a retroreflector is a specialized feedback device or surface that reflects incoming electromagnetic radiation (e.g., a portion of celestial energy beam 40) directly back toward its source (e.g., electromagnetic radiation energy source 38), regardless of the angle at which celestial energy beam 40 arrives. Unlike a standard mirror, which reflects light at an angle equal to the incident angle, a retroreflector returns celestial energy beam 40 along a near-exact path from which it came through geometric structures (e.g., corner cubes, cat's-eye lenses, or Bragg gratings).

As discussed above, the feedback devices (e.g., feedback devices 226) may include an RF component. Specifically, feedback devices 226 may include a plurality of opto-electrical sensors (e.g., photodiodes, photodetectors and/or photovoltaic cells). This plurality of sensors (e.g., feedback devices 226) may monitor the position of celestial energy beam 40, which is received on electromagnetic radiation energy receiver 200 from electromagnetic radiation energy source 38. This information concerning beam alignment (i.e., the manner in which celestial energy beam 40 is striking electromagnetic radiation energy receiver 200) may be provided to an RF transmitter (e.g., wireless communication system 332) that is included within/coupled to/available to electromagnetic radiation energy receiver 200 so that such information may be transmitted to the electromagnetic radiation energy source (e.g., electromagnetic radiation energy source 38). This information may then be used by electromagnetic radiation energy source 38 to reposition celestial energy beam 40 via beam aiming assembly 102 (if adjustment is needed).

When performing 2304 an initial alignment procedure based upon alignment feedback (e.g., feedback 234) received from the electromagnetic radiation energy receiver (e.g., electromagnetic radiation energy receiver 200) to initially align the celestial energy beam (e.g., celestial energy beam 40) with the electromagnetic radiation energy receiver (e.g., electromagnetic radiation energy receiver 200), energy acquisition and delivery process 300 may:
reduce 2306 the energy density of the celestial energy beam (e.g., celestial energy beam 40);
align 2308 the celestial energy beam (e.g., celestial energy beam 40) with the electromagnetic radiation energy receiver (e.g., electromagnetic radiation energy receiver 200); and
increase 2310 the energy density of the celestial energy beam (e.g., celestial energy beam 40).

As discussed above, the energy density of a celestial energy beam (e.g., celestial energy beam 40) refers to the amount of energy delivered per unit area of the celestial energy beam (e.g., celestial energy beam 40). Also and as discussed above, when reducing 2306 the energy density of the celestial energy beam (e.g., celestial energy beam 40), energy acquisition and delivery process 300 may: increase 2312 the divergence of the celestial energy beam (e.g., celestial energy beam 40); and/or reduce 2314 the power of the celestial energy beam (e.g., celestial energy beam 40).

As stated above and when aligning 2308 the celestial energy beam (e.g., celestial energy beam 40) with the electromagnetic radiation energy receiver (e.g., electromagnetic radiation energy receiver 200), energy acquisition and delivery process 300 may: initiate 2316 a location sweeping operation; receive 2318 feedback (e.g., feedback 234) from the electromagnetic radiation energy receiver (e.g., electromagnetic radiation energy receiver 200) at a defined point (e.g., defined point 238) within the location sweeping operation; reinitiate 2320 the location sweeping operation at the defined point (e.g., defined point 238); and receive 2322 updated feedback (e.g., feedback 234) from the electromagnetic radiation energy receiver (e.g., electromagnetic radiation energy receiver 200) at an updated point (e.g., updated point 240) within the location sweeping operation.

As stated above and when aligning 2308 the celestial energy beam (e.g., celestial energy beam 40) with the electromagnetic radiation energy receiver (e.g., electromagnetic radiation energy receiver 200), energy acquisition and delivery process 300 may: repeatedly reinitiate 2324 the location sweeping operation until feedback (e.g., feedback 234) is received from the electromagnetic radiation energy receiver (e.g., electromagnetic radiation energy receiver 200) that identifies a point within the location sweeping operation that defines a peak return power, thus defining a location for the electromagnetic radiation energy receiver (e.g., electromagnetic radiation energy receiver 200).

As discussed above, when increasing 2310 the energy density of the celestial energy beam (e.g., celestial energy beam 40), energy acquisition and delivery process 300 may: decrease 2326 the divergence of the celestial energy beam (e.g., celestial energy beam 40); and/or increase 2328 the power of the celestial energy beam (e.g., celestial energy beam 40).

Energy acquisition and delivery process 300 may periodically perform 2330 a realignment procedure based upon alignment feedback (e.g., feedback 234) received from the electromagnetic radiation energy receiver (e.g., electromagnetic radiation energy receiver 200) to realign the celestial energy beam (e.g., celestial energy beam 40) with the electromagnetic radiation energy receiver (e.g., electromagnetic radiation energy receiver 200) to offset movement of the first spacecraft (e.g., first spacecraft 266) and/or the second spacecraft (e.g., satellite 14)

(29) Methodologies of Reflecting Sunlight Using a First Orbit Reflector Satellite to a Second Orbit Gathering Satellite that Beams the Power Down to an Earth-Based Receiver.

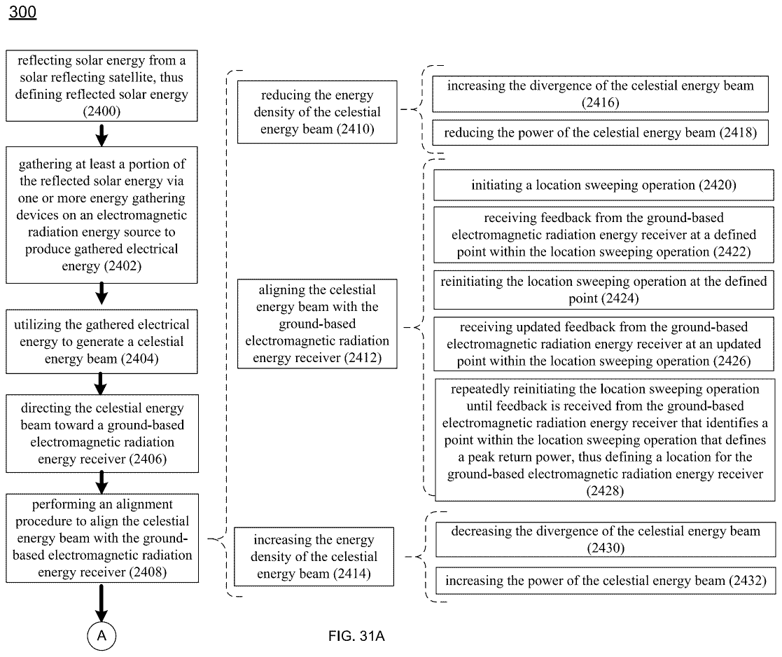

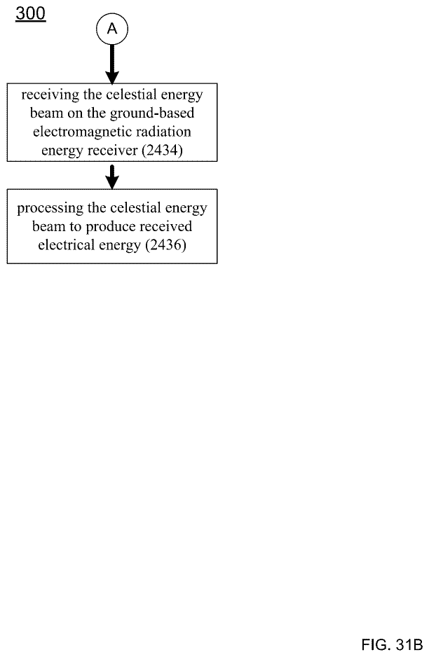

Referring also to FIGS. 31A-31B, the following discussion concerns the manner in which energy acquisition and delivery process 300 may reflect solar energy from a reflecting satellite in a first orbit to a space-based electromagnetic radiation energy source in a second orbit so that electrical energy (in the form of a celestial energy beam) may be provided to an electromagnetic radiation energy receiver.

Energy acquisition and delivery process 300 may reflect 2400 solar energy (e.g., solar energy 20) from a solar reflecting satellite (e.g., solar reflecting satellite 134), thus defining reflected solar energy (e.g., reflected solar energy 136).

Energy acquisition and delivery process 300 may gather 2402 at least a portion of the reflected solar energy (e.g., reflected solar energy 136) via one or more energy gathering devices (e.g., energy gathering devices 18) on an electromagnetic radiation energy source (e.g., electromagnetic radiation energy source 38) to produce gathered electrical energy (e.g., gathered electrical energy 34). As discussed above, the one or more energy gathering devices may include one or more of: one or more photovoltaic cells; one or more photodiodes; one or more heat engines; and one or more rectenna arrays.

Electromagnetic radiation energy source (e.g., electromagnetic radiation energy source 38) may be a portion of a spacecraft, examples of which may include but are not limited to satellite 14. Further, solar reflecting satellite (e.g., solar reflecting satellite 134) may be positioned within a different (e.g., higher) orbit than (in this example) satellite 14, enabling solar reflecting satellite 134 to receive and reflect solar energy 20 even if satellite 14 (which contains electromagnetic radiation energy source 38) is shrouded in darkness.

Energy acquisition and delivery process 300 may utilize 2404 the gathered electrical energy (e.g., gathered electrical energy 34) to generate a celestial energy beam (e.g., celestial energy beam 40) via a space-based electromagnetic radiation energy source (e.g., electromagnetic radiation energy source 38).

Energy acquisition and delivery process 300 may direct 2406 the celestial energy beam (e.g., celestial energy beam 40) toward a ground-based electromagnetic radiation energy receiver (e.g., electromagnetic radiation energy receiver 200).

As discussed above and for directing 2406 a celestial energy beam (e.g., celestial energy beam 40), the electromagnetic radiation energy source (e.g., electromagnetic radiation energy source 38) may include: an energy beam source (e.g., energy beam source 100) for generating the celestial energy beam (e.g., celestial energy beam 40); a beam aiming assembly (e.g., beam aiming assembly 102) for steering the celestial energy beam (e.g., celestial energy beam 40) toward a target; and a beam forming package (e.g., beam forming package 104) for forming the celestial energy beam (e.g., celestial energy beam 40).

The energy beam source (e.g., energy beam source 100) for generating the celestial energy beam (e.g., celestial energy beam 40) may include one or more of: a visible-light laser beam source; an Infrared laser beam source; a short wavelength Infrared laser beam source, a mid-Infrared laser beam source; a near-Infrared laser beam source; and a microwave beam source.

The beam aiming assembly (e.g., beam aiming assembly 102) for steering the celestial energy beam (e.g., celestial energy beam 40) may include: a Gimbal mount assembly (e.g., Gimbal mount assembly 106) configured to direct the celestial energy beam (e.g., celestial energy beam 40) toward a target; a phased array assembly (e.g., phased array assembly 107) configured to direct the celestial energy beam (e.g., celestial energy beam 40) toward a target and/or a periscope assembly (e.g., periscope assembly 108) configured to direct the celestial energy beam (e.g., celestial energy beam 40) toward a target. A Gimbal mount assembly (e.g., Gimbal mount assembly 106), a phased array assembly (e.g., phased array assembly 107) and a periscope assembly (e.g., periscope assembly 108) can be effectively used in space-based energy systems to accurately direct a celestial energy beam (e.g., celestial energy beam 40), such as a laser or microwave beam, from a satellite (e.g., satellite 14) to a electromagnetic radiation energy receiver (e.g., electromagnetic radiation energy receiver 200).

The beam forming package (e.g., beam forming package 104) for forming the celestial energy beam (e.g., celestial energy beam 40) may include: collimating optics (e.g., collimating optics 110); and focusing optics (e.g., focusing optics 112). Collimating optics (e.g., collimating optics 110) are used to shape a celestial energy beam (e.g., celestial energy beam 40) so that its rays are parallel, resulting in a collimated beam i.e., one that doesn't spread out (diverge) significantly over distance. When a celestial energy beam (e.g., celestial energy beam 40) exits a source (e.g., energy beam source 100) like a diode, it typically diverges, meaning the beam spreads out as it travels.

Collimating optics (e.g., collimating optics 110), such as a lens or a lens system, are placed in the beam path to correct this divergence. By focusing the light emerging from a point-like or narrow source, collimating optics (e.g., collimating optics 110) create a beam with minimal angular spread. This is especially important for applications that require the beam to travel long distances (e.g., power transmission) or interact with precise optical components. In short, collimating optics (e.g., collimating optics 110) make a celestial energy beam (e.g., celestial energy beam 40) straighter and more focused over distance, improving its usability and efficiency in various optical systems.

Focusing optics (e.g., focusing optics 112) do the opposite of collimating optics (e.g., collimating optics 110), as they take a celestial energy beam (e.g., celestial energy beam 40) and converge it to a point or a small spot. This is usually achieved with lenses or curved mirrors that bend the incoming rays inward, concentrating the beam's energy into a smaller area. When a collimated or diverging celestial energy beam (e.g., celestial energy beam 40) passes through focusing optics (e.g., focusing optics 112), the optics manipulate the beam's path so that all rays come together at a focal point.

Energy acquisition and delivery process 300 may perform 2408 an alignment procedure to align the celestial energy beam (e.g., celestial energy beam 40) with the ground-based electromagnetic radiation energy receiver (e.g., electromagnetic radiation energy receiver 200). This alignment procedure may be based upon feedback (e.g., feedback 234) received from the electromagnetic radiation energy receiver (e.g., electromagnetic radiation energy receiver 200).

As discussed above, such feedback (e.g., feedback 234) may be received on feedback receiving devices (e.g., feedback receiving devices 128) included within electromagnetic radiation energy source 38. Examples of such feedback receiving devices (e.g., feedback receiving devices 128) may include but are not limited to one or more of: one or more photovoltaic cells; one or more photodiodes; one or more heat engines; and one or more rectenna arrays.

The electromagnetic radiation energy receiver (e.g., electromagnetic radiation energy receiver 200) includes: a single-sided feedback system (e.g., single-sided feedback system 264) configured to generate the feedback (e.g., feedback 234).

The single-sided feedback system (e.g., single-sided feedback system 264) may include one or more feedback devices (e.g., feedback devices 226), wherein the one or more feedback devices (e.g., feedback devices 226) may include one or more of: a centrally-positioned feedback device; and a plurality of peripherally-positioned feedback devices.

At least one of the feedback devices (e.g., feedback devices 226) may be a retroreflector. As discussed above, a retroreflector is a specialized feedback device or surface that reflects incoming electromagnetic radiation (e.g., a portion of celestial energy beam 40) directly back toward its source (e.g., electromagnetic radiation energy source 38), regardless of the angle at which celestial energy beam 40 arrives. Unlike a standard mirror, which reflects light at an angle equal to the incident angle, a retroreflector returns celestial energy beam 40 along a near-exact path from which it came through geometric structures (e.g., corner cubes, cat's-eye lenses, or Bragg gratings).

As discussed above, the feedback devices (e.g., feedback devices 226) may include an RF component. Specifically, feedback devices 226 may include a plurality of opto-electrical sensors (e.g., photodiodes, photodetectors and/or photovoltaic cells). This plurality of sensors (e.g., feedback devices 226) may monitor the position of celestial energy beam 40, which is received on electromagnetic radiation energy receiver 200 from electromagnetic radiation energy source 38. This information concerning beam alignment (i.e., the manner in which celestial energy beam 40 is striking electromagnetic radiation energy receiver 200) may be provided to an RF transmitter (e.g., wireless communication system 332) that is included within/coupled to/available to electromagnetic radiation energy receiver 200 so that such information may be transmitted to the electromagnetic radiation energy source (e.g., electromagnetic radiation energy source 38). This information may then be used by electromagnetic radiation energy source 38 to reposition celestial energy beam 40 via beam aiming assembly 102 (if adjustment is needed).

When performing 2408 an alignment procedure to align the celestial energy beam (e.g., celestial energy beam 40) with the ground-based electromagnetic radiation energy receiver (e.g., electromagnetic radiation energy receiver 200), energy acquisition and delivery process 300 may:
reduce 2410 the energy density of the celestial energy beam (e.g., celestial energy beam 40);
align 2412 the celestial energy beam (e.g., celestial energy beam 40) with the ground-based electromagnetic radiation energy receiver (e.g., electromagnetic radiation energy receiver 200); and
increase 2414 the energy density of the celestial energy beam (e.g., celestial energy beam 40).

As discussed above, the energy density of a celestial energy beam (e.g., celestial energy beam 40) refers to the amount of energy delivered per unit area of the celestial energy beam (e.g., celestial energy beam 40). Also and as discussed above, when reducing 2410 the energy density of the celestial energy beam (e.g., celestial energy beam 40), energy acquisition and delivery process 300 may: increase 2416 the divergence of the celestial energy beam (e.g., celestial energy beam 40); and/or reduce 2418 the power of the celestial energy beam (e.g., celestial energy beam 40).

When aligning 2412 the celestial energy beam (e.g., celestial energy beam 40) with the ground-based electromagnetic radiation energy receiver (e.g., electromagnetic radiation energy receiver 200), energy acquisition and delivery process 300 may:
initiate 2420 a location sweeping operation;
receive 2422 feedback (e.g., feedback 234) from the ground-based electromagnetic radiation energy receiver (e.g., electromagnetic radiation energy receiver 200) at a defined point (e.g., defined point 238) within the location sweeping operation;
reinitiate 2424 the location sweeping operation at the defined point (e.g., defined point 238);
receive 2426 updated feedback (e.g., feedback 234) from the ground-based electromagnetic radiation energy receiver (e.g., electromagnetic radiation energy receiver 200) at an updated point (e.g., updated point 240) within the location sweeping operation; and
repeatedly reinitiate 2428 the location sweeping operation until feedback (e.g., feedback 234) is received from the ground-based electromagnetic radiation energy receiver (e.g., electromagnetic radiation energy receiver 200) that identifies a point within the location sweeping operation that defines a peak return power, thus defining a location for the ground-based electromagnetic radiation energy receiver (e.g., electromagnetic radiation energy receiver 200).

As discussed above, when increasing 2414 the energy density of the celestial energy beam (e.g., celestial energy beam 40), energy acquisition and delivery process 300 may: decrease 2430 the divergence of the celestial energy beam (e.g., celestial energy beam 40); and/or increase 2432 the power of the celestial energy beam (e.g., celestial energy beam 40).

Energy acquisition and delivery process 300 may receive 2434 the celestial energy beam (e.g., celestial energy beam 40) on the ground-based electromagnetic radiation energy receiver (e.g., electromagnetic radiation energy receiver 200) and process 2436 the celestial energy beam (e.g., celestial energy beam 40) to produce received electrical energy (e.g., received electrical energy 204).

As discussed above, the electromagnetic radiation energy receiver (e.g., electromagnetic radiation energy receiver 200) may include one or more energy receiving devices (e.g., energy receiving devices 202), wherein the electromagnetic radiation energy receiver (e.g., electromagnetic radiation energy receiver 200) may be configured to receive at least a portion of the celestial energy beam (e.g., celestial energy beam 40) on the one or more energy receiving devices (e.g., energy receiving devices 202) and generate received electrical energy (e.g., received electrical energy 204).

As discussed above, the electromagnetic radiation energy receiver (e.g., electromagnetic radiation energy receiver 200) may include: an energy distribution system (e.g., energy distribution system 206) configured to enable distribution of the received electrical energy (e.g., received electrical energy 204) to various devices/systems.

(30) Methodologies for Simultaneously Receiving Electromagnetic Radiation-Based Energy from a Plurality of Space-Based Gathering Components (Multiple Optical Components).

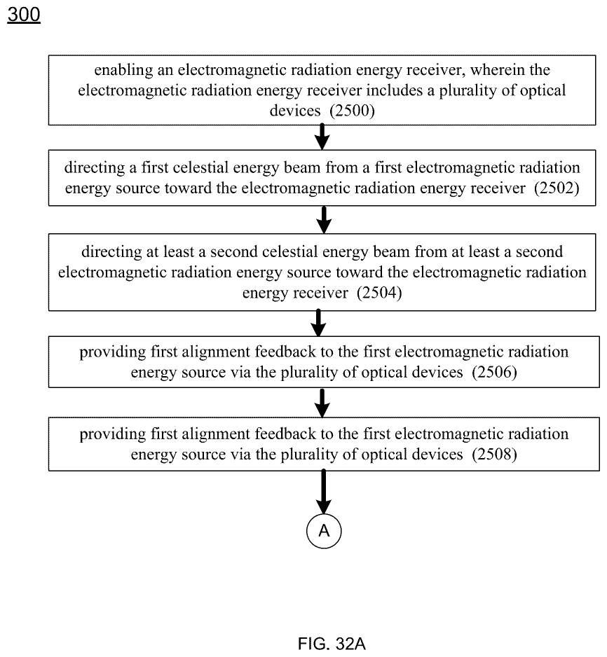

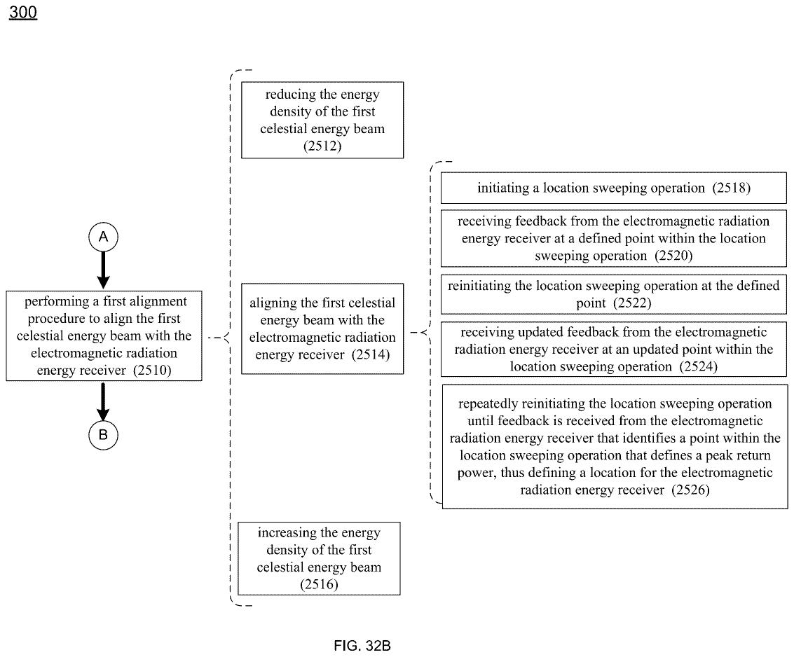

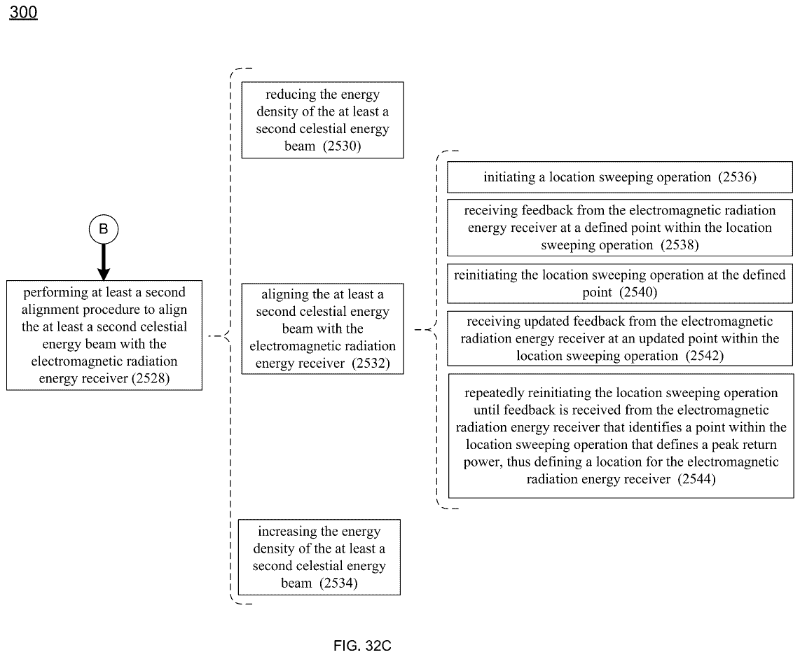

Referring also to FIGS. 32A-32C, the following discussion concerns the manner in which energy acquisition and delivery process 300 may provide electrical energy (in the form of multiple celestial energy beams) from multiple space-based electromagnetic radiation energy sources to a single electromagnetic radiation energy receiver that includes multiple optical components.

Energy acquisition and delivery process 300 may enable 2500 an electromagnetic radiation energy receiver (e.g., electromagnetic radiation energy receiver 200), wherein the electromagnetic radiation energy receiver (e.g., electromagnetic radiation energy receiver 200) includes a plurality of feedback devices (e.g., feedback devices 226).

For example and when enabling 2500 an electromagnetic radiation energy receiver (e.g., electromagnetic radiation energy receiver 200), energy acquisition and delivery process 300 may energize and/or provide power to the electromagnetic radiation energy receiver (e.g., electromagnetic radiation energy receiver 200). For example, it is foreseeable that the electromagnetic radiation energy receiver (e.g., electromagnetic radiation energy receiver 200) may be powered down until it is needed. Additionally/alternatively and when enabling 2500 an electromagnetic radiation energy receiver (e.g., electromagnetic radiation energy receiver 200), the electromagnetic radiation energy receiver (e.g., electromagnetic radiation energy receiver 200) may be configured to receive a particular type of celestial energy beam, such as laser or microwave.

Energy acquisition and delivery process 300 may direct 2502 a first celestial energy beam (e.g., celestial energy beam 40) from a first electromagnetic radiation energy source (e.g., electromagnetic radiation energy source 38) toward the electromagnetic radiation energy receiver (e.g., electromagnetic radiation energy receiver 200).

As discussed above and for directing 2502 a celestial energy beam (e.g., celestial energy beam 40), the electromagnetic radiation energy source (e.g., electromagnetic radiation energy source 38) may include: an energy beam source (e.g., energy beam source 100) for generating the celestial energy beam (e.g., celestial energy beam 40); a beam aiming assembly (e.g., beam aiming assembly 102) for steering the celestial energy beam (e.g., celestial energy beam 40) toward a target; and a beam forming package (e.g., beam forming package 104) for forming the celestial energy beam (e.g., celestial energy beam 40).

The energy beam source (e.g., energy beam source 100) for generating the celestial energy beam (e.g., celestial energy beam 40) may include one or more of: a visible-light laser beam source; an Infrared laser beam source; a short wavelength Infrared laser beam source, a mid-Infrared laser beam source; a near-Infrared laser beam source; and a microwave beam source.

The beam aiming assembly (e.g., beam aiming assembly 102) for steering the celestial energy beam (e.g., celestial energy beam 40) may include: a Gimbal mount assembly (e.g., Gimbal mount assembly 106) configured to direct the celestial energy beam (e.g., celestial energy beam 40) toward a target; a phased array assembly (e.g., phased array assembly 107) configured to direct the celestial energy beam (e.g., celestial energy beam 40) toward a target and/or a periscope assembly (e.g., periscope assembly 108) configured to direct the celestial energy beam (e.g., celestial energy beam 40) toward a target. A Gimbal mount assembly (e.g., Gimbal mount assembly 106), a phased array assembly (e.g., phased array assembly 107) and a periscope assembly (e.g., periscope assembly 108) can be effectively used in space-based energy systems to accurately direct a celestial energy beam (e.g., celestial energy beam 40), such as a laser or microwave beam, from a satellite (e.g., satellite 14) to a electromagnetic radiation energy receiver (e.g., electromagnetic radiation energy receiver 200).

The beam forming package (e.g., beam forming package 104) for forming the celestial energy beam (e.g., celestial energy beam 40) may include: collimating optics (e.g., collimating optics 110); and focusing optics (e.g., focusing optics 112). Collimating optics (e.g., collimating optics 110) are used to shape a celestial energy beam (e.g., celestial energy beam 40) so that its rays are parallel, resulting in a collimated beam i.e., one that doesn't spread out (diverge) significantly over distance. When a celestial energy beam (e.g., celestial energy beam 40) exits a source (e.g., energy beam source 100) like a diode, it typically diverges, meaning the beam spreads out as it travels.

Collimating optics (e.g., collimating optics 110), such as a lens or a lens system, are placed in the beam path to correct this divergence. By focusing the light emerging from a point-like or narrow source, collimating optics (e.g., collimating optics 110) create a beam with minimal angular spread. This is especially important for applications that require the beam to travel long distances (e.g., power transmission) or interact with precise optical components. In short, collimating optics (e.g., collimating optics 110) make a celestial energy beam (e.g., celestial energy beam 40) straighter and more focused over distance, improving its usability and efficiency in various optical systems.

Focusing optics (e.g., focusing optics 112) do the opposite of collimating optics (e.g., collimating optics 110), as they take a celestial energy beam (e.g., celestial energy beam 40) and converge it to a point or a small spot. This is usually achieved with lenses or curved mirrors that bend the incoming rays inward, concentrating the beam's energy into a smaller area. When a collimated or diverging celestial energy beam (e.g., celestial energy beam 40) passes through focusing optics (e.g., focusing optics 112), the optics manipulate the beam's path so that all rays come together at a focal point.

Additionally, energy acquisition and delivery process 300 may also direct 2504 at least a second celestial energy beam (e.g., celestial energy beam 40A) from at least a second electromagnetic radiation energy source (e.g., electromagnetic radiation energy source 38A) toward the electromagnetic radiation energy receiver (e.g., electromagnetic radiation energy receiver 200).

As discussed above and for directing 2504 a celestial energy beam (e.g., celestial energy beam 40A), the electromagnetic radiation energy source (e.g., electromagnetic radiation energy source 38A) may include: an energy beam source (e.g., energy beam source 100) for generating the celestial energy beam (e.g., celestial energy beam 40A); a beam aiming assembly (e.g., beam aiming assembly 102) for steering the celestial energy beam (e.g., celestial energy beam 40A) toward a target; and a beam forming package (e.g., beam forming package 104) for forming the celestial energy beam (e.g., celestial energy beam 40A).

The energy beam source (e.g., energy beam source 100) for generating the celestial energy beam (e.g., celestial energy beam 40A) may include one or more of: a visible-light laser beam source; an Infrared laser beam source; a short wavelength Infrared laser beam source, a mid-Infrared laser beam source; a near-Infrared laser beam source; and a microwave beam source.

The beam aiming assembly (e.g., beam aiming assembly 102) for steering the celestial energy beam (e.g., celestial energy beam 40A) may include: a Gimbal mount assembly (e.g., Gimbal mount assembly 106) configured to direct the celestial energy beam (e.g., celestial energy beam 40A) toward a target; a phased array assembly (e.g., phased array assembly 107) configured to direct the celestial energy beam (e.g., celestial energy beam 40) toward a target and/or a periscope assembly (e.g., periscope assembly 108) configured to direct the celestial energy beam (e.g., celestial energy beam 40A) toward a target. A Gimbal mount assembly (e.g., Gimbal mount assembly 106), a phased array assembly (e.g., phased array assembly 107) and a periscope assembly (e.g., periscope assembly 108) can be effectively used in space-based energy systems to accurately direct a celestial energy beam (e.g., celestial energy beam 40A), such as a laser or microwave beam, from a satellite (e.g., satellite 14) to a electromagnetic radiation energy receiver (e.g., electromagnetic radiation energy receiver 200).

The beam forming package (e.g., beam forming package 104) for forming the celestial energy beam (e.g., celestial energy beam 40A) may include: collimating optics (e.g., collimating optics 110); and focusing optics (e.g., focusing optics 112). Collimating optics (e.g., collimating optics 110) are used to shape a celestial energy beam (e.g., celestial energy beam 40A) so that its rays are parallel, resulting in a collimated beam i.e., one that doesn't spread out (diverge) significantly over distance. When a celestial energy beam (e.g., celestial energy beam 40A) exits a source (e.g., energy beam source 100) like a diode, it typically diverges, meaning the beam spreads out as it travels.

Collimating optics (e.g., collimating optics 110), such as a lens or a lens system, are placed in the beam path to correct this divergence. By focusing the light emerging from a point-like or narrow source, collimating optics (e.g., collimating optics 110) create a beam with minimal angular spread. This is especially important for applications that require the beam to travel long distances (e.g., power transmission) or interact with precise optical components. In short, collimating optics (e.g., collimating optics 110) make a celestial energy beam (e.g., celestial energy beam 40A) straighter and more focused over distance, improving its usability and efficiency in various optical systems.

Focusing optics (e.g., focusing optics 112) do the opposite of collimating optics (e.g., collimating optics 110), as they take a celestial energy beam (e.g., celestial energy beam 40A) and converge it to a point or a small spot. This is usually achieved with lenses or curved mirrors that bend the incoming rays inward, concentrating the beam's energy into a smaller area. When a collimated or diverging celestial energy beam (e.g., celestial energy beam 40A) passes through focusing optics (e.g., focusing optics 112), the optics manipulate the beam's path so that all rays come together at a focal point.

Energy acquisition and delivery process 300 may provide 2506 first alignment feedback (e.g., feedback 234) to the first electromagnetic radiation energy source (e.g., electromagnetic radiation energy source 38) via the plurality of feedback devices (e.g., feedback devices 226).

As discussed above, such feedback (e.g., feedback 234) may be received on feedback receiving devices (e.g., feedback receiving devices 128) included within electromagnetic radiation energy source 38. Examples of such feedback receiving devices (e.g., feedback receiving devices 128) may include but are not limited to one or more of: one or more photovoltaic cells; one or more photodiodes; one or more heat engines; and one or more rectenna arrays.

As discussed above, the plurality of feedback devices (e.g., feedback devices 226) may include one or more of: a centrally-positioned feedback device; and a plurality of peripherally-positioned feedback devices. At least one of the feedback devices (e.g., feedback devices 226) may be a retroreflector. As discussed above, a retroreflector is a specialized feedback device or surface that reflects incoming electromagnetic radiation (e.g., a portion of celestial energy beam 40) directly back toward its source (e.g., electromagnetic radiation energy source 38), regardless of the angle at which celestial energy beam 40 arrives. Unlike a standard mirror, which reflects light at an angle equal to the incident angle, a retroreflector returns celestial energy beam 40 along a near-exact path from which it came through geometric structures (e.g., corner cubes, cat's-eye lenses, or Bragg gratings).

As discussed above, the feedback devices (e.g., feedback devices 226) may include an RF component. Specifically, feedback devices 226 may include a plurality of opto-electrical sensors (e.g., photodiodes, photodetectors and/or photovoltaic cells). This plurality of sensors (e.g., feedback devices 226) may monitor the position of celestial energy beam 40, which is received on electromagnetic radiation energy receiver 200 from electromagnetic radiation energy source 38. This information concerning beam alignment (i.e., the manner in which celestial energy beam 40 is striking electromagnetic radiation energy receiver 200) may be provided to an RF transmitter (e.g., wireless communication system 332) that is included within/coupled to/available to electromagnetic radiation energy receiver 200 so that such information may be transmitted to the electromagnetic radiation energy source (e.g., electromagnetic radiation energy source 38). This information may then be used by electromagnetic radiation energy source 38 to reposition celestial energy beam 40 via beam aiming assembly 102 (if adjustment is needed).

Energy acquisition and delivery process 300 may provide 2508 at least second alignment feedback (e.g., feedback 234A) to the at least a second electromagnetic radiation energy source (e.g., electromagnetic radiation energy source 38A) via the plurality of feedback devices (e.g., feedback devices 226).

As discussed above, such feedback (e.g., feedback 234A) may be received on feedback receiving devices included within electromagnetic radiation energy source 38A. Examples of such feedback receiving devices may include but are not limited to one or more of: one or more photovoltaic cells; one or more photodiodes; one or more heat engines; and one or more rectenna arrays.

As discussed above, the plurality of feedback devices (e.g., feedback devices 226) may include one or more of: a centrally-positioned feedback device; and a plurality of peripherally-positioned feedback devices. At least one of the feedback devices (e.g., feedback devices 226) may be a retroreflector. As discussed above, a retroreflector is a specialized feedback device or surface that reflects incoming electromagnetic radiation (e.g., a portion of celestial energy beam 40) directly back toward its source (e.g., electromagnetic radiation energy source 38), regardless of the angle at which celestial energy beam 40 arrives. Unlike a standard mirror, which reflects light at an angle equal to the incident angle, a retroreflector returns celestial energy beam 40 along a near-exact path from which it came through geometric structures (e.g., corner cubes, cat's-eye lenses, or Bragg gratings).

As discussed above, the feedback devices (e.g., feedback devices 226) may include an RF component. Specifically, feedback devices 226 may include a plurality of opto-electrical sensors (e.g., photodiodes, photodetectors and/or photovoltaic cells). This plurality of sensors (e.g., feedback devices 226) may monitor the position of celestial energy beam 40, which is received on electromagnetic radiation energy receiver 200 from electromagnetic radiation energy source 38. This information concerning beam alignment (i.e., the manner in which celestial energy beam 40 is striking electromagnetic radiation energy receiver 200) may be provided to an RF transmitter (e.g., wireless communication system 332) that is included within/coupled to/available to electromagnetic radiation energy receiver 200 so that such information may be transmitted to the electromagnetic radiation energy source (e.g., electromagnetic radiation energy source 38). This information may then be used by electromagnetic radiation energy source 38 to reposition celestial energy beam 40 via beam aiming assembly 102 (if adjustment is needed).

Energy acquisition and delivery process 300 may perform 2510 a first alignment procedure to align the first celestial energy beam (e.g., celestial energy beam 40) with the electromagnetic radiation energy receiver (e.g., electromagnetic radiation energy receiver 200).

When performing 2510 a first alignment procedure to align the first celestial energy beam (e.g., celestial energy beam 40) with the electromagnetic radiation energy receiver (e.g., electromagnetic radiation energy receiver 200), energy acquisition and delivery process 300 may: reduce 2512 the energy density of the first celestial energy beam (e.g., celestial energy beam 40); align 2514 the first celestial energy beam (e.g., celestial energy beam 40) with the electromagnetic radiation energy receiver (e.g., electromagnetic radiation energy receiver 200); and increase 2516 the energy density of the first celestial energy beam (e.g., celestial energy beam 40).

As discussed above, the energy density of a celestial energy beam (e.g., celestial energy beam 40) refers to the amount of energy delivered per unit area of the celestial energy beam (e.g., celestial energy beam 40). Also and as discussed above, when reducing 2512 the energy density of the celestial energy beam (e.g., celestial energy beam 40), energy acquisition and delivery process 300 may: increase the divergence of the celestial energy beam (e.g., celestial energy beam 40); and/or reduce the power of the celestial energy beam (e.g., celestial energy beam 40).

When aligning 2514 the first celestial energy beam (e.g., celestial energy beam 40) with the electromagnetic radiation energy receiver (e.g., electromagnetic radiation energy receiver 200), energy acquisition and delivery process 300 may: initiate 2518 a location sweeping operation; receive 2520 feedback (e.g., feedback 234) from the electromagnetic radiation energy receiver (e.g., electromagnetic radiation energy receiver 200) at a defined point (e.g., defined point 238) within the location sweeping operation; reinitiate 2522 the location sweeping operation at the defined point (e.g., defined point 238); receive 2524 updated feedback (e.g., feedback 234) from the electromagnetic radiation energy receiver (e.g., electromagnetic radiation energy receiver 200) at an updated point (e.g., updated point 240) within the location sweeping operation; and repeatedly reinitiate 2526 the location sweeping operation until feedback (e.g., feedback 234) is received from the electromagnetic radiation energy receiver (e.g., electromagnetic radiation energy receiver 200) that identifies a point within the location sweeping operation that defines a peak return power, thus defining a location for the electromagnetic radiation energy receiver (e.g., electromagnetic radiation energy receiver 200).

As discussed above, when increasing 2516 the energy density of the celestial energy beam (e.g., celestial energy beam 40), energy acquisition and delivery process 300 may: decrease the divergence of the celestial energy beam (e.g., celestial energy beam 40); and/or increase the power of the celestial energy beam (e.g., celestial energy beam 40).

Energy acquisition and delivery process 300 may perform 2528 at least a second alignment procedure to align the at least a second celestial energy beam (e.g., celestial energy beam 40A) with the electromagnetic radiation energy receiver (e.g., electromagnetic radiation energy receiver 200).

When performing 2528 at least a second alignment procedure to align the at least a second celestial energy beam (e.g., celestial energy beam 40) with the electromagnetic radiation energy receiver (e.g., electromagnetic radiation energy receiver 200), energy acquisition and delivery process 300 may: reduce 2530 the energy density of the at least a second celestial energy beam (e.g., celestial energy beam 40); align 2532 the at least a second celestial energy beam (e.g., celestial energy beam 40) with the electromagnetic radiation energy receiver (e.g., electromagnetic radiation energy receiver 200); and increase 2534 the energy density of the at least a second celestial energy beam (e.g., celestial energy beam 40).

As discussed above, the energy density of a celestial energy beam (e.g., celestial energy beam 40) refers to the amount of energy delivered per unit area of the celestial energy beam (e.g., celestial energy beam 40). Also and as discussed above, when reducing 2530 the energy density of the celestial energy beam (e.g., celestial energy beam 40), energy acquisition and delivery process 300 may: increase the divergence of the celestial energy beam (e.g., celestial energy beam 40); and/or reduce the power of the celestial energy beam (e.g., celestial energy beam 40).

When aligning 2532 the at least a second celestial energy beam (e.g., celestial energy beam 40) with the electromagnetic radiation energy receiver (e.g., electromagnetic radiation energy receiver 200), energy acquisition and delivery process 300 may: initiate 2536 a location sweeping operation; receive 2538 feedback (e.g., feedback 234A) from the electromagnetic radiation energy receiver (e.g., electromagnetic radiation energy receiver 200) at a defined point (e.g., defined point 238) within the location sweeping operation; reinitiate 2540 the location sweeping operation at the defined point (e.g., defined point 238); receive 2542 updated feedback (e.g., feedback 234A) from the electromagnetic radiation energy receiver (e.g., electromagnetic radiation energy receiver 200) at an updated point (e.g., updated point 240) within the location sweeping operation; and repeatedly reinitiate 2544 the location sweeping operation until feedback (e.g., feedback 234A) is received from the electromagnetic radiation energy receiver (e.g., electromagnetic radiation energy receiver 200) that identifies a point within the location sweeping operation that defines a peak return power, thus defining a location for the electromagnetic radiation energy receiver (e.g., electromagnetic radiation energy receiver 200).

As discussed above, when increasing 2534 the energy density of the celestial energy beam (e.g., celestial energy beam 40), energy acquisition and delivery process 300 may: decrease the divergence of the celestial energy beam (e.g., celestial energy beam 40); and/or increase the power of the celestial energy beam (e.g., celestial energy beam 40).

The electromagnetic radiation energy receiver (e.g., electromagnetic radiation energy receiver 200) may include energy absorbing materials to prevent reflection of the first celestial energy beam (e.g., celestial energy beam 40) and/or the at least a second celestial energy beam (e.g., celestial energy beam 40A) onto undesired objects. As discussed above, the electromagnetic radiation energy receiver (e.g., electromagnetic radiation energy receiver 200) may include: an energy absorbing system (e.g., energy absorbing system 224) configured to absorb at least a portion of the celestial energy beam (e.g., celestial energy beams 40, 40A) within the security zone (e.g., security zone 214).

To safely manage and utilize the power delivered by celestial energy beams 40, 40A, whether in the form of laser or microwave radiation, energy absorbing system (e.g., energy absorbing system 224) may be employed. This system (e.g., energy absorbing system 224) is designed to dissipate incoming electromagnetic energy safely without damage. This energy absorbing system (e.g., energy absorbing system 224) may fall into two categories: energy absorbing coatings and energy absorbing structures, each tailored for the specific characteristics of celestial energy beam 40, 40A. For example, areas outside of the energy receiving devices 202 may be protected by energy absorbing system 224 so that electromagnetic radiation from celestial energy beams 40, 40A that does not strike energy receiving devices 202 will be safely absorbed/dissipated by energy absorbing system 224.

Energy Absorbing Coatings: Laser-absorbing coatings are engineered materials applied to surfaces to efficiently absorb specific laser wavelengths. These coatings typically consist of layers of carbon black, ceramic-metal composites (cermets), or dielectric materials designed for optical interference absorption. The energy absorbed is converted into heat, which can either be dissipated or redirected. For microwave energy, coatings known as RAM (Radar Absorbing Materials) may be used. These materials are composed of ferromagnetic particles or dielectric composites that absorb and attenuate incoming microwave radiation by converting it into heat through magnetic and electric losses.

Energy Absorbing Structures: Thermal absorbing structures may be used to absorb the electromagnetic energy included within celestial energy beam 40. These structures are made of materials with high thermal conductivity (e.g., graphite, tungsten, or ceramics) and are designed to absorb the beam's energy as heat. The heat can then be transferred to a heat engine to produce electricity or dissipated through radiator panels. Advanced absorbing structures may also employ metamaterials-engineered materials with unique electromagnetic properties that enable them to absorb specific frequencies with minimal reflection or transmission. These can be designed for either laser or microwave energy and offer high levels of energy absorption.

The role of energy absorbing system 224 is to prevent damage to sensitive equipment, surrounding infrastructure, humans and animals by absorbing and dissipating the electromagnetic radiation within celestial energy beam 40 that fails to strike energy receiving devices 202. By using purpose-built coatings and structural absorbers, celestial energy beam 40 may be harnessed effectively, safely, and reliably.

(31) Methodologies for Simultaneously Receiving Electromagnetic Radiation-Based Energy from a Plurality of Space-Based Gathering Components (Single Optical Component).

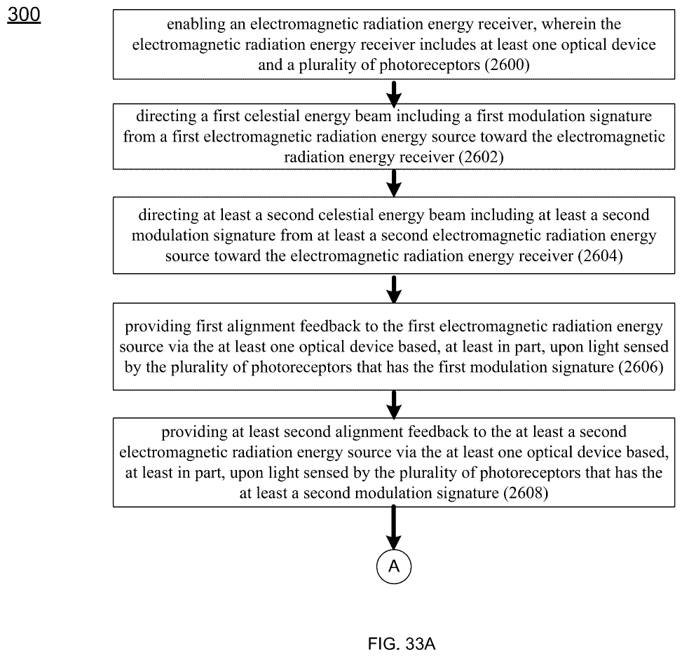

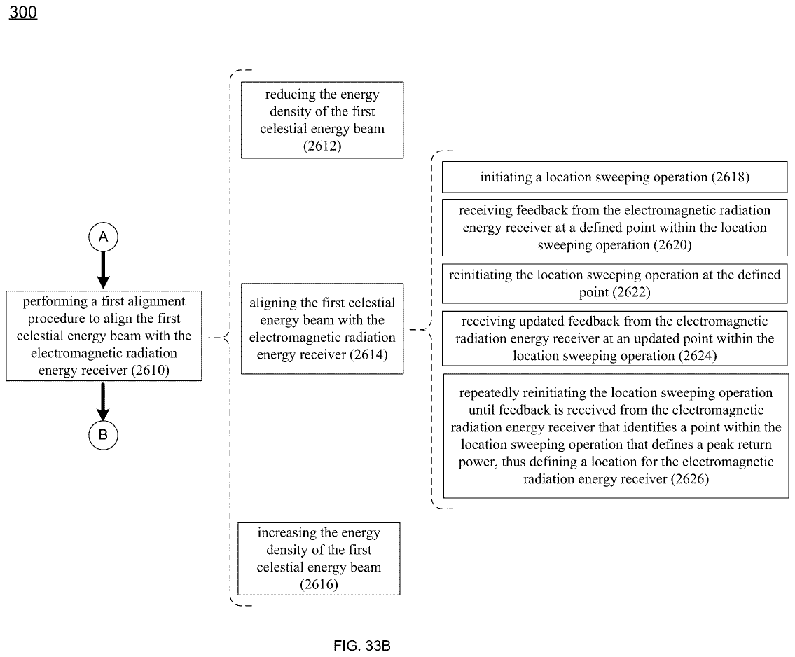

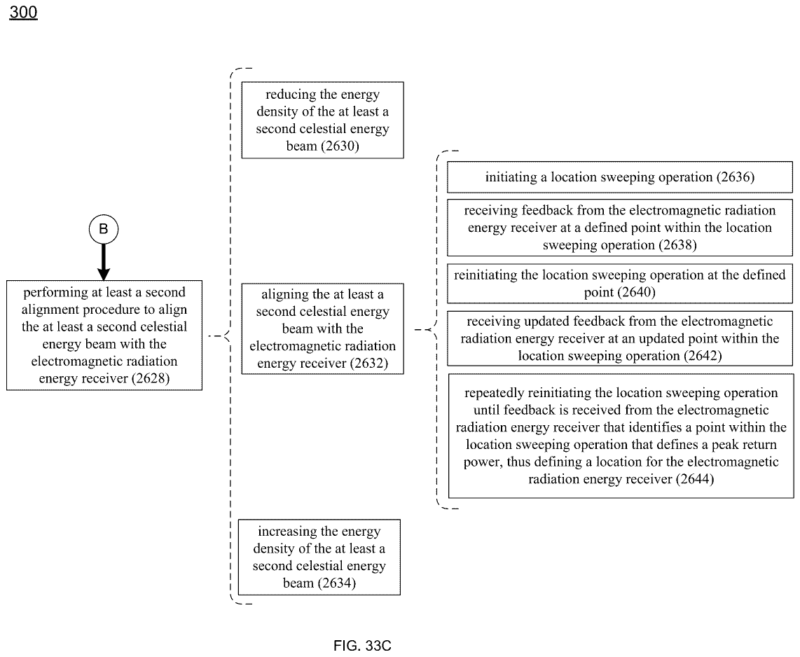

Referring also to FIGS. 33A-33C, the following discussion concerns the manner in which energy acquisition and delivery process 300 may provide electrical energy (in the form of multiple celestial energy beams) from multiple space-based electromagnetic radiation energy sources to a single electromagnetic radiation energy receiver that includes a single optical component and one or more photoreceptors.

Energy acquisition and delivery process 300 may enable 2600 an electromagnetic radiation energy receiver (e.g., electromagnetic radiation energy receiver 200), wherein the electromagnetic radiation energy receiver (e.g., electromagnetic radiation energy receiver 200) includes at least one feedback device (e.g., at least one of feedback devices 226) and a plurality of photoreceptors (e.g., photoreceptors 268).

For example and when enabling 2600 an electromagnetic radiation energy receiver (e.g., electromagnetic radiation energy receiver 200), energy acquisition and delivery process 300 may energize and/or provide power to the electromagnetic radiation energy receiver (e.g., electromagnetic radiation energy receiver 200). For example, it is foreseeable that the electromagnetic radiation energy receiver (e.g., electromagnetic radiation energy receiver 200) may be powered down until it is needed. Additionally/alternatively and when enabling 2600 an electromagnetic radiation energy receiver (e.g., electromagnetic radiation energy receiver 200), the electromagnetic radiation energy receiver (e.g., electromagnetic radiation energy receiver 200) may be configured to receive a particular type of celestial energy beam, such as laser or microwave.

Photoreceptors (e.g., photoreceptors 268) may be employed as part of a feedback system to help an electromagnetic radiation energy source (e.g., electromagnetic radiation energy source 38) identify and track multiple incoming celestial energy beams (e.g., celestial energy beams 40, 40A), wherein each of such energy beams may be uniquely encoded to distinguish its origin. These photoreceptors (e.g., photoreceptors 268) may act as sensors that detect specific characteristics of the incoming beams (e.g., celestial energy beams 40, 40A), such as intensity, wavelength, modulation pattern, polarization, or phase.

Each celestial energy beam (e.g., celestial energy beams 40, 40A) can be uniquely encoded using techniques like temporal modulation (e.g., pulsing in a specific binary pattern), wavelength multiplexing (e.g., assigning different beams slightly different wavelengths), or phase/frequency modulation. When these beams (e.g., celestial energy beams 40, 40A) arrive at the receiver (e.g., electromagnetic radiation energy receiver 200), these photoreceptors (e.g., photoreceptors 268) may be used to differentiate and decode the individual signals encoded into the celestial energy beams (e.g., celestial energy beams 40, 40A). The decoded identification data from each beam (e.g., celestial energy beams 40, 40A) allows the receiver (e.g., electromagnetic radiation energy receiver 200) to determine which beam (e.g., celestial energy beams 40, 40A) corresponds to which source (e.g., electromagnetic radiation energy source 38). Feedback (e.g., feedback 234) may then be relayed to the electromagnetic radiation energy source (e.g., electromagnetic radiation energy source 38), enabling the source (e.g., electromagnetic radiation energy source 38) to e.g., adjust beam alignment/divergence.

Accordingly, energy acquisition and delivery process 300 may direct 2602 a first celestial energy beam (e.g., celestial energy beam 40) including a first modulation signature (e.g., first modulation signature 270) from a first electromagnetic radiation energy source (e.g., electromagnetic radiation energy source 38) toward the electromagnetic radiation energy receiver (e.g., electromagnetic radiation energy receiver 200).

As discussed above and for directing 2602 a celestial energy beam (e.g., celestial energy beam 40), the electromagnetic radiation energy source (e.g., electromagnetic radiation energy source 38) may include: an energy beam source (e.g., energy beam source 100) for generating the celestial energy beam (e.g., celestial energy beam 40); a beam aiming assembly (e.g., beam aiming assembly 102) for steering the celestial energy beam (e.g., celestial energy beam 40) toward a target; and a beam forming package (e.g., beam forming package 104) for forming the celestial energy beam (e.g., celestial energy beam 40).

The energy beam source (e.g., energy beam source 100) for generating the celestial energy beam (e.g., celestial energy beam 40) may include one or more of: a visible-light laser beam source; an Infrared laser beam source; a short wavelength Infrared laser beam source, a mid-Infrared laser beam source; a near-Infrared laser beam source; and a microwave beam source.

The beam aiming assembly (e.g., beam aiming assembly 102) for steering the celestial energy beam (e.g., celestial energy beam 40) may include: a Gimbal mount assembly (e.g., Gimbal mount assembly 106) configured to direct the celestial energy beam (e.g., celestial energy beam 40) toward a target; a phased array assembly (e.g., phased array assembly 107) configured to direct the celestial energy beam (e.g., celestial energy beam 40) toward a target and/or a periscope assembly (e.g., periscope assembly 108) configured to direct the celestial energy beam (e.g., celestial energy beam 40) toward a target. A Gimbal mount assembly (e.g., Gimbal mount assembly 106), a phased array assembly (e.g., phased array assembly 107) and a periscope assembly (e.g., periscope assembly 108) can be effectively used in space-based energy systems to accurately direct a celestial energy beam (e.g., celestial energy beam 40), such as a laser or microwave beam, from a satellite (e.g., satellite 14) to a electromagnetic radiation energy receiver (e.g., electromagnetic radiation energy receiver 200).

The beam forming package (e.g., beam forming package 104) for forming the celestial energy beam (e.g., celestial energy beam 40) may include: collimating optics (e.g., collimating optics 110); and focusing optics (e.g., focusing optics 112). Collimating optics (e.g., collimating optics 110) are used to shape a celestial energy beam (e.g., celestial energy beam 40) so that its rays are parallel, resulting in a collimated beam i.e., one that doesn't spread out (diverge) significantly over distance. When a celestial energy beam (e.g., celestial energy beam 40) exits a source (e.g., energy beam source 100) like a diode, it typically diverges, meaning the beam spreads out as it travels.

Collimating optics (e.g., collimating optics 110), such as a lens or a lens system, are placed in the beam path to correct this divergence. By focusing the light emerging from a point-like or narrow source, collimating optics (e.g., collimating optics 110) create a beam with minimal angular spread. This is especially important for applications that require the beam to travel long distances (e.g., power transmission) or interact with precise optical components. In short, collimating optics (e.g., collimating optics 110) make a celestial energy beam (e.g., celestial energy beam 40) straighter and more focused over distance, improving its usability and efficiency in various optical systems.

Focusing optics (e.g., focusing optics 112) do the opposite of collimating optics (e.g., collimating optics 110), as they take a celestial energy beam (e.g., celestial energy beam 40) and converge it to a point or a small spot. This is usually achieved with lenses or curved mirrors that bend the incoming rays inward, concentrating the beam's energy into a smaller area. When a collimated or diverging celestial energy beam (e.g., celestial energy beam 40) passes through focusing optics (e.g., focusing optics 112), the optics manipulate the beam's path so that all rays come together at a focal point.

Additionally, energy acquisition and delivery process 300 may also direct 2604 at least a second celestial energy beam (e.g., celestial energy beam 40A) including at least a second modulation signature (e.g., second modulation signature 272) from at least a second electromagnetic radiation energy source (e.g., electromagnetic radiation energy source 38A) toward the electromagnetic radiation energy receiver (e.g., electromagnetic radiation energy receiver 200).

As discussed above and for directing 2604 a celestial energy beam (e.g., celestial energy beam 40A), the electromagnetic radiation energy source (e.g., electromagnetic radiation energy source 38A) may include: an energy beam source (e.g., energy beam source 100) for generating the celestial energy beam (e.g., celestial energy beam 40A); a beam aiming assembly (e.g., beam aiming assembly 102) for steering the celestial energy beam (e.g., celestial energy beam 40A) toward a target; and a beam forming package (e.g., beam forming package 104) for forming the celestial energy beam (e.g., celestial energy beam 40A).

The energy beam source (e.g., energy beam source 100) for generating the celestial energy beam (e.g., celestial energy beam 40A) may include one or more of: a visible-light laser beam source; an Infrared laser beam source; a short wavelength Infrared laser beam source, a mid-Infrared laser beam source; a near-Infrared laser beam source; and a microwave beam source.

The beam aiming assembly (e.g., beam aiming assembly 102) for steering the celestial energy beam (e.g., celestial energy beam 40A) may include: a Gimbal mount assembly (e.g., Gimbal mount assembly 106) configured to direct the celestial energy beam (e.g., celestial energy beam 40A) toward a target; a phased array assembly (e.g., phased array assembly 107) configured to direct the celestial energy beam (e.g., celestial energy beam 40) toward a target and/or a periscope assembly (e.g., periscope assembly 108) configured to direct the celestial energy beam (e.g., celestial energy beam 40A) toward a target. A Gimbal mount assembly (e.g., Gimbal mount assembly 106), a phased array assembly (e.g., phased array assembly 107) and a periscope assembly (e.g., periscope assembly 108) can be effectively used in space-based energy systems to accurately direct a celestial energy beam (e.g., celestial energy beam 40A), such as a laser or microwave beam, from a satellite (e.g., satellite 14) to a electromagnetic radiation energy receiver (e.g., electromagnetic radiation energy receiver 200).

The beam forming package (e.g., beam forming package 104) for forming the celestial energy beam (e.g., celestial energy beam 40A) may include: collimating optics (e.g., collimating optics 110); and focusing optics (e.g., focusing optics 112). Collimating optics (e.g., collimating optics 110) are used to shape a celestial energy beam (e.g., celestial energy beam 40A) so that its rays are parallel, resulting in a collimated beam i.e., one that doesn't spread out (diverge) significantly over distance. When a celestial energy beam (e.g., celestial energy beam 40A) exits a source (e.g., energy beam source 100) like a diode, it typically diverges, meaning the beam spreads out as it travels.

Collimating optics (e.g., collimating optics 110), such as a lens or a lens system, are placed in the beam path to correct this divergence. By focusing the light emerging from a point-like or narrow source, collimating optics (e.g., collimating optics 110) create a beam with minimal angular spread. This is especially important for applications that require the beam to travel long distances (e.g., power transmission) or interact with precise optical components. In short, collimating optics (e.g., collimating optics 110) make a celestial energy beam (e.g., celestial energy beam 40A) straighter and more focused over distance, improving its usability and efficiency in various optical systems.

Focusing optics (e.g., focusing optics 112) do the opposite of collimating optics (e.g., collimating optics 110), as they take a celestial energy beam (e.g., celestial energy beam 40A) and converge it to a point or a small spot. This is usually achieved with lenses or curved mirrors that bend the incoming rays inward, concentrating the beam's energy into a smaller area. When a collimated or diverging celestial energy beam (e.g., celestial energy beam 40A) passes through focusing optics (e.g., focusing optics 112), the optics manipulate the beam's path so that all rays come together at a focal point.

Energy acquisition and delivery process 300 may provide 2606 first alignment feedback (e.g., feedback 234) to the first electromagnetic radiation energy source (e.g., electromagnetic radiation energy source 38) via the at least one feedback device (e.g., at least one of feedback devices 226) based, at least in part, upon light sensed by the plurality of photoreceptors (e.g., photoreceptors 268) that has the first modulation signature (e.g., first modulation signature 270).

As discussed above, such feedback (e.g., feedback 234) may be received on feedback receiving devices (e.g., feedback receiving devices 128) included within electromagnetic radiation energy source 38. Examples of such feedback receiving devices (e.g., feedback receiving devices 128) may include but are not limited to one or more of: one or more photovoltaic cells; one or more photodiodes; one or more heat engines; and one or more rectenna arrays.

As discussed above, the at least one feedback device (e.g., at least one of feedback devices 226) may include one or more of: a centrally-positioned feedback device; a plurality of peripherally-positioned feedback devices and/or a retroreflector. As discussed above, a retroreflector is a specialized feedback device or surface that reflects incoming electromagnetic radiation (e.g., a portion of celestial energy beam 40) directly back toward its source (e.g., electromagnetic radiation energy source 38), regardless of the angle at which celestial energy beam 40 arrives. Unlike a standard mirror, which reflects light at an angle equal to the incident angle, a retroreflector returns celestial energy beam 40 along a near-exact path from which it came through geometric structures (e.g., corner cubes, cat's-eye lenses, or Bragg gratings).

As discussed above, the feedback devices (e.g., feedback devices 226) may include an RF component. Specifically, feedback devices 226 may include a plurality of opto-electrical sensors (e.g., photodiodes, photodetectors and/or photovoltaic cells). This plurality of sensors (e.g., feedback devices 226) may monitor the position of celestial energy beam 40, which is received on electromagnetic radiation energy receiver 200 from electromagnetic radiation energy source 38. This information concerning beam alignment (i.e., the manner in which celestial energy beam 40 is striking electromagnetic radiation energy receiver 200) may be provided to an RF transmitter (e.g., wireless communication system 332) that is included within/coupled to/available to electromagnetic radiation energy receiver 200 so that such information may be transmitted to the electromagnetic radiation energy source (e.g., electromagnetic radiation energy source 38). This information may then be used by electromagnetic radiation energy source 38 to reposition celestial energy beam 40 via beam aiming assembly 102 (if adjustment is needed).

As discussed above, the feedback (e.g., feedback 234) received from the electromagnetic radiation energy receiver (e.g., electromagnetic radiation energy receiver 200) may include feedback encoded to identify the electromagnetic radiation energy receiver (e.g., electromagnetic radiation energy receiver 200).

The at least one feedback device (e.g., at least one of feedback devices 226) may be modulated to encode data (e.g., the identity of the electromagnetic radiation energy receiver) within the feedback (e.g., feedback 234) by dynamically altering how the at least one feedback device (e.g., at least one of feedback devices 226) reflects incoming electromagnetic energy (e.g., celestial energy beam 40) over time. This encoding may be accomplished by modulating the intensity, phase, polarization, or timing of the reflected signal (e.g., feedback 234) in a controlled way, with the changes representing the encoded information.

One common method to achieve such encoding is through the use of a modulating feedback device (e.g., a modulating retroreflector), where the feedback device may be paired with a system/actuator that rapidly changes the optical properties of the feedback device. Some methods of achieving such modulation may include but are not limited to:
Mechanical Modulation: A small shutter, MEMS (microelectromechanical system) device, or vibrating mirror may physically open and close or change orientation of the at least one feedback device (e.g., at least one of feedback devices 226) to modulate how much light is reflected, wherein these open/closed states may represent encoded binary data.
Electro-Optical Modulation: Materials like liquid crystals or electro-optic polymers placed in front of the at least one feedback device (e.g., at least one of feedback devices 226) may change their optical properties (such as transparency, refractive index, or polarization) when voltage is applied, allowing fast, electronic control of the reflected beam's characteristics to represent encoded binary data.
Acousto-Optic Modulation: Sound waves may be used to modulate the surface of the at least one feedback device (e.g., at least one of feedback devices 226) or an optical material may be placed in front of the at least one feedback device (e.g., at least one of feedback devices 226), altering the properties of the reflected beam to encode binary data.
Thermal or Phase Modulation: The surface temperature or refractive index of the at least one feedback device (e.g., at least one of feedback devices 226) may be slightly altered to create phase shifts in the reflected beam, which may be used to encode binary data.

By modulating the reflection characteristics of the at least one feedback device (e.g., at least one of feedback devices 226) in a precise, time-controlled manner, data (e.g., telemetry, identification signals, or communications) may be encoded within the reflected energy beam (e.g., feedback 234) without requiring the feedback device to generate its own signals.

Energy acquisition and delivery process 300 may provide 2608 at least second alignment feedback (e.g., feedback 234A) to the at least a second electromagnetic radiation energy source (e.g., electromagnetic radiation energy source 38A) via the at least one feedback device (e.g., at least one of feedback devices 226) based, at least in part, upon light sensed by the plurality of photoreceptors (e.g., photoreceptors 268) that has the at least a second modulation signature (e.g., second modulation signature 272).

As discussed above, such feedback (e.g., feedback 234A) may be received on feedback receiving devices included within electromagnetic radiation energy source 38A. Examples of such feedback receiving devices may include but are not limited to one or more of: one or more photovoltaic cells; one or more photodiodes; one or more heat engines; and one or more rectenna arrays.

As discussed above, the at least one feedback device (e.g., at least one of feedback devices 226) may include one or more of: a centrally-positioned feedback device; a plurality of peripherally-positioned feedback devices and/or a retroreflector. As discussed above, a retroreflector is a specialized feedback device or surface that reflects incoming electromagnetic radiation (e.g., a portion of celestial energy beam 40) directly back toward its source (e.g., electromagnetic radiation energy source 38), regardless of the angle at which celestial energy beam 40 arrives. Unlike a standard mirror, which reflects light at an angle equal to the incident angle, a retroreflector returns celestial energy beam 40 along a near-exact path from which it came through geometric structures (e.g., corner cubes, cat's-eye lenses, or Bragg gratings).

As discussed above, the feedback devices (e.g., feedback devices 226) may include an RF component. Specifically, feedback devices 226 may include a plurality of opto-electrical sensors (e.g., photodiodes, photodetectors and/or photovoltaic cells). This plurality of sensors (e.g., feedback devices 226) may monitor the position of celestial energy beam 40, which is received on electromagnetic radiation energy receiver 200 from electromagnetic radiation energy source 38. This information concerning beam alignment (i.e., the manner in which celestial energy beam 40 is striking electromagnetic radiation energy receiver 200) may be provided to an RF transmitter (e.g., wireless communication system 332) that is included within/coupled to/available to electromagnetic radiation energy receiver 200 so that such information may be transmitted to the electromagnetic radiation energy source (e.g., electromagnetic radiation energy source 38). This information may then be used by electromagnetic radiation energy source 38 to reposition celestial energy beam 40 via beam aiming assembly 102 (if adjustment is needed).

As discussed above, the feedback (e.g., feedback 234A) received from the electromagnetic radiation energy receiver (e.g., electromagnetic radiation energy receiver 200) may include feedback encoded to identify the electromagnetic radiation energy receiver (e.g., electromagnetic radiation energy receiver 200).

The at least one feedback device (e.g., at least one of feedback devices 226) may be modulated to encode data (e.g., the identity of the electromagnetic radiation energy receiver) within the feedback (e.g., feedback 234A) by dynamically altering how the at least one feedback device (e.g., at least one of feedback devices 226) reflects incoming electromagnetic energy (e.g., celestial energy beam 40A) over time. This encoding may be accomplished by modulating the intensity, phase, polarization, or timing of the reflected signal (e.g., feedback 234A) in a controlled way, with the changes representing the encoded information.

One common method to achieve such encoding is through the use of a modulating feedback device (e.g., a modulating retroreflector), where the feedback device may be paired with a system/actuator that rapidly changes the optical properties of the feedback device. Some methods of achieving such modulation may include but are not limited to:
Mechanical Modulation: A small shutter, MEMS (microelectromechanical system) device, or vibrating mirror may physically open and close or change orientation of the at least one feedback device (e.g., at least one of feedback devices 226) to modulate how much light is reflected, wherein these open/closed states may represent encoded binary data.
Electro-Optical Modulation: Materials like liquid crystals or electro-optic polymers placed in front of the at least one feedback device (e.g., at least one of feedback devices 226) may change their optical properties (such as transparency, refractive index, or polarization) when voltage is applied, allowing fast, electronic control of the reflected beam's characteristics to represent encoded binary data.
Acousto-Optic Modulation: Sound waves may be used to modulate the surface of the at least one feedback device (e.g., at least one of feedback devices 226) or an optical material may be placed in front of the at least one feedback device (e.g., at least one of feedback devices 226), altering the properties of the reflected beam to encode binary data.
Thermal or Phase Modulation: The surface temperature or refractive index of the at least one feedback device (e.g., at least one of feedback devices 226) may be slightly altered to create phase shifts in the reflected beam, which may be used to encode binary data.

By modulating the reflection characteristics of the at least one feedback device (e.g., at least one of feedback devices 226) in a precise, time-controlled manner, data (e.g., telemetry, identification signals, or communications) may be encoded within the reflected energy beam (e.g., feedback 234A) without requiring the feedback device to generate its own signals.

Energy acquisition and delivery process 300 may perform 2610 a first alignment procedure to align the first celestial energy beam (e.g., celestial energy beam 40) with the electromagnetic radiation energy receiver (e.g., electromagnetic radiation energy receiver 200).

When performing 2610 a first alignment procedure to align the first celestial energy beam (e.g., celestial energy beam 40) with the electromagnetic radiation energy receiver (e.g., electromagnetic radiation energy receiver 200), energy acquisition and delivery process 300 may: reduce 2612 the energy density of the first celestial energy beam (e.g., celestial energy beam 40); align 2614 the first celestial energy beam (e.g., celestial energy beam 40) with the electromagnetic radiation energy receiver (e.g., electromagnetic radiation energy receiver 200); and increase 2616 the energy density of the first celestial energy beam (e.g., celestial energy beam 40).

As discussed above, the energy density of a celestial energy beam (e.g., celestial energy beam 40) refers to the amount of energy delivered per unit area of the celestial energy beam (e.g., celestial energy beam 40). Also and as discussed above, when reducing 2612 the energy density of the celestial energy beam (e.g., celestial energy beam 40), energy acquisition and delivery process 300 may: increase the divergence of the celestial energy beam (e.g., celestial energy beam 40); and/or reduce the power of the celestial energy beam (e.g., celestial energy beam 40).

When aligning 2614 the first celestial energy beam (e.g., celestial energy beam 40) with the electromagnetic radiation energy receiver (e.g., electromagnetic radiation energy receiver 200), energy acquisition and delivery process 300 may: initiate 2618 a location sweeping operation; receive 2620 feedback (e.g., feedback 234) from the electromagnetic radiation energy receiver (e.g., electromagnetic radiation energy receiver 200) at a defined point (e.g., defined point 238) within the location sweeping operation; reinitiate 2622 the location sweeping operation at the defined point (e.g., defined point 238); receive 2624 updated feedback (e.g., feedback 234) from the electromagnetic radiation energy receiver (e.g., electromagnetic radiation energy receiver 200) at an updated point (e.g., updated point 240) within the location sweeping operation; and repeatedly reinitiate 2626 the location sweeping operation until feedback (e.g., feedback 234) is received from the electromagnetic radiation energy receiver (e.g., electromagnetic radiation energy receiver 200) that identifies a point within the location sweeping operation that defines a peak return power, thus defining a location for the electromagnetic radiation energy receiver (e.g., electromagnetic radiation energy receiver 200).

As discussed above, when increasing 2616 the energy density of the celestial energy beam (e.g., celestial energy beam 40), energy acquisition and delivery process 300 may: decrease the divergence of the celestial energy beam (e.g., celestial energy beam 40); and/or increase the power of the celestial energy beam (e.g., celestial energy beam 40).

Energy acquisition and delivery process 300 may also perform 2628 at least a second alignment procedure to align the at least a second celestial energy beam (e.g., celestial energy beam 40A) with the electromagnetic radiation energy receiver (e.g., electromagnetic radiation energy receiver 200).

When performing 2628 at least a second alignment procedure to align the at least a second celestial energy beam (e.g., celestial energy beam 40A) with the electromagnetic radiation energy receiver (e.g., electromagnetic radiation energy receiver 200), energy acquisition and delivery process 300 may: reduce 2630 the energy density of the at least a second celestial energy beam (e.g., celestial energy beam 40A); align 2632 the at least a second celestial energy beam (e.g., celestial energy beam 40A) with the electromagnetic radiation energy receiver (e.g., electromagnetic radiation energy receiver 200); and increase 2634 the energy density of the at least a second celestial energy beam (e.g., celestial energy beam 40A).

As discussed above, the energy density of a celestial energy beam (e.g., celestial energy beam 40A) refers to the amount of energy delivered per unit area of the celestial energy beam (e.g., celestial energy beam 40A). Also and as discussed above, when reducing 2630 the energy density of the celestial energy beam (e.g., celestial energy beam 40A), energy acquisition and delivery process 300 may: increase the divergence of the celestial energy beam (e.g., celestial energy beam 40A); and/or reduce the power of the celestial energy beam (e.g., celestial energy beam 40A).

When aligning 2632 the at least a second celestial energy beam (e.g., celestial energy beam 40A) with the electromagnetic radiation energy receiver (e.g., electromagnetic radiation energy receiver 200), energy acquisition and delivery process 300 may: initiate 2636 a location sweeping operation; receive 2638 feedback (e.g., feedback 234A) from the electromagnetic radiation energy receiver (e.g., electromagnetic radiation energy receiver 200) at a defined point (e.g., defined point 238) within the location sweeping operation; reinitiate 2640 the location sweeping operation at the defined point (e.g., defined point 238); receive 2642 updated feedback (e.g., feedback 234A) from the electromagnetic radiation energy receiver (e.g., electromagnetic radiation energy receiver 200) at an updated point (e.g., updated point 240) within the location sweeping operation; and repeatedly reinitiate 2644 the location sweeping operation until feedback (e.g., feedback 234A) is received from the electromagnetic radiation energy receiver (e.g., electromagnetic radiation energy receiver 200) that identifies a point within the location sweeping operation that defines a peak return power, thus defining a location for the electromagnetic radiation energy receiver (e.g., electromagnetic radiation energy receiver 200).

As discussed above, when increasing 2634 the energy density of the celestial energy beam (e.g., celestial energy beam 40A), energy acquisition and delivery process 300 may: decrease the divergence of the celestial energy beam (e.g., celestial energy beam 40A); and/or increase the power of the celestial energy beam (e.g., celestial energy beam 40A).

The electromagnetic radiation energy receiver (e.g., electromagnetic radiation energy receiver 200) may include energy absorbing materials to prevent reflection of the first celestial energy beam (e.g., celestial energy beam 40) and/or the at least a second celestial energy beam (e.g., celestial energy beam 40A) onto undesired objects. As discussed above, the electromagnetic radiation energy receiver (e.g., electromagnetic radiation energy receiver 200) may include: an energy absorbing system (e.g., energy absorbing system 224) configured to absorb at least a portion of the celestial energy beam (e.g., celestial energy beams 40, 40A) within the security zone (e.g., security zone 214).

To safely manage and utilize the power delivered by celestial energy beams 40, 40A, whether in the form of laser or microwave radiation, an energy absorbing system (e.g., energy absorbing system 224) may be employed. This system (e.g., energy absorbing system 224) is designed to dissipate incoming electromagnetic energy safely without damage. This energy absorbing system (e.g., energy absorbing system 224) may fall into two categories: energy absorbing coatings and energy absorbing structures, each tailored for the specific characteristics of celestial energy beams 40, 40A. For example, areas outside of the energy receiving devices 202 may be protected by energy absorbing system 224 so that electromagnetic radiation from celestial energy beams 40, 40A that does not strike energy receiving devices 202 will be safely absorbed/dissipated by energy absorbing system 224.

Energy Absorbing Coatings: Laser-absorbing coatings are engineered materials applied to surfaces to efficiently absorb specific laser wavelengths. These coatings typically consist of layers of carbon black, ceramic-metal composites (cermets), or dielectric materials designed for optical interference absorption. The energy absorbed is converted into heat, which can either be dissipated or redirected. For microwave energy, coatings known as RAM (Radar Absorbing Materials) may be used. These materials are composed of ferromagnetic particles or dielectric composites that absorb and attenuate incoming microwave radiation by converting it into heat through magnetic and electric losses.

Energy Absorbing Structures: Thermal absorbing structures may be used to absorb the electromagnetic energy included within celestial energy beam 40. These structures are made of materials with high thermal conductivity (e.g., graphite, tungsten, or ceramics) and are designed to absorb the beam's energy as heat. The heat can then be transferred to a heat engine to produce electricity or dissipated through radiator panels. Advanced absorbing structures may also employ metamaterials-engineered materials with unique electromagnetic properties that enable them to absorb specific frequencies with minimal reflection or transmission. These can be designed for either laser or microwave energy and offer high levels of energy absorption.

The role of energy absorbing system 224 is to prevent damage to sensitive equipment, surrounding infrastructure, humans and animals by absorbing and dissipating the electromagnetic radiation within celestial energy beams 40, 40A that fails to strike energy receiving devices 202. By using purpose-built coatings and structural absorbers, celestial energy beam 40 may be harnessed effectively, safely, and reliably.

### (32) Establishing a Communication Channel Between an Electromagnetic Radiation Source and a Defined Receiver.

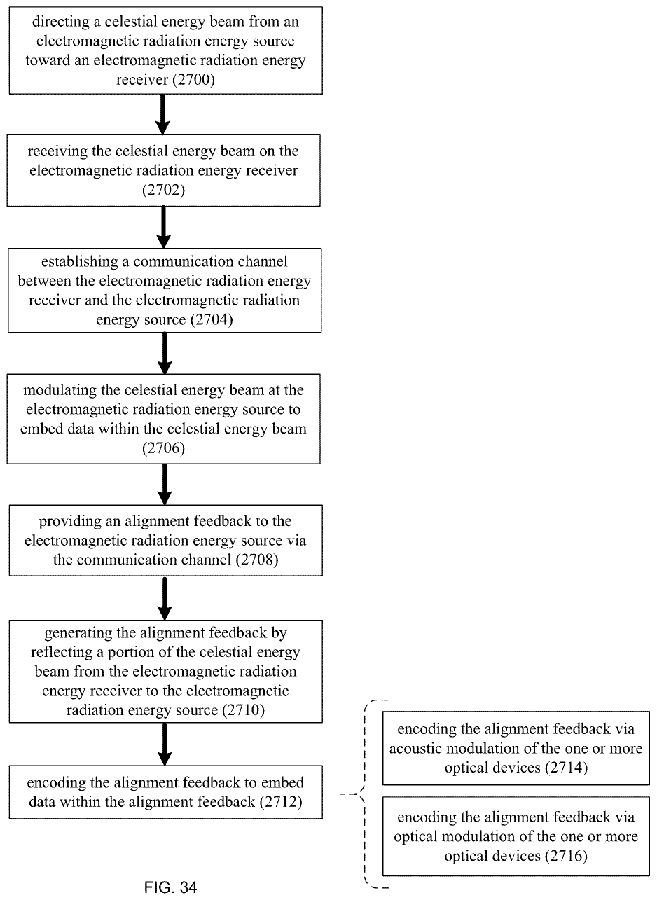

Referring also to FIG. 34, the following discussion concerns the manner in which energy acquisition and delivery process 300 may establish a communication channel between an electromagnetic radiation energy source and an electromagnetic radiation energy receiver by modulating a celestial energy beam between the source and the receiver.

Energy acquisition and delivery process 300 may direct 2700 a celestial energy beam (e.g., celestial energy beam 40) from an electromagnetic radiation energy source (e.g., electromagnetic radiation energy source 38) toward an electromagnetic radiation energy receiver (e.g., electromagnetic radiation energy receiver 200).

As discussed above and for directing 2700 a celestial energy beam (e.g., celestial energy beam 40), the electromagnetic radiation energy source (e.g., electromagnetic radiation energy source 38) may include: an energy beam source (e.g., energy beam source 100) for generating the celestial energy beam (e.g., celestial energy beam 40); a beam aiming assembly (e.g., beam aiming assembly 102) for steering the celestial energy beam (e.g., celestial energy beam 40) toward a target; and a beam forming package (e.g., beam forming package 104) for forming the celestial energy beam (e.g., celestial energy beam 40).

The energy beam source (e.g., energy beam source 100) for generating the celestial energy beam (e.g., celestial energy beam 40) may include one or more of: a visible-light laser beam source; an Infrared laser beam source; a short wavelength Infrared laser beam source, a mid-Infrared laser beam source; a near-Infrared laser beam source; and a microwave beam source.

The beam aiming assembly (e.g., beam aiming assembly 102) for steering the celestial energy beam (e.g., celestial energy beam 40) may include: a Gimbal mount assembly (e.g., Gimbal mount assembly 106) configured to direct the celestial energy beam (e.g., celestial energy beam 40) toward a target; a phased array assembly (e.g., phased array assembly 107) configured to direct the celestial energy beam (e.g., celestial energy beam 40) toward a target and/or a periscope assembly (e.g., periscope assembly 108) configured to direct the celestial energy beam (e.g., celestial energy beam 40) toward a target. A Gimbal mount assembly (e.g., Gimbal mount assembly 106), a phased array assembly (e.g., phased array assembly 107) and a periscope assembly (e.g., periscope assembly 108) can be effectively used in space-based energy systems to accurately direct a celestial energy beam (e.g., celestial energy beam 40), such as a laser or microwave beam, from a satellite (e.g., satellite 14) to a electromagnetic radiation energy receiver (e.g., electromagnetic radiation energy receiver 200).

The beam forming package (e.g., beam forming package 104) for forming the celestial energy beam (e.g., celestial energy beam 40) may include: collimating optics (e.g., collimating optics 110); and focusing optics (e.g., focusing optics 112). Collimating optics (e.g., collimating optics 110) are used to shape a celestial energy beam (e.g., celestial energy beam 40) so that its rays are parallel, resulting in a collimated beam i.e., one that doesn't spread out (diverge) significantly over distance. When a celestial energy beam (e.g., celestial energy beam 40) exits a source (e.g., energy beam source 100) like a diode, it typically diverges, meaning the beam spreads out as it travels.

Collimating optics (e.g., collimating optics 110), such as a lens or a lens system, are placed in the beam path to correct this divergence. By focusing the light emerging from a point-like or narrow source, collimating optics (e.g., collimating optics 110) create a beam with minimal angular spread. This is especially important for applications that require the beam to travel long distances (e.g., power transmission) or interact with precise optical components. In short, collimating optics (e.g., collimating optics 110) make a celestial energy beam (e.g., celestial energy beam 40) straighter and more focused over distance, improving its usability and efficiency in various optical systems.

Focusing optics (e.g., focusing optics 112) do the opposite of collimating optics (e.g., collimating optics 110), as they take a celestial energy beam (e.g., celestial energy beam 40) and converge it to a point or a small spot. This is usually achieved with lenses or curved mirrors that bend the incoming rays inward, concentrating the beam's energy into a smaller area. When a collimated or diverging celestial energy beam (e.g., celestial energy beam 40) passes through focusing optics (e.g., focusing optics 112), the optics manipulate the beam's path so that all rays come together at a focal point.

Energy acquisition and delivery process 300 may receive 2702 the celestial energy beam (e.g., celestial energy beam 40) on the electromagnetic radiation energy receiver (e.g., electromagnetic radiation energy receiver 200).

As discussed above, while this celestial energy beam (e.g., celestial energy beam 40) is typically transmitted from a space-based electromagnetic radiation energy source (e.g., electromagnetic radiation energy source 38) to a ground-based electromagnetic radiation energy receiver (e.g., electromagnetic radiation energy receiver 200), this is for illustrative purposes only and is not intended to be a limitation of this disclosure, as other configurations are possible and are considered to be within the scope of this disclosure. For example and in some configurations, this celestial energy beam (e.g., celestial energy beam 40) may be transmitted from a ground-based electromagnetic radiation energy source (e.g., electromagnetic radiation energy source 38G) to a space-based electromagnetic radiation energy receiver (e.g., electromagnetic radiation energy receiver 200S).

Energy acquisition and delivery process 300 may establish 2704 a communication channel (e.g., communication channel 274) between the electromagnetic radiation energy receiver (e.g., electromagnetic radiation energy receiver 200) and the electromagnetic radiation energy source.

For example and to enable the establishment 2704 of communication channel 274, energy acquisition and delivery process 300 may modulate 2706 the celestial energy beam (e.g., celestial energy beam 40) at the electromagnetic radiation energy source (e.g., electromagnetic radiation energy source 38) to embed data (e.g., data 276) within the celestial energy beam (e.g., celestial energy beam 40).

Specifically and via such modulation 2706 of celestial energy beam 40, the celestial energy beam (e.g., celestial energy beams 40) may be encoded using techniques like temporal modulation (e.g., pulsing in a specific binary pattern), wavelength multiplexing (e.g., assigning different beams slightly different wavelengths), or phase/frequency modulation to embed data 276 within celestial energy beam 40. Examples of data 276 may include but is not limited to: data that identifies the source of celestial energy beam 40, data the defines the intended target of celestial energy beam 40, and data that defines various specifications of celestial energy beam 40.

Energy acquisition and delivery process 300 may provide 2708 alignment feedback (e.g., feedback 234) to the electromagnetic radiation energy source (e.g., electromagnetic radiation energy source 38) via the communication channel (e.g., communication channel 274).

Specifically, energy acquisition and delivery process 300 may generate 2710 the alignment feedback (e.g., feedback 234) by reflecting a portion of the celestial energy beam (e.g., celestial energy beam 40) from the electromagnetic radiation energy receiver (e.g., electromagnetic radiation energy receiver 200) to the electromagnetic radiation energy source (e.g., electromagnetic radiation energy source 38).

And being energy acquisition and delivery process 300 may modulate 2706 the celestial energy beam (e.g., celestial energy beam 40) at the electromagnetic radiation energy source (e.g., electromagnetic radiation energy source 38) to embed data (e.g., data 276) within the celestial energy beam (e.g., celestial energy beam 40), the portion of celestial energy beam 40 that is reflected back to electromagnetic radiation energy source 38 (namely feedback 234) will include the embedded data (e.g., data 276). Accordingly, the alignment feedback (e.g., feedback 234) may define e.g., the source (e.g., electromagnetic radiation energy source 38) of celestial energy beam 40, the intended target (e.g., electromagnetic radiation energy receiver 200) of celestial energy beam 40, and data that defines various specifications of celestial energy beam 40 (e.g., the transmission power of celestial energy beam 40, the location/orbit of electromagnetic radiation energy source 38, etc.).

As discussed above, such feedback (e.g., feedback 234) may be received on feedback receiving devices (e.g., feedback receiving devices 128) included within electromagnetic radiation energy source 38. Examples of such feedback receiving devices (e.g., feedback receiving devices 128) may include but are not limited to one or more of: one or more photovoltaic cells; one or more photodiodes; one or more heat engines; and one or more rectenna arrays.

This alignment feedback (e.g., feedback 234) may be reflected via one or more feedback devices (e.g., feedback devices 226) included within the electromagnetic radiation energy receiver (e.g., electromagnetic radiation energy receiver 200).

As discussed above, the one or more feedback devices (e.g., feedback devices 226) may include one or more of: a centrally-positioned feedback device; a plurality of peripherally-positioned feedback devices and/or a retroreflector. As discussed above, a retroreflector is a specialized feedback device or surface that reflects incoming electromagnetic radiation (e.g., a portion of celestial energy beam 40) directly back toward its source (e.g., electromagnetic radiation energy source 38), regardless of the angle at which celestial energy beam 40 arrives. Unlike a standard mirror, which reflects light at an angle equal to the incident angle, a retroreflector returns celestial energy beam 40 along a near-exact path from which it came through geometric structures (e.g., corner cubes, cat's-eye lenses, or Bragg gratings).

As discussed above, the feedback devices (e.g., feedback devices 226) may include an RF component. Specifically, feedback devices 226 may include a plurality of opto-electrical sensors (e.g., photodiodes, photodetectors and/or photovoltaic cells). This plurality of sensors (e.g., feedback devices 226) may monitor the position of celestial energy beam 40, which is received on electromagnetic radiation energy receiver 200 from electromagnetic radiation energy source 38. This information concerning beam alignment (i.e., the manner in which celestial energy beam 40 is striking electromagnetic radiation energy receiver 200) may be provided to an RF transmitter (e.g., wireless communication system 332) that is included within/coupled to/available to electromagnetic radiation energy receiver 200 so that such information may be transmitted to the electromagnetic radiation energy source (e.g., electromagnetic radiation energy source 38). This information may then be used by electromagnetic radiation energy source 38 to reposition celestial energy beam 40 via beam aiming assembly 102 (if adjustment is needed).

Energy acquisition and delivery process 300 may encode 2712 the alignment feedback (e.g., feedback 234) to embed data (e.g., data 278) within the alignment feedback (e.g., feedback 234). Examples of such embedded data (e.g., data 278) within the alignment feedback (e.g., feedback 234) may include but is not limited to: data that identifies electromagnetic radiation energy receiver 200, data that defines the quantity of energy extracted from celestial energy beam 40, and data that defines the efficiency of celestial energy beam 40.

When encoding 2712 the alignment feedback (e.g., feedback 234) to embed data (e.g., data 278) within the alignment feedback (e.g., feedback 234), energy acquisition and delivery process 300 may:
encode 2714 the alignment feedback (e.g., feedback 234) via acoustic modulation of the one or more feedback devices (e.g., feedback devices 226); and/or
encode 2716 the alignment feedback (e.g., feedback 234) via optical modulation of the one or more feedback devices (e.g., feedback devices 226).

As discussed above, the one or more feedback devices (e.g., feedback devices 226) included within the electromagnetic radiation energy receiver (e.g., electromagnetic radiation energy receiver 200) may be modulated to encode data (e.g., data 278) within the feedback (e.g., feedback 234) by dynamically altering how the one or more feedback devices (e.g., feedback devices 226) reflects incoming electromagnetic energy (e.g., celestial energy beam 40) over time. This encoding may be accomplished by modulating the intensity, phase, polarization, or timing of the reflected signal (e.g., feedback 234) in a controlled way, with the changes representing the encoded information.

One common method to achieve such encoding is through the use of a modulating feedback device (e.g., a modulating retroreflector), where the feedback device may be paired with a system/actuator that rapidly changes the optical properties of the feedback device. Some methods of achieving such modulation may include but are not limited to:
Mechanical Modulation: A small shutter, MEMS (microelectromechanical system) device, or vibrating mirror may physically open and close or change orientation of the one or more feedback devices (e.g., feedback devices 226) to modulate how much light is reflected, wherein these open/closed states may represent encoded binary data.
Electro-Optical Modulation: Materials like liquid crystals or electro-optic polymers placed in front of the one or more feedback devices (e.g., feedback devices 226) may change their optical properties (such as transparency, refractive index, or polarization) when voltage is applied, allowing fast, electronic control of the reflected beam's characteristics to represent encoded binary data.
Acousto-Optic Modulation: Sound waves may be used to modulate the surface of the one or more feedback devices (e.g., feedback devices 226) or an optical material may be placed in front of the one or more feedback devices (e.g., feedback devices 226), altering the properties of the reflected beam to encode binary data.
Thermal or Phase Modulation: The surface temperature or refractive index of the one or more feedback devices (e.g., feedback devices 226) may be slightly altered to create phase shifts in the reflected beam, which may be used to encode binary data.

By modulating the reflection characteristics of the one or more feedback devices (e.g., feedback devices 226) in a precise, time-controlled manner, data (e.g., telemetry, identification signals, or communications) may be encoded within the reflected energy beam (e.g., feedback 234) without requiring the feedback device to generate its own signals.

### (33) Methodologies for Locating a Ground-Based Receiver Via Iteratively Finer Resolution Scans.

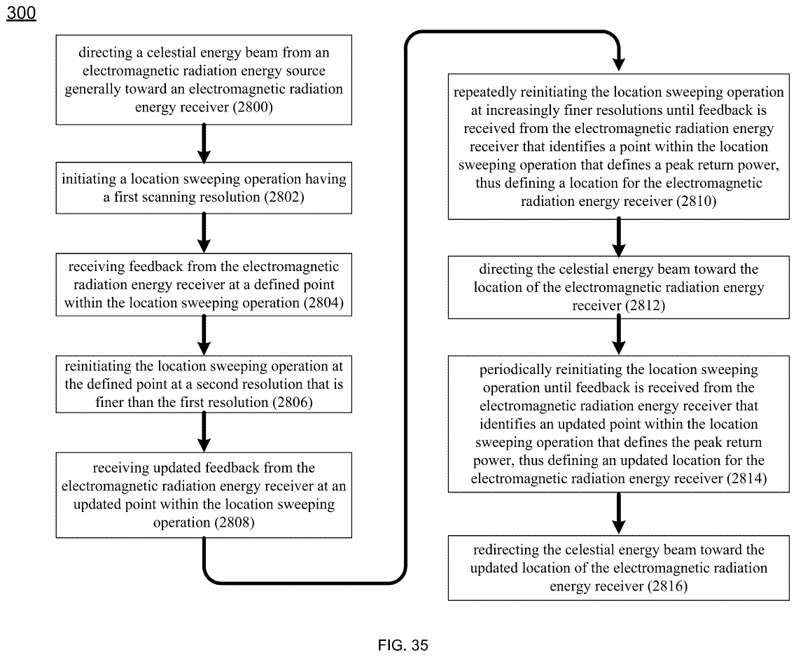

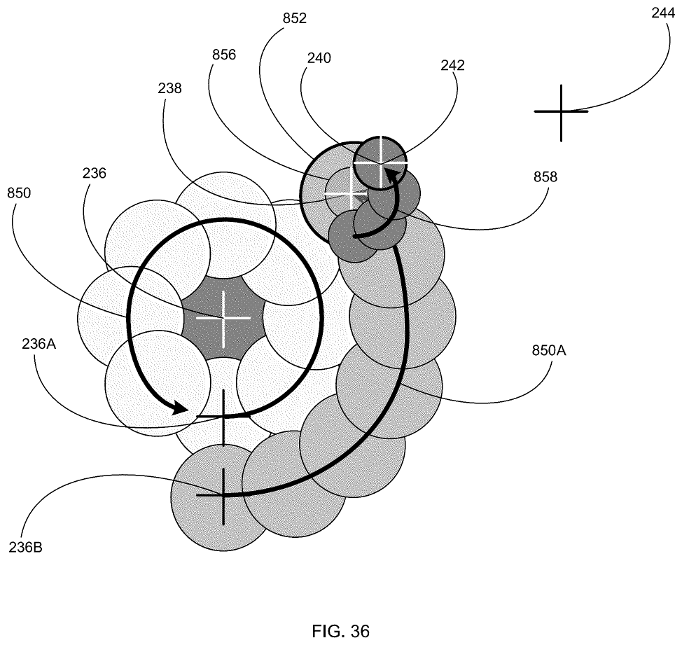

Referring also to FIGS. 35-36, the following discussion concerns the manner in which energy acquisition and delivery process 300 may locate an electromagnetic radiation energy receiver (e.g., electromagnetic radiation energy receiver 200) using a predefined sweeping pattern and received feedback in an iterative fashion that utilizes increasingly finer resolution scans.

Energy acquisition and delivery process 300 may direct 2800 a celestial energy beam (e.g., celestial energy beam 40) from an electromagnetic radiation energy source (e.g., electromagnetic radiation energy source 38) generally toward an electromagnetic radiation energy receiver (e.g., electromagnetic radiation energy receiver 200). For example, energy acquisition and delivery process 300 may reduce the energy density of the celestial energy beam (e.g., celestial energy beam 40) and direct 2800 the energy beam toward the general direction of an electromagnetic radiation energy receiver (e.g., electromagnetic radiation energy receiver 200).

As discussed above, while this celestial energy beam (e.g., celestial energy beam 40) is typically transmitted from a space-based electromagnetic radiation energy source (e.g., electromagnetic radiation energy source 38) to a ground-based electromagnetic radiation energy receiver (e.g., electromagnetic radiation energy receiver 200), this is for illustrative purposes only and is not intended to be a limitation of this disclosure, as other configurations are possible and are considered to be within the scope of this disclosure. For example and in some configurations, this celestial energy beam (e.g., celestial energy beam 40) may be transmitted from a ground-based electromagnetic radiation energy source (e.g., electromagnetic radiation energy source 38G) to a space-based electromagnetic radiation energy receiver (e.g., electromagnetic radiation energy receiver 200S).

As discussed above and for directing 2800 a celestial energy beam (e.g., celestial energy beam 40), the electromagnetic radiation energy source (e.g., electromagnetic radiation energy source 38) may include: an energy beam source (e.g., energy beam source 100) for generating the celestial energy beam (e.g., celestial energy beam 40); a beam aiming assembly (e.g., beam aiming assembly 102) for steering the celestial energy beam (e.g., celestial energy beam 40) toward a target; and a beam forming package (e.g., beam forming package 104) for forming the celestial energy beam (e.g., celestial energy beam 40).

The energy beam source (e.g., energy beam source 100) for generating the celestial energy beam (e.g., celestial energy beam 40) may include one or more of: a visible-light laser beam source; an Infrared laser beam source; a short wavelength Infrared laser beam source, a mid-Infrared laser beam source; a near-Infrared laser beam source; and a microwave beam source.

The beam aiming assembly (e.g., beam aiming assembly 102) for steering the celestial energy beam (e.g., celestial energy beam 40) may include: a Gimbal mount assembly (e.g., Gimbal mount assembly 106) configured to direct the celestial energy beam (e.g., celestial energy beam 40) toward a target; a phased array assembly (e.g., phased array assembly 107) configured to direct the celestial energy beam (e.g., celestial energy beam 40) toward a target and/or a periscope assembly (e.g., periscope assembly 108) configured to direct the celestial energy beam (e.g., celestial energy beam 40) toward a target. A Gimbal mount assembly (e.g., Gimbal mount assembly 106), a phased array assembly (e.g., phased array assembly 107) and a periscope assembly (e.g., periscope assembly 108) can be effectively used in space-based energy systems to accurately direct a celestial energy beam (e.g., celestial energy beam 40), such as a laser or microwave beam, from a satellite (e.g., satellite 14) to a electromagnetic radiation energy receiver (e.g., electromagnetic radiation energy receiver 200).

The beam forming package (e.g., beam forming package 104) for forming the celestial energy beam (e.g., celestial energy beam 40) may include: collimating optics (e.g., collimating optics 110); and focusing optics (e.g., focusing optics 112). Collimating optics (e.g., collimating optics 110) are used to shape a celestial energy beam (e.g., celestial energy beam 40) so that its rays are parallel, resulting in a collimated beam i.e., one that doesn't spread out (diverge) significantly over distance. When a celestial energy beam (e.g., celestial energy beam 40) exits a source (e.g., energy beam source 100) like a diode, it typically diverges, meaning the beam spreads out as it travels.

Collimating optics (e.g., collimating optics 110), such as a lens or a lens system, are placed in the beam path to correct this divergence. By focusing the light emerging from a point-like or narrow source, collimating optics (e.g., collimating optics 110) create a beam with minimal angular spread. This is especially important for applications that require the beam to travel long distances (e.g., power transmission) or interact with precise optical components. In short, collimating optics (e.g., collimating optics 110) make a celestial energy beam (e.g., celestial energy beam 40) straighter and more focused over distance, improving its usability and efficiency in various optical systems.

Focusing optics (e.g., focusing optics 112) do the opposite of collimating optics (e.g., collimating optics 110), as they take a celestial energy beam (e.g., celestial energy beam 40) and converge it to a point or a small spot. This is usually achieved with lenses or curved mirrors that bend the incoming rays inward, concentrating the beam's energy into a smaller area. When a collimated or diverging celestial energy beam (e.g., celestial energy beam 40) passes through focusing optics (e.g., focusing optics 112), the optics manipulate the beam's path so that all rays come together at a focal point.

Energy acquisition and delivery process 300 may initiate 2802 a location sweeping operation having a first scanning resolution. The location sweeping operation may include a sweeping operation that initiates at an initial point (e.g., initial point 236) and spirals outwardly away from the initial point (e.g., initial point 236). Concerning the first scanning resolution, such scanning resolution may refer to the size of the area scanned by each scanning operation that is used to form the sweeping operation. For this example, assume that the first scanning resolution is a 500 foot diameter circle, which is the diameter of celestial energy beam 40 when it strikes the surface of Earth 16 proximate electromagnetic radiation energy receiver 200.

Continuing with this example, energy acquisition and delivery process 300 may initiate 2802 the location sweeping operation by scanning a 500 foot diameter circle at initial point 236. If no feedback (e.g., feedback 234) is received during this first scanning operation, this lack of feedback (e.g., feedback 234) indicates that electromagnetic radiation energy receiver 200 is not located within this 500 foot diameter circle and the location sweeping operation may spiral outwardly away from initial point 236.

As discussed above, energy acquisition and delivery process 300 may spiral outwardly away from initial point 236 and continue the location sweeping operation from a new point (e.g., point 236A) that is spaced radially away from initial point 236. Again, assume that energy acquisition and delivery process 300 begins repeatedly scanning 500 foot diameter circles while moving in the direction of arrow 850 to form a ring around the initial 500 foot diameter circle (that is positioned at initial point 236). During each of these 500 foot diameter scans, energy acquisition and delivery process 300 may monitor for feedback (e.g., feedback 234) in an attempt to locate the electromagnetic radiation energy receiver (e.g., electromagnetic radiation energy receiver 200). As discussed above, if feedback (e.g., feedback 234) is not received from electromagnetic radiation energy receiver 200 during any of these scanning operations, such a lack of feedback indicates that electromagnetic radiation energy receiver 200 is not positioned within the 500 foot diameter circle that is currently being scanned while moving along arrow 850.

Assume that no feedback is received while scanning each of the 500 foot diameter circles positioned along arrow 850, thus indicating that electromagnetic radiation energy receiver 200 is not located within any of these 500 foot diameter circles. Again, the location sweeping operation may spiral outwardly further away from initial point 236 and continue the location sweeping operation at a new point (e.g., point 238B) that is spaced even further radially away from initial point 236. For this example, assume that energy acquisition and delivery process 300 begins repeatedly scanning 500 foot diameter circles while moving in the direction of arrow 850A to form a second (and more distal) ring around the initial 500 foot diameter circle positioned at initial point 236.

As discussed above, energy acquisition and delivery process 300 may repeat this process until feedback (e.g., feedback 234) is received from electromagnetic radiation energy receiver 200, thus indicating that electromagnetic radiation energy receiver 200 has been located.

At some point during this sweeping operation, energy acquisition and delivery process 300 may receive 2804 feedback (e.g., feedback 234) from the electromagnetic radiation energy receiver (e.g., electromagnetic radiation energy receiver 200) at a defined point (e.g., defined point 238) within the location sweeping operation.

This feedback (e.g., feedback 234) may be generated via one or more feedback devices (e.g., feedback devices 226) included within the electromagnetic radiation energy receiver (e.g., electromagnetic radiation energy receiver 200). As discussed above, the one or more feedback devices (e.g., feedback devices 226) included within the electromagnetic radiation energy receiver (e.g., electromagnetic radiation energy receiver 200) may include: a centrally-positioned feedback device within the electromagnetic radiation energy receiver (e.g., electromagnetic radiation energy receiver 200) and a plurality of peripherally-positioned feedback devices within the electromagnetic radiation energy receiver (e.g., electromagnetic radiation energy receiver 200).

At least one of the feedback devices (e.g., feedback devices 226) may be a retroreflector. As discussed above, a retroreflector is a specialized feedback device or surface that reflects incoming electromagnetic radiation (e.g., a portion of celestial energy beam 40) directly back toward its source (e.g., electromagnetic radiation energy source 38), regardless of the angle at which celestial energy beam 40 arrives. Unlike a standard mirror, which reflects light at an angle equal to the incident angle, a retroreflector returns celestial energy beam 40 along a near-exact path from which it came through geometric structures (e.g., corner cubes, cat's-eye lenses, or Bragg gratings).

As discussed above, the feedback devices (e.g., feedback devices 226) may include an RF component. Specifically, feedback devices 226 may include a plurality of opto-electrical sensors (e.g., photodiodes, photodetectors and/or photovoltaic cells). This plurality of sensors (e.g., feedback devices 226) may monitor the position of celestial energy beam 40, which is received on electromagnetic radiation energy receiver 200 from electromagnetic radiation energy source 38. This information concerning beam alignment (i.e., the manner in which celestial energy beam 40 is striking electromagnetic radiation energy receiver 200) may be provided to an RF transmitter (e.g., wireless communication system 332) that is included within/coupled to/available to electromagnetic radiation energy receiver 200 so that such information may be transmitted to the electromagnetic radiation energy source (e.g., electromagnetic radiation energy source 38). This information may then be used by electromagnetic radiation energy source 38 to reposition celestial energy beam 40 via beam aiming assembly 102 (if adjustment is needed).

This feedback (e.g., feedback 234) may be received on feedback receiving devices (e.g., feedback receiving devices 128) included within electromagnetic radiation energy source 38, wherein such feedback receiving devices (e.g., feedback receiving devices 128) may include but are not limited to one or more of: one or more photovoltaic cells; one or more photodiodes; one or more heat engines; and one or more rectenna arrays.

During each of these 500 foot diameter scans along arrow 850A, energy acquisition and delivery process 300 may monitor for feedback (e.g., feedback 234) in an attempt to locate the electromagnetic radiation energy receiver (e.g., electromagnetic radiation energy receiver 200). Again, if feedback (e.g., feedback 234) is not received from electromagnetic radiation energy receiver 200 during a scanning operation, such a lack of feedback indicates that electromagnetic radiation energy receiver 200 is not positioned within the 500 foot diameter circles being scanned while moving in the direction of arrow 850A.

Continuing with this example, assume that feedback (e.g., feedback 234) is received 2804 by energy acquisition and delivery process 300 from a specific 500 foot diameter circle (e.g., circle 852) positioned along arrow 850A, thus indicating that electromagnetic radiation energy receiver 200 is positioned therein and identifying a defined point (e.g., defined point 238) within the location sweeping operation

In response to such feedback being received, energy acquisition and delivery process 300 may reinitiate 2806 the location sweeping operation at the defined point (e.g., defined point 238) at a second resolution that is finer than the first resolution. Specifically, this new location sweeping operation may be centered about (and spiral outwardly from) defined point 238. Continuing with this example, assume that the second scanning resolution is a 250 foot diameter circle, which is the diameter of celestial energy beam 40 when it strikes the surface of Earth 16 at defined point 238.

Continuing with this example, energy acquisition and delivery process 300 may reinitiate 2806 the location sweeping operation by scanning a 250 foot diameter circle (e.g., circle 856) at defined point 238. If no feedback is received, this indicates that electromagnetic radiation energy receiver 200 is not located within this 250 foot diameter circle (e.g., circle 856) at defined point 238. Accordingly, this initial 250 foot diameter scan may be sequentially surrounded by a first ring of 250 foot diameter scans along arrow 854, wherein this scanning process may be repeated until feedback is received and the location of electromagnetic radiation energy receiver 200 is defined.

Specifically and in response to this lack of feedback, energy acquisition and delivery process 300 may spiral outwardly from defined point 238 and begin repeatedly scanning 250 foot diameter circles while moving in the direction of arrow 858 to form a ring around circle 856 positioned at defined point 238. During each of these 250 foot diameter scans, energy acquisition and delivery process 300 may monitor for feedback (e.g., feedback 234) from the electromagnetic radiation energy receiver (e.g., electromagnetic radiation energy receiver 200).

Energy acquisition and delivery process 300 may receive 2808 updated feedback (e.g., feedback 234) from the electromagnetic radiation energy receiver (e.g., electromagnetic radiation energy receiver 200) at an updated point (e.g., updated point 240) within the location sweeping operation, further refining the location of the electromagnetic radiation energy receiver (e.g., electromagnetic radiation energy receiver 200).

Continuing with this example, assume that updated feedback (e.g., feedback 234) is received 2808 by energy acquisition and delivery process 300 from a 250 foot diameter scan within the first ring of scans positioned along arrow 858 that surrounds the initial 250 foot diameter scan at defined point 238, thus identifying the updated point (e.g., defined point 240) within the location sweeping operation

As discussed above, energy acquisition and delivery process 300 may repeatedly reinitiate 2810 the location sweeping operation at increasingly finer resolutions until feedback (e.g., feedback 234) is received from the electromagnetic radiation energy receiver (e.g., electromagnetic radiation energy receiver 200) that identifies a point within the location sweeping operation that defines a peak return power. This point, in turn, defines a location (e.g., receiver location 242) for the electromagnetic radiation energy receiver (e.g., electromagnetic radiation energy receiver 200).

For example, each time new feedback (e.g., feedback 234) is received from electromagnetic radiation energy receiver 200, subsequent sweeping operations may be initiated by energy acquisition and delivery process 300 at increasingly finer resolutions (e.g., 500 feet→250 feet→125 feet→62.5 feet) until the peak return power is identified, at which point the location of the electromagnetic radiation energy receiver (e.g., electromagnetic radiation energy receiver 200) will be deemed to be sufficiently defined. In the interest of brevity, assume that this location (e.g., receiver location 242) is updated point 240. For example, shrinking the search region may be accomplished by a) decreasing the divergence of the celestial energy beam (e.g., celestial energy beam 40) and looking for any nonzero feedback, or b) by keeping the divergence of the celestial energy beam (e.g., celestial energy beam 40) the same and choosing the region that has the brightest feedback.

Once sufficiently located, energy acquisition and delivery process 300 may direct 2812 the celestial energy beam (e.g., celestial energy beam 40) toward the location (e.g., receiver location 242) of the electromagnetic radiation energy receiver (e.g., electromagnetic radiation energy receiver 200).

Additionally, energy acquisition and delivery process 300 may periodically reinitiate 2814 the location sweeping operation until feedback (e.g., feedback 234) is received from the electromagnetic radiation energy receiver (e.g., electromagnetic radiation energy receiver 200) that identifies an updated point within the location sweeping operation that defines the peak return power, thus defining an updated location (e.g., updated location 244) for the electromagnetic radiation energy receiver (e.g., electromagnetic radiation energy receiver 200).

Energy acquisition and delivery process 300 may redirect 2816 the celestial energy beam (e.g., celestial energy beam 40) toward the updated location (e.g., updated location 244) of the electromagnetic radiation energy receiver (e.g., electromagnetic radiation energy receiver 200).

### (34) Methodologies for Locating a Ground-Based Receiver Via a Longitudinal Feedback Axis.

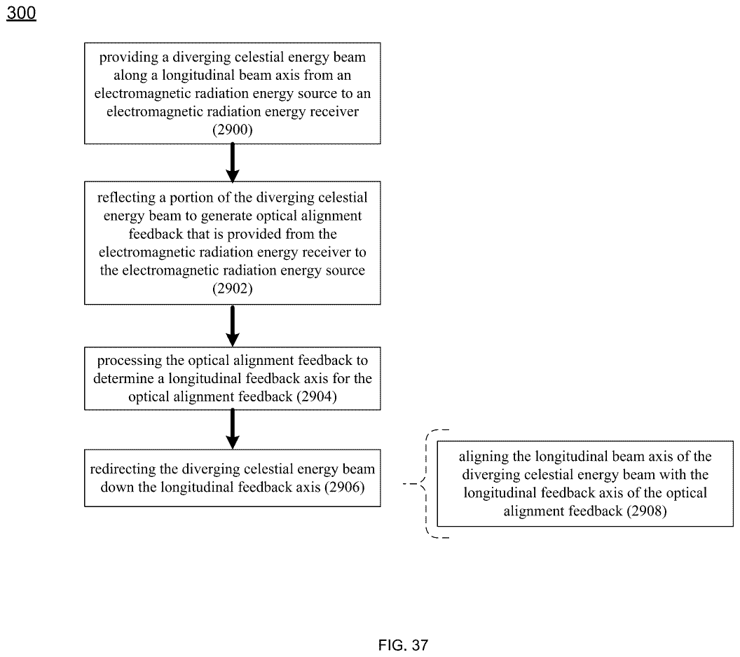

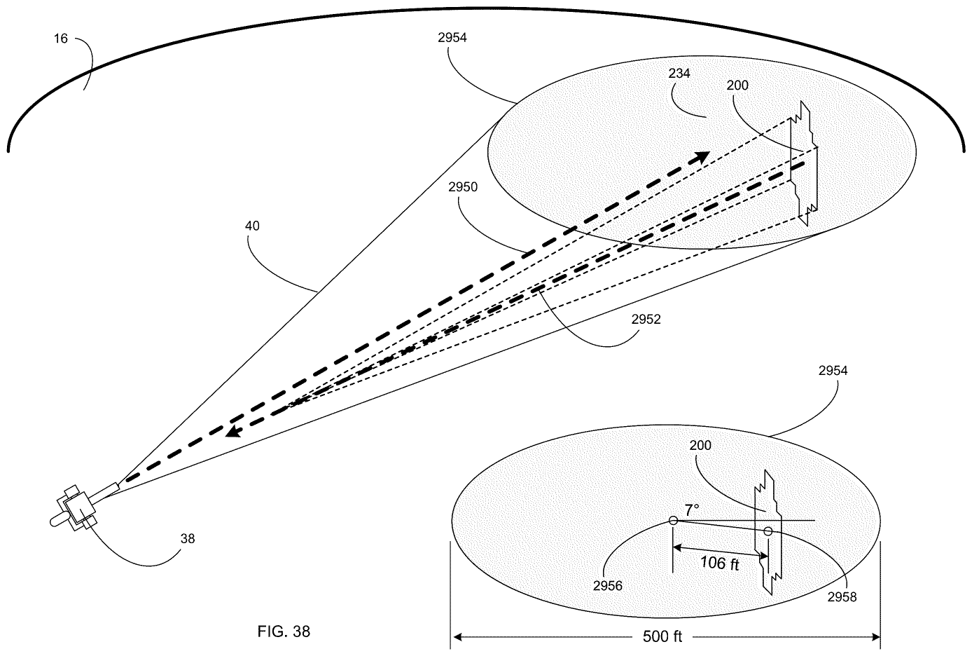

Referring also to FIGS. 37-38, the following discussion concerns the manner in which energy acquisition and delivery process 300 may locate an electromagnetic radiation energy receiver (e.g., electromagnetic radiation energy receiver 200) based upon a longitudinal feedback axis for optical alignment feedback.

Energy acquisition and delivery process 300 may provide 2900 a diverging celestial energy beam (e.g., celestial energy beam 40) along a longitudinal beam axis (e.g., longitudinal beam axis 2950) from an electromagnetic radiation energy source (e.g., electromagnetic radiation energy source 38) to an electromagnetic radiation energy receiver (e.g., electromagnetic radiation energy receiver 200).

As discussed above, while this diverging celestial energy beam (e.g., celestial energy beam 40) is typically transmitted from a space-based electromagnetic radiation energy source (e.g., electromagnetic radiation energy source 38) to a ground-based electromagnetic radiation energy receiver (e.g., electromagnetic radiation energy receiver 200), this is for illustrative purposes only and is not intended to be a limitation of this disclosure, as other configurations are possible and are considered to be within the scope of this disclosure. For example and in some configurations, this diverging celestial energy beam (e.g., celestial energy beam 40) may be transmitted from a ground-based electromagnetic radiation energy source (e.g., electromagnetic radiation energy source 38G) to a space-based electromagnetic radiation energy receiver (e.g., electromagnetic radiation energy receiver 200S).

As discussed above and for providing 2900 a diverging celestial energy beam (e.g., celestial energy beam 40), the electromagnetic radiation energy source (e.g., electromagnetic radiation energy source 38) may include: an energy beam source (e.g., energy beam source 100) for generating the diverging celestial energy beam (e.g., celestial energy beam 40); a beam aiming assembly (e.g., beam aiming assembly 102) for steering the diverging celestial energy beam (e.g., celestial energy beam 40) toward a target; and a beam forming package (e.g., beam forming package 104) for forming the diverging celestial energy beam (e.g., celestial energy beam 40).

The energy beam source (e.g., energy beam source 100) for generating the diverging celestial energy beam (e.g., celestial energy beam 40) may include one or more of: a visible-light laser beam source; an Infrared laser beam source; a short wavelength Infrared laser beam source, a mid-Infrared laser beam source; a near-Infrared laser beam source; and a microwave beam source.

The beam aiming assembly (e.g., beam aiming assembly 102) for steering the diverging celestial energy beam (e.g., celestial energy beam 40) may include: a Gimbal mount assembly (e.g., Gimbal mount assembly 106) configured to direct the diverging celestial energy beam (e.g., celestial energy beam 40) toward a target; a phased array assembly (e.g., phased array assembly 107) configured to direct the celestial energy beam (e.g., celestial energy beam 40) toward a target and/or a periscope assembly (e.g., periscope assembly 108) configured to direct the diverging celestial energy beam (e.g., celestial energy beam 40) toward a target. A Gimbal mount assembly (e.g., Gimbal mount assembly 106), a phased array assembly (e.g., phased array assembly 107) and a periscope assembly (e.g., periscope assembly 108) can be effectively used in space-based energy systems to accurately direct a diverging celestial energy beam (e.g., celestial energy beam 40), such as a laser or microwave beam, from a satellite (e.g., satellite 14) to a electromagnetic radiation energy receiver (e.g., electromagnetic radiation energy receiver 200).

The beam forming package (e.g., beam forming package 104) for forming the diverging celestial energy beam (e.g., celestial energy beam 40) may include: collimating optics (e.g., collimating optics 110); and focusing optics (e.g., focusing optics 112). Collimating optics (e.g., collimating optics 110) are used to shape a diverging celestial energy beam (e.g., celestial energy beam 40) so that its rays are parallel, resulting in a collimated beam i.e., one that doesn't spread out (diverge) significantly over distance. When a diverging celestial energy beam (e.g., celestial energy beam 40) exits a source (e.g., energy beam source 100) like a diode, it typically diverges, meaning the beam spreads out as it travels.

Collimating optics (e.g., collimating optics 110), such as a lens or a lens system, are placed in the beam path to correct this divergence. By focusing the light emerging from a point-like or narrow source, collimating optics (e.g., collimating optics 110) create a beam with minimal angular spread. This is especially important for applications that require the beam to travel long distances (e.g., power transmission) or interact with precise optical components. In short, collimating optics (e.g., collimating optics 110) make a diverging celestial energy beam (e.g., celestial energy beam 40) straighter and more focused over distance, improving its usability and efficiency in various optical systems.

Focusing optics (e.g., focusing optics 112) do the opposite of collimating optics (e.g., collimating optics 110), as they take a diverging celestial energy beam (e.g., celestial energy beam 40) and converge it to a point or a small spot. This is usually achieved with lenses or curved mirrors that bend the incoming rays inward, concentrating the beam's energy into a smaller area. When a collimated or diverging celestial energy beam (e.g., celestial energy beam 40) passes through focusing optics (e.g., focusing optics 112), the optics manipulate the beam's path so that all rays come together at a focal point.

Energy acquisition and delivery process 300 may reflect 2902 a portion of the diverging celestial energy beam (e.g., celestial energy beam 40) to generate optical alignment feedback (e.g., feedback 234) that is provided from the electromagnetic radiation energy receiver (e.g., electromagnetic radiation energy receiver 200) to the electromagnetic radiation energy source (e.g., electromagnetic radiation energy source 38). The optical alignment feedback (e.g., feedback 234) may concern the level of alignment of the diverging celestial energy beam (e.g., celestial energy beam 40) at the point of striking the electromagnetic radiation energy receiver (e.g., electromagnetic radiation energy receiver 200).

This optical alignment feedback (e.g., feedback 234) may be generated via one or more feedback devices (e.g., feedback devices 226) included within the electromagnetic radiation energy receiver (e.g., electromagnetic radiation energy receiver 200). As discussed above, the one or more feedback devices (e.g., feedback devices 226) included within the electromagnetic radiation energy receiver (e.g., electromagnetic radiation energy receiver 200) may include: a centrally-positioned feedback device within the electromagnetic radiation energy receiver (e.g., electromagnetic radiation energy receiver 200) and a plurality of peripherally-positioned feedback devices within the electromagnetic radiation energy receiver (e.g., electromagnetic radiation energy receiver 200).

At least one of the feedback devices (e.g., feedback devices 226) may be a retroreflector. As discussed above, a retroreflector is a specialized feedback device or surface that reflects incoming electromagnetic radiation (e.g., a portion of celestial energy beam 40) directly back toward its source (e.g., electromagnetic radiation energy source 38), regardless of the angle at which celestial energy beam 40 arrives. Unlike a standard mirror, which reflects light at an angle equal to the incident angle, a retroreflector returns celestial energy beam 40 along a near-exact path from which it came through geometric structures (e.g., corner cubes, cat's-eye lenses, or Bragg gratings).

As discussed above, the feedback devices (e.g., feedback devices 226) may include an RF component. Specifically, feedback devices 226 may include a plurality of opto-electrical sensors (e.g., photodiodes, photodetectors and/or photovoltaic cells). This plurality of sensors (e.g., feedback devices 226) may monitor the position of celestial energy beam 40, which is received on electromagnetic radiation energy receiver 200 from electromagnetic radiation energy source 38. This information concerning beam alignment (i.e., the manner in which celestial energy beam 40 is striking electromagnetic radiation energy receiver 200) may be provided to an RF transmitter (e.g., wireless communication system 332) that is included within/coupled to/available to electromagnetic radiation energy receiver 200 so that such information may be transmitted to the electromagnetic radiation energy source (e.g., electromagnetic radiation energy source 38). This information may then be used by electromagnetic radiation energy source 38 to reposition celestial energy beam 40 via beam aiming assembly 102 (if adjustment is needed).

This optical alignment feedback (e.g., feedback 234) may be received on feedback receiving devices (e.g., feedback receiving devices 128) included within electromagnetic radiation energy source 38, wherein such feedback receiving devices (e.g., feedback receiving devices 128) may include but are not limited to one or more of: one or more photovoltaic cells; one or more photodiodes; one or more heat engines; and one or more rectenna arrays.

Energy acquisition and delivery process 300 may process 2904 the optical alignment feedback (e.g., feedback 234) to determine a longitudinal feedback axis (e.g., longitudinal feedback axis 2952) for the optical alignment feedback (e.g., feedback 234).

Assume for this example that the diverging celestial energy beam (e.g., celestial energy beam 40) has a diameter of 500 feet when it strikes the ground, resulting in footprint 2954. Accordingly, an example of the manner in which energy acquisition and delivery process 300 may process 2904 the optical alignment feedback (e.g., feedback 234) to determine a longitudinal feedback axis (e.g., longitudinal feedback axis 2952) for the optical alignment feedback (e.g., feedback 234) may be via the use of polar coordinates.

As is known in the art, polar coordinates are a method of representing points in a plane using a distance and an angle, rather than the traditional x and y values found in Cartesian coordinates. In this system, a point is defined by two values: (R), the distance from the origin; and (θ), the angle measured from the positive x-axis, usually in radians or degrees. To locate a point, you move R units away from the origin in the direction specified by (θ). Polar coordinates are particularly useful when dealing with circular or rotational motion, where the relationship between points is better described using angles and radii rather than horizontal and vertical distances.

Assume for this example that point 2956 represents the center of 500 foot diameter footprint 2954 of celestial energy beam 40 when it strikes the ground (e.g., the surface of earth 16). Accordingly, point 2956 also is the location where the longitudinal beam axis (e.g., longitudinal beam axis 2950) of the diverging celestial energy beam (e.g., celestial energy beam 40) strikes the ground. Assume that within this 500 foot diameter footprint (e.g., foot print 2954), the origin (e.g., origin 2958) of feedback 234 is at an angle of 7° with respect to the positive x-axis and at a distance of 106 feet from the cartesian origin (e.g., point 2956). Accordingly and by knowing the distance that celestial energy beam 40 travels from electromagnetic radiation energy source 38 to the surface of Earth 16, a vector may be defined for the longitudinal feedback axis (e.g., longitudinal feedback axis 2950).

As stated above, this above-described method for processing 2904 the optical alignment feedback (e.g., feedback 234) to determine a longitudinal feedback axis (e.g., longitudinal feedback axis 2952) for the optical alignment feedback (e.g., feedback 234) is for illustrative purposes only and is not intended to be a limitation of this disclosure, as other configurations are possible and are considered to be within the scope of this disclosure.

Accordingly, energy acquisition and delivery process 300 may redirect 2906 the diverging celestial energy beam (e.g., celestial energy beam 40) down the longitudinal feedback axis (e.g., longitudinal feedback axis 2952). For example and when redirecting 2906 the diverging celestial energy beam (e.g., celestial energy beam 40) down the longitudinal feedback axis (e.g., longitudinal feedback axis 2952), energy acquisition and delivery process 300 may align 2908 the longitudinal beam axis (e.g., longitudinal beam axis 2950) of the diverging celestial energy beam (e.g., celestial energy beam 40) with the longitudinal feedback axis (e.g., longitudinal feedback axis 2952) of the optical alignment feedback (e.g., feedback 234).

As discussed above, at least one of the feedback devices (e.g., feedback devices 226) may be a retroreflector, wherein a retroreflector reflects incoming electromagnetic radiation (e.g., a portion of celestial energy beam 40) directly back toward its source (e.g., electromagnetic radiation energy source 38) regardless of the angle at which celestial energy beam 40 arrives. Accordingly, the longitudinal feedback axis (e.g., longitudinal feedback axis 2952) defines a direct path to (in the example) the electromagnetic radiation energy receiver (e.g., electromagnetic radiation energy receiver 200). Therefore, by aligning 2908 the longitudinal beam axis (e.g., longitudinal beam axis 2950) of the diverging celestial energy beam (e.g., celestial energy beam 40) with the longitudinal feedback axis (e.g., longitudinal feedback axis 2952) of the optical alignment feedback (e.g., feedback 234), the footprint (e.g., footprint 2954) of the celestial energy beam (e.g., celestial energy beam 40) will be centered on the electromagnetic radiation energy receiver (e.g., electromagnetic radiation energy receiver 200).

As discussed above, the one or more feedback devices (e.g., feedback devices 226) included within the electromagnetic radiation energy receiver (e.g., electromagnetic radiation energy receiver 200) may include: a centrally-positioned feedback device within the electromagnetic radiation energy receiver (e.g., electromagnetic radiation energy receiver 200) and a plurality of peripherally-positioned feedback devices within the electromagnetic radiation energy receiver (e.g., electromagnetic radiation energy receiver 200).

Accordingly it is foreseeable that there may be a plurality of longitudinal feedback axes (e.g., longitudinal feedback axis 2952). Accordingly, energy acquisition and delivery process 300 may be configured to select the appropriate longitudinal feedback axis (e.g., longitudinal feedback axis 2952). For example, energy acquisition and delivery process 300 may select the longitudinal feedback axis that is centrally positioned within the electromagnetic radiation energy receiver (e.g., electromagnetic radiation energy receiver 200).

### General:

As will be appreciated by one skilled in the art, the present disclosure may be embodied as a method, a system, or a computer program product. Accordingly, the present disclosure may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, the present disclosure may take the form of a computer program product on a computer-usable storage medium having computer-usable program code embodied in the medium.

Any suitable computer usable or computer readable medium may be utilized. The computer-usable or computer-readable medium may be, for example but not limited to, an electronic, magnetic, optical, electromagnetic, Infrared, or semiconductor system, apparatus, device, or propagation medium. More specific examples (a non-exhaustive list) of the computer-readable medium may include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a transmission media such as those supporting the Internet or an intranet, or a magnetic storage device. The computer-usable or computer-readable medium may also be paper or another suitable medium upon which the program is printed, as the program can be electronically captured, via, for instance, optical scanning of the paper or other medium, then compiled, interpreted, or otherwise processed in a suitable manner, if necessary, and then stored in a computer memory. In the context of this document, a computer-usable or computer-readable medium may be any medium that can contain, store, communicate, propagate, or transport the program for use by or in connection with the instruction execution system, apparatus, or device. The computer-usable medium may include a propagated data signal with the computer-usable program code embodied therewith, either in baseband or as part of a carrier wave. The computer usable program code may be transmitted using any appropriate medium, including but not limited to the Internet, wireline, optical fiber cable, RF, etc.

Computer program code for carrying out operations of the present disclosure may be written in an object oriented programming language such as Java, Smalltalk, C++ or the like. However, the computer program code for carrying out operations of the present disclosure may also be written in conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through a local area network/a wide area network/the Internet (e.g., network 14).

The present disclosure is described with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, may be implemented by computer program instructions. These computer program instructions may be provided to a processor of a general purpose computer/special purpose computer/other programmable legal research processing apparatus, such that the instructions, which execute via the processor of the computer or other programmable legal research processing apparatus, create means for implementing the functions/acts specified in the flowchart and/or block diagram block or blocks.

These computer program instructions may also be stored in a computer-readable memory that may direct a computer or other programmable legal research processing apparatus to function in a particular manner, such that the instructions stored in the computer-readable memory produce an article of manufacture including instruction means which implement the function/act specified in the flowchart and/or block diagram block or blocks.

The computer program instructions may also be loaded onto a computer or other programmable legal research processing apparatus to cause a series of operational steps to be performed on the computer or other programmable apparatus to produce a computer implemented process such that the instructions which execute on the computer or other programmable apparatus provide steps for implementing the functions/acts specified in the flowchart and/or block diagram block or blocks.

The flowcharts and block diagrams in the figures may illustrate the architecture, functionality, and operation of possible implementations of systems, methods and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustrations, and combinations of blocks in the block diagrams and/or flowchart illustrations, may be implemented by special purpose hardware-based systems that perform the specified functions or acts, or combinations of special purpose hardware and computer instructions.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

A number of implementations have been described. Having thus described the disclosure of the present application in detail and by reference to embodiments thereof, it will be apparent that modifications and variations are possible without departing from the scope of the disclosure defined in the appended claims.

What is claimed is:

1. A computer-implemented method, executed on a computing device, comprising:
enabling an electromagnetic radiation energy receiver on a terrestrial vehicle;
providing a celestial energy beam from an electromagnetic radiation energy source toward the electromagnetic radiation energy receiver;
providing alignment feedback to the electromagnetic radiation energy source via one or more feedback devices included within the electromagnetic radiation energy receiver; and
performing an initial alignment procedure based upon the alignment feedback received from the electromagnetic radiation energy receiver to initially align the celestial energy beam with the electromagnetic radiation energy receiver on the terrestrial vehicle.

2. The computer-implemented method of claim 1 wherein the one or more feedback devices included within the electromagnetic radiation energy receiver includes one or more of:
a centrally-positioned feedback device within the electromagnetic radiation energy receiver; and
a plurality of peripherally-positioned feedback devices within the electromagnetic radiation energy receiver.

3. The computer-implemented method of claim 1 wherein at least one of the feedback devices is a retroreflector.

4. The computer-implemented method of claim 1 wherein performing an initial alignment procedure based upon the alignment feedback received from the electromagnetic radiation energy receiver to initially align the celestial energy beam with the electromagnetic radiation energy receiver on the terrestrial vehicle includes:
reducing the energy density of the celestial energy beam;
aligning the celestial energy beam with the electromagnetic radiation energy receiver on the terrestrial vehicle; and
increasing the energy density of the celestial energy beam.

5. The computer-implemented method of claim 4 wherein reducing the energy density of the celestial energy beam includes one or more of:
increasing the divergence of the celestial energy beam; and
reducing the power of the celestial energy beam.

6. The computer-implemented method of claim 4 wherein aligning the celestial energy beam with the electromagnetic radiation energy receiver on the terrestrial vehicle includes:
initiating a location sweeping operation;
receiving feedback from the electromagnetic radiation energy receiver at a defined point within the location sweeping operation;
reinitiating the location sweeping operation at the defined point; and
receiving updated feedback from the electromagnetic radiation energy receiver at an updated point within the location sweeping operation.

7. The computer-implemented method of claim 6 wherein aligning the celestial energy beam with the electromagnetic radiation energy receiver on the terrestrial vehicle further includes:
repeatedly reinitiating the location sweeping operation until feedback is received from the electromagnetic radiation energy receiver that identifies a point within the location sweeping operation that defines a peak return power, thus defining a location for the electromagnetic radiation energy receiver.

8. The computer-implemented method of claim 4 wherein increasing the energy density of the celestial energy beam includes one or more of:
decreasing the divergence of the celestial energy beam; and
increasing the power of the celestial energy beam.

9. The computer-implemented method of claim 1 wherein the electromagnetic radiation energy source includes:
a energy beam source; and
a beam forming package.

10. The computer-implemented method of claim 1 further comprising:
periodically performing a realignment procedure based upon alignment feedback received from the electromagnetic radiation energy receiver to realign the celestial energy beam with the electromagnetic radiation energy receiver to offset movement of the terrestrial vehicle.

11. A computer program product residing on a computer readable medium having a plurality of instructions stored thereon which, when executed by a processor, cause the processor to perform operations comprising:
enabling an electromagnetic radiation energy receiver on a terrestrial vehicle;
providing a celestial energy beam from an electromagnetic radiation energy source toward the electromagnetic radiation energy receiver;
providing alignment feedback to the electromagnetic radiation energy source via one or more feedback devices included within the electromagnetic radiation energy receiver; and
performing an initial alignment procedure based upon the alignment feedback received from the electromagnetic radiation energy receiver to initially align the celestial energy beam with the electromagnetic radiation energy receiver on the terrestrial vehicle.

12. The computer program product of claim 11 wherein the one or more feedback devices included within the electromagnetic radiation energy receiver includes one or more of:
a centrally-positioned feedback device within the electromagnetic radiation energy receiver; and
a plurality of peripherally-positioned feedback devices within the electromagnetic radiation energy receiver.

13. The computer program product of claim 11 wherein at least one of the feedback devices is a retroreflector.

14. The computer program product of claim 11 wherein performing an initial alignment procedure based upon the alignment feedback received from the electromagnetic radiation energy receiver to initially align the celestial energy beam with the electromagnetic radiation energy receiver on the terrestrial vehicle includes:
reducing the energy density of the celestial energy beam;
aligning the celestial energy beam with the electromagnetic radiation energy receiver on the terrestrial vehicle; and
increasing the energy density of the celestial energy beam.

15. The computer program product of claim 14 wherein reducing the energy density of the celestial energy beam includes one or more of:
increasing the divergence of the celestial energy beam; and
reducing the power of the celestial energy beam.

16. The computer program product of claim 14 wherein aligning the celestial energy beam with the electromagnetic radiation energy receiver on the terrestrial vehicle includes:
initiating a location sweeping operation;
receiving feedback from the electromagnetic radiation energy receiver at a defined point within the location sweeping operation;
reinitiating the location sweeping operation at the defined point; and
receiving updated feedback from the electromagnetic radiation energy receiver at an updated point within the location sweeping operation.

17. The computer program product of claim 16 wherein aligning the celestial energy beam with the electromagnetic radiation energy receiver on the terrestrial vehicle further includes:
repeatedly reinitiating the location sweeping operation until feedback is received from the electromagnetic radiation energy receiver that identifies a point within the location sweeping operation that defines a peak return power, thus defining a location for the electromagnetic radiation energy receiver.

18. The computer program product of claim 14 wherein increasing the energy density of the celestial energy beam includes one or more of:
decreasing the divergence of the celestial energy beam; and
increasing the power of the celestial energy beam.

19. The computer program product of claim 11 wherein the electromagnetic radiation energy source includes:
a energy beam source; and
a beam forming package.

20. The computer program product of claim 11 further comprising:
periodically performing a realignment procedure based upon alignment feedback received from the electromagnetic radiation energy receiver to realign the celestial energy beam with the electromagnetic radiation energy receiver to offset movement of the terrestrial vehicle.

21. A computing system including a processor and memory configured to perform operations comprising:
enabling an electromagnetic radiation energy receiver on a terrestrial vehicle;
providing a celestial energy beam from an electromagnetic radiation energy source toward the electromagnetic radiation energy receiver;
providing alignment feedback to the electromagnetic radiation energy source via one or more feedback devices included within the electromagnetic radiation energy receiver; and
performing an initial alignment procedure based upon the alignment feedback received from the electromagnetic radiation energy receiver to initially align the celestial energy beam with the electromagnetic radiation energy receiver on the terrestrial vehicle.

22. The computing system of claim 21 wherein the one or more feedback devices included within the electromagnetic radiation energy receiver includes one or more of:
a centrally-positioned feedback device within the electromagnetic radiation energy receiver; and
a plurality of peripherally-positioned feedback devices within the electromagnetic radiation energy receiver.

23. The computing system of claim 21 wherein at least one of the feedback devices is a retroreflector.

24. The computing system of claim 21 wherein performing an initial alignment procedure based upon the alignment feedback received from the electromagnetic radiation energy receiver to initially align the celestial energy beam with the electromagnetic radiation energy receiver on the terrestrial vehicle includes:
reducing the energy density of the celestial energy beam;
aligning the celestial energy beam with the electromagnetic radiation energy receiver on the terrestrial vehicle; and
increasing the energy density of the celestial energy beam.

25. The computing system of claim 24 wherein reducing the energy density of the celestial energy beam includes one or more of:
increasing the divergence of the celestial energy beam; and
reducing the power of the celestial energy beam.

26. The computing system of claim 24 wherein aligning the celestial energy beam with the electromagnetic radiation energy receiver on the terrestrial vehicle includes:
initiating a location sweeping operation;
receiving feedback from the electromagnetic radiation energy receiver at a defined point within the location sweeping operation;
reinitiating the location sweeping operation at the defined point; and
receiving updated feedback from the electromagnetic radiation energy receiver at an updated point within the location sweeping operation.

27. The computing system of claim 26 wherein aligning the celestial energy beam with the electromagnetic radiation energy receiver on the terrestrial vehicle further includes:
repeatedly reinitiating the location sweeping operation until feedback is received from the electromagnetic radiation energy receiver that identifies a point within the location sweeping operation that defines a peak return power, thus defining a location for the electromagnetic radiation energy receiver.

28. The computing system of claim 24 wherein increasing the energy density of the celestial energy beam includes one or more of:
decreasing the divergence of the celestial energy beam; and
increasing the power of the celestial energy beam.

29. The computing system of claim 21 wherein the electromagnetic radiation energy source includes:
a energy beam source; and
a beam forming package.

30. The computing system of claim 21 further comprising:
periodically performing a realignment procedure based upon alignment feedback received from the electromagnetic radiation energy receiver to realign the celestial energy beam with the electromagnetic radiation energy receiver to offset movement of the terrestrial vehicle.
